(19) United States
(12) Patent Application Publication
(10) Pub. No.: US 2017/0146908 A1
(43) Pub. Date: May 25, 2017

(54) PATTERN FORMING METHOD AND METHOD FOR MANUFACTURING ELECTRONIC DEVICE USING SAME

(71) Applicant: FUJIFILM Corporation, Tokyo (JP)

(72) Inventors: Michihiro SHIRAKAWA, Shizuoka (JP); Keita KATO, Shizuoka (JP)

(73) Assignee: FUJIFILM Corporation, Tokyo (JP)

(21) Appl. No.: 15/427,455

(22) Filed: Feb. 8, 2017

Related U.S. Application Data
(63) Continuation of application No. PCT/JP2015/070056, filed on Jul. 13, 2015.

(30) Foreign Application Priority Data
Aug. 22, 2014 (JP) 2014-169674

(51) Int. Cl. G03F 7/11; G03F 7/039; G03F 7/038; G03F 7/40; G03F 7/004; G03F 7/38; G03F 7/30; G03F 7/16; G03F 7/20

(52) U.S. Cl. CPC G03F 7/11; G03F 7/16; G03F 7/039; G03F 7/038; G03F 7/2006; G03F 7/0045; G03F 7/168; G03F 7/38; G03F 7/30; G03F 7/40

(57) ABSTRACT

Provided is a pattern forming method including (A) a step of forming a planarization layer on a stepped substrate by using a composition (a) for forming the planarization layer, the composition (a) containing a solvent, (B) a step of forming a resist film on the planarization layer by using a resist composition, (C) a step of subjecting the resist film to exposure, and (D) a step of forming a first pattern by developing the resist film having undergone exposure, in which the planarization layer having undergone the step (D) is dissolved in the solvent. By the pattern forming method, there are provided a pattern forming method, which makes it possible to form a high-resolution resist pattern on a ultrafine stepped substrate (for example, a stepped substrate having groove portions having a groove width of equal to or less than 40 nm and cylindrical depressions having a diameter of equal to or less than 40 nm) and to make the resist pattern exhibit excellent peeling properties in a resist pattern peeling step, a method for manufacturing an electronic device using the pattern forming method, and an electronic device.

### CROSS REFERENCE TO RELATED APPLICATION(S)

This is a continuation of International Application No. PCT/JP2015/070056 filed on Jul. 13, 2015, and claims priority from Japanese Patent Application No. 2014-169674 filed on Aug. 22, 2014, the entire disclosures of which are incorporated herein by reference.

### BACKGROUND OF THE INVENTION

1. Field of the Invention

The present invention relates to a pattern forming method, a method for manufacturing an electronic device using the pattern forming method, and an electronic device. More specifically, the present invention relates to a pattern forming method, which is suitable for a process of manufacturing a semiconductor such as IC, manufacturing of a circuit board of liquid crystals, thermal heads, and the like, and other photofabrication lithography processes, a method for manufacturing an electronic device using the pattern forming method, and an electronic device.

2. Description of the Related Art

A resist pattern, which is obtained by exposing and developing a resist film during ion implantation (charge injection) as one of the steps performed at the time of logic device fabrication or the like, plays an important role as a pattern that blocks ions in a specific region.

In a case where a resist composition is used for ion implantation, sometimes a substrate patterned in advance (hereinafter, referred to as a stepped substrate) is coated with the resist composition, exposed, and developed, and microfabrication needs to be performed on the stepped substrate.

As a technique for forming a resist pattern on a stepped substrate, a technique (see JP2012-133329A) of forming a resist film having a film thickness of equal to or greater than 200 nm on a stepped substrate and exposing and developing the resist film or a technique (see JP2012-215842A) of forming a resist underlayer film having excellent etching resistance and a resist film on a stepped substrate, forming a resist pattern by exposing and developing the resist film, and then etching the resist underlayer film by using the resist pattern as a mask is known.

### SUMMARY OF THE INVENTION

In recent years, it has been required for an excellent resist pattern to be formed on a ultrafine stepped substrate. In a case where an attempt is made to form a resist pattern on, for example, a stepped substrate having groove portions having a groove width of equal to or less than 40 nm or a stepped substrate having cylindrical depressions having a diameter of equal to or less than 40 nm so as to meet the aforementioned requirement, from the viewpoint of the resolution of the resist pattern and the peeling properties of the resist pattern after the ion implantation step, the methods used in the technique of the related art described above needs to be further improved.

The present invention has been made to solve the above problems, and an object thereof is to provide a pattern forming method, which makes it possible to form a high-resolution resist pattern on an ultrafine stepped substrate (for example, a stepped substrate having groove portions having a groove width of equal to or less than 40 nm and cylindrical depressions having a diameter of equal to or less than 40 nm) and makes the resist pattern exhibit excellent peeling properties in a resist pattern peeling step, a method for manufacturing an electronic device using the pattern forming method, and an electronic device.

The present invention has the following constitution, and the aforementioned object of the present invention is achieved by the constitution.

[1] A pattern forming method comprising (A) a step of forming a planarization layer on a stepped substrate by using a composition (a) for forming the planarization layer, the composition (a) containing a solvent, (B) a step of forming a resist film on the planarization layer by using a resist composition, (C) a step of subjecting the resist film to exposure, and (D) a step of forming a first pattern by developing the resist film having undergone exposure, in which the planarization layer having undergone the step (D) is dissolved in the solvent.

[2] The pattern forming method described in [1], in which the composition (a) does not contain a compound that causes a reaction triggered by at least either heat or light.

[3] The pattern forming method described in [1] or [2], in the planarization layer is substantially not developed by the step (D).

[4] The pattern forming method described in any one of [1] to [3], in which the step (D) is a step of forming a positive pattern as the first pattern by using an alkaline developer.

[5] The pattern forming method described in any one of [1] to [3], in which the step (D) is a step of forming a negative pattern as the first pattern by using a developer containing an organic solvent.

[6] The pattern forming method described in any one of [1] to [5], in which the planarization layer is a layer containing a resin having an Onishi parameter of equal to or greater than 3.0.

[7] The pattern forming method described in any one of [1] to [6], in which the first pattern contains a silicon atom.

[8] The pattern forming method described in any one of [1] to [7], in which the exposure in the step (C) is exposure performed using a KrF excimer laser.

[9] The pattern forming method described in any one of [1] to [7], in which the exposure in the step (C) is exposure performed using an ArF excimer laser.

[10] The pattern forming method described in any one of [1] to [9], further comprising (E) a step of forming a second pattern by performing an etching treatment on the planarization layer by using the first pattern as a mask, after the step (D).

[11] A method for manufacturing an electronic device, comprising the pattern forming method according to any one of claims 1 to 10.

According to the present invention, it is possible to provide a pattern forming method, which makes it possible to form a high-resolution resist pattern on a ultrafine stepped substrate (for example, a stepped substrate having groove portions having a groove width of equal to or less than 40 nm and cylindrical depressions having a diameter of equal to or less than 40 nm) and to make the resist pattern exhibit excellent peeling properties in a resist pattern peeling step, a method for manufacturing an electronic device using the pattern forming method, and an electronic device.

### BRIEF DESCRIPTION OF THE DRAWINGS

FIGS. 1A to 1F are schematic cross-sectional views for describing embodiments of the present invention.

### DESCRIPTION OF THE PREFERRED EMBODIMENTS

Hereinafter, embodiments of the present invention will be described.

In the present specification, regarding a description of a group (atomic group), in a case where there is no description regarding whether the group is substituted or unsubstituted, the group includes both of a group (atomic group) not having a substituent and a group (atomic group) having a substituent. For example, an “alkyl group” includes not only an alkyl group not having a substituent (unsubstituted alkyl group) but also an alkyl group having a substituent (substituted alkyl group).

In the present specification, “actinic rays” or “radiation” means, for example, a bright-line spectrum of a mercury lamp, far ultraviolet rays represented by an excimer laser, extreme ultraviolet rays (EUV light), X-rays, or electron beams. Furthermore, in the present invention, light means actinic rays or radiation.

In the present specification, “exposure” is not particularly limited, and includes not only exposure performed using a mercury lamp, far ultraviolet rays represented by an excimer laser, extreme ultraviolet rays, X-rays, EUV light, and the like but also lithography performed using electron beams and corpuscular beams such as ion beams.

The pattern forming method of the present invention is a pattern forming method including (A) a step of forming a planarization layer on a stepped substrate by using a composition for forming a planarization layer (a) containing a solvent, (B) a step of forming a resist film on the planarization layer by using a resist composition, (C) a step of subjecting the resist film to exposure, and (D) a step of forming a first pattern by developing the resist film having undergone exposure, in which the planarization layer having undergone the step (D) is dissolved in the solvent of the composition for forming a planarization layer (a).

The pattern forming method of the present invention is preferably a pattern forming method for ion implantation.

The pattern forming method of the present invention makes it possible to form a high-resolution resist pattern on an ultrafine stepped substrate (for example, a stepped substrate having groove portions having a groove width of equal to or less than 40 nm and cylindrical depressions having a diameter of equal to or less than 40 nm) and to make the resist pattern exhibit excellent peeling properties in a resist pattern peeling step. The reason why the pattern forming method makes it possible to form such a resist pattern is unclear but is assumed to be as below.

In a case where a resist film is formed on a stepped substrate, and the resist film is subjected to exposure and development so as to form a resist pattern, if a dimension such as a groove width or a diameter of depressions of the stepped substrate is smaller than the exposure wavelength, there will be problems in that optical contrast between an exposed portion and an unexposed portion in the resist film sunk into the depressions of the stepped substrate decreases due to the diffraction of light, and hence an excellent resist pattern is not easily formed. Particularly, in a case where the stepped substrate is ultrafine (for example, in a case where the groove width of the groove portions is equal to or less than 40 nm, and the diameter of the cylindrical depressions is equal to or less than 40 nm), it is much more difficult for light in the exposure step to reach the bottom portion of the resist film sunk into the depressions of the stepped substrate. As a result, resist pattern collapse easily occurs in a negative pattern forming method, and residues are easily caused in a positive pattern forming method. For this reason, the resolution of the resist pattern easily deteriorates.

In contrast, according to the pattern forming method of the present invention, first, in the step (A), a planarization layer is formed on a stepped substrate by using a composition for forming a planarization layer (a) containing a solvent. Herein, the planarization layer is for functioning as a basis for forming a resist film thereon.

Then, through the step (B), a resist film is formed on the planarization layer, and through the steps (C) and (D), a first pattern is formed by subjecting the resist film to exposure and development. In this case, because the bottom surface of the resist film is provided on the planarization layer, the resist film is planar, and accordingly, sufficient optical contrast can be established between an exposed portion and unexposed portion in the resist film. Consequently, a first pattern with high resolution can be formed.

Therefore, after the step (D), for example, by performing (E) a step of forming a second pattern by performing an etching treatment on the planarization layer by using the first pattern as a mask, a high-resolution second pattern to which the shape of the high-resolution first pattern is transferred can be formed on an ultrafine stepped substrate. That is, a high-resolution resist pattern can be formed on an ultrafine stepped substrate.

Typically, a pattern formed on a stepped substrate is removed after a treatment step such as an ion implantation step. If a load is excessively applied to the stepped substrate at the time of removing the pattern sunk into depressions of the stepped substrate, particularly in a case where the stepped substrate is the aforementioned ultrafine stepped substrate, a problem such as damage of the precisely formed depressions easily occurs.

In contrast, in the pattern forming method of the present invention, as described above, the planarization layer is formed such that it is dissolved in the solvent of the composition for forming a planarization layer (a) after the step (D). Therefore, at the time of removing the formed pattern from the planarization layer, by bringing the solvent of the composition for forming a planarization layer (a) or a solvent similar to the solvent into contact with the pattern, it is possible to dissolve and remove the pattern without damaging the stepped substrate. That is, it is possible to make the resist pattern exhibit excellent peeling properties during the resist pattern peeling step.

In the pattern forming method of the present invention, each of the steps (A) to (D) can be performed by a generally known method.

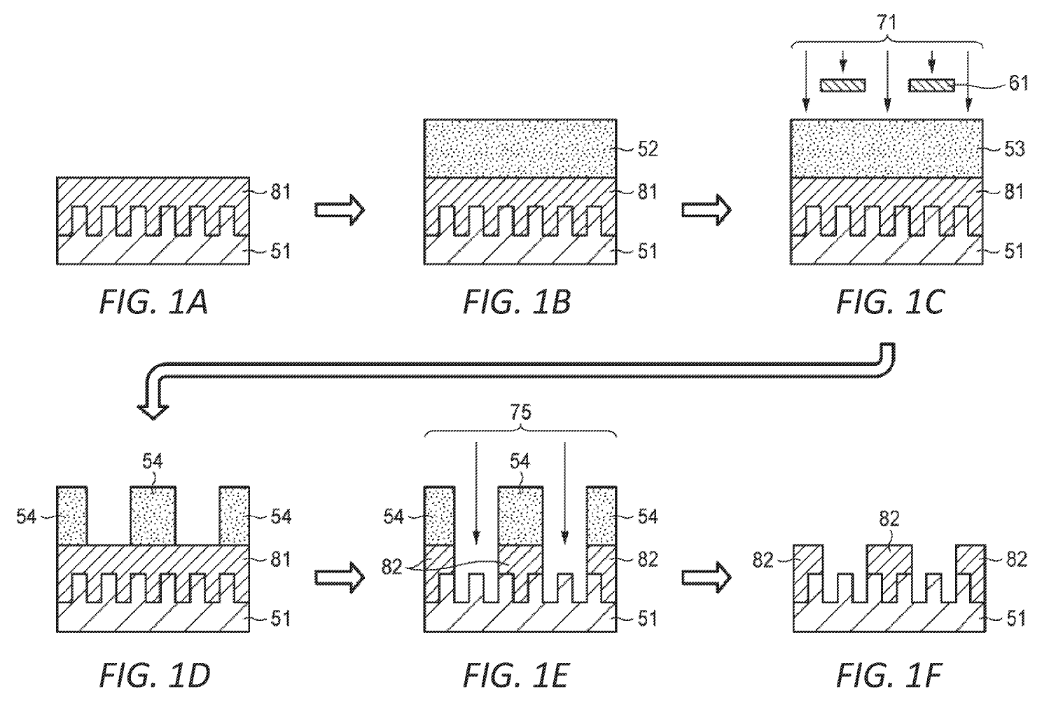

In an embodiment of the present invention, as shown in FIG. 1A which is a schematic cross-sectional view, first, a planarization layer 81 is formed on a stepped substrate 51 by using a composition for forming a planarization layer (a) containing a solvent (step (A)).

Details of the composition for forming a planarization layer (a) will be described later.

In the step (A), the method for forming the planarization layer on the stepped substrate can be performed typically by coating the stepped substrate with the composition for forming a planarization layer (a). As the coating method, it is possible to use a spin coating method, a spray method, a roller coating method, a dipping method, and the like known in the related art. It is preferable that the substrate is coated with the composition for forming a planarization layer (a) by a spin coating method.

A film thickness of the planarization layer is preferably 30 to 300 nm, more preferably 50 to 240 nm, and even more preferably 70 to 200 nm.

The stepped substrate is a substrate in which at least one step shape is formed thereon.

The stepped substrate is not particularly limited, and it is possible to use substrates such as an inorganic substrate of silicon, SiO₂, SiN, or the like and an inorganic substrate for coating of SOG or the like that are generally used in a process of manufacturing a semiconductor such as IC, a process of manufacturing a circuit board of liquid crystals, a thermal head, and the like, and other photofabrication lithography processes. If necessary, an underlayer film such as an antireflection film may be formed between the planarization layer and the substrate. As the underlayer film, an organic antireflection film, an inorganic antireflection film, and others can be appropriately selected. Materials of the underlayer film are available from Brewer Science, Inc., NISSAN CHEMICAL INDUSTRIES, LTD., and the like. Examples of the underlayer film suitable for a process of performing development by using a developer containing an organic solvent include the underlayer film described in WO2012/039337A.

The film thickness of the planarization layer formed on the stepped substrate means a height to the top surface of the formed planarization layer formed from the bottom surface of the stepped substrate (the bottom portion of the portion of the step shape in the stepped substrate).

The height from the bottom surface of the stepped substrate to the top surface of the step shape is preferably smaller than the film thickness of the planarization layer. For example, the height is preferably less than 200 nm.

For example, in a case where the stepped substrate is used for microfabrication such as ion implantation, as the stepped substrate, it is possible to use a substrate obtained by patterning fins or gates on a planar substrate. The stepped substrate on which fins or gates are patterned is coated with the composition for forming a planarization layer (a). A film thickness of the formed planarization layer is not a height to the top surface of the planarization layer formed from the top surface of the fins or gates but a height to the top surface of the planarization layer formed from the bottom surface of the stepped substrate as described above.

As the size (width, length, height, or the like) of the fins and gates, an interval therebetween, and a structure and constitution thereof, and the like, for example, it is possible to appropriately use those described in the Journal of The Institute of Electronics, Information and Communication Engineers, Vol. 91, No. 1, 2008, pp. 25˜29, “The Latest FinFET Process·Integration Technology” or Jpn. J. Appl. Phys. Vol. 42 (2003) pp. 4142-4146 Part 1, No. 6B, June 2003 “Fin-Type Double-Gate Metal-Oxide-Semiconductor Field-Effect Transistors Fabricated by Orientation-Dependent Etching and Electron Beam Lithography”.

Examples of the stepped substrate include a stepped substrate with grooves having a groove width which is equal to or less than an exposure wavelength (preferably equal to or less than 100 nm, more preferably equal to or less than 40 nm, and generally equal to or greater than 15 nm) and a depth of equal to or less than 100 nm (preferably 50 to 100 nm and more preferably 65 to 100 nm), a stepped substrate with cylindrical depressions having a diameter which is equal to or less than an exposure wavelength (preferably equal to or less than 100 nm, more preferably equal to or less than 40 nm, and generally equal to or greater than 15 nm) and a depth of equal to or less than 100 nm (preferably 50 to 100 nm and more preferably 65 to 100 nm), and the like.

Examples of the stepped substrate with groove portions described above include a stepped substrate having a plurality of repeating grooves that are arrayed at an equal interval at a pitch of, for example, 20 nm to 200 nm (preferably 50 to 150 nm and more preferably 70 to 120 nm), and the like.

Examples of the stepped substrate with cylindrical depressions described above include a stepped substrate having a plurality of repeating cylindrical depressions that are arrayed at an equal interval at a pitch of, for example, 20 nm to 200 nm (preferably 50 to 150 nm and more preferably 70 to 120 nm).

It is also preferable that the pattern forming method of the present invention includes a prebake step (PB1) between the step (A) and the step (B).

In the prebake step (PB1), a heating temperature is preferably 70° C. to 130° C., and more preferably 80° C. to 120° C.

A heating time is preferably 30 to 300 seconds, more preferably 30 to 180 seconds, and even more preferably 30 to 90 seconds.

The heating can be performed using means including a general exposure•developing machine or may be performed using a hot plate or the like.

The prebake step (PB1) may include a heating step performed plural times.

Then, as shown in FIG. 1B which is a schematic sectional view, a resist film 52 is formed on the planarization layer 81 by using a resist composition (step (B)).

Examples of the method for forming the resist film 52 by using a resist composition in the step (B) include the same method as the method for forming the planarization layer on the stepped substrate by using the composition for forming a planarization layer (a) in the step (A).

A film thickness of the resist film is preferably 50 to 800 nm, more preferably 80 to 500 nm, and even more preferably 100 to 300 nm.

It is also preferable that the pattern forming method of the present invention includes a prebake step (PB2) between the step (B) and the step (C).

Furthermore, it is preferable that the pattern forming method of the present invention includes a post exposure bake step (PEB) between the step (C) and the step (D).

In both of PB2 and PEB, heating is performed preferably at a temperature of 70° C. to 130° C. and more preferably at a temperature of 80° C. to 120° C.

The heating time is preferably 30 to 300 seconds, more preferably 30 to 180 seconds, and even more preferably 30 to 90 seconds.

The heating can be performed by means equipped with a general exposure and developing machine or may be performed using a hot plate.

Due to the baking, the reaction of an exposed portion is accelerated, and hence the sensitivity or the pattern profile is improved.

At least one of the PB step and the PEB step may include a heating step performed plural times.

Then, as shown in FIG. 1C which is a schematic cross-sectional view, the resist film 52 is irradiated with (that is, exposed to) actinic rays or radiation 71 through a mask 61, thereby obtaining a resist film 53 having undergone exposure (step (C)).

In the step (C), a wavelength of a light source used in an exposure device is not particularly limited, and examples of the light source include infrared light, visible light, ultraviolet light, far ultraviolet light, extreme ultraviolet light, X-rays, electron beams, and the like. Among these, far ultraviolet light preferably having a wavelength of equal to or less than 250 nm, more preferably having a wavelength of equal to or less than 220 nm, and particularly preferably having a wavelength of 1 to 200 nm is preferable. Specific examples thereof include a KrF excimer laser (248 nm), an ArF excimer laser (193 nm), an F₂ excimer laser (157 nm), X-rays, EUV (13 nm), electron beams, and the like. Among these, a KrF excimer laser, an ArF excimer laser, EUV, or electron beams are preferable, and a KrF excimer laser or an ArF excimer laser is more preferable.

The step (C) may include an exposure step performed plural times.

In the step (C), a liquid immersion exposure method can be applied.

The liquid immersion exposure method is a technique for improving resolving power. In this technique, exposure is performed in a state where a space between a projection lens and a sample is filled with a liquid (hereinafter, referred to as an “immersion liquid” as well) having a high refractive index.

As described above, regarding the “effect of liquid immersion”, provided that a wavelength of exposure light in the air is λ₀, a refractive index of an immersion liquid with respect to the air is n, and a convergence half angle θ of light rays is expressed by NA₀=sin θ, in a case where liquid immersion is performed, a resolving power and a focal depth can be represented by the following equations. Herein, k₁ and k₂ are coefficients involved in the process.

(Resolving power)=k₁·(λ₀/n)/NA₀

(Focal depth)=±k₂·(λ₀/n)/NA₀²

That is, the effect of liquid immersion is equivalent to an effect obtained when an exposure wavelength of 1/n is used. In other words, in a case of a projection optical system having the same NA, by liquid immersion, a focal depth can be increased by a factor of n. The liquid immersion is effective for various pattern shapes, and can be combined with super-resolution techniques that are currently under investigation, such as a phase shifting method and a modified illumination method.

In a case where liquid immersion exposure is performed, at either or both of (1) a point in time before the step of exposure is performed after the resist film is formed on a planarization layer and (2) a point in time before the step of heating the resist film is performed after the step of exposing the resist film through the immersion liquid, a step of rinsing the surface of the resist film with an aqueous chemical solution may be performed.

The immersion liquid is preferably a liquid which transmits the exposure wavelength and of which a temperature coefficient of a refractive index is as small as possible such that the distortion of an optical image projected onto the resist film is minimized. Particularly, in a case where the exposure light source is an ArF excimer laser (wavelength; 193 nm), from the viewpoint described above and in view of ease of availability and ease of handleability, it is preferable to use water.

In a case where water is used, an additive (liquid), which reduces the surface tension of water and enhancing surface activity, may be added in a small proportion. As the additive, a liquid is preferable which does not dissolve a resist layer on a wafer and negligibly affects an optical coat of a lower surface of a lens element.

As the additive, an aliphatic alcohol is preferable which has a refractive index that is substantially the same as the refractive index of water, and specific examples thereof include methyl alcohol, ethyl alcohol, isopropyl alcohol, and the like. The addition of an alcohol having a refractive index that is substantially the same as the refractive index of water results in an advantage that, even if the alcohol component in water evaporates and hence the concentration thereof contained changes, an overall change of a refractive index of the liquid can be minimized.

In contrast, in a case where a substance which does not transmit light of 193 nm or impurities which have a refractive index greatly different from the refractive index of water are intermixed, an optical image projected onto a lens is distorted. Therefore, as water to be used, distilled water is preferable. Furthermore, pure water filtered through an ion exchange filter may also be used.

An electric resistance of water used as an immersion liquid is desirably equal to or greater than 18.3 MΩcm, and a total organic carbon (TOC) thereof is desirably equal to or less than 20 ppb. Furthermore, it is desirable that the water has undergone a deaeration treatment.

If a refractive index of an immersion liquid is increased, lithography performance can be improved. From this viewpoint, an additive that will increase the refractive index may be added to water, or heavy water (D₂O) may be used instead of water.

In a case where the resist film is exposed through a liquid immersion medium, if necessary, a hydrophobic surface modification resin (HR) which will be described later can be added. The addition of the hydrophobic surface modification resin (HR) improves a receding contact angle of a surface. A receding contact angle of the resist film is preferably 60° to 90°, and more preferably equal to or greater than 70°.

In the liquid immersion exposure step, the immersion liquid needs to move along with the movement of an exposure head that forms an exposure pattern by performing scanning on a wafer at a high speed. Therefore, a contact angle of the immersion liquid with respect to the resist film in a dynamic state is important, and the resist is required to have performance of following the high-speed scanning performed by the exposure head without leaving liquid droplets.

In order to prevent the film from directly contacting the immersion liquid, a film poorly soluble in the immersion liquid (hereinafter, referred to as a “top coat” as well) may be provided between the resist film and the immersion liquid. Examples of functions required for the top coat include a property of being suitable for coating an upper layer portion of resist, transparency with respect to radiation particularly having a wavelength of 193 nm, and a property of being poorly soluble in the immersion liquid. It is preferable that the top coat is not mixed with the resist and can evenly coat an upper layer of the resist.

From the viewpoint of transparency at 193 nm, the top coat is preferably a polymer not containing an aromatic group.

Specifically, examples thereof include a hydrocarbon polymer, an acrylic acid ester polymer, polymethacrylic acid, polyacrylic acid, polyvinyl ether, a silicon-containing polymer, a fluorine-containing polymer, and the like. The hydrophobic surface modification resin (HR) which will be described later is also suitable as a top coat. If impurities are eluted onto the immersion liquid from the top coat, the optical lens is contaminated. Therefore, it is preferable that the amount of a residual monomer component of the polymer contained in the top coat is small.

At the time of peeling the top coat, a developer may be used, or a release agent may be separately used. As a release agent, a solvent that hardly permeates the resist film is preferable.

It is preferable that a difference in a refractive index between the top coat and the immersion liquid is zero or small. In this case, the resolving power can be improved. In a case where an ArF excimer laser (wavelength: 193 nm) is an exposure light source, it is preferable to use water as an immersion liquid, and accordingly, a refractive index of the top coat for ArF liquid immersion exposure is preferably close to the refractive index (1.44) of water. From the viewpoint of the transparency and refractive index, the top coat is preferably a thin film.

It is preferable that the top coat is not mixed with the resist film and the immersion liquid. From this viewpoint, in a case where water is an immersion liquid, it is preferable that a solvent used in the top coat is poorly soluble in a solvent used in the composition of the present invention and is a water-insoluble medium. In a case where an organic solvent is an immersion liquid, the top coat may be water-soluble or water-insoluble.

Then, as shown in FIG. 1D which is a schematic cross-sectional view, by developing the resist film 53 having undergone exposure, a first pattern 54 is formed (step (D)).

In the step (D), the developer which can be used in the step of forming the first pattern by developing the resist film may be an organic developer or an alkaline developer.

As the step (D), it is possible to suitably exemplify a step of forming a negative pattern as the first pattern by using a developer containing an organic solvent and a step of forming a positive pattern as the first pattern by using an alkaline developer.

As described above, the first pattern 54 may be a negative pattern or a positive pattern.

In the step (D), as the developer (hereinafter, referred to as an organic developer as well) in the step of forming the first pattern by developing the first resist film by using a developer containing an organic solvent, it is possible to use a polar solvent, such as a ketone-based solvent, an ester-based solvent, an alcohol-based solvent, an amide-based solvent, or an ether-based solvent, and a hydrocarbon-based solvent.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methyl cyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, propylene carbonate, and the like.

Examples of the ester-based solvent include methyl acetate, butyl acetate, ethyl acetate, isopropyl acetate, pentyl acetate, isopentyl acetate, amyl acetate, cyclohexyl acetate, isobutyl isobutyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, and the like.

Examples of the alcohol-based solvent include an alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, or n-decanol, a glycol-based solvent such as ethylene glycol, diethylene glycol, or triethylene glycol, a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, or methoxymethyl butanol, and the like.

Examples of the ether-based solvent include the aforementioned glycol ether-based solvent, dioxane, tetrahydrofuran, phenetole, dibutyl ether, and the like.

Examples of the amide-based solvent include N-methyl-2-pyrrolidone, N,N-dimethylacetamide, N,N-dimethylformamide, hexamethylphosphoric triamide, 1,3-dimethyl-2-imidazolidinone, and the like.

Examples of the hydrocarbon-based solvent include an aromatic hydrocarbon-based solvent such as toluene or xylene and an aliphatic hydrocarbon-based solvent such as pentane, hexane, octane, or decane.

The above solvent may be used as a mixture of plural solvents or used by being mixed with solvents other than the above or water. Here, in order to fully bring about the effects of the present invention, a total moisture content of the developer is preferably less than 10% by mass and more preferably substantially 0% by mass.

That is, an amount of the organic solvent used in the organic developer is, with respect to a total amount of the developer, preferably equal to or greater than 90% by mass and equal to or less than 100% by mass, and more preferably equal to or greater than 95% by mass and equal to or less than 100% by mass.

Particularly, the organic developer is preferably a developer containing at least one kind of organic solvent selected from the group consisting of a ketone-based solvent, an ester-based solvent, an alcohol-based solvent, an amide-based solvent, and an ether-based solvent.

At 20° C., a vapor pressure of the organic developer is preferably equal to or less than 5 kPa, more preferably equal to or less than 3 kPa, and particularly preferably equal to or less than 2 kPa. If the vapor pressure of the organic developer is equal to or less than 5 kPa, the developer is inhibited from evaporating on the substrate or in a developing cup, and temperature uniformity within the wafer surface is improved. As a result, dimensional uniformity within the wafer surface is improved.

Specific examples of the organic developer having a vapor pressure of equal to or less than 5 kPa include a ketone-based solvent such as 1-octanone, 2-octanone, 1-nonanone, 2-nonanone, 2-heptanone (methyl amyl ketone), 4-heptanone, 2-hexanone, diisobutyl ketone, cyclohexanone, methyl cyclohexanone, phenylacetone, or methyl isobutyl ketone, an ester-based solvent such as butyl acetate, pentyl acetate, isopentyl acetate, amyl acetate, cyclohexyl acetate, isobutyl isobutyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate, or propyl formate, an alcohol-based solvent such as n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, or n-decanol, a glycol-based solvent such as ethylene glycol, diethylene glycol, or triethylene glycol, an glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, or methoxymethyl butanol, an ether-based solvent such as tetrahydrofuran, phenetole, or dibutyl ether, an amide-based solvent such as N-methyl-2-pyrrolidone, N,N-dimethylacetamide, or N,N-dimethylformamide, an aromatic hydrocarbon-based solvent such as toluene or xylene, and an aliphatic hydrocarbon-based solvent such as octane or decane.

Specific examples of the organic developer having a vapor pressure of equal to or less than 2 kPa which is a particularly preferred range include a ketone-based solvent such as 1-octanone, 2-octanone, 1-nonanone, 2-nonanone, 4-heptanone, 2-hexanone, diisobutyl ketone, cyclohexanone, methyl cyclohexanone, or phenylacetone, an ester-based solvent such as butyl acetate, amyl acetate, cyclohexyl acetate, isobutyl isobutyrate, propylene glycol monomethyl ether acetate, ethylene glycol monoethyl acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate, or propyl lactate, an alcohol-based solvent such as n-butyl alcohol, sec-butyl alcohol, tert-butyl alcohol, isobutyl alcohol, n-hexyl alcohol, n-heptyl alcohol, n-octyl alcohol, or n-decanol, a glycol-based solvent such as ethylene glycol, diethylene glycol, or triethylene glycol, a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, or methoxymethyl butanol, an ether-based solvent such as phenetole or dibutyl ether, an amide-based solvent such as N-methyl-2-pyrrolidone, N,N-dimethylacetamide, or N,N-dimethylformamide, an aromatic hydrocarbon-based solvent such as xylene, and an aliphatic hydrocarbon-based solvent such as octane or decane.

If necessary, an appropriate amount of surfactant can be added to the organic developer.

The surfactant is not particularly limited, and for example, ionic or nonionic fluorine-based surfactant and/or silicon-based surfactant can be used. Examples of the fluorine-based surfactant and/or silicon-based surfactant include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H07-230165A), JP1996-62834A (JP-H08-62834A), JP1997-54432A (JP-H09-54432A), JP1997-5988A (JP-H09-5988A), U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A. Among these, a nonionic surfactant is preferable. The nonionic surfactant is not particularly limited, and it is more preferable to use a fluorine-based surfactant or a silicon-based surfactant.

An amount of the surfactant used is, with respect to a total amount of the developer, generally 0.001% to 5% by mass, preferably 0.005% to 2% by mass, and even more preferably 0.01% to 0.5% by mass.

If necessary, the organic developer may contain a basic compound. Examples of the basic compound include nitrogen-containing basic compounds such as the nitrogen-containing compounds described in paragraphs “0021” to “0063” of JP2013-11833A, and basic compounds that the resist composition, which will be described later, may contain. If the organic developer contains a basic compound, the improvement of contrast at the time of development, the inhibition of film thinning, and the like can be expected.

In the step (D), as the alkaline developer in the step of forming the first pattern by performing development by using the alkaline developer, for example, it is possible to use an alkaline aqueous solution of inorganic alkalis such as sodium hydroxide, potassium hydroxide, sodium carbonate, sodium silicate, sodium metasilicate, and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide and tetraethylammonium hydroxide, and cyclic amines such as pyrrole and piperidine.

Furthermore, an appropriate amount of alcohols or surfactants may be used by being added to the aforementioned alkaline aqueous solution. Examples of the surfactants include the surfactants described above.

An alkali concentration of the alkaline developer is generally 0.1% to 20% by mass.

A pH of the alkaline developer is generally 10.0 to 15.0.

Particularly, a 2.38% by mass aqueous solution of tetramethylammonium hydroxide is desirable.

As a development method, for example, it is possible to use a method of dipping a substrate into a tank filled with a developer for a certain period of time (dipping method), a method of performing development by heaping up a developer on the surface of a substrate by exploiting surface tension and allowing the developer standstill for a certain period of time (paddle method), a method of spraying a developer onto the surface of a substrate (spray method), a method of continuously jetting a developer onto a substrate, which is spinning at a certain rate, while scanning a developer-jetting nozzle at a certain rate (dynamic dispense method), and the like.

In a case where the aforementioned various development methods include a step of jetting a developer from a developing nozzle of a developing device to a resist film, a jetting pressure of the developer jetted (a flow rate of the jetted developer per unit area) is preferably equal to or less than 2 mL/sec/mm², more preferably equal to or less than 1.5 mL/sec/mm², and even more preferably equal to or less than 1 mL/sec/mm². A lower limit of the flow rate is not particularly limited. Considering throughput, the lower limit is preferably equal to or greater than 0.2 mL/sec/mm².

If the jetting pressure of the jetted developer is within the above range, it is possible to markedly reduce the pattern defect resulting from resist residues remaining after development.

The details of the mechanism thereof are unclear. Presumably, if the jetting pressure is within the above range, a pressure that the developer applies to the resist film may be reduced, the resist film and the resist pattern may be inhibited from being unnecessarily scraped or collapsed, and hence the aforementioned effect may be obtained.

The jetting pressure (mL/sec/mm²) of the developer is a value at an exit of a developing nozzle in a developing device.

Examples of a method of adjusting the jetting pressure of the developer include a method of adjusting the jetting pressure by using a pump or the like, a method of changing the jetting pressure by adjusting the pressure by means of supplying the developer from a pressurized tank, and the like.

After the step of performing development by using a developer containing an organic solvent, a step of stopping development while substituting the developer with other solvents may be performed.

The pattern forming method of the present invention may have, as the step (D), a step of forming a negative pattern by using a developer containing an organic solvent and a step of forming a positive pattern by using an alkaline developer. If the development using the organic developer and the development using the alkaline developer are combined, as described in FIGS. 1 to 11 of US8,227,183B, for example, a pattern having a line width that is ½ of a line width of a mask pattern could be resolved.

The pattern forming method of the present invention may include a step of performing rinsing by using a rinsing liquid (rinsing step) after the step (D).

The rinsing liquid, which is used in the rinsing step following the step of performing development by using a developer containing an organic solvent, is not particularly limited as long as the rinsing liquid does not dissolve the resist pattern, and a solution containing a general organic solvent can be used. As the rinsing liquid, it is preferable to use a rinsing liquid containing at least one kind of organic solvent selected from the group consisting of a hydrocarbon-based solvent, a ketone-based solvent, an ester-based solvent, an alcohol-based solvent, an amide-based solvent, and an ether-based solvent.

Specific examples of the hydrocarbon-based solvent, the ketone-based solvent, the ester-based solvent, the alcohol-based solvent, the amide-based solvent, and the ether-based solvent include the same solvents as described above for the developer containing an organic solvent.

The pattern forming method of the present invention more preferably includes a step of performing rinsing by using a rinsing liquid containing at least one kind of organic solvent selected from the group consisting of a ketone-based solvent, an ester-based solvent, an alcohol-based solvent, and an amide-based solvent, even more preferably includes a step of performing rinsing by using a rinsing liquid containing an alcohol-based solvent or an ester-based solvent, particularly preferably includes a step of performing rinsing by using a rinsing liquid containing a monohydric alcohol, and most preferably includes a step of performing rinsing by using a rinsing liquid containing a monohydric alcohol having 5 or more carbon atoms, after the step of performing development by using a developer containing an organic solvent.

Examples of the monohydric alcohol used in the rinsing step include a linear, branched, or cyclic monohydric alcohol. Specifically, it is possible to use 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol, and the like. As a particularly preferred monohydric alcohol having 5 or more carbon atoms, it is possible to use 1-hexanol, 2-hexanol, 4-methyl-2-pentanol, 1-pentanol, 3-methyl-1-butanol, and the like.

A plurality of each of the components described above may be mixed together, or each of the components may be used by being mixed with an organic solvent other than those described above.

A moisture content in the rinsing liquid is preferably equal to or less than 10% by mass, more preferably equal to or less than 5% by mass, and particularly preferably equal to or less than 3% by mass. If the moisture content is equal to or less than 10% by mass, excellent developing characteristics can be obtained.

At 20° C., a vapor pressure of the rinsing liquid used after the step of performing development by using a developer containing an organic solvent is preferably equal to or greater than 0.05 kPa and equal to or less than 5 kPa, more preferably equal to or greater than 0.1 kPa and equal to or less than 5 kPa, and most preferably equal to or greater than 0.12 kPa and equal to or less than 3 kPa. If the vapor pressure of the rinsing liquid is equal to or greater than 0.05 kPa and equal to or less than 5 kPa, temperature uniformity within the wafer surface is improved, swelling resulting from the permeation of the rinsing liquid is inhibited, and hence dimensional uniformity within the wafer surface is improved.

As the rinsing liquid used in the rinsing step following the step of performing development by using an alkaline developer, pure water is used, and a surfactant may also be used by being added thereto in an appropriate amount.

A method of rinsing treatment in the aforementioned rinsing step is not particularly limited. For example, it is possible to use a method of continuously jetting the rinsing liquid onto a substrate that is spinning at a certain rate (spin coating method), a method of dipping a substrate into a tank filled with the rinsing liquid for a certain period of time (dipping method), a method of spraying the rinsing liquid onto the surface of a substrate (spray method), and the like. Particularly, it is preferable to perform the rinsing treatment by using the spin coating method among the above methods and to remove the rinsing liquid from the surface of the substrate by spinning the substrate after rinsing at a rotation speed of 2,000 rpm to 4,000 rpm. It is also preferable that the pattern forming method of the present invention includes a heating step (Post Bake) after the rinsing step. Through baking, the developer and the rinsing liquid remaining between the patterns and inside the patterns is removed. The heating step after the rinsing step is performed generally at 40° C. to 160° C. and preferably at 70° C. to 95° C., generally for 10 seconds to 3 minutes and preferably for 30 seconds to 90 seconds.

After the developing treatment or the rinsing treatment, it is possible to perform a treatment for removing the developer or the rinsing liquid that has adhered onto the pattern by using a supercritical fluid.

It is preferable that the planarization layer 81 is substantially not developed by the step (D). In order for the planarization layer 81 not to be developed, it is preferable that the planarization layer 81 is not developed in the developer used in the step (D).

The state where the planarization layer is substantially not developed typically means that, when the planarization layer is dipped into a developer for 1,000 seconds at room temperature (25° C.), an average dissolution rate (planarization layer reduction rate) thereof measured using a quartz crystal microbalance (QCM) sensor or the like is less than 0.1 nm/sec, preferably less than 0.05 nm/sec, and more preferably less than 0.01 nm/sec.

In a case where the developer used in the step (D) is an organic developer, the above dissolution rate is suitably achieved when the composition for forming a planarization layer (a) (and the planarization layer) contains a hydrophilic resin. In a case where the developer used in the step (D) is an alkaline developer, the above dissolution rate is suitably achieved when the composition for forming a planarization layer (a) (and the planarization layer) contains a hydrophobic resin.

Then, as shown in FIG. 1E which is a schematic cross-sectional view, an etching treatment using an etching gas 75 or the like is performed on the planarization layer 81 by using the first pattern 54 as a mask, thereby converting the planarization layer 81 into a second pattern 82 (step (E)).

The etching treatment method is not particularly limited, and any of known methods can be used. Various conditions and the like are appropriately determined according to the type of the layer subjected to the etching treatment and the like. For example, etching can be performed based on Proceedings of SPIE (Proc. of SPIE) Vol. 6924, 692420 (2008), JP2009-267112A, and the like.

Herein, an aspect in which at least the first pattern contains a silicon atom can be suitably exemplified.

This aspect is preferably an aspect in which at least the resist composition contains a silicon atom (for example, a silicon atom-containing resin), and hence the first pattern contains a silicon atom (for example, a silicon atom-containing resin).

According to this aspect, by adopting etching conditions under which an etching reaction easily occurs in a film containing a silicon atom, etching conditions are easily set under which an etching rate of the planarization layer becomes sufficiently greater than an etching rate of the first pattern. As a result, the second pattern 82 obtained by the transfer of the shape of the first pattern 54 to the planarization layer 81 can be more easily formed.

Then, as shown in FIG. 1F which is a schematic cross-sectional view, the first pattern 54 may be removed (step (F)).

The step (F) is not particularly limited as long as the first pattern can be removed. The step (F) can be suitably performed by performing one or more kinds of treatment selected from an “etching treatment”, “exposure using a solvent”, and “exposure using an aqueous solution (for example, an acidic aqueous solution or a basic aqueous solution)” on the first pattern.

In the step (F), it is preferable to remove the first pattern 54 without damaging the second pattern 82, in other words, to selectively remove the first pattern 54. Therefore, among the treatments exemplified above, a treatment that makes it possible to selectively remove the first pattern 54 is preferably adopted.

Considering the above aspect, in a case where the first pattern 54 is removed by the etching treatment, it is preferable that the step (F) includes a step of performing the etching treatment on the first pattern 54 under the conditions in which an etching rate of the first pattern 54 becomes greater than an etching rate of the second pattern 82.

The step (E) may be a step that functions as the step (F). That is, in a process of converting the planarization layer 81 into the second pattern 82 by performing an etching treatment on the planarization layer 81 by using the first pattern 54 as a mask, the first pattern 54 may also be removed by the etching treatment. In this case, the etching rate of the first pattern 54 can be approximately the same as the etching rate of the planarization layer 81.

The aforementioned conditions can be established by appropriately adjusting the makeup of each of the resist composition, the composition for forming a planarization layer, the type of etching gas, and the like. As will be described later, it is preferable that the planarization layer 81 is a layer containing a resin having an Onishi parameter of equal to or greater than 3.0, because then the aforementioned etching conditions are easily established.

In a case where the pattern forming method is for ion implantation, ion implantation is then performed on a predetermined region of the stepped substrate 51 by using the second pattern 82 as a mask. As the ion implantation method, any of known methods can be adopted.

The planarization layer 81 having undergone the step (D) is dissolved in the solvent of the composition for forming a planarization layer (a). Therefore, after the ion implantation, by bringing the second pattern 82 on the stepped substrate 51 into contact with the solvent of the composition for forming a planarization layer (a) or a solvent similar to the solvent, the second pattern 82 can be easily dissolved and removed by the solvent. The solvent used for dissolving and removing the second pattern 82 can be appropriately selected from those described as the solvent of the composition for forming a planarization layer (a) that will be described later.

The state where the planarization layer having undergone the step (D) is dissolved in the solvent of the composition for forming a planarization layer (a) typically means that, when the planarization layer having undergone the step (D) is dipped into the composition for forming a planarization layer (a) for 1,000 seconds at room temperature (25° C.), an average dissolution rate (planarization layer reduction rate) measured using a quartz crystal microbalance (QCM) sensor is equal to or greater than 0.1 nm/sec, preferably equal to or greater than 1 nm/sec, and more preferably equal to or greater than 10 nm/sec.

The composition for forming a planarization layer (a) preferably does not contain a compound that causes a cross-linking reaction triggered by at least either heat or light, and more preferably does not contain a compound that causes a reaction (herein, the reaction is not limited to a cross-linking reaction) triggered by at least either heat or light.

More specifically, the composition for forming a planarization layer (a) preferably does not contain one or more kinds of compound selected from the group consisting of a compound (for example, a resin) having a thermally cross-linkable group, a photo-cross-linkable group, an acid-cross-linkable group, or a radically cross-linkable group, an acid, an acid generator, and a radical generator.

It is preferable that the pattern forming method of the present invention does not include a step of heating the planarization layer at a temperature of equal to or higher than 170° C., in the step (A) or between the step (A) and the step (B).

It is preferable that the pattern forming method of the present invention does not include a step of subjecting the planarization layer to exposure between the step (A) and the step (B).

By adopting the above aspects, the requirement that “the planarization layer having undergone the step (D) is not dissolved in the solvent of the composition for forming a planarization layer (a)” is suitably satisfied.

[Resist Composition]

Hereinafter, the resist composition used in the pattern forming method of the present invention will be described.

The resist composition may be a negative resist composition or a positive resist composition.

Hereinafter, each component that can be obtained in the resist composition will be described.

<Resin (A)>

It is preferable that the resist composition contains (A) a resin (hereinafter, referred to as a “resin (A)” as well) that undergoes a polarity change due to the action of an acid.

In an aspect, the composition according to the present invention contains, as the resin (A), a resin (hereinafter, referred to as a “resin (A1) as well”) having a group decomposed by the action of an acid. In another aspect, the composition according to the present invention contains, as the resin (A), a resin (hereinafter, referred to as a “resin (A2) as well”) having a phenolic hydroxyl group.

[1] Resin (A1) having group decomposed by action of acid

The resin (A1) is a resin of which the solubility in an alkaline developer increases by the action of an acid or of which the solubility in a developer containing an organic solvent decreases by the action of an acid. The resin (A1) has a group, which generates a polar group by being decomposed by the action of an acid (hereinafter, referred to as an “acid-decomposable group” as well), on either or both of a main chain and a side chain of the resin.

The resin (A1) is preferably insoluble or poorly soluble in an alkaline developer.

It is preferable that the acid-decomposable group has a structure protected with a group that decomposes and eliminates a polar group by the action of an acid.

Examples of the polar group include a phenolic hydroxyl group, a carboxyl group, a fluorinated alcohol group, a sulfonic acid group, a sulfonamide group, a sulfonyl imide group, an (alkylsulfonyl) (alkylcarbonyl) methylene group, an (alkylsulfonyl) (alkylcarbonyl) imide group, a bis(alkylcarbonyl) methylene group, a bis(alkylcarbonyl) imide group, a bis(alkylsulfonyl) methylene group, a bis(alkylsulfonyl) imide group, a tris(alkylcarbonyl) methylene group, a tris(alkylsulfonyl) methylene group, and the like.

Examples of a preferred polar group include a carboxyl group, a fluorinated alcohol group (such as a hexafluoroisopropanol group), and a sulfonic acid group.

As the acid-decomposable group, the groups obtained by substituting a hydrogen atom of the aforementioned polar groups with a group eliminated by an acid are preferable.

Examples of the group eliminated by an acid include —C(R₃₆)(R₃₇)(R₃₈), —C(R₃₆)(R₃₇)(OR₃₉), —C(R₀₁)(R₀₂)(OR₃₉), and the like.

In the formulae, R₃₆ to R₃₉ each independently represent an alkyl group, a cycloalkyl group, an aryl group, an aralkyl group, or an alkenyl group. R₃₆ and R₃₇ may form a ring by being bonded to each other.

R₀₁ and R₀₂ each independently represent a hydrogen atom, an alkyl group, a cycloalkyl group, an aryl group, an aralkyl group, or an alkenyl group.

The acid-decomposable group is preferably a cumyl ester group, an enol ester group, an acetal ester group, a tertiary alkyl ester group, or the like, and more preferably a tertiary alkyl ester group.

As an acid-decomposable group-containing repeating unit that the resin (A1) can contain, a repeating unit represented by the following Formula (AI) is preferable.

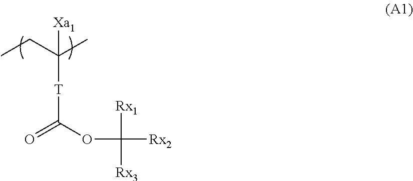

In Formula (AI), Xa₁ represents a hydrogen atom or an alkyl group which may have a substituent.

T represents a single bond or a divalent linking group.

Rx₁ to Rx₃ each independently represent a (linear or branched) alkyl group or a (monocyclic or polycyclic) cycloalkyl group.

Two out of Rx₁ to Rx₃ may form a (monocyclic or polycyclic) cycloalkyl group by being bonded to each other.

Examples of the alkyl group represented by Xa₁ that may have a substituent include a methyl group or a group represented by —CH₂—R₁₁. R₁₁ represents a halogen atom (fluorine atom or the like), a hydroxyl group, or a monovalent organic group, and examples thereof include an alkyl group having 5 or more carbon atoms and an acyl group having 5 or less carbon atoms. The alkyl group is preferably an alkyl group having 3 or less carbon atoms, and more preferably a methyl group. In an aspect, Xa₁ is preferably a hydrogen atom, a methyl group, a trifluoromethyl group, a hydroxymethyl group, or the like.

Examples of the divalent linking group as T include an alkylene group, a —COO—Rt- group, a —O—Rt- group, and the like. In the formulae, Rt represents an alkylene group or a cycloalkylene group.

T is preferably a single bond or a —COO—Rt- group. Rt is preferably an alkylene group having 1 to 5 carbon atoms, and more preferably a —CH₂— group, a —(CH₂)₂— group, or a —(CH₂)₃— group.

The alkyl group as Rx₁ to Rx₃ is preferably an alkyl group having 1 to 4 carbon atoms, such as a methyl group, an ethyl group, a n-propyl group, an isopropyl group, a n-butyl group, an isobutyl group, or a t-butyl group.

The cycloalkyl group as Rx₁ to Rx₃ is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group.

The cycloalkyl group formed by the bonding between two out of Rx₁ to Rx₃ is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group. The cycloalkyl group is particularly preferably a monocyclic cycloalkyl group having 5 or 6 carbon atoms.

In the cycloalkyl group formed by the bonding between two out of Rx₁ to Rx₃, for example, one methylene group constituting the ring may be substituted with a heteroatom such as an oxygen atom or a heteroatom-containing group such as a carbonyl group.

It is preferable that the repeating unit represented by Formula (AI) has, for example, an aspect in which Rx₁ represents a methyl group or an ethyl group, and Rx₂ and Rx₃ form the aforementioned cycloalkyl group by being bonded to each other.

Each group described above may have a substituent, and examples of the substituent include an alkyl group (having 1 to 4 carbon atoms), a halogen atom, a hydroxyl group, an alkoxy group (having 1 to 4 carbon atoms), a carboxyl group, an alkoxycarbonyl group (having 2 to 6 carbon atoms), and the like. The number of carbon atoms of the substituent is preferably equal to or less than 8.

A total content of the acid-decomposable group-containing repeating unit is, with respect to all of the repeating units in the resin (A1), preferably 20 to 90 mol %, more preferably 25 to 85 mol %, and even more preferably 30 to 80 mol %.

Specific examples of preferred acid-decomposable group-containing repeating units will be shown below, but the present invention is not limited thereto.

In the specific examples, Rx represents a hydrogen atom, CH₃, CF₃, or CH₂OH. Rxa and Rxb each independently represent an alkyl group having 1 to 4 carbon atoms. Z represents a polar group-containing substituent, and in a case where there is a plurality of Z's, they are independent from each other. p represents 0 or a positive integer. Examples of the polar group-containing substituent represented by Z include a linear or branched alkyl group or a cycloalkyl group having a hydroxyl group, a cyano group, an amino group, an alkylamide group, or a sulfonamide group, and among these, an alkyl group having a hydroxyl group is preferable. As the branched alkyl group, an isopropyl group is particularly preferable.

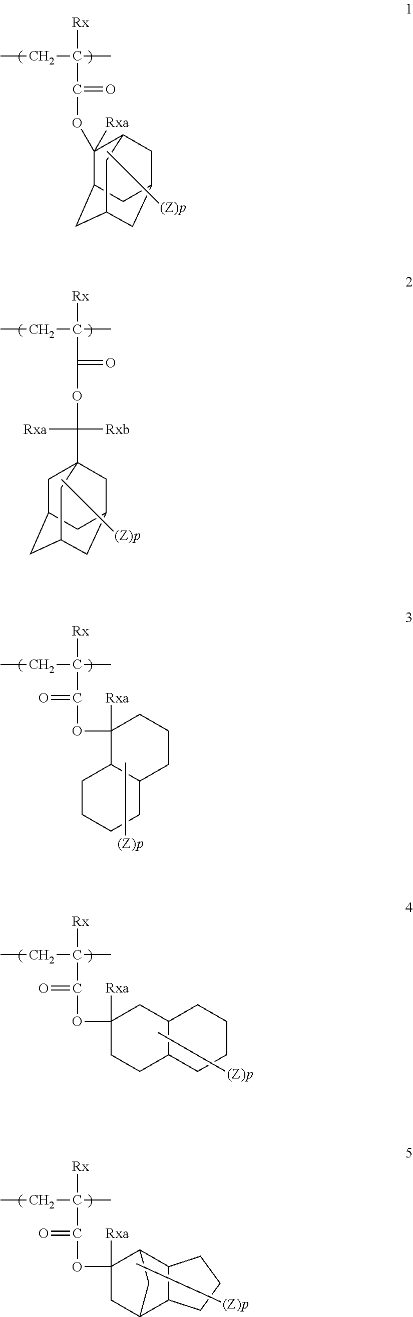

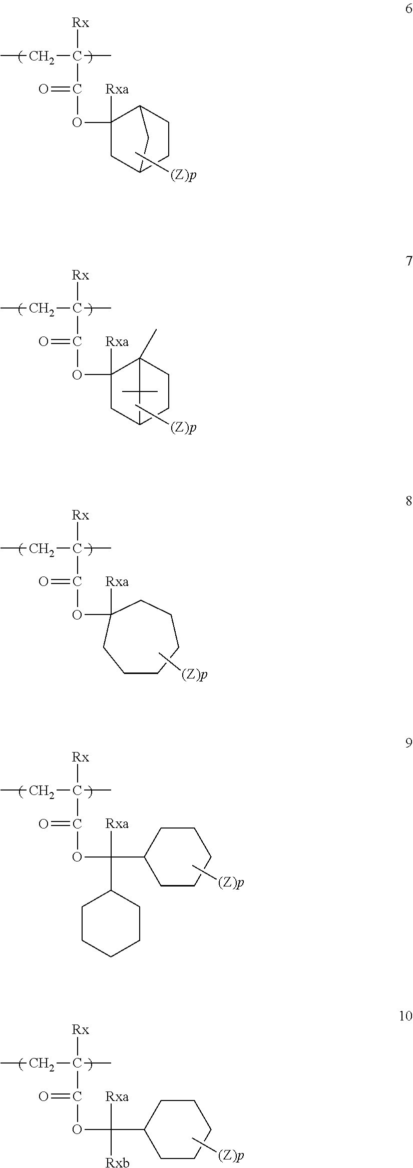

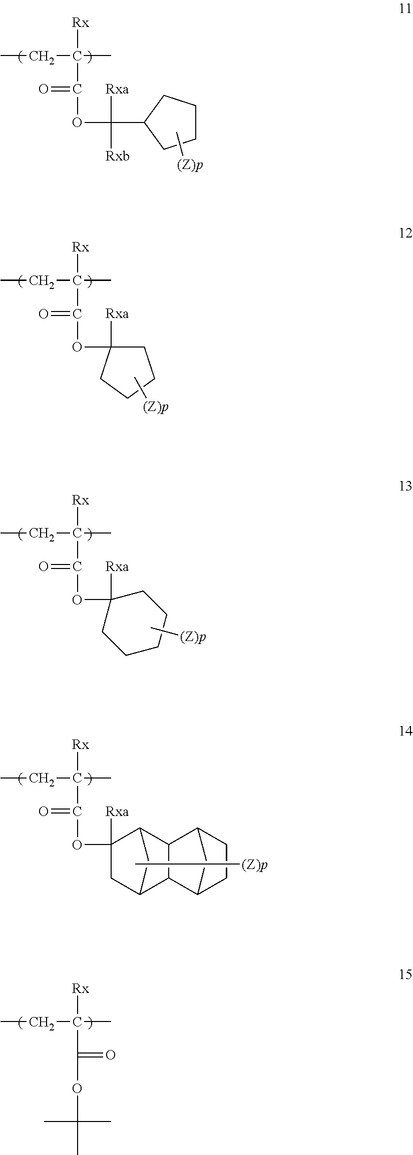

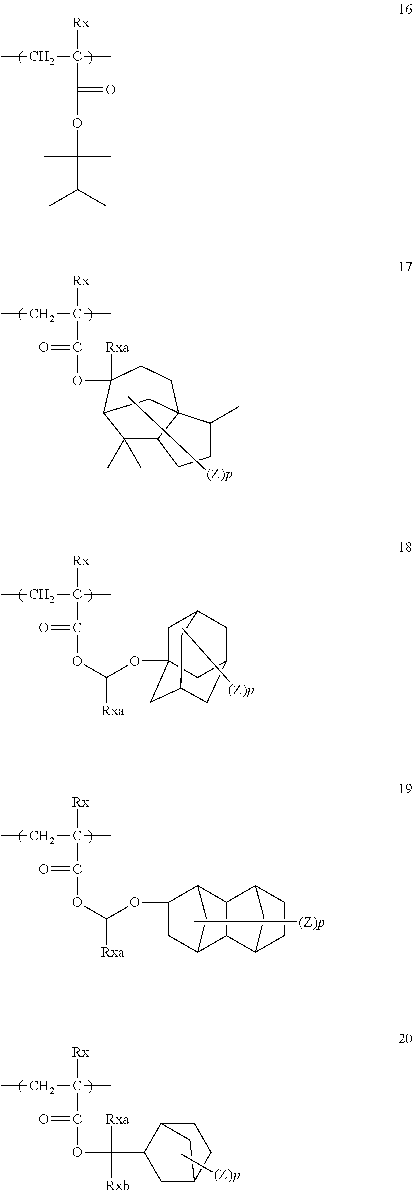

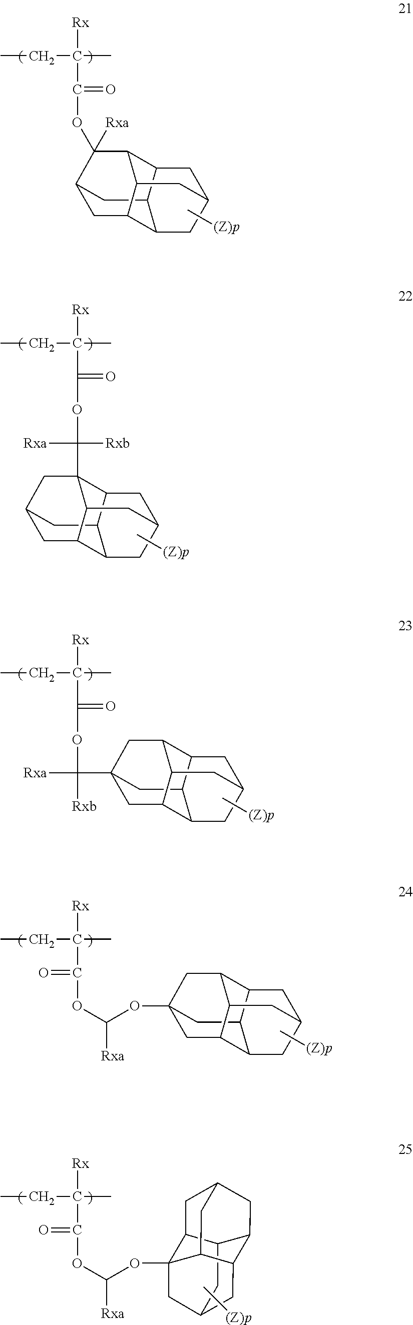

It is preferable that the resin (A1) contains, as the repeating unit represented by Formula (AI), for example, a repeating unit represented by Formula (3).

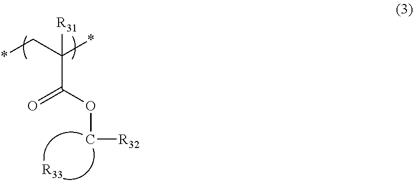

In Formula (3), R₃₁ represents a hydrogen atom or an alkyl group.

R₃₂ represents a methyl group, an ethyl group, a n-propyl group, an isopropyl group, a n-butyl group, an isobutyl group, or a sec-butyl group.

R₃₃ is an atomic group necessary for forming a monocyclic alicyclic hydrocarbon structure together with a carbon atom to which R₃₂ is bonded. In the alicyclic hydrocarbon structure, some of carbon atoms constituting the ring may be substituted with a heteroatom or a heteroatom-containing group.

The alkyl group as R₃₁ may have a substituent, and examples of the substituent include a fluorine atom, a hydroxyl group, and the like.

R₃₁ preferably represents a hydrogen atom, a methyl group, a trifluoromethyl group, or a hydroxymethyl group.

R₃₂ is preferably a methyl group, an ethyl group, a n-propyl group, or an isopropyl group, and more preferably a methyl group or an ethyl group.

The monocyclic alicyclic hydrocarbon structure that R₃₃ forms together with a carbon atom is preferably a 3- to 8-membered ring, and more preferably a 5- or 6-membered ring.

In the monocyclic alicyclic hydrocarbon structure that R₃₃ forms together with a carbon atom, examples of the heteroatom forming the ring include an oxygen atom, a sulfur atom, and the like, and examples of the heteroatom-containing group include a carbonyl group and the like. Here, it is preferable that the heteroatom-containing group is not an ester group (ester bond).

It is preferable that the monocyclic alicyclic hydrocarbon structure that R₃₃ forms together with a carbon atom formed of only a hydrocarbon atom and a hydrogen atom.

The repeating unit represented by Formula (3) is preferably a repeating unit represented by the following Formula (3′).

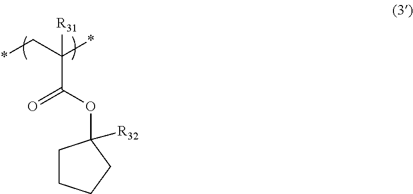

In Formula (3′), R₃₁ and R₃₂ have the same definition as R₃₁ and R₃₂ in Formula (3) respectively.

Specific examples of the repeating unit having the structure represented by Formula (3) will be shown below, but the repeating unit is not limited thereto.

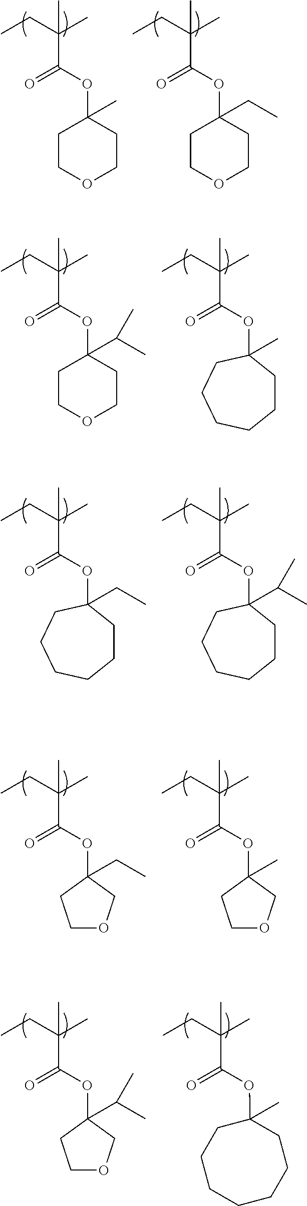

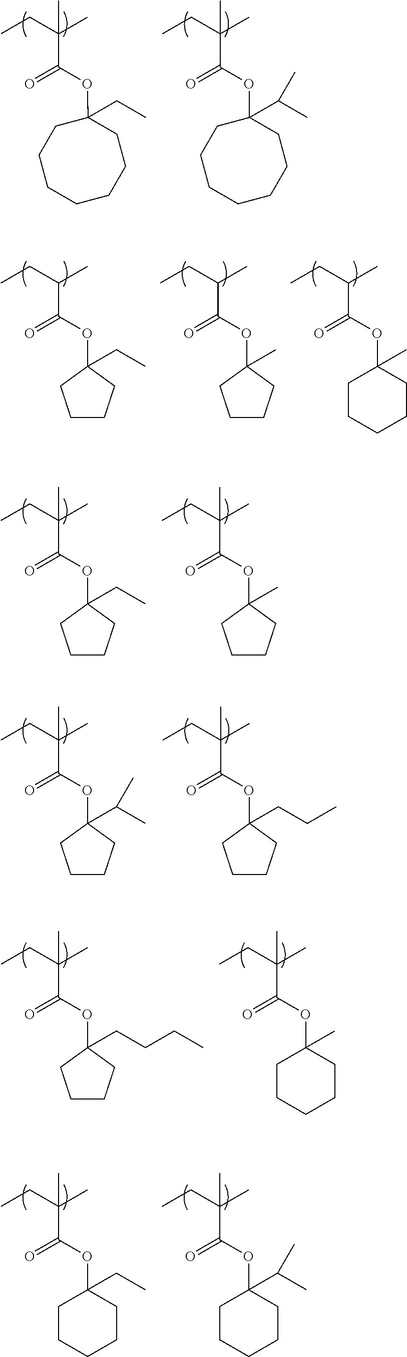

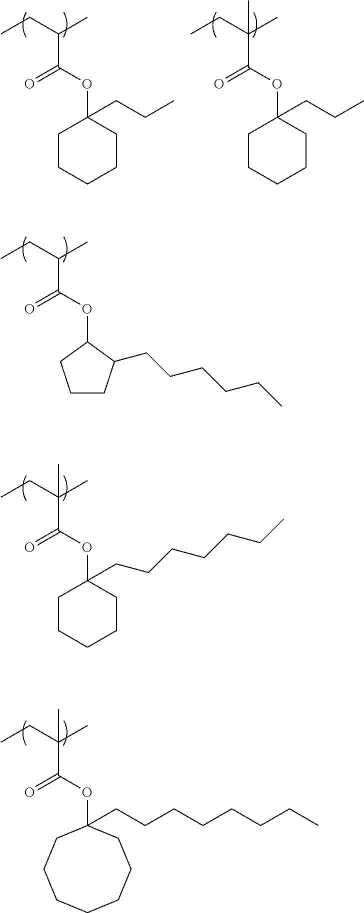

A content of the repeating unit having the structure represented by Formula (3) is, with respect to all of the repeating units in the resin (A1), preferably 20 to 80 mol %, more preferably 25 to 75 mol %, and even more preferably 30 to 70 mol %.

It is more preferable that the resin (A1) is a resin which has, as the repeating unit represented by Formula (AI), for example, at least either a repeating unit represented by Formula (I) or a repeating unit represented by Formula (II).

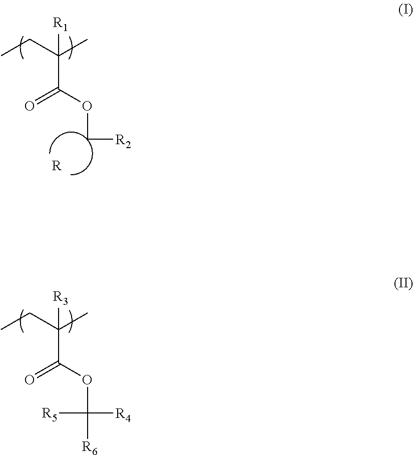

In Formulae (I) and (II), R₁ and R₃ each independently represent a hydrogen atom, a methyl group which may have a substituent, or a group represented by —CH₂—R₁₁. R₁₁ represents a monovalent organic group.

R₂, R₄, R₅, and R₆ each independently represent an alkyl group or a cycloalkyl group.

R represents an atomic group necessary for forming an alicyclic structure together with a carbon atom to which R₂ is bonded.

R₁ and R₃ preferably represent a hydrogen atom, a methyl group, a trifluoromethyl group, or a hydroxymethyl group. Specific and preferred examples of the monovalent organic group represented by R₁₁ are the same as those listed above for R₁₁ in Formula (AI).

The alkyl group as R₂ may be linear or branched and may have a substituent.

The cycloalkyl group as R₂ may be monocyclic or polycyclic and may have a substituent.

R₂ is an alkyl group. R₂ is more preferably an alkyl group having 1 to 10 carbon atoms, and more preferably an alkyl group having 1 to 5 carbon atoms. Examples thereof include a methyl group, an ethyl group, and the like.

R represents an atomic group necessary for forming an alicyclic structure together with a carbon atom. The alicyclic structure that R form together with a carbon atom is preferably a monocyclic alicyclic structure, and the number of carbon atoms thereof is preferably 3 to 7, and more preferably 5 or 6.

R₃ is preferably a hydrogen atom or a methyl group, and more preferably a methyl group.

The alkyl group as R₄, R₅, and R₆ may be linear or branched, and may have a substituent. As the alkyl group, an alkyl group having 1 to 4 carbon atoms, such as a methyl group, an ethyl group, a n-propyl group, an isopropyl group, a n-butyl group, an isobutyl group, or a t-butyl group, is preferable.

The cycloalkyl group as R₄, R₅, and R₆ may be monocyclic or polycyclic, and may have a substituent. The cycloalkyl group is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group.

Examples of the substituent that each group described above can have include the same groups as described above as substituents that each group in Formula (AI) can have.

The acid-decomposable resin is more preferably a resin which contains, as the repeating unit represented by Formula (AI), the repeating unit represented by Formula (I) and the repeating unit represented by Formula (II).

In another aspect, the acid-decomposable resin is more preferably a resin which contains, as the repeating unit represented by Formula (AI), at least two kinds of repeating unit represented by Formula (I). In a case where the resin contains two or more kinds of repeating unit represented by Formula (I), it is preferable that the resin contains both of the repeating unit in which the alicyclic structure that R forms together with a carbon atom is a monocyclic alicyclic structure and the repeating unit in which the alicyclic structure that R forms together with a carbon atom is a polycyclic alicyclic structure. The number of carbon atoms of the monocyclic alicyclic structure is preferably 5 to 8, more preferably 5 or 6, and particularly preferably 5. The polycyclic alicyclic structure is preferably a norbornyl group, a tetracyclodecanyl group, a tetracyclododecanyl group, or an adamantyl group.

The resin (A1) may contain one kind of acid-decomposable group-containing repeating unit, or two or more kinds thereof in combination. When the resin contains two or more kinds of repeating unit, they are preferably combined in the following way, for example. In the following formulae, R each independently represents a hydrogen atom or a methyl group.

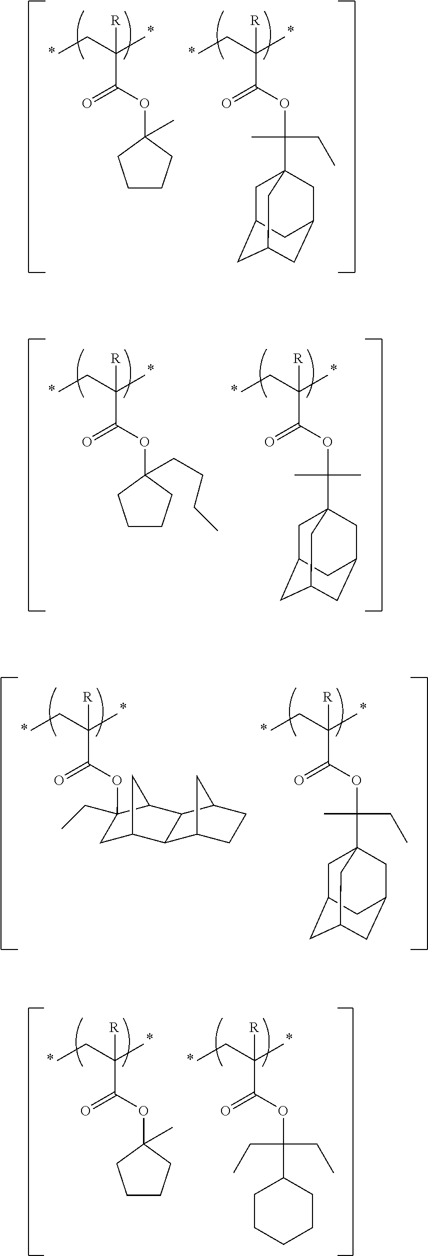

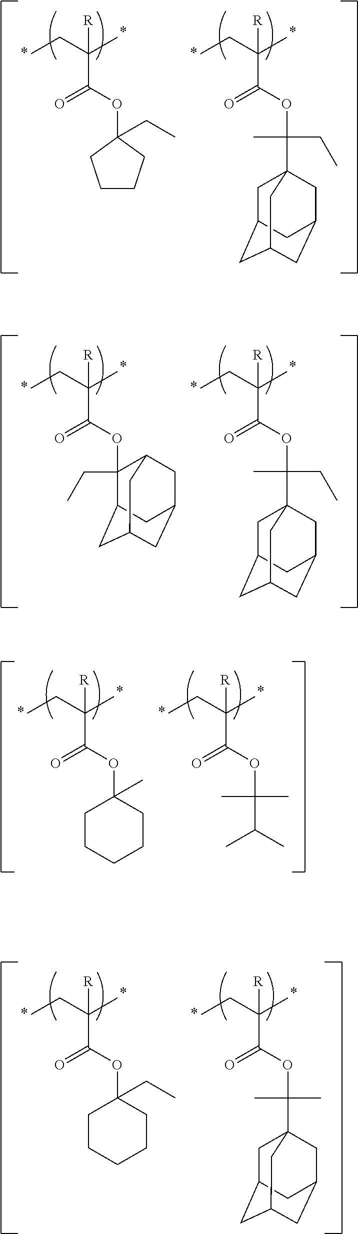

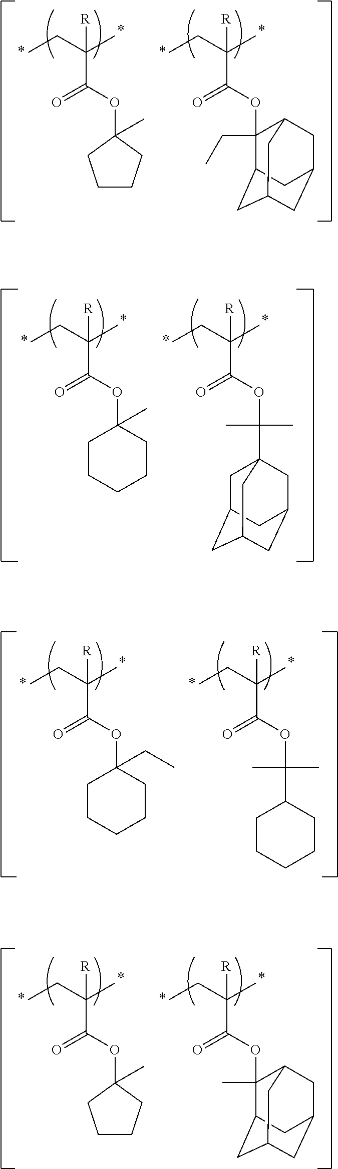

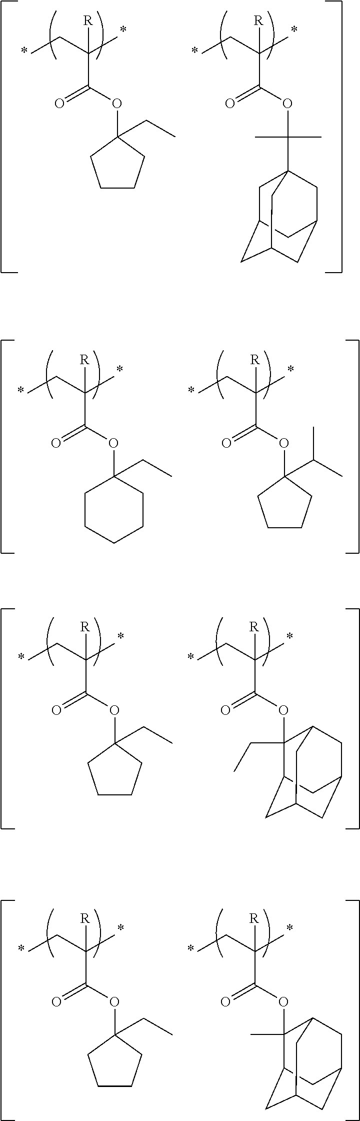

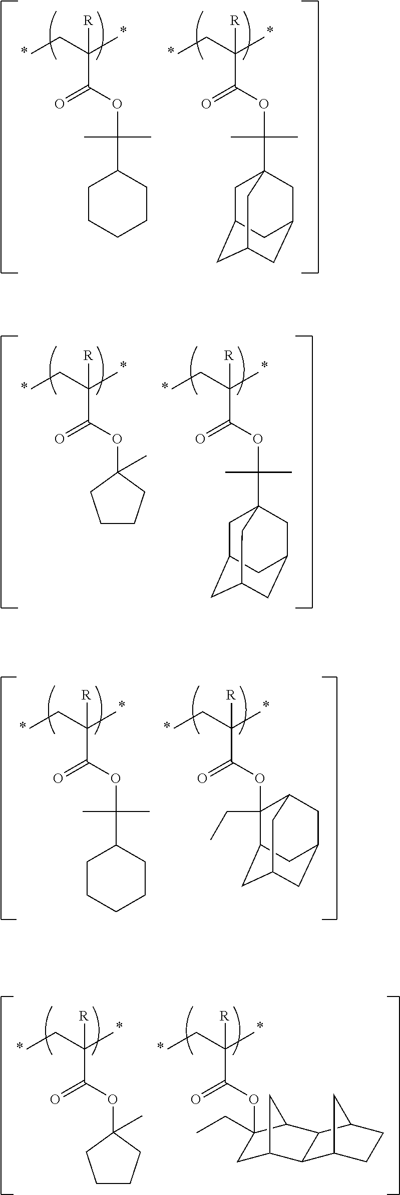

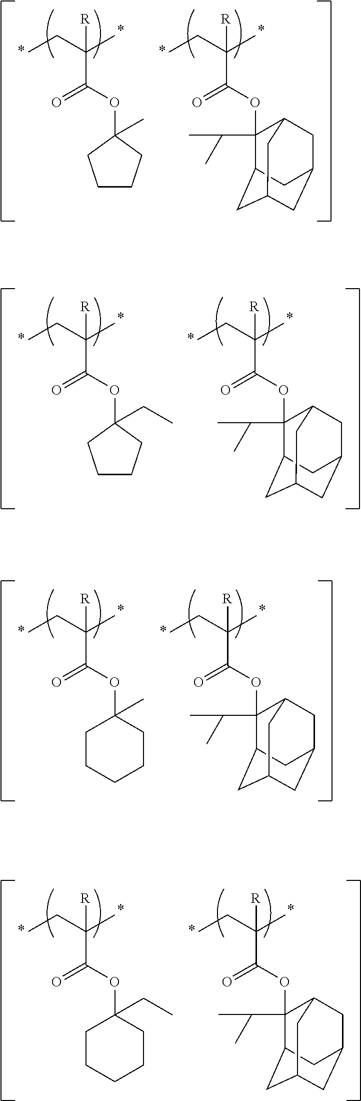

In an aspect, it is preferable that the resin (A1) contains a repeating unit having a cyclic carbonic acid ester structure. The cyclic carbonic acid ester structure is a structure having a ring which contains a bond represented by —O—C(═O)—O— as an atomic group constituting a ring. The ring containing the bond represented by —O—C(═O)—O— as an atomic group constituting a ring is preferably a 5- to 7-membered ring, and most preferably a 5-membered ring. Such a ring may form a fused ring by being fused with other rings.

It is preferable that the resin (A1) contains a repeating unit having a lactone structure or a sultone (cyclic sulfonic acid ester) structure.

Any of lactone structures or sultone structures can be used as long as they have a lactone structure or a sultone structure. The lactone structure or the sultone structure is preferably a 5- to 7-membered lactone ring structure or a 5- to 7-membered sultone ring structure, and more preferably a structure in which other ring structures are condensed with a 5- to 7-membered lactone ring structure by forming a bicyclo structure or a spiro structure or a structure in which other ring structures are condensed with a 5- to 7-membered sultone ring structure by forming a bicyclo structure or a spiro structure. It is even more preferable that the resin (A1) has a repeating unit having a lactone structure or a sultone structure represented by any of the following Formulae (LC1-1) to (LC1-17) and (SL1-1) to (SL1-3). The lactone structure or the sultone structure may be directly bonded to a main chain. Those represented by (LC1-1), (LC1-4), (LC1-5), and (LC1-8) are preferable as the lactone structure or sultone structure, and a lactone structure or sultone structure represented by (LC1-4) is particularly preferable. If a specific lactone structure or sultone structure is used, LWR and development defects are improved.

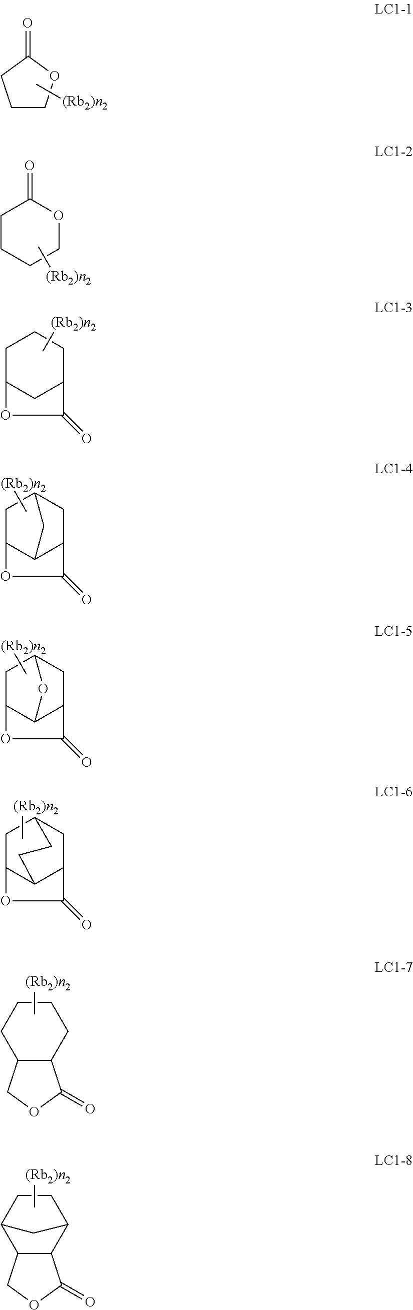

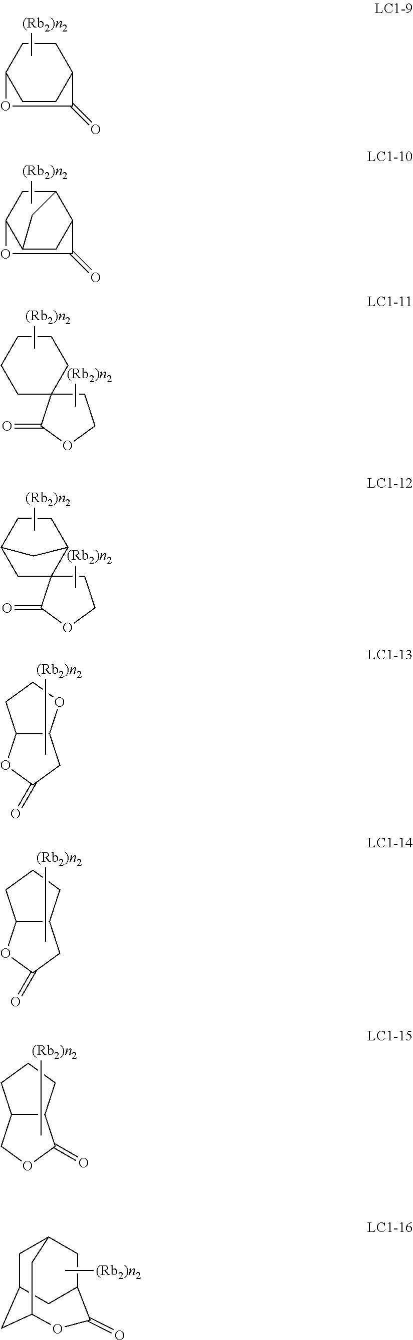

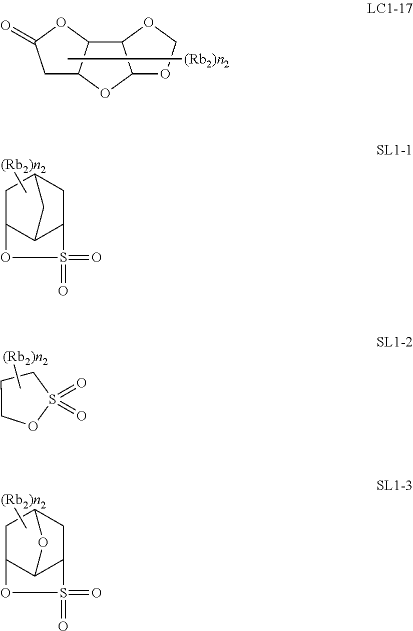

The lactone structure portion or the sultone structure portion may or may not have a substituent (Rb₂). Examples of the preferred substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid-decomposable group, and the like. The substituent (Rb₂) is more preferably an alkyl group having 1 to 4 carbon atoms, a cyano group, or an acid-decomposable group. n₂ represents an integer of 0 to 4. When n₂ is equal to or greater than 2, a plurality of substituents (Rb₂) may be the same as or different from each other. Furthermore, a plurality of substituents (Rb₂) may form a ring by being bonded to each other.

It is preferable that the resin (A1) contains a repeating unit having a lactone structure or a sultone structure represented by the following Formula (III).

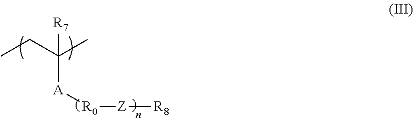

In Formula (III), A represents an ester bond (a group represented by —COO—) or an amide bond (a group represented by —CONH—).

In a case where there is a plurality of R₀'s, R₀ each independently represents an alkylene group, a cycloalkylene group, or a combination of these.

In a case where there is a plurality of Z's, Z each independently represents a single bond, an ether bond, an ester bond, an amide bond, a urethane bond,

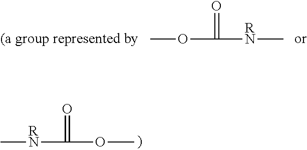

or a urea bond.

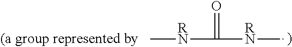

Herein, R each independently represents a hydrogen atom, an alkyl group, a cycloalkyl group, or an aryl group.

R₈ represents a monovalent organic group having a lactone structure or a sultone structure.

n is a repetition number of a structure represented by —R₀—Z— and represents an integer of 0 to 2.

R₇ represents a hydrogen atom, a halogen atom, or an alkyl group.

The alkylene group or the cycloalkylene group as R₀ may have a substituent.

Z is preferably an ether bond or an ester bond, and particularly preferably an ester bond.

The alkyl group as R₇ is preferably an alkyl group having 1 to 4 carbon atoms, more preferably a methyl group or an ethyl group, and particularly preferably a methyl group. The alkylene group or the cycloalkylene group as R₀ and the alkyl group as R₇ may each have a substituent, and examples of the substituent include a halogen atom such as a fluorine atom, a chlorine atom, or a bromine atom, a mercapto group, a hydroxy group, an alkoxy group such as a methoxy group, an ethoxy group, an isopropoxy group, a t-butoxy group, or a benzyloxy group, and an acetoxy group such as an acetyloxy group or a propionyloxy group. R₇ is preferably a hydrogen atom, a methyl group, a trifluoromethyl group, or a hydroxymethyl group.

R₀ is preferably a linear alkylene group having 1 to 10 carbon atoms and more preferably a linear alkylene group having 1 to 5 carbon atoms, and examples thereof include a methylene group, an ethylene group, a propylene group, and the like. The cycloalkylene group as R₀ is preferably a cycloalkylene group having 3 to 20 carbon atoms, and examples thereof include a cyclohexylene group, a cyclopentylene group, a norbornylene group, an adamantylene group, and the like. In order to bring about the effects of the present invention, a linear alkylene group is more preferable, and a methylene group is particularly preferable.

The monovalent organic group represented by R₈ having a lactone structure or a sultone structure is not limited as long as it has a lactone structure or a sultone structure, and specific examples thereof include a lactone structure or a sultone structure represented by any of Formulae (LC1-1) to (LC1-17), (SL1-1), and (SL1-2) described above. Among these, a structure represented by (LC1-4) is particularly preferable. n₂ in (LC1-1) to (LC1-17), (SL1-1), and (SL1-2) is more preferably equal to or less than 2.

R₈ is preferably a monovalent organic group having an unsubstituted lactone structure or sultone structure or a monovalent organic group having a lactone structure or a sultone structure having a methyl group, a cyano group, or an alkoxycarbonyl group as a substituent, and more preferably a monovalent organic group having a lactone structure (cyanolactone) or a sultone structure (cyanosultone) having a cyano group as a substituent.

n in Formula (III) is preferably 1 or 2.

Specific examples of the repeating unit having the lactone structure or the sultone structure represented by Formula (III) will be shown below, but the present invention is not limited thereto.

In the following specific examples, R represents a hydrogen atom, an alkyl group which may have a substituent, or a halogen atom. R preferably represents a hydrogen atom, a methyl group, a hydroxymethyl group, or an acetoxymethyl group.

In the following formulae, Me represents a methyl group.

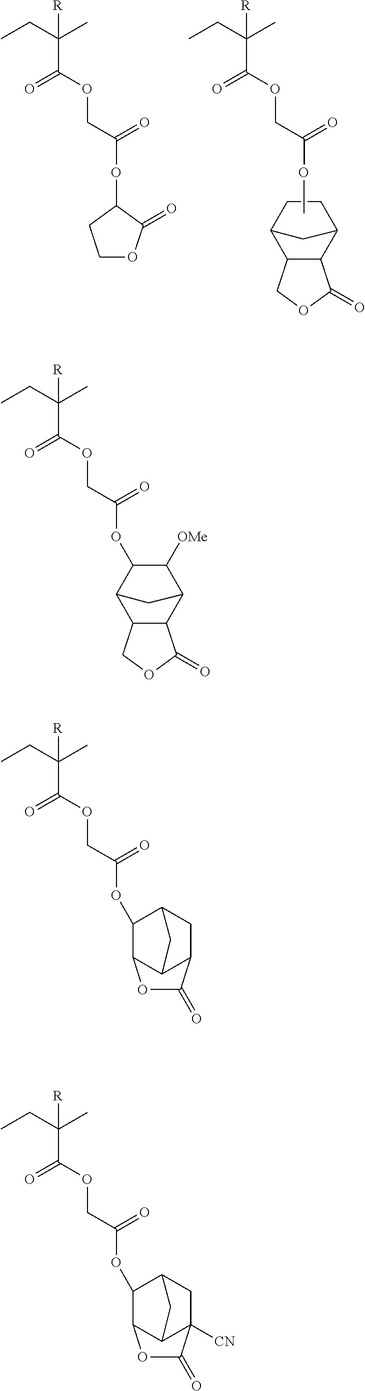

As the repeating unit having a lactone structure and a sultone structure, a repeating unit represented by the following Formula (III-1) or (III-1′) is more preferable.

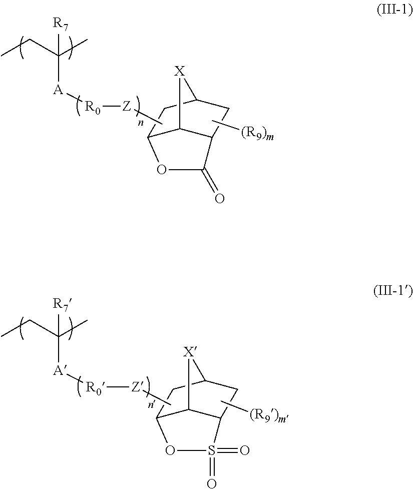

In Formulae (III-1) and (III-1′), R₇, A, R₀, Z, and n have the same definition as described in Formula (III).

R₇′, A′, R₀′, Z′, and n′ have the same definition as R₇, A, R₀, Z, and n in Formula (III) respectively.

In a case where there is a plurality of R₉'s, R₉ each independently represents an alkyl group, a cycloalkyl group, an alkoxycarbonyl group, a cyano group, a hydroxyl group, or an alkoxy group. In a case where there is a plurality of R₉'s, two R₉'s may form a ring by being bonded to each other.

In a case where there is a plurality of R₉′'s, R₉′ each independently represents an alkyl group, a cycloalkyl group, an alkoxycarbonyl group, a cyano group, a hydroxyl group, or an alkoxy group. In a case where there is a plurality of R₉′'s, two R₉′'s may form a ring by being bonded to each other.

X and X′ each independently represent an alkylene group, an oxygen atom, or a sulfur atom.

m and m′ show the number of substituents. m and m′ each independently represent an integer of 0 to 5. It is preferable that m and m′ each independently represent 0 or 1.

The alkyl group as R₉ and R₉′ is preferably an alkyl group having 1 to 4 carbon atoms, more preferably a methyl group or an ethyl group, and most preferably a methyl group. Examples of the cycloalkyl group include a cyclopropyl, cyclobutyl, cyclopentyl, or cyclohexyl group. Examples of the alkoxycarbonyl group include a methoxycarbonyl group, an ethoxycarbonyl group, a n-butoxycarbonyl group, a t-butoxycarbonyl group, and the like. Examples of the alkoxy group include a methoxy group, an ethoxy group, a propoxy group, an isopropoxy group, a butoxy group, and the like. These groups may have a substituent, and examples of the substituent include a hydroxy group, an alkoxy group such as a methoxy group or an ethoxy group, a cyano group, and a halogen atom such as a fluorine atom. R₉ and R₉′ are more preferably a methyl group, a cyano group, or an alkoxycarbonyl group, and even more preferably a cyano group.

Examples of the alkylene group as X and X′ include a methylene group, an ethylene group, and the like. X and X′ are preferably an oxygen atom or a methylene group, and more preferably a methylene group.

In a case where each of m and m′ is equal to or greater than 1, at least one R₉ and one R₉′ substitute a carbonyl group of lactone preferably in an α position or a β position, and particularly preferably in an α position.

Specific examples of the repeating unit represented by Formula (III-1) or (III-1′) having a group having a lactone structure or a sultone structure will be shown below, but the present invention is not limited thereto. In the following specific examples, R represents a hydrogen atom, an alkyl group which may have a substituent, or a halogen atom. R preferably represents a hydrogen atom, a methyl group, a hydroxymethyl group, or an acetoxymethyl group.

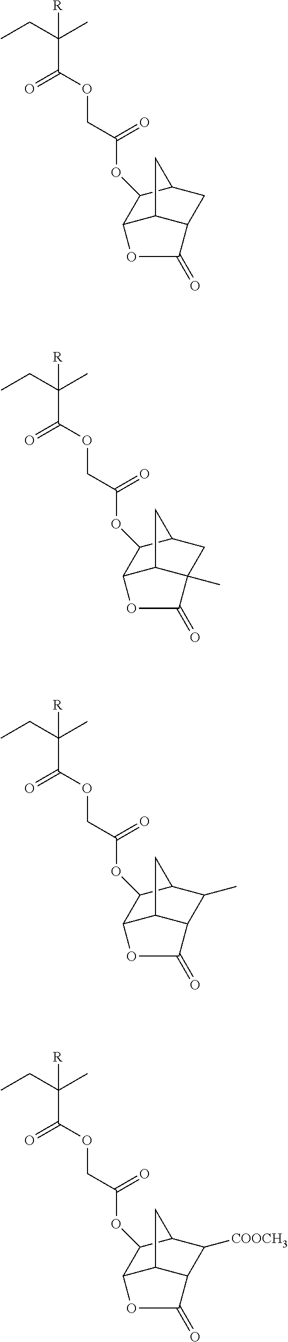

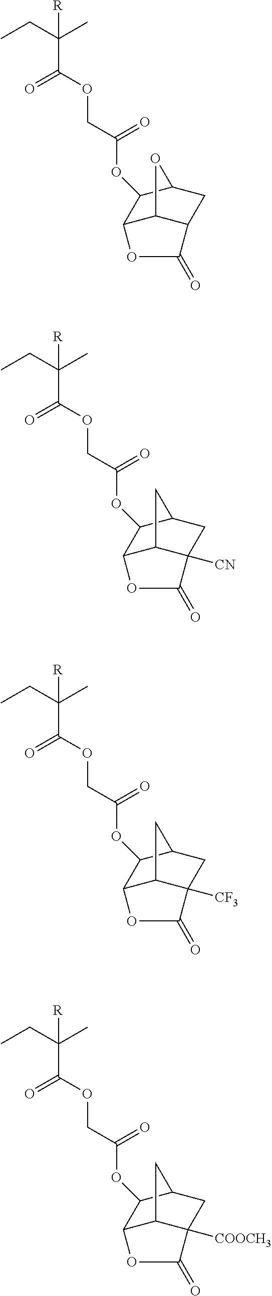

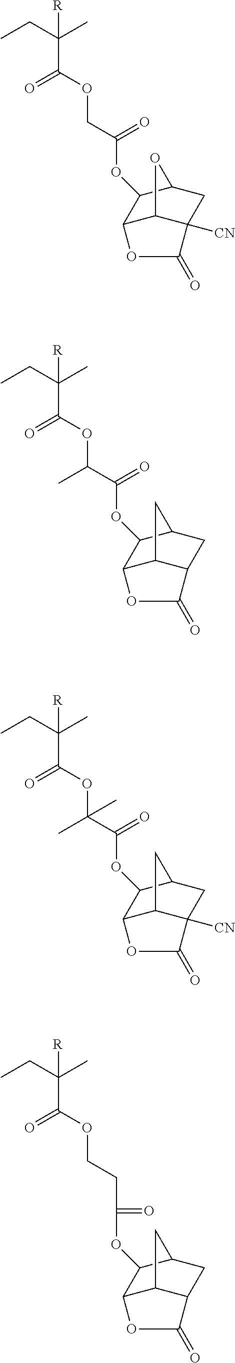

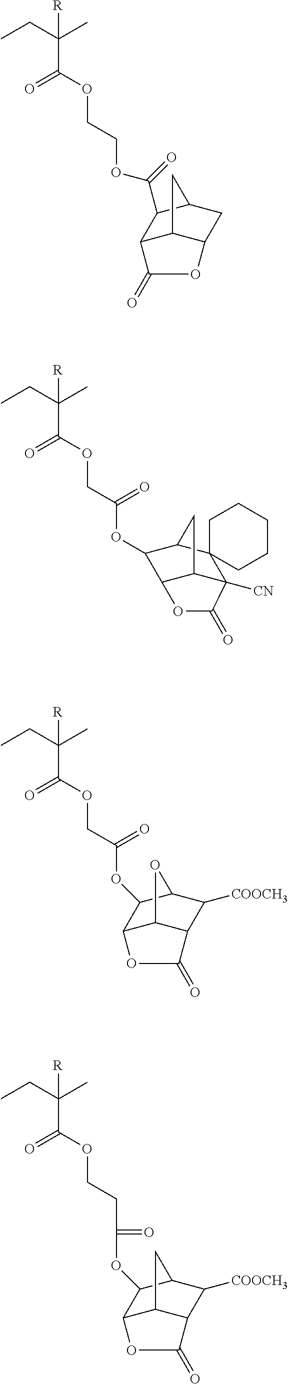

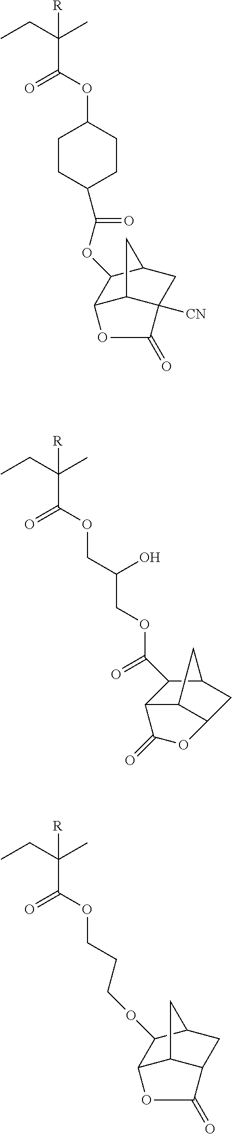

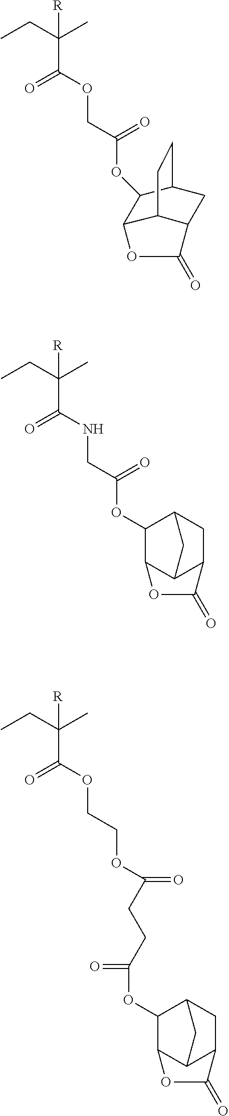

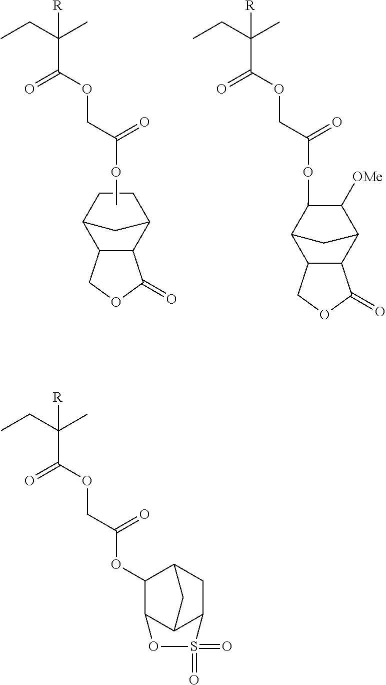

In a case where the resin (A1) contains plural kinds of repeating unit represented by Formula (III), a total content of the repeating unit represented by Formula (III) is, with respect to all of the repeating units in resin (A1), preferably 15 to 60 mol %, more preferably 20 to 60 mol %, and even more preferably 30 to 50 mol %.

The resin (A1) may contain the aforementioned repeating unit having a lactone structure or a sultone structure in addition to the unit represented by Formula (III).

In addition to the specific examples listed above, specific examples of repeating units having a lactone group or a sultone group will be shown below, but the present invention is not limited thereto.

(In the formulae, Rx represents H, CH₃, CH₂OH, or CF₃.)

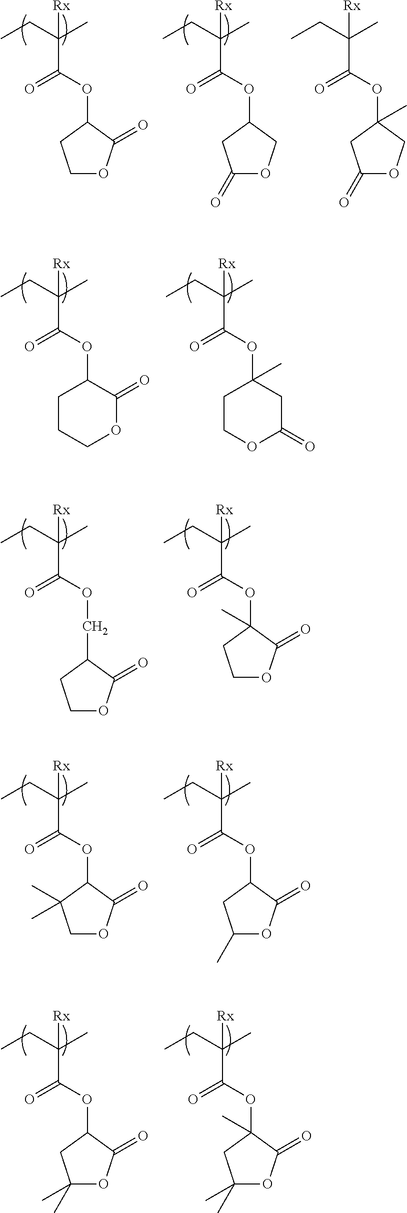

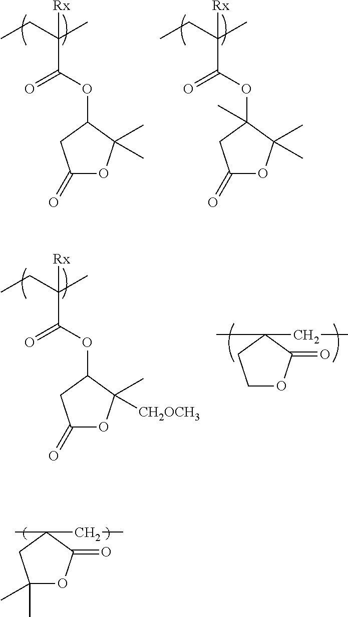

(In the formulae, Rx represents H, CH₃, CH₂OH, or CF₃.)

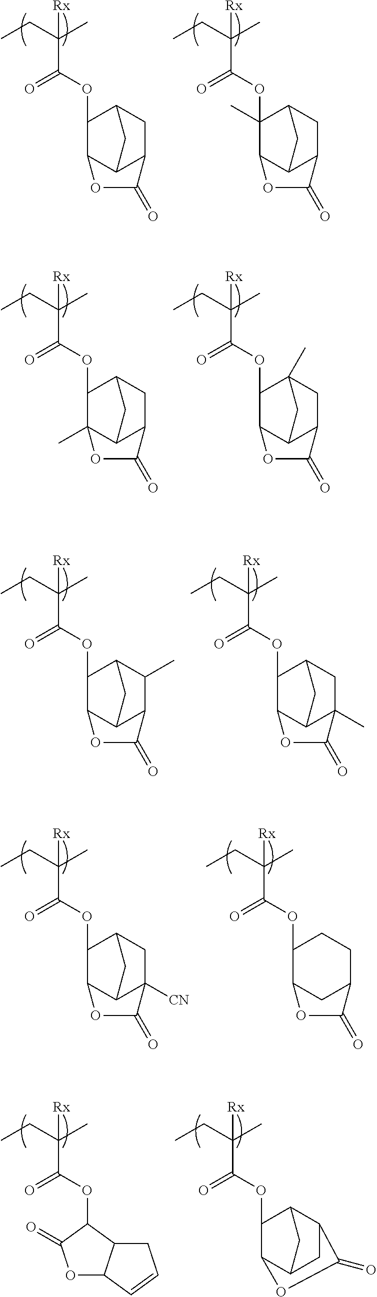

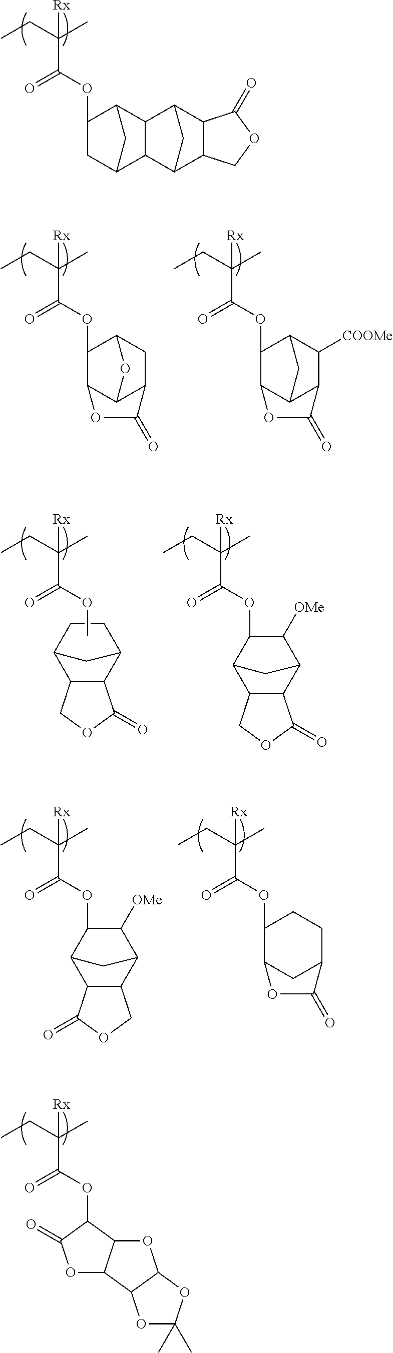

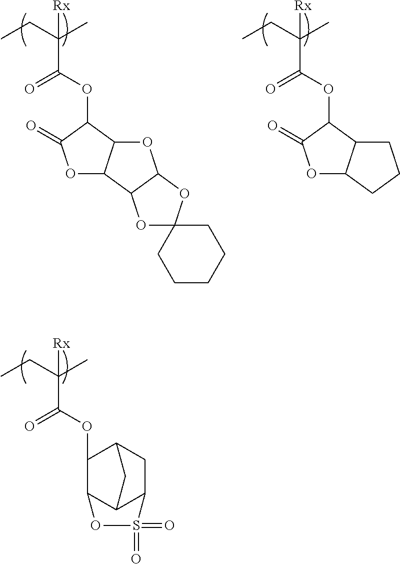

(In the formulae, Rx represents H, CH₃, CH₂OH, or CF₃.)

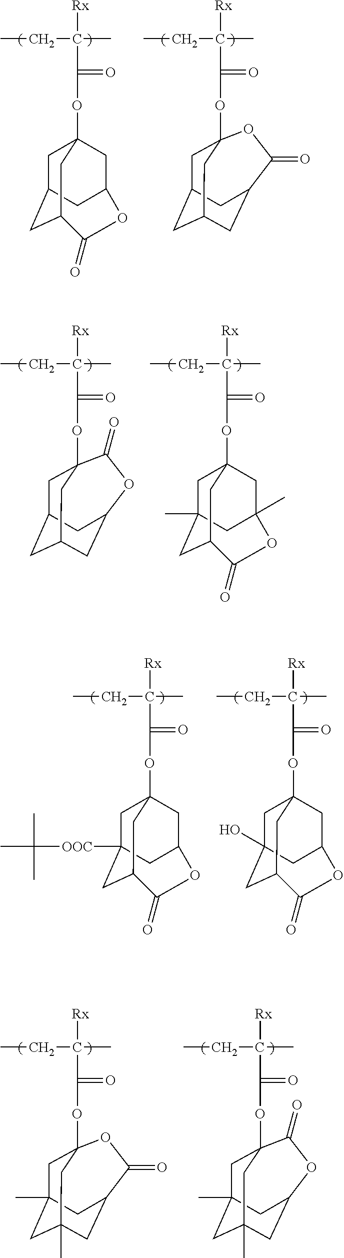

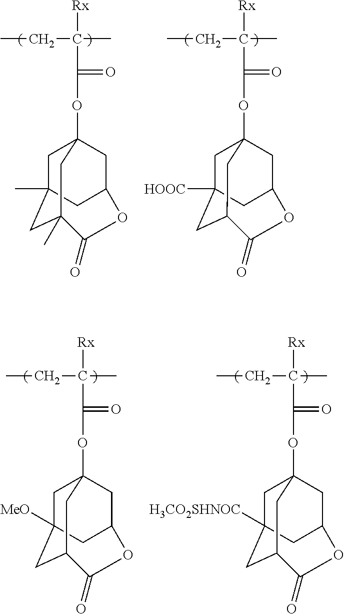

As particularly preferred repeating units among the above specific examples, the following repeating units are exemplified. By selecting an optimal lactone group or sultone group, the pattern profile and density distribution dependency are improved.

(In the formulae, Rx represents H, CH₃, CH₂OH, or CF₃.)

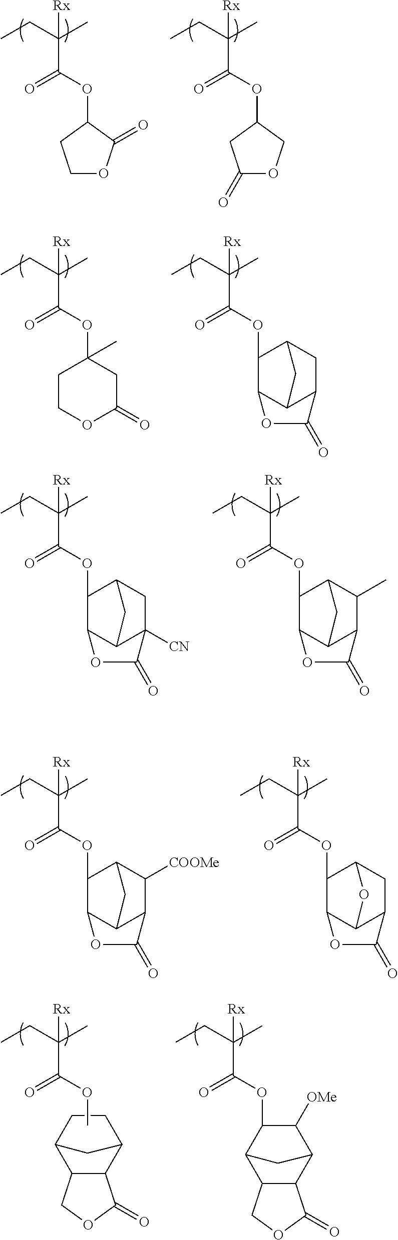

Generally, the repeating unit having a lactone structure or a sultone structure has an optical isomer, and any of optical isomers may be used. One kind of optical isomer may be used singly, or a plurality of optical isomers may be used by being mixed together. In a case where one kind of optical isomer is mainly used, an optical purity (ee) thereof is preferably equal to or higher than 90% and more preferably equal to or higher than 95%.

In a case where the resin (A1) contains plural kinds of the repeating unit having a lactone structure or a sultone structure, a total content of the repeating unit, which has a lactone structure or a sultone structure, other than the repeating unit represented by Formula (III) is, with respect to all of the repeating units in the resin, preferably 15 to 60 mol %, more preferably 20 to 50 mol %, and even more preferably 30 to 50 mol %.

In order to enhance the effects of the present invention, two or more kinds of lactone or sultone repeating unit selected from repeating units represented by Formula (III) can be used in combination. In a case where the repeating units are used in combination, it is preferable to select two or more kinds of lactone or sultone repeating unit in which n in Formula (III) is 1 and to use them in combination.

It is preferable that the resin (A1) has a repeating unit having a hydroxyl group or a cyano group that is other than the repeating units represented by Formulae (AI) and (III). If the resin (A1) has such a repeating unit, the adhesiveness to a substrate and the affinity with a developer are improved. The repeating unit having a hydroxyl group or a cyano group is preferably a repeating unit which has an alicyclic hydrocarbon structure substituted with a hydroxyl group or a cyano group and does not have an acid-decomposable group. In the alicycilc hydrocarbon structure substituted with a hydroxyl group or a cyano group, the alicyclic hydrocarbon structure is preferably an adamantyl group, a diadamantyl group, or a norbornane group. As the alicyclic hydrocarbon structure having a hydroxyl group or a cyano group, partial structures represented by the following Formulae (VIIa) to (VIId) are preferable.

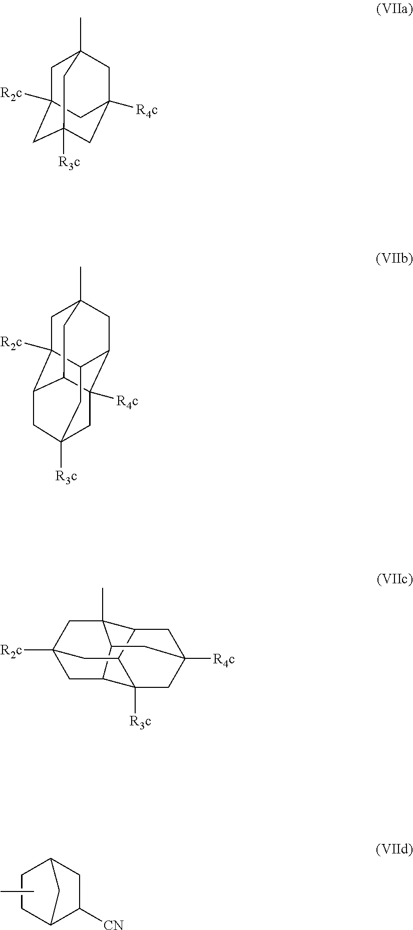

In Formulae (VIIa) to (VIII), R₂c to R₄c each independently represent a hydrogen atom, a hydroxyl group, or a cyano group. Here, at least one of R₂c to R₄c represents a hydroxyl group or a cyano group. It is preferable that one or two out of R₂c to R₄c represent a hydroxyl group, and the rest represents a hydrogen atom. It is more preferable that, in Formula (VIIa), two out of R₂c to R₄c represent a hydroxyl group, and the rest represents a hydrogen atom.

Examples of repeating units having partial structures represented by Formulae (VIIa) to (VIId) include repeating units represented by the following Formulae (AIIa) to (AIId).

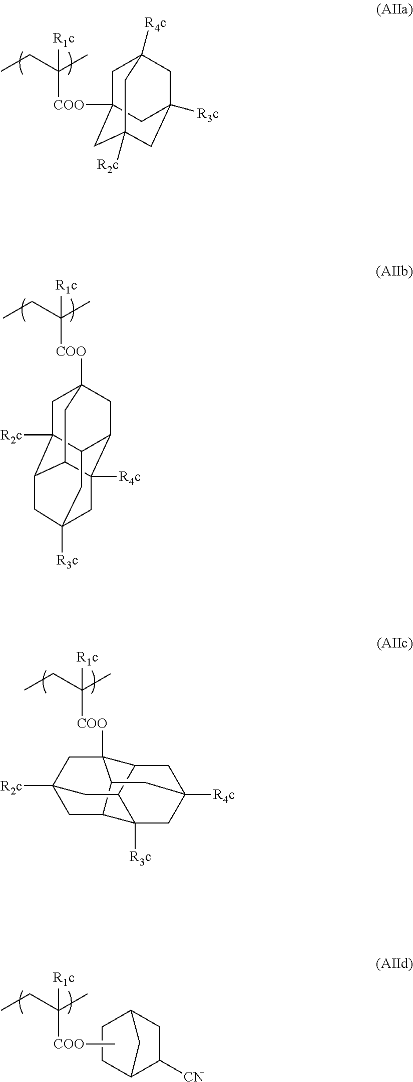

In Formulae (AIIa) to (AIId), R1c represents a hydrogen atom, a methyl group a trifluoromethyl group, or a hydroxymethyl group.

R₂c to R₄c have the same definition as R₂c to R₄c in Formulae (VIIa) to (VIIc).

A content of the repeating unit having a hydroxyl group or a cyano group is, with respect to all of the repeating units in the resin (A1), preferably 5 to 40 mol %, more preferably 5 to 30 mol %, and even more preferably 10 to 25 mol %.

Specific examples of the repeating unit having a hydroxyl group or a cyano group will be shown below, but the present invention is not limited thereto.

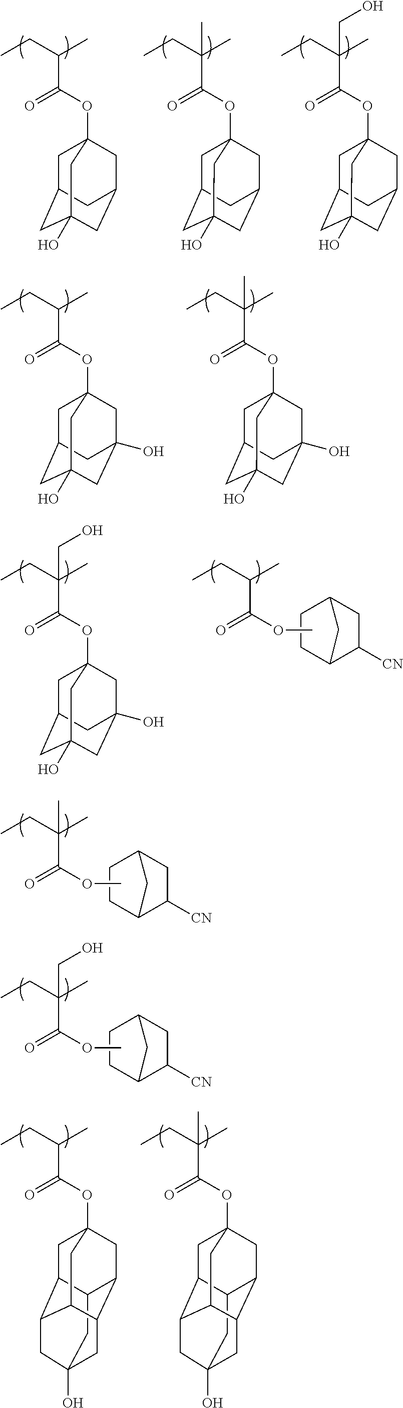

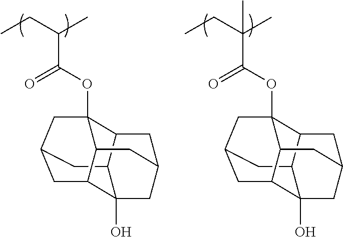

The resin (A1) used in the resist composition of the present invention may also have a repeating unit having an acid group. Examples of the acid group include a carboxyl group, a sulfonamide group, a sulfonylimide group, a bissulfonylimide group, a naphthol structure, and an aliphatic alcohol group (for example, hexafluoroisopropanol group) in which the α position is substituted with an electron-withdrawing group. The resin (A1) more preferably has a repeating unit having a carboxyl group. If the resin (A1) contains the repeating unit having an acid group, resolution thereof used for contact holes is improved. As the repeating unit having an acid group, all of a repeating unit in which an acid group is directly bonded to a main chain of a resin, such as a repeating unit composed of an acrylic acid or a methacrylic acid, a repeating unit in which an acid group is bonded to a main chain of a resin through a linking group, and a repeating unit introduced into a terminal of a polymer by using a polymerization initiator or a chain transfer agent having an acid group at the time of polymerization are preferable. The linking group may have a monocyclic or polycyclic hydrocarbon structure. Among the above, a repeating unit composed of an acrylic acid or a methacrylic acid is particularly preferable.

The resin (A1) may or may not contain the repeating unit having an acid group. In a case where the resin (A1) contains the repeating unit having an acid group, a content of the repeating unit is, with respect to all of the repeating units in the resin (A1), preferably 1 to 20 mol %, more preferably 3 to 15 mol %, and even more preferably 5 to 10 mol %.

Specific examples of the repeating unit having an acid group will be shown below, but the present invention is not limited thereto.

In the specific examples, Rx represents H, CH₃, CH₂OH, or CF₃.

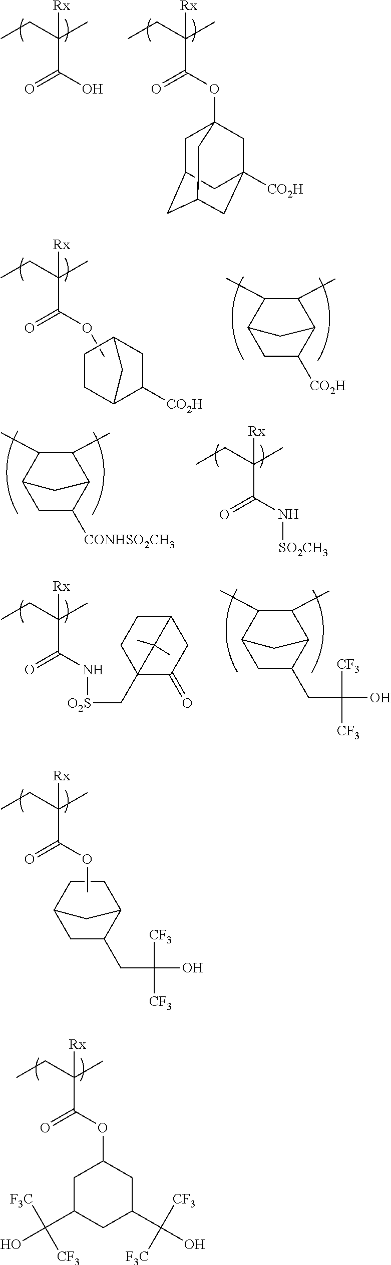

The resin (A1) of the present invention can further have a repeating unit which has an alicyclic hydrocarbon structure not having a polar group (for example, the aforementioned acid group, a hydroxyl group, or a cyano group) and is not decomposed by an acid. Examples of such a repeating unit include a repeating unit represented by Formula (IV).

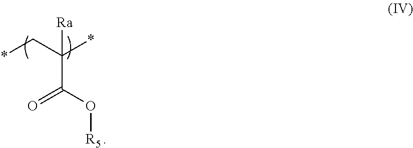

In Formula (IV), R₅ represents a hydrocarbon group which has at least one cyclic structure and does not have a polar group.

Ra represents a hydrogen atom, an alkyl group, or a —CH₂—O—Ra₂ group. In the formula, Ra₂ represents a hydrogen atom, an alkyl group, or an acyl group. Ra is preferably a hydrogen atom, a methyl group, a hydroxymethyl group, or a trifluoromethyl group, and particularly preferably a hydrogen atom or a methyl group.

The cyclic structure that R₅ has include a monocyclic hydrocarbon group and a polycyclic hydrocarbon group which may be a saturated ring, a partially saturated ring, or an aromatic ring. Examples of the monocyclic hydrocarbon group include a cycloalkyl group having 3 to 12 carbon atoms, such as a cyclopentyl group, a cyclohexyl group, a cycloheptyl group, or a cyclooctyl group, a cycloalkenyl group having 3 to 12 carbon atoms such as a cyclohexenyl group, and a phenyl group. The monocyclic hydrocarbon group is preferably a monocyclic hydrocarbon group having 3 to 7 carbon atoms, and more preferably, for example, a cyclopentyl group or a cyclohexyl group.

The polycyclic hydrocarbon group include a ring-aggregated hydrocarbon group and a cross-linked cyclic hydrocarbon group. Examples of the ring-aggregated hydrocarbon group include a bicyclohexyl group, perhydronaphthalenyl group, and the like. Examples of the cross-linked cyclic hydrocarbon group include a bicyclic hydrocarbon ring such as pinane, bornane, norpinane, norbornane, a bicyclooctane ring (a bicyclo[2.2.2]octane ring, a bicyclo[3.2.1]octane ring, or the like), a tricyclic hydrocarbon ring such as homobredane, adamantane, tricyclo[5.2.1.0^{2,6}]decane, or a tricyclo[4.3.1.1^{2,5}]undecane ring, a tetracyclic hydrocarbon ring such as tetracyclo[4.4.0.1^{2,5}.1^{7,10}]dodecane or perhydro-1,4-methano-5,8-methanonaphthalene ring, and the like. The cross-linked cyclic hydrocarbon group also includes a condensed cyclic hydrocarbon ring, for example, a condensed ring in which a plurality of 5- to 8-membered cycloalkane rings is condensed, such as perhydronaphthalene (decalin), perhydroanthracene, perhydrophenanthrene, perhydroacenaphthene, perhydrofluorene, perhydroindene, or a perhydrophenalene ring.

Examples of a preferred cross-linked cyclic hydrocarbon ring include a norbornyl group, an adamantyl group, a bicyclooctanyl group, a tricyclo[5.2.1.0^{2,6}]decanyl group, and the like. Examples of a more preferred cross-linked cyclic hydrocarbon ring include a norbornyl group and an adamantyl group.

These alicyclic hydrocarbon groups may have a substituent, and examples of a preferred substituent include a halogen atom, an alkyl group, a hydroxyl group in which a hydrogen atom is substituted, an amino group in which a hydrogen atom is substituted, and the like. Examples of a preferred halogen atom include bromine, chlorine, and fluorine atoms, and examples of a preferred alkyl group include a methyl, ethyl, butyl, or a t-butyl group. The above alkyl group may further have a substituent, and examples of the substituent that the alkyl group may further have include a halogen atom, an alkyl group, a hydroxyl group in which a hydrogen atom is substituted, and an amino group in which a hydrogen atom is substituted.

Examples of the group in which a hydrogen atom is substituted include an alkyl group, a cycloalkyl group, an aralkyl group, a substituted methyl group, a substituted ethyl group, an alkoxycarbonyl group, and an aralkyloxycarbonyl group. Examples of the preferred alkyl group include an alkyl group having 1 to 4 carbon atoms. Examples of the preferred substituted methyl group include a methoxymethyl, methoxythiomethyl, benzyloxymethyl, t-butoxymethyl, or 2-methoxyethoxymethyl group. Examples of the preferred substituted ethyl group include 1-ethoxyethyl and 1-methyl-1-methoxyethyl. Examples of the preferred acyl group include an aliphatic acyl group having 1 to 6 carbon atoms such as a formyl, acetyl, propionyl, butyryl, isobutyryl, valeryl, or pivalolyl group. Examples of the alkoxycarbonyl group include an alkoxycarbonyl group having 1 to 4 carbon atoms and the like.

The resin (A1) may or may not contain the repeating unit which has an alicyclic hydrocarbon structure not having a polar group and is not decomposed by an acid. In a case where the resin (A1) contains such a repeating unit, a content of the repeating unit is, with respect to all of the repeating units in the resin (A1), preferably 1 to 40 mol %, and more preferably 2 to 20 mol %.

Specific examples of the repeating unit which has an alicyclic hydrocarbon structure not having a polar group and is not decomposed by an acid will be shown below, but the present invention is not limited thereto. In the formulae, Ra represents H, CH₃, CH₂OH, or CF₃.

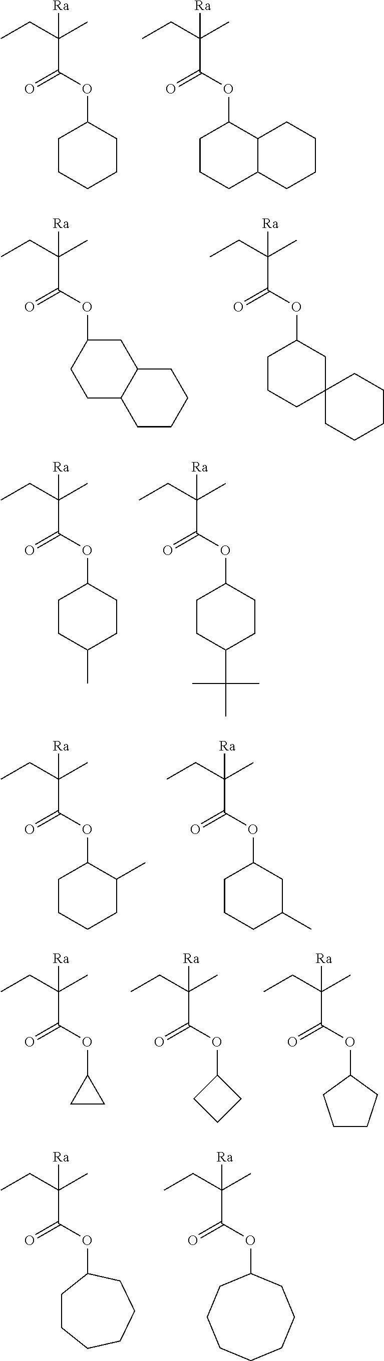

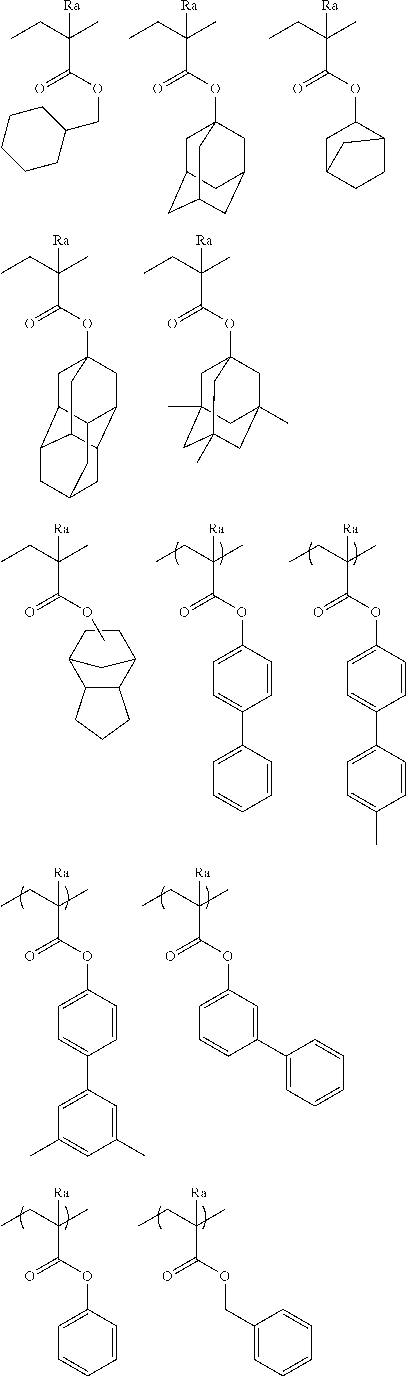

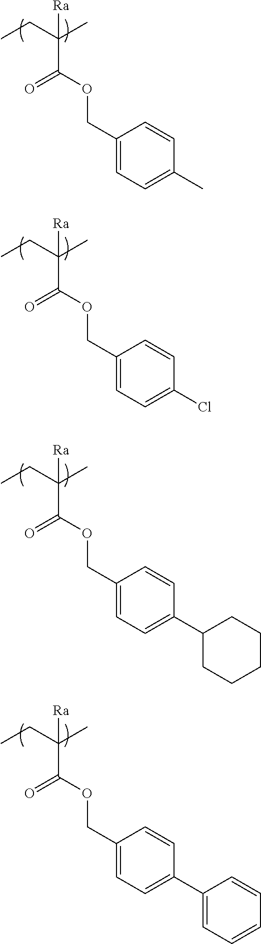

For the purpose of controlling the dry etching resistance, suitability for a standard developer, adhesiveness to a substrate, and resist profile as well as the resolving power, heat resistance, sensitivity, and the like which are characteristics generally required for the resist, the resin (A1) used in the composition of the present invention can have various repeating structural units in addition to the aforementioned repeating structural units.

Examples of such repeating structural units include, but are not limited to, repeating structural units corresponding to the following monomers.

If the resin (A1) contains the following monomers, the performances required for the resin used in the composition of the present invention, particularly, (1) solubility in a coating solvent, (2) film formability (glass transition point), (3) alkali developability, (4) film thinning (hydrophilicity, hydrophobicity, and selection of an alkali-soluble group), (5) adhesiveness of an unexposed portion to a substrate, (6) dry etching resistance, and the like can be finely adjusted.

Examples of such monomers include a compound having one addition-polymerizable unsaturated bond selected from acrylic acid esters, methacrylic acid esters, acrylamides, methacrylamides, an allyl compound, vinyl ethers, and vinyl esters, and the like.

In addition, other addition-polymerizable unsaturated compounds can be copolymerized with the monomers corresponding to the aforementioned various repeating structural units as long as the compounds can be copolymerized with the monomers.

In the resin (A1) used in the composition of the present invention, a molar ratio of each repeating structural unit contained is appropriately set so as to control the dry etching resistance, suitability for a standard developer, adhesiveness to a substrate, and resist profile of the resist as well as the resolving power, heat resistance, sensitivity, and the like which are characteristics generally required for the resist.

When the composition of the present invention is for ArF exposure, in view of transparency with respect to ArF light, it is preferable that the resin (A1) used in the composition of the present invention substantially does not have an aromatic group. More specifically, a total content of a repeating unit having an aromatic group is, with respect to all of the repeating units of the resin (A1), preferably equal to or less than 5 mol %, more preferably equal to or less than 3 mol %, and ideally 0 mol %; that is, it is preferable that the resin does not have a repeating unit having an aromatic group. Furthermore, it is preferable that the resin (A1) has a monocyclic or polycyclic alicyclic hydrocarbon structure.

In a case where the composition of the present invention is irradiated with KrF excimer laser light, electron beams, X-rays, or high-energy beams (EUV or the like) having a wavelength of equal to or less than 50 nm, it is preferable that the resin (A1) further has a hydroxystyrene repeating unit. It is more preferable that the resin (A1) has either a copolymer of hydroxystyrene and hydroxystyrene which is protected with a group eliminated by the action of an acid or a copolymer of hydroxystyrene and a (meth)acrylic acid tertiary alkyl ester.

Specific examples of such a resin include a resin having a repeating unit represented by the following Formula (A).

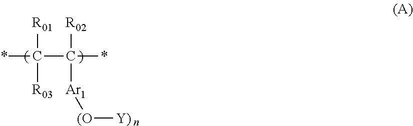

In the formula, R₀₁, R₀₂, and R₀₃ each independently represent hydrogen atom, an alkyl group, a cycloalkyl group, a halogen atom, a cyano group, or an alkoxycarbonyl group. Ar₁ represents an aromatic ring group, for example. R₀₃ and Ar₁ may be an alkylene group and may form a 5- or 6-membered ring together with a —C—C— chain by being bonded to each other.

n Y's each independently represent a hydrogen atom or a group eliminated by the action of an acid. Here, at least one Y represents a group eliminated by the action of an acid.

n represents an integer of 1 to 4. n is preferably 1 or 2, and more preferably 1.

The alkyl group as R₀₁ to R₀₃ is, for example, an alkyl group having 20 or less carbon atoms. The alkyl group is preferably a methyl group, an ethyl group, a propyl group, an isopropyl group, a n-butyl group, a sec-butyl group, a hexyl group, a 2-ethylhexyl group, an octyl group, or a dodecyl group. It is preferable that each of these alkyl groups is an alkyl group having 8 or less carbon atoms. These alkyl groups may have a substituent.

The alkyl group contained in the alkoxycarbonyl group is preferably the same as the alkyl group as R₀₁ to R₀₃.

The cycloalkyl may be a monocyclic cycloalkyl group or a polycyclic cycloalkyl group. Examples of the cycloalkyl group include a monocyclic cycloalkyl group having 3 to 8 carbon atoms, such as a cyclopropyl group, a cyclopentyl group, and a cyclohexyl group. These cycloalkyl groups may have a substituent.

Examples of the halogen atom include a fluorine atom, a chlorine atom, a bromine atom, and an iodine atom. The halogen atom is preferably a fluorine atom.

In a case where R03 represents an alkylene group, examples of the alkylene group preferably include an alkylene group having 1 to 8 carbon atoms, such as a methylene group, an ethylene group, a propylene group, a butylene group, a hexylene group, and an octylene group.

The aromatic ring group as Ar₁ is preferably an aromatic ring group having 6 to 14 carbon atoms, and examples thereof include a benzene ring, a toluene ring, and a naphthalene ring. These aromatic groups may have a substituent.

Examples of the group Y eliminated by the action of an acid include groups represented by —C(R₃₆)(R₃₇)(R₃₈), —C(═O)—O—C(R₃₆)(R₃₇)(R₃₈), —C(R₀₁)(R₀₂)(OR₃₉), —C(R₀₁)(R₀₂)—C(═O)—O—C(R₃₆)(R₃₇)(R₃₈), and —CH(R₃₆)(Ar).

In the formulae, R₃₆ to R₃₉ each independently represent represents an alkyl group, a cycloalkyl group, an aryl group, an aralkyl group, or an alkenyl group. R₃₆ and R₃₇ may form a ring structure by being bonded to each other.

R₀₁ and R₀₂ each independently represent a hydrogen atom, an alkyl group, a cycloalkyl group, an aryl group, an aralkyl group, or an alkenyl group.

Ar represents an aryl group.

The alkyl group as R₃₆ to R₃₉, R₀₁, or R₀₂ is preferably an alkyl group having 1 to 8 carbon atoms, and examples thereof include a methyl group, an ethyl group, a propyl group, a n-butyl group, a sec-butyl group, a hexyl group, and an octyl group.

The cycloalkyl group as R₃₆ to R₃₉, R₀₁, or R₀₂ may be a monocyclic cycloalkyl group or a polycyclic cycloalkyl group. The monocyclic cycloalkyl group is preferably a cycloalkyl group having 3 to 8 carbon atoms, and examples thereof include a cyclopropyl group, a cyclobutyl group, a cyclopentyl group, a cyclohexyl group, and a cyclooctyl group. The polycyclic cycloalkyl group is preferably a cycloalkyl group having 6 to 20 carbon atoms, and examples thereof include an adamantyl group, a norbornyl group, an isobornyl group, a camphanyl group, a dicyclopentyl group, an α-pinanyl group, a tricyclodecanyl group, a tetracyclododecyl group, and an androstanyl group. Some of the carbon atoms in the cycloalkyl group may be substituted with a heteroatom such as an oxygen atom.

The aryl group as R₃₆ to R₃₉, R₀₁, R₀₂, or Ar is preferably an aryl group having 6 to 10 carbon atoms, and examples thereof include a phenyl group, a naphthyl group, and an anthryl group.

The aralkyl group as R₃₆ to R₃₉, R₀₁, or R₀₂ is preferably an aralkyl group having 7 to 12 carbon atoms, and examples thereof preferably include a benzyl group, an phenethyl group, and a naphthylmethyl group.

The alkenyl group as R₃₆ to R₃₉, R₀₁, or R₀₂ is preferably an alkenyl group having 2 to 8 carbon atoms, and examples thereof include a vinyl group, an allyl group, a butenyl group, and a cyclohexenyl group.

The ring formed by the bonding between R₃₆ and R₃₇ may be monocyclic or polycyclic. The monocyclic ring is preferably a cycloalkane structure having 3 to 8 carbon atoms, and examples thereof include a cyclopropane structure, a cyclobutane structure, a cyclopentane structure, a cyclohexane structure, a cycloheptane structure, and a cyclooctane structure. The polycyclic ring is preferably a cycloalkane structure having 6 to 20 carbon atoms, and examples thereof include an adamantane structure, a norbornane structure, a dicyclopentane structure, a tricyclodecane structure, and a tetracyclododecane structure. Some of the carbon atoms in the ring structure may be substituted with a heteroatom such as an oxygen atom.

The aforementioned groups may each have a substituent. Examples of the substituent include an alkyl group, a cycloalkyl group, an aryl group, an amino group, an amide group, a ureide group, a urethane group, a hydroxyl group, a carboxyl group, a halogen atom, an alkoxy group, a thioether group, an acyl group, an acyloxy group, an alkoxycarbonyl group, a cyano group, and a nitro group. The number of carbon atoms of these substituents is preferably equal to or less than 8.

As the group Y eliminated by the action of an acid is more preferably a structure represented by the following Formula (B).

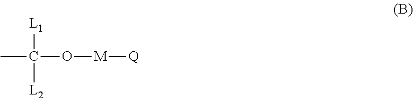

In the formula, L₁ and L₂ each independently represent a hydrogen atom, an alkyl group, a cycloalkyl group, an aryl group, or an aralkyl group.

M represents a single bond or a divalent linking group.

Q represents an alkyl group, a cycloalkyl group, a cyclic aliphatic group, an aromatic ring group, an amino group, an ammonium group, a mercapto group, a cyano group, or an aldehyde group. These cyclic aliphatic groups and aromatic ring groups may contain a heteroatom.

At least two out of Q, M, and L₁ may form a 5- or 6-membered ring by being bonded to each other.

The alkyl group as L₁ and L₂ is, for example, an alkyl group having 1 to 8 carbon atoms, and specific examples thereof include a methyl group, an ethyl group, a propyl group, a n-butyl group, a sec-butyl group, a hexyl group, and an octyl group.

The cycloalkyl group as L₁ and L₂ is, for example, a cycloalkyl group having 3 to 15 carbon atoms, and specific examples thereof include a cyclopentyl group, a cyclohexyl group, a norbornyl group, and an damantyl group.

The aryl group as L₁ and L₂ is, for example, an aryl group having 6 to 15 carbon atoms, and specific examples thereof include a phenyl group, a tolyl group, a naphthyl group, and an anthryl group.

The aralkyl group as L₁ and L₂ is, for example, an aralkyl group having 6 to 20 carbon atoms, and specific examples thereof include a benzyl group and an phenethyl group.

The divalent linking group as M is, for example, an alkylene group (for example, a methylene group, an ethylene group, a propylene group, a butylene group, a hexylene group, or an octylene group), a cycloalkylene group (for example, a cyclopentylene group or a cyclohexylene group), an alkenylene group (for example, an ethylene group, a propenylene group, or a butenylene group), an arylene group (for example, a phenylene group, a tolylene group, or a naphthylene group), —S—, —O—, —CO—, —SO₂—, —N(R₀)—, or a combination of two or more of these. Herein, R₀ represents a hydrogen atom or an alkyl group. The alkyl group as R₀ is, for example, an alkyl group having 1 to 8 carbon atoms, and specific examples thereof include a methyl group, an ethyl group, a propyl group, a n-butyl group, a sec-butyl group, a hexyl group, and an octyl group.

The alkyl group and the cycloalkyl group as Q are the same as the alkyl group and the cycloalkyl group as L₁ and L₂ described above.

Examples of the cyclic aliphatic group or the aromatic ring group as Q include the cycloalkyl group and the aryl group as L₁ and L₂ described above. The cycloalkyl group and the aryl group preferably have 3 to 15 carbon atoms.

Examples of the heteroatom-containing cyclic aliphatic group and aromatic ring group as Q include groups having heterocyclic ring structure, such as thiirane, cyclothiolane, thiophene, furan, pyrrole, benzothiophene, benzofuran, benzopyrrole, triazine, imidazole, benzimidazole, triazole, thiadiazole, thiazole, and pyrrolidone. Here, the heteroatom-containing cyclic aliphatic group and aromatic ring group as Q are not limited to these as long as they are a ring formed of carbon and a heteroatom or a ring formed only of a heteroatom.

Examples of the ring structure that can be formed by the bonding between at least two out of Q, M, and L₁ include a 5- or 6-membered ring structure formed when the groups form a propylene group or a butylene group. The 5- or 6-membered ring structure contains an oxygen atom.

The groups represented by L₁, L₂, M, and Q in Formula (2) may each have a substituent. Examples of the substituent include an alkyl group, a cycloalkyl group, an aryl group, an amino group, an amide group, a ureide group, a urethane group, a hydroxyl group, a carboxyl group, a halogen atom, an alkoxy group, a thiether group, an acyl group, an acyloxy group, an alkoxycarbonyl group, a cyano group, and a nitro group. The number of carbon atoms of these substituents is preferably equal to or less than 8.

The group represented by -(M-Q) is preferably a group having 1 to 20 carbon atoms, more preferably a group having 1 to 10 carbon atoms, and even more preferably a group having 1 to 8 carbon atoms.

Specific examples of the resin (A1) having the hydroxystyrene repeating unit will be shown below, but the present invention is not limited thereto.

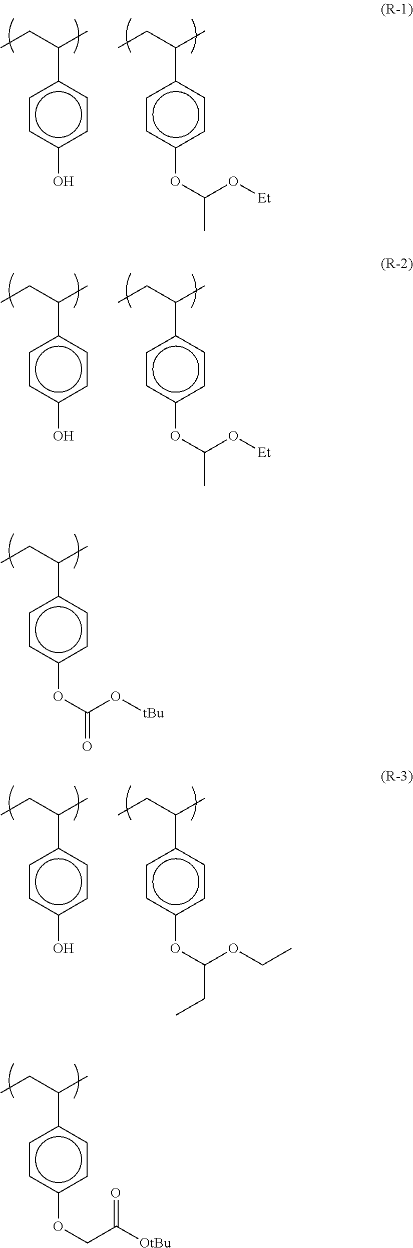

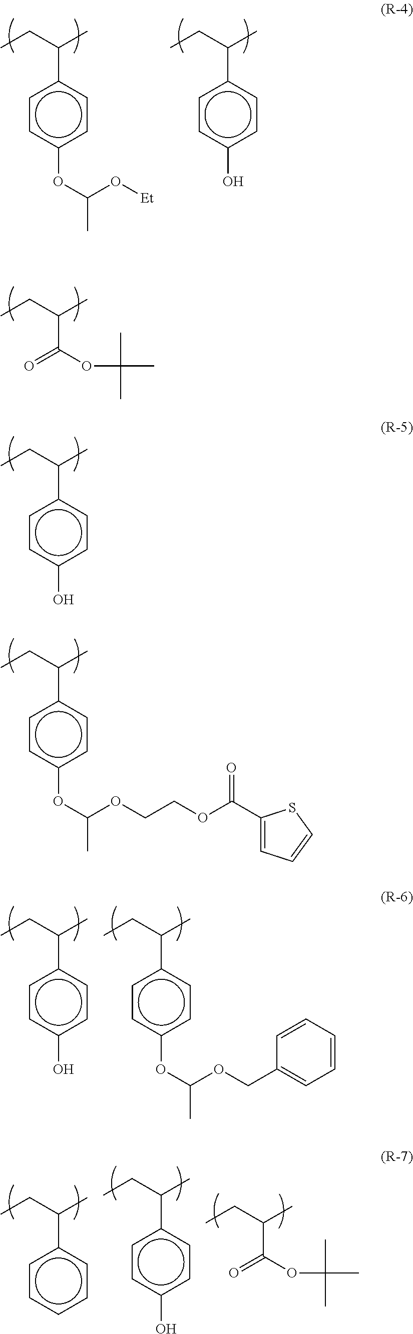

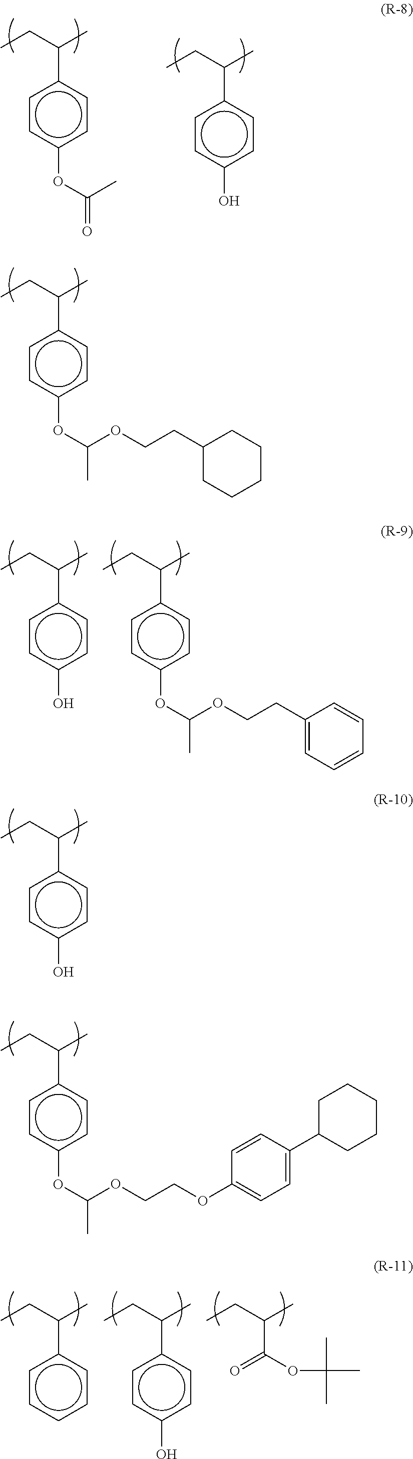

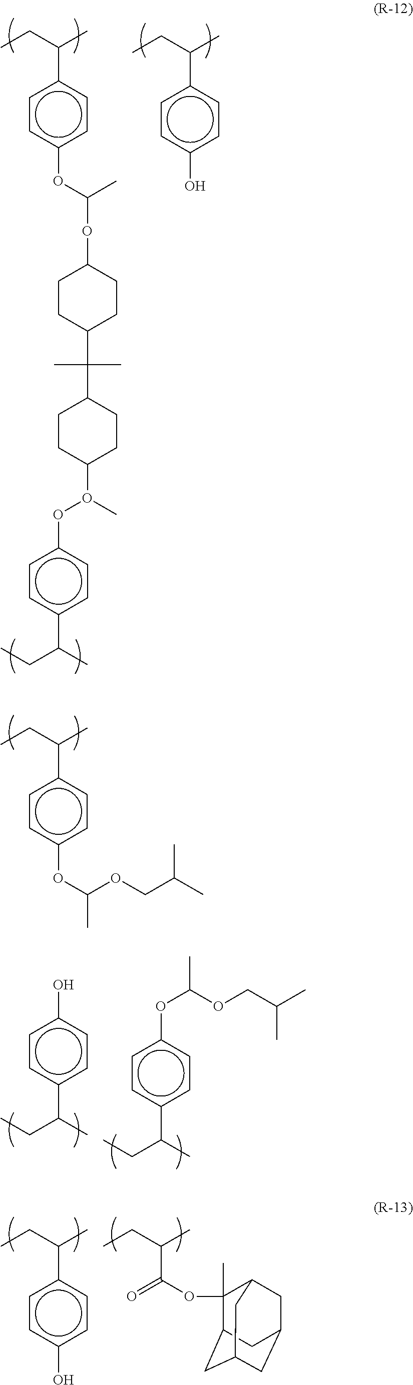

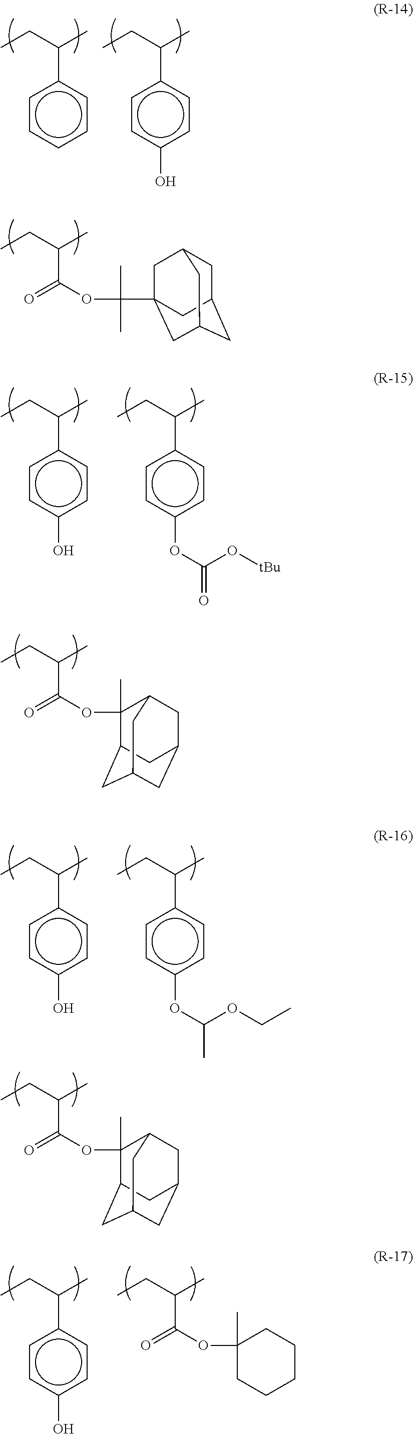

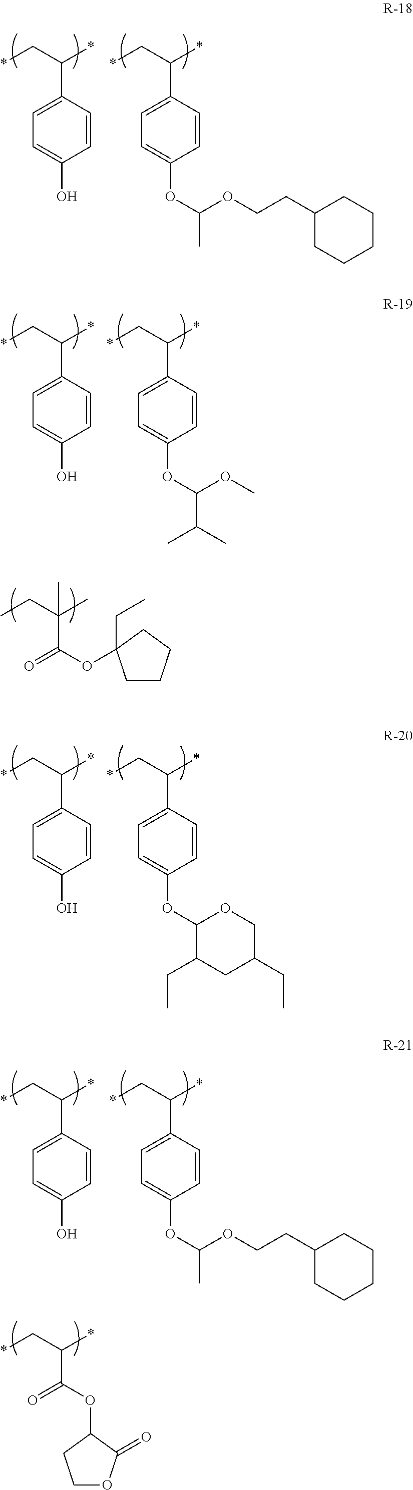

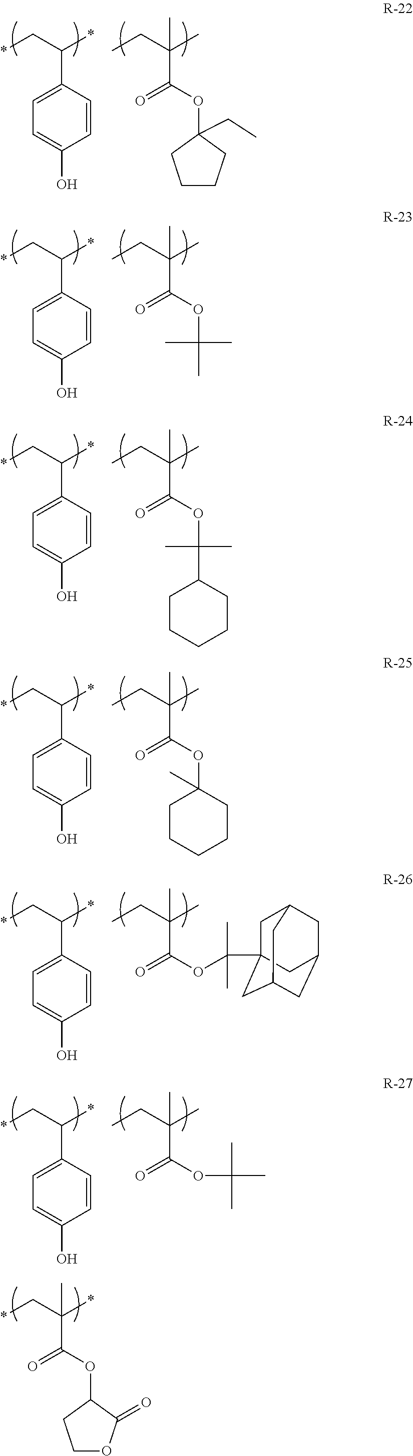

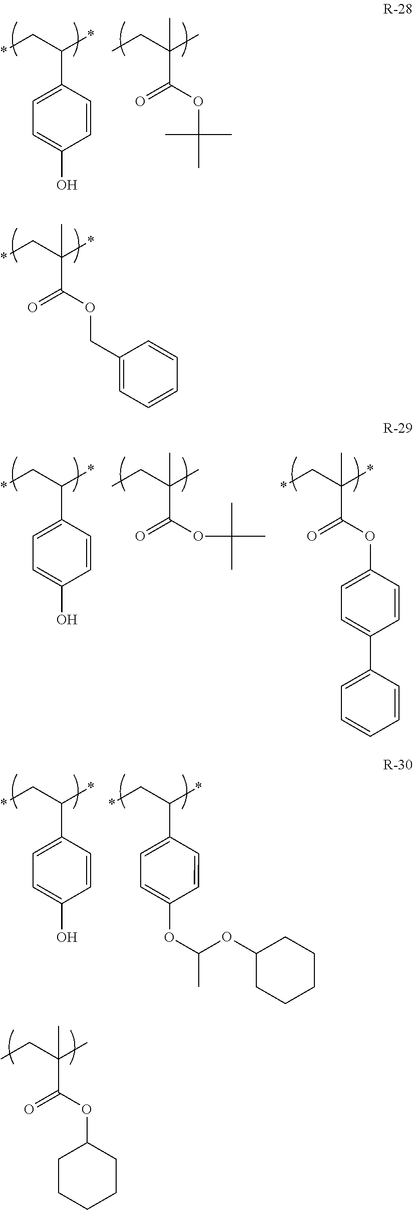

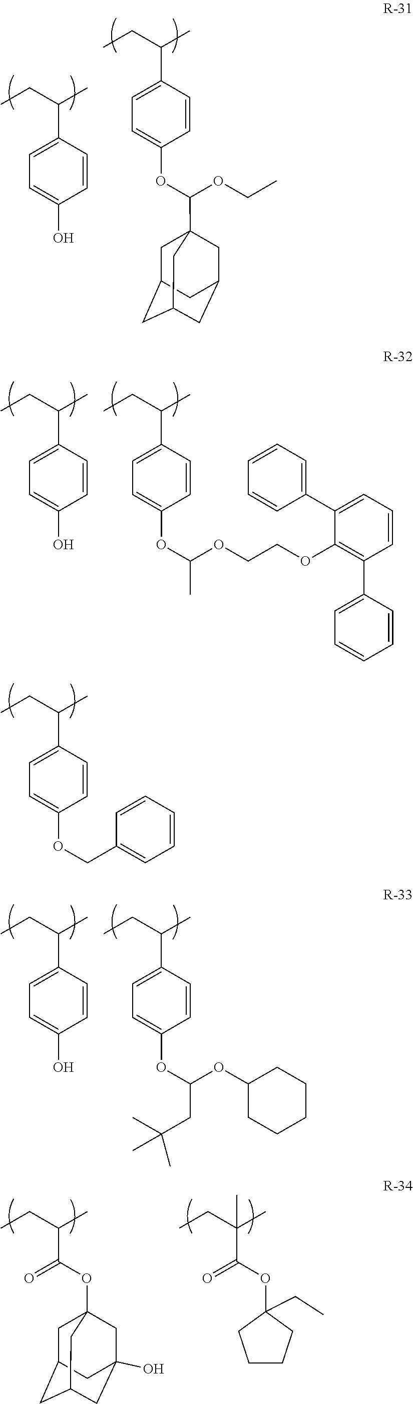

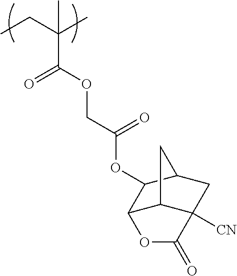

In the above specific examples, tBu represents a t-butyl group.

From the viewpoint of compatibility with a hydrophobic surface modification resin (HR) which will be described later, the resin (A) preferably does not contain a fluorine atom and a silicon atom.

As the resin (A1) used in the composition of the present invention, a resin in which all of the repeating units are constituted with a (meth)acrylate-based repeating unit is preferable. In this case, it is possible to use all of a resin in which all of the repeating units are methacrylate-based repeating units, a resin in which all of the repeating units are acrylate-based repeating units, and a resin in which all of the repeating units are methacrylate-based repeating units and acrylate-based repeating units. It is preferable that a proportion of the acrylate-based repeating units is preferably equal to or less than 50 mol % with respect to all of the repeating units. Furthermore, a copolymer is also preferable which contains a (meth)acrylate-based repeating unit having an acid-decomposable group in an amount of 20 to 50 mol %, a (meth)acrylate-based repeating unit having a lactone group in an amount of 20 to 50 mol %, a (meth)acrylate-based repeating unit having an alicyclic hydrocarbon structure substituted with a hydroxyl group or a cyano group in an amount of 5 to 30 mol %, and other (meth)acrylate-based repeating unit in an amount of 0 to 20 mol %.

The resin (A1) in the present invention can be synthesized according to a common method (for example, radical polymerization). Examples of the general synthesis method include a batch polymerization method in which polymerization is performed by dissolving a monomer species and an initiator in a solvent and heating the solution, a dropping polymerizaton method in which a solution containing a monomer species and an initiator is added dropwise to a heated solvent for 1 to 10 hours, and the like. Among these, a dropping polymerization method is preferable. Examples of the reaction solvent include ethers such as tetrahydrofuran, 1,4-dioxane, and diisopropyl ether, ketones such as methyl ethyl ketone and methyl isobutyl ketone, an ester solvent such as ethyl acetate, an amide solvent such as dimethyl formamide or a dimethyl acetamide, and a solvent dissolving the composition of the present invention such as propylene glycol monomethyl ether acetate, propylene glycol monomethyl ether, or cyclohexanone which will be descried later. It is more preferable to perform polymerization by using the same solvent as the solvent used in the resist composition of the present invention. If such a solvent is used, the occurrence of particles at the time of storage can be inhibited.

It is preferable to perform the polymerization reaction in an atmosphere of inert gas such as nitrogen or argon. The polymerization is initiated using a commercially available radical initiator (an azo-based initiator, a peroxide, or the like) as a polymerization initiator. As the radical initiator, an azo-based initiator is preferable, and as the azo-based initiator, an azo-based initiator having an ester group, a cyano group, or a carboxyl group is preferable. Examples of a preferred initiator include azobisisobutyronitrile, azobisdimethylvaleronitrile, dimethyl 2,2′-azobis(2-methylpropionate), and the like. The initiator is added as desired or added in divided portions, the resultant is added to a solvent after the reaction ends, and a desired polymer is collected by a method such as collecting powder or a solid. A concentration of the reaction is 5% to 50% by mass and preferably 10% to 30% by mass. A reaction temperature is generally 10° C. to 150° C., preferably 30° C. to 120° C., and even more preferably 60° C. to 100° C.

A weight-average molecular weight of the resin (A1) in the present invention that is measured by GPC and expressed in terms of polystyrene is preferably 1,000 to 200,000, more preferably 2,000 to 20,000, even more preferably 3,000 to 15,000, and particularly preferably 3,000 to 11,000. If the weight-average molecular weight is 1,000 to 200,000, the deterioration of heat resistance or dry etching resistance can be prevented, and the deterioration of developability and the deterioration of film formability resulting from an increase of viscosity can be prevented.

A dispersity (molecular weight distribution) is generally 1.0 to 3.0, and a resin is used which has a dispersity preferably within a range of 1.0 to 2.6, more preferably within a range of 1.0 to 2.0, and particularly preferably within a range of 1.1 to 2.0. The smaller the molecular weight distribution, the better the resolution and the pattern shape. Furthermore, a side wall of the resist pattern becomes smooth, and roughness properties become excellent.

In the present specification, a weight-average molecular weight and a dispersity can be determined by using, for example, HLC-8120 (manufactured by Tosoh Corporation), TSK gel Multipore HXL-M (manufactured by Tosoh Corporation, 7.8 mmID×30.0 cm) as a column, and tetrahydrofuran (THF) as an eluent.

In the present invention, a content of the resin (A) in the entirety of the composition is preferably 30% to 99% by mass and more preferably 50% to 98% by mass in the total solid contents.

In the present invention, one kind of the resin (A1) may be used singly, or plural kinds thereof may be used in combination.

[2] Resin (A2) having phenolic hydroxyl group

In an aspect, the composition of the present invention contains a resin (A2) having a phenolic hydroxyl group.

In the present invention, the phenolic hydroxyl group is a group obtained by substituting a hydrogen atom of an aromatic ring group with a hydroxy group. The aromatic ring in the aromatic ring group is a monocyclic or polycyclic aromatic ring, and examples thereof include a benzene ring, a naphthalene ring, and the like.

According to the composition of the present invention containing the resin (A2), in an exposed portion, due to the action of an acid generated from the compound (B) by the irradiation of actinic rays or radiation, a cross-linking reaction occurs between the resin (A2) having a phenolic hydroxyl group and a cross-linking agent (C) which will be described later, and hence a negative pattern is formed.

The resin (A2) having a phenolic hydroxyl group of the present invention preferably contains a repeating unit having at least one kind of phenolic hydroxyl group. The repeating unit having a phenolic hydroxyl group is not particularly limited, but is preferably a repeating unit represented by the following Formula (1).

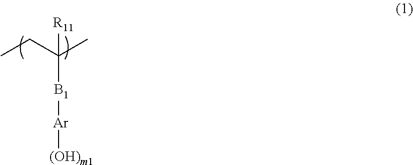

In Formula (1), R₁₁ represents a hydrogen atom, a methyl group which may have a substituent, or a halogen atom.

B₁ represents a single bond or a divalent linking group.

Ar represents an aromatic ring.

m1 represents an integer of equal to or greater than 1.

Examples of the methyl group as R₁₁ that may have a substituent include a trifluoromethyl group, a hydroxymethyl group, and the like.

R₁₁ is preferably a hydrogen atom or a methyl group. In view of developability, R₁₁ is preferably a hydrogen atom.

The divalent linking group as B₁ is preferably a carbonyl group, an alkylene group (preferably having 1 to 10 carbon atoms, and more preferably having 1 to 5 carbon atoms), a sulfonyl group (—S(═O)₂—), —O—, —NH—, or a divalent linking group obtained by combining these.

B₁ preferably represents a single bond, a carbonyloxy group (—C(═O)—O—) or —C(═O)—NH—, more preferably represents a single bond or a carbonyloxy group (—C(═O)—O—), and particularly preferably represents a single bond from the viewpoint of improving dry etching resistance.

The aromatic ring as Ar is a monocyclic or polycyclic aromatic ring, and examples thereof include a aromatic hydrocarbon ring having 6 to 18 carbon atoms that may have a substituent, such as a benzene ring, a naphthalene ring, an anthracene ring, a fluorene ring, and a phenanthrene ring, and a heteroatom-containing aromatic hetero ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among these, a benzene ring and a naphthalene ring are preferable from the viewpoint of resolution, and a benzene ring is most preferable from the viewpoint of sensitivity.

m1 is preferably an integer of 1 to 5, and most preferably 1. When m1 is 1, and Ar is a benzene ring, the substitution position of —OH may be a para position, a meta position, or an ortho position with respect to a position in which the benzene ring is bonded to B₁ (in a case where B₁ is a single bond, a polymer main chain). From the viewpoint of cross-linking reaction properties, a para position or a meta position is preferable, and a para position is more preferable.

The aromatic ring as Ar may have a substituent other than the group represented by —OH, and examples of the substituent include an alkyl group, a cycloalkyl group, a halogen atom, a hydroxyl group, an alkoxy group, a carboxyl group, an alkoxycarbonyl group, an alkylcarbonyl group, an alkylcarbonyloxy group, an alkylsulfonyloxy group, and an arylsulfonyloxy group.

In view of cross-linking reaction properties, developability, and dry etching resistance, the repeating unit having a phenolic hydroxyl group is more preferably a repeating unit represented by the following Formula (2).

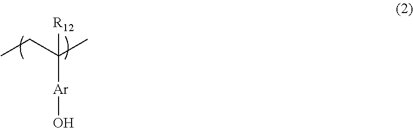

In Formula (2), R₁₂ represents a hydrogen atom or a methyl group.

Ar represents an aromatic ring.

R₁₂ represents a hydrogen atom or a methyl group. In view of developability, R₁₂ is preferably a hydrogen atom.

Ar in Formula (2) has the same definition as Ar in Formula (1), and a preferred range thereof is also the same. From the viewpoint of sensitivity, the repeating unit represented by Formula (2) is preferably a repeating unit derived from hydroxystyrene (that is, a repeating unit in which R₁₂ and Ar in Formula (2) are a hydrogen atom and a benzene ring respectively).

The resin (A2) may be constituted only with the aforementioned repeating unit having a phenolic hydroxyl group. The resin (A2) may also have a repeating unit, which will be described later, in addition to the aforementioned repeating unit having a phenolic hydroxyl group. In this case, a content rate of the repeating unit having a phenolic hydroxyl group is, with respect to all of the repeating units of the resin (A2), preferably 10 to 98 mol %, more preferably 30 to 97 mol %, and even more preferably 40 to 95 mol %. If the content rate is within the above range, particularly in a case where the resist film is a thin film (for example, in a case where a thickness of the resist film is 10 to 150 nm), the dissolution rate of an exposed portion, which is in the resist film of the present invention that is formed using the resin (A2), in an alkaline developer can be more reliably reduced (that is, the dissolution rate of the resist film using the resin (A2) can be more reliably controlled within an optimal range). As a result, the sensitivity can be more reliably improved.

Examples of the repeating unit having a phenolic hydroxyl group will be shown below, but the present invention is not limited thereto.

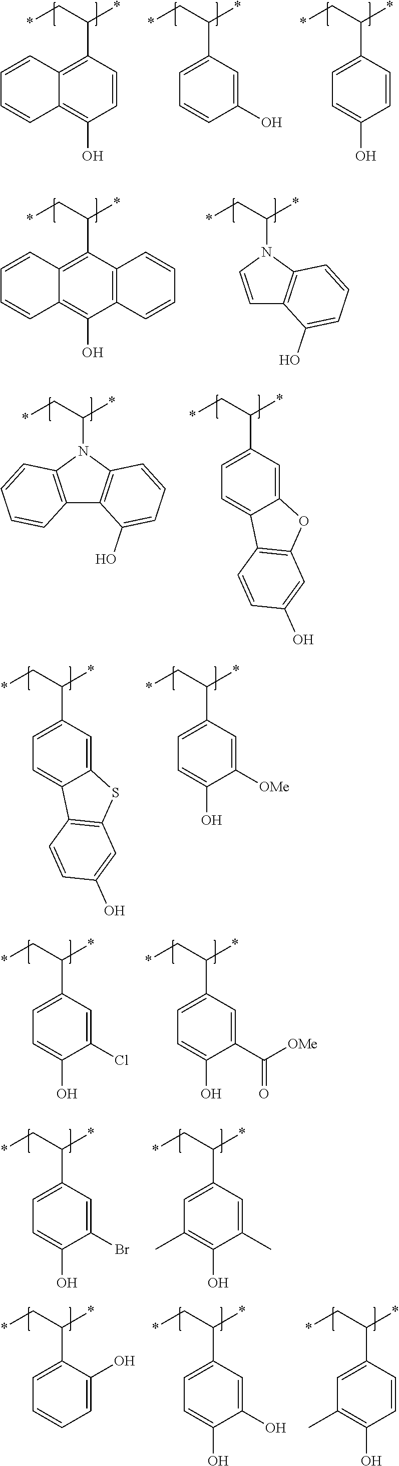

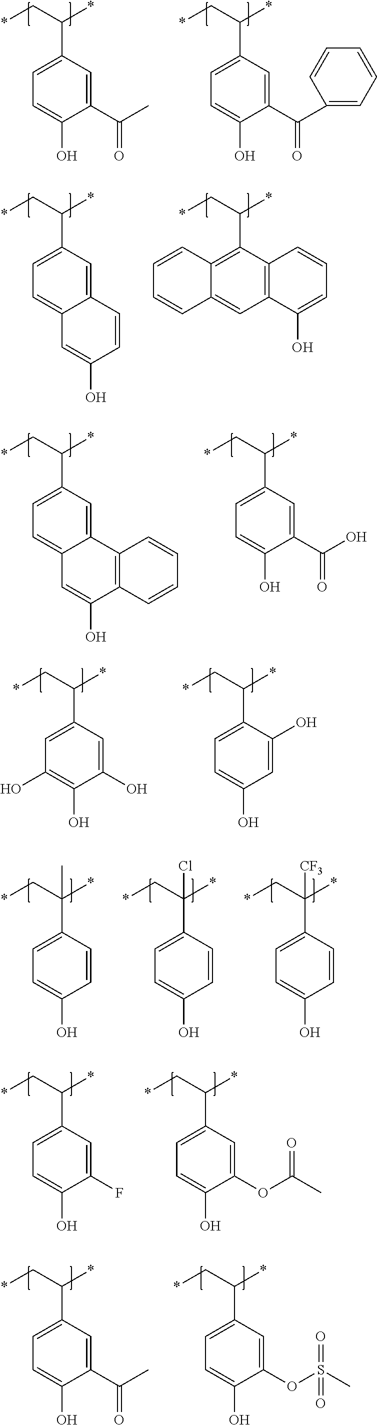

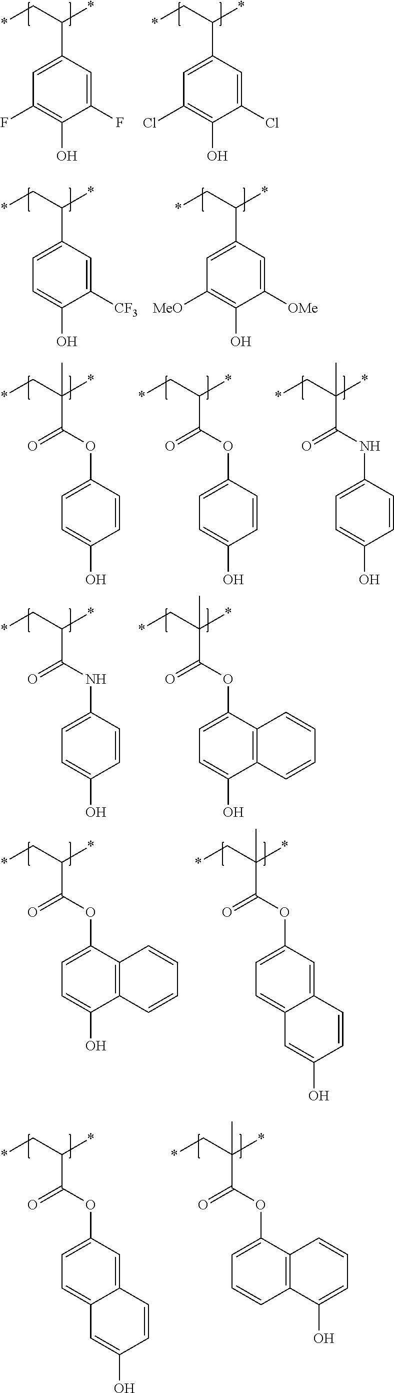

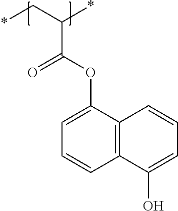

It is preferable that the resin (A2) has a structure in which a hydrogen atom of a phenolic hydroxyl group is substituted with a group having a polycyclic alicyclic hydrocarbon structure having non-acid-decomposable properties, because then a high glass transition temperature (Tg) is obtained, and the dry etching resistance is improved.

If the resin (A2) has a specific structure described above, the glass transition temperature (Tg) of the resin (A2) is increased. Accordingly, an extremely hard resist film can be obtained, and the diffusitivity of an acid or the dry etching resistance can be controlled. Consequently, the diffusitivity of an acid in a portion exposed to actinic rays or radiation such as electron beams or extreme ultraviolet rays is extremely suppressed, and hence the resolving power, the pattern shape, and LER in a fine pattern are further improved. Furthermore, presumably, the fact that the resin (A2) has a polycyclic alicyclic hydrocarbon structure having non-acid-decomposable properties may make a contribution to the improvement of the dry etching resistance. In addition, presumably, although the details are unclear, the polycyclic alicyclic hydrocarbon structure readily releases a hydrogen radical and thus becomes a hydrogen source at the time when the aforementioned acid generator (B) as a photoacid generator is decomposed, and accordingly, the decomposition efficiency of the photoacid generator and the acid generation efficiency may be further improved. It is considered that, for this reason, the specific structure may make a contribution to further improve sensitivity.

In the aforementioned specific structure that the resin (A2) according to the present invention may have, an aromatic ring such as a benzene ring and a group having a polycylcic alicyclic hydrocarbon structure having non-acid-decomposable properties are linked to each other through an oxygen atom derived from the phenolic hydroxyl group. As described above, the structure can make a contribution to high dry etching resistance and can increase the glass transition temperature (Tg) of the resin (A2), and presumably, due to the effect as a combination of these, a high resolving power may be provided.

In the present invention, the “non-acid-decomposable properties” means properties of not causing a decomposition reaction by an acid generated by the acid generator (B) which will be described later.

More specifically, the group having a polycyclic alicyclic hydrocarbon structure having non-acid-decomposable properties is preferably a group stable against an acid or an alkali. A group stable against an acid and an alkali means a group which does not exhibit acid-decomposable properties and alkali-decomposable properties. Herein, the acid-decomposable properties mean properties of causing a decomposition reaction by the action of an acid generated by the acid generator (B) which will be described later, and examples of the group that exhibits acid-decomposable properties include the acid-decomposable groups described above for the resin (A1).

The alkali-decomposable properties mean properties of causing a decomposition reaction by the action of an alkaline developer, and examples of the group that exhibits alkaline-decomposable properties include a group (for example, a group having a lactone structure) which is contained in a resin suitably used in a positive chemical amplification-type resist composition and of which the dissolution rate in an alkaline developer increases by being decomposed by the action of an alkaline developer known in the related art.

The group having a polycyclic alicyclic hydrocarbon structure is not particularly limited as long as it is a monovalent group having a polycyclic alicyclic hydrocarbon structure. A total number of carbon atoms of the group is preferably 5 to 40, and more preferably 7 to 30. The polycyclic alicyclic hydrocarbon structure may have an unsaturated bond in the ring.

The polycyclic alicyclic hydrocarbon structure in the group having a polycyclic alicyclic hydrocarbon structure means a structure having a plurality of monocyclic alicyclic hydrocarbon groups or a polycyclic alicyclic hydrocarbon structure, and may be a bridged structure. The monocyclic alicyclic hydrocarbon group is preferably a cycloalkyl group having 3 to 8 carbon atoms, and examples thereof include a cyclopropyl group, a cyclopentyl group, a cyclohexyl group, a cyclobutyl group, a cyclooctyl group, and the like. The structure having a plurality of monocyclic alicyclic hydrocarbon groups has a plurality of groups described above. The structure having a plurality of monocyclic alicyclic hydrocarbon groups preferably has 2 to 4 monocyclic alicyclic hydrocarbon groups, and more preferably has two monocyclic alicyclic hydrocarbon groups.

Examples of the polycyclic alicyclic hydrocarbon structure include bicyclo, tricyclo, or tetracyclo structures having 5 or more carbon atoms, and the like. The polycyclic alicyclic hydrocarbon structure is preferably a polycyclic cyclo structure having 6 to 30 carbon atoms, and examples thereof include an adamantane structure, a decalin structure, a norbornane structure, a norbornene structure, a cedrol structure, an isobornane structure, a bornane structure, a dicyclopentane structure, an α-pinene structure, a tricyclodecane structure, a tetracyclodecane structure, and an androstane structure. Some of the carbon atoms in the monocyclic or polycyclic cycloalkyl group may be substituted with a heteroatom such as an oxygen atom.

Examples of structures preferable as the polycyclic alicyclic hydrocarbon structure include an adamantane structure, a decalin structure, a norbornane structure, a norbornene structure, a cedrol structure, a structure having a plurality of cyclohexyl groups, a structure having a plurality of cycloheptyl groups, a structure having a plurality of cyclooctyl groups, a structure having a plurality of cyclodecanyl groups, a structure having a plurality of cyclododecanyl groups, and a tricyclodecane structure. From the viewpoint of dry etching resistance, an adamantane structure is most preferable (that is, it is most preferable that the group having a polycyclic alicyclic hydrocarbon structure having non-acid-decomposable properties is a group having an adamantane structure having non-acid-decomposable properties).

Chemical formulae of these polycyclic alicyclic hydrocarbon structures (regarding the structure having a plurality of monocyclic alicyclic hydrocarbon groups, monocyclic alicyclic hydrocarbon structures corresponding to the monocyclic alicyclic hydrocarbon groups (specifically, the structures of the following Formulae (47) to (50)) will be shown below.

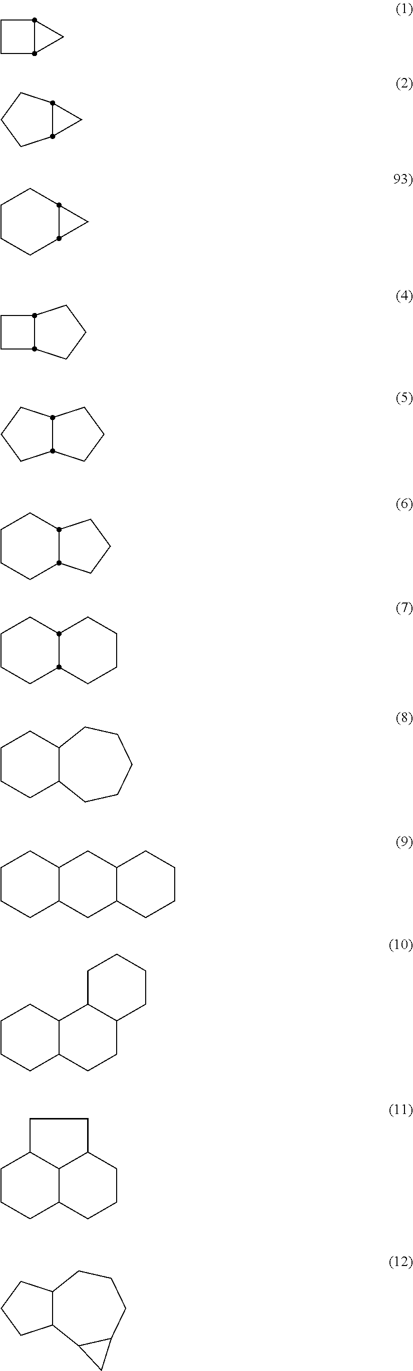

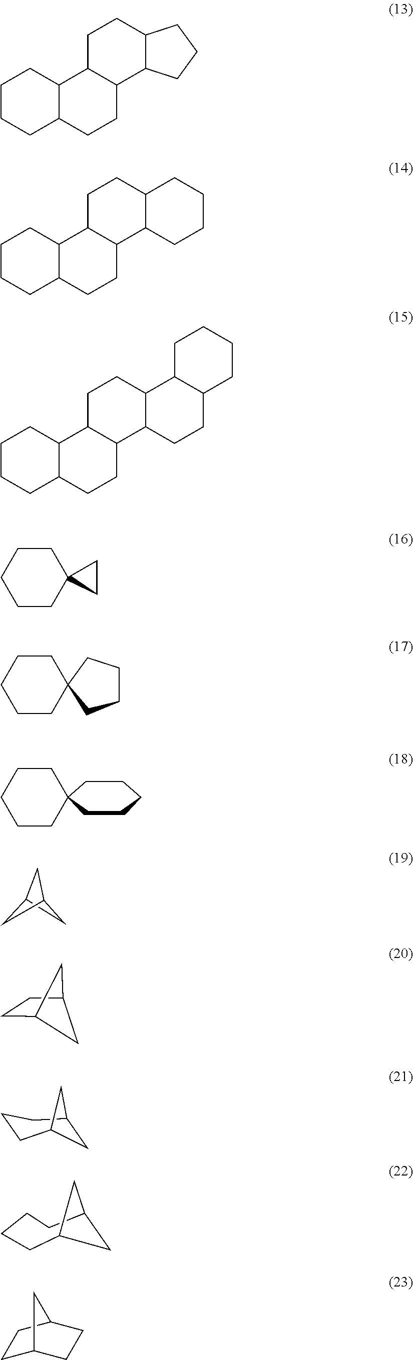

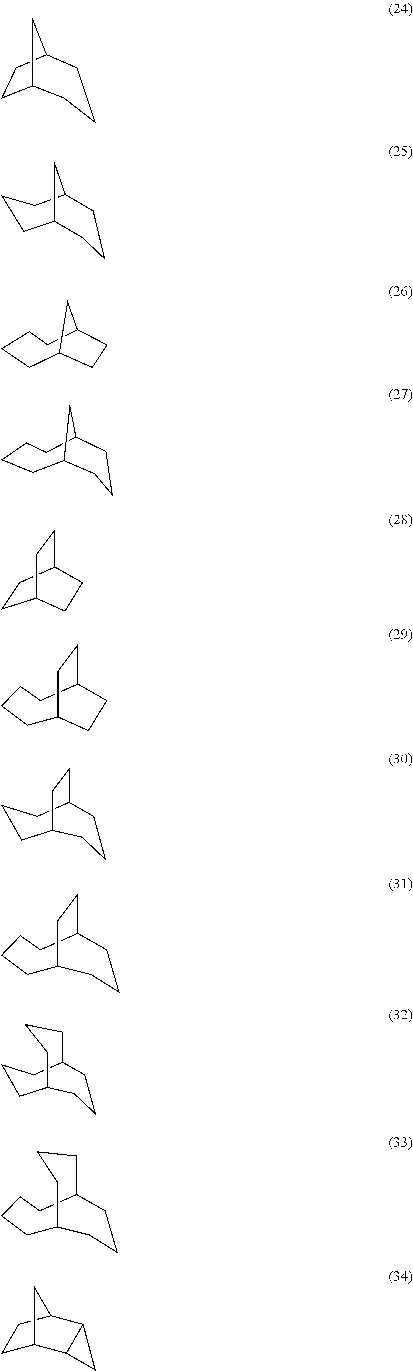

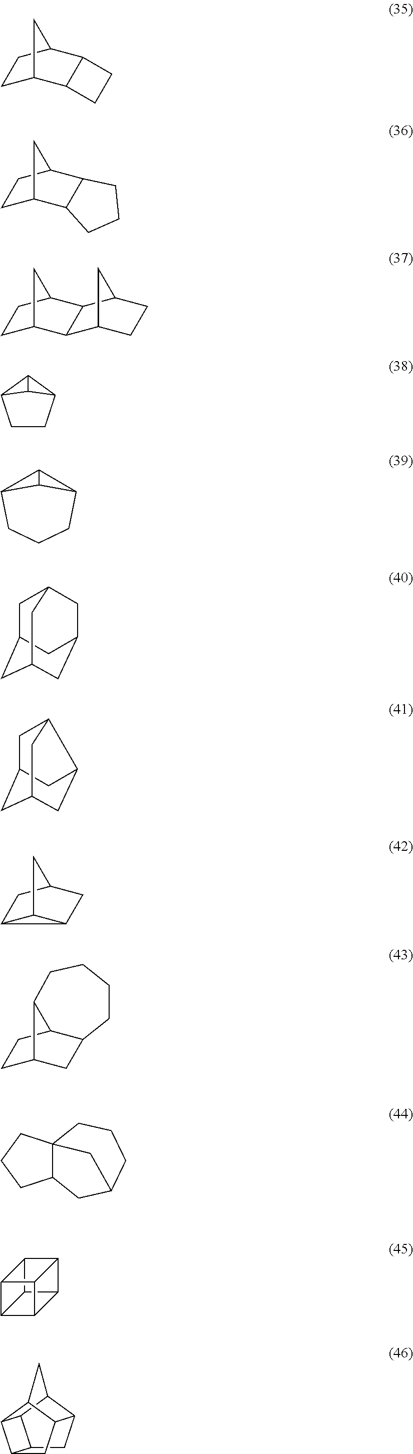

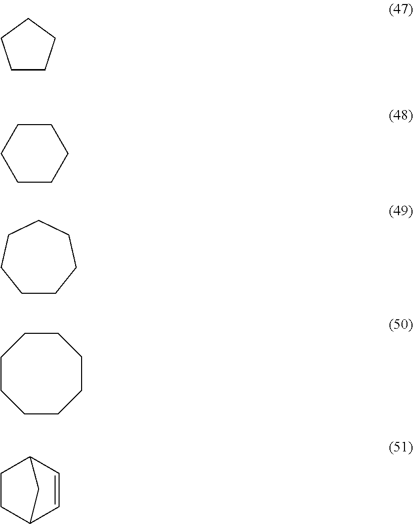

The polycyclic alicyclic hydrocarbon structure may have a substituent, and examples of the substituent include an alkyl group (preferably having 1 to 6 carbon atoms), a cycloalkyl group (preferably having 3 to 10 carbon atoms), an aryl group (preferably having 6 to 15 carbon atoms), a halogen atom, a hydroxyl group, an alkoxy group (preferably having 1 to 6 carbon atoms), an carboxyl group, a carbonyl group, a thiocarbonyl group, an alkoxycarbonyl group (preferably having 2 to 7 carbon atoms), and a group obtained by combining these (preferably having 1 to 30 carbon atoms in total, and more preferably having 1 to 15 carbon atoms in total).

The polycyclic alicyclic hydrocarbon structure is preferably a structure represented by any of Formulae (7), (23), (40), (41), and (51) or a structure having two monovalent groups having any one hydrogen atom in the structure of Formula (48) as a direct bond, more preferably a structure represented by any of Formulae (23), (40), and (51) or a structure having two monovalent groups having any one hydrogen atom in the structure of Formula (48) as a direct bond, and most preferably the structure represented by Formula (40).

The group having a polycyclic alicyclic hydrocarbon structure is preferably a monovalent group having any one hydrogen atom of the aforementioned polycyclic alicyclic hydrocarbon structure as a direct bond.

The structure, in which a hydrogen atom of the phenolic hydroxyl group is substituted with the aforementioned group having a polycyclic alicyclic hydrocarbon structure having non-acid-decomposable properties, preferably contains the resin (A2) as a repeating unit contained in the structure in which a hydrogen atom of the phenolic hydroxyl group is substituted with the aforementioned group having a polycyclic alicyclic hydrocarbon structure having non-acid-decomposable properties, and more preferably contains the resin (A2) as a repeating unit represented by the following Formula (3).

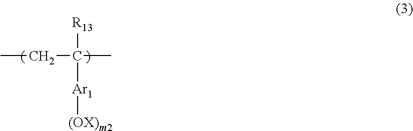

In Formula (3), R₁₃ represents a hydrogen atom or a methyl group.

X represents a group having a polycyclic alicyclic hydrocarbon structure having non-acid-decomposable properties.

Ar₁ represents an aromatic ring.

m2 represents an integer of equal to or greater than 1.

R₁₃ in Formula (3) represents a hydrogen atom or a methyl group. R₁₃ particularly preferably represents a hydrogen atom.

Examples of the aromatic ring as Ar₁ in Formula (3) include an aromatic hydrocarbon having 6 to 18 carbon atoms that may have a substituent, such as a benzene ring, a naphthalene ring, an anthracene ring, a fluorene ring, and a phenanthrene ring, and a hetero ring-containing aromatic hetero ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among these, from the viewpoint of resolution, a benzene ring and a naphthalene ring are preferable, and a benzene ring is most preferable.

The aromatic ring as Ar₁ may have a substituent in addition to the group represented by —OX, and examples of the substituent include an alkyl group (preferably having 1 to 6 carbon atoms), a cycloalkyl group (preferably having 3 to 10 carbon atoms), an aryl group (preferably having 6 to 15 carbon atoms), a halogen atom, a hydroxyl group, an alkoxy group (preferably having 1 to 6 carbon atoms), a carboxyl group, and an alkoxycarbonyl group (preferably having 2 to 7). Among these, an alkyl group, an alkoxy group, and an alkoxycarbonyl group are preferable, and an alkoxy group is more preferable.

X represents a group having a polycyclic alicyclic hydrocarbon structure having non-acid-decomposable properties. Specific examples and a preferred range of the group represented by X having a polycyclic alicyclic hydrocarbon structure having non-acid-decomposable properties are the same as described above. X is more preferably a group represented by —Y—X₂ in Formula (4) which will be described later.

m2 is preferably an integer of 1 to 5, and most preferably 1. When m2 is 1, and Ar₁ is a benzene ring, the substitution position of —OX may be a para position, a meta position, or an ortho position with respect to a position in which the benzene ring is bonded to a polymer main chain. The substitution position of —OX is preferably a para position or a meta position, and more preferably a para position.

In the present invention, the repeating unit represented by Formula (3) is preferably a repeating unit represented by the following Formula (4).

If the resin (A2) having a repeating unit represented by Formula (4) is used, Tg of the resin (A2) is increased, and an extremely hard resist film is obtained. Therefore, the diffusivity of an acid or drying etching resistance can be more reliably controlled.

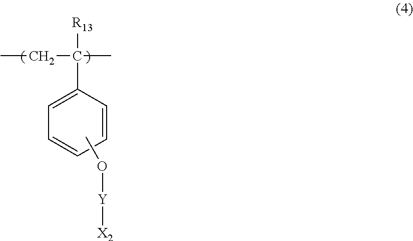

In Formula (4), R₁₃ represents a hydrogen atom or a methyl group.

Y represents a single bond or a divalent linking group.

X2 represents a polycyclic alicyclic hydrocarbon group having non-acid-decomposable properties.

Preferred examples of the repeating unit represented by Formula (4) used in the present invention will be described below.

R₁₃ in Formula (4) preferably represents a hydrogen atom or a methyl group, and particularly preferably represents a hydrogen atom.

In Formula (4) Y is preferably a divalent linking group. The divalent linking group as Y is preferably a carbonyl group, a thiocarbonyl group, an alkylene group (preferably having 1 to 10 carbon atoms and more preferably having 1 to 5 carbon atoms), a sulfonyl group, —COCH₂—, —NH—, or a divalent linking group obtained by combining these (preferably having 1 to 20 carbon atoms in total and more preferably having 1 to 10 carbon atoms in total), more preferably a carbonyl group, —COCH₂—, a sulfonyl group, —CONH—, or —CSNH—, even more preferably a carbonyl group or —COCH₂—, and particularly preferably a carbonyl group.

X₂ represents a polycyclic alicyclic hydrocarbon group having non-acid-decomposable properties. A total number of carbon atoms of the polycyclic alicyclic hydrocarbon group is preferably 5 to 40, and more preferably 7 to 30. The polycyclic alicyclic hydrocarbon group may have an unsaturated bond in the ring.

The aforementioned polycyclic alicyclic hydrocarbon group is a group having a plurality of monocyclic alicyclic hydrocarbon groups or a polycyclic alicyclic group, and may be a bridged group. The monocyclic alicyclic hydrocarbon group is preferably a cycloalkyl group having 3 to 8 carbon atoms, and examples thereof include a cyclopropyl group, a cyclopentyl group, a cyclohexyl group, a cyclobutyl group, a cyclooctyl group, and the like. The polycyclic alicyclic hydrocarbon group has a plurality of these groups. The group having a plurality of monocyclic alicyclic hydrocarbon groups preferably has 2 to 4 monocyclic alicyclic hydrocarbon groups, and particularly preferably has two monocyclic alicyclic hydrocarbon groups.

Examples of the polycyclic alicyclic hydrocarbon group include groups having bicyclo, tricyclo, and tetracyclo structures and the like having 5 or more carbon atoms. The polycyclic alicyclic hydrocarbon group is preferably a group having a polycyclic cyclo structure having 6 to 30 carbon atoms, and examples thereof include an adamantyl group, a norbornyl group, a norbornenyl group, an isobornyl group, a camphanyl group, a dicyclopentyl group, an α-pinel group, a tricyclodecanyl group, a tetracyclododecyl group, and an androstanyl group. Some of the carbon atoms in the monocyclic or polycyclic cycloalkyl group may be substituted with a heteroatom such as an oxygen atom.

The polycyclic alicyclic hydrocarbon group as X₂ is preferably an adamantyl group, a decalin group, a norbornyl group, a norbornenyl group, a cedrol group, a group having a plurality of cyclohexyl groups, a group having a plurality of cycloheptyl groups, a group having a plurality of cyclooctyl groups, a group having a plurality of cyclodecanyl groups, a group having a plurality of cyclododecanyl groups, or a tricyclodecanyl group. From the viewpoint of dry etching resistance, the polycyclic alicyclic hydrocarbon group is most preferably an adamantyl group. As chemical formulae of the polycyclic alicyclic hydrocarbon structure in the polycyclic alicyclic hydrocarbon group as X₂, the same chemical formulae as the chemical formulae of the polycyclic alicyclic hydrocarbon structure in the group having a polycyclic alicyclic hydrocarbon structure are exemplified, and a preferred range thereof is also the same. Examples of the polycyclic alicyclic hydrocarbon group as X₂ include a monovalent group having any one hydrogen atom in the polycyclic alicyclic hydrocarbon structure as a direct bond.

The alicyclic hydrocarbon group may have a substituent, and examples of the substituent include the same substituents as the substituents that the polycyclic alicyclic hydrocarbon structure may have.

The substitution position of —O—Y—X₂ in Formula (4) may be a para position, a meta position, or an ortho position with respect to a position in which a benzene ring is bonded to a polymer main chain. The substitution position of —O—Y—X₂ is preferably a para position.

In the present invention, it is most preferable that the repeating unit represented by Formula (3) is a repeating unit represented by the following Formula (4′).

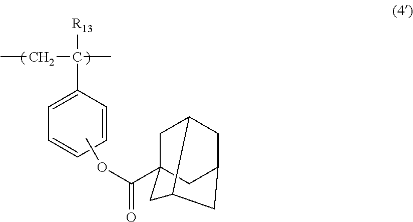

In Formula (4′), R₁₃ represents a hydrogen atom or a methyl group.

R₁₃ in Formula (4′) represents a hydrogen atom or a methyl group, and particularly preferably represents a hydrogen atom.

The substitution position of an adamantyl ester group in Formula (4′) may be a para position, a meta position, or an ortho position with respect to a position in which the benzene ring is bonded to a polymer main chain. The substitution position of the adamantyl ester group is preferably a para position.

Specific examples of the repeating unit represented by Formula (3) will be shown below.

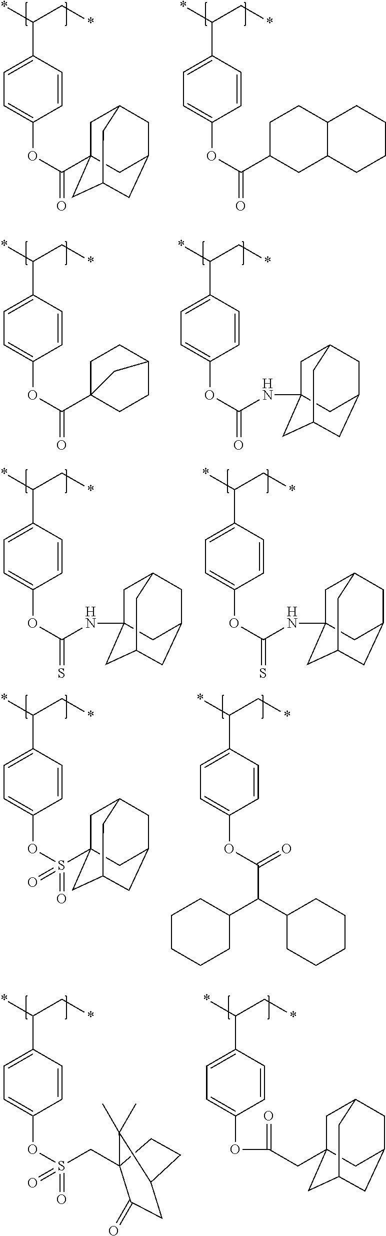

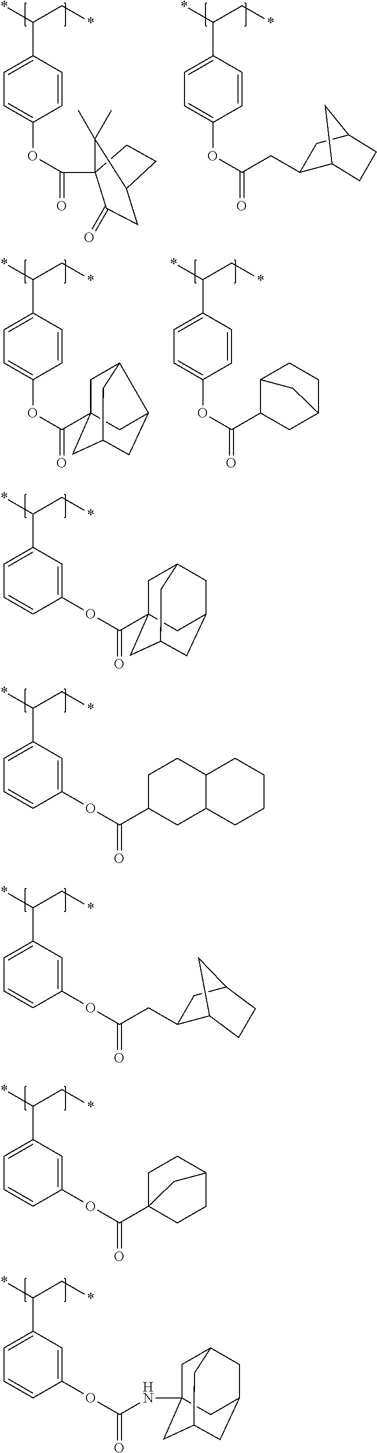

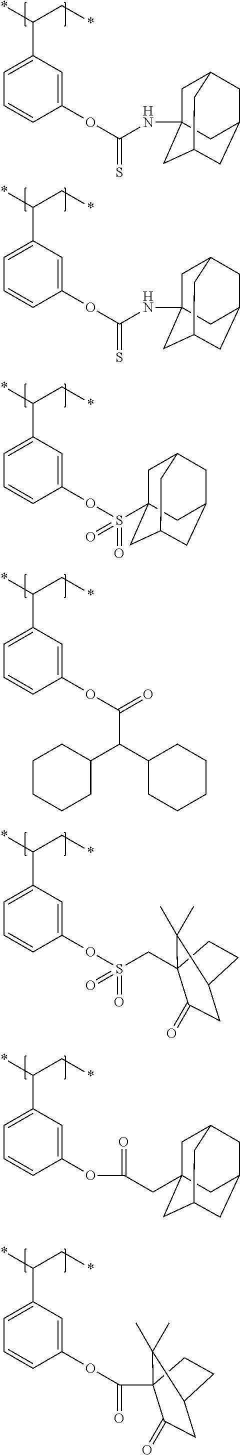

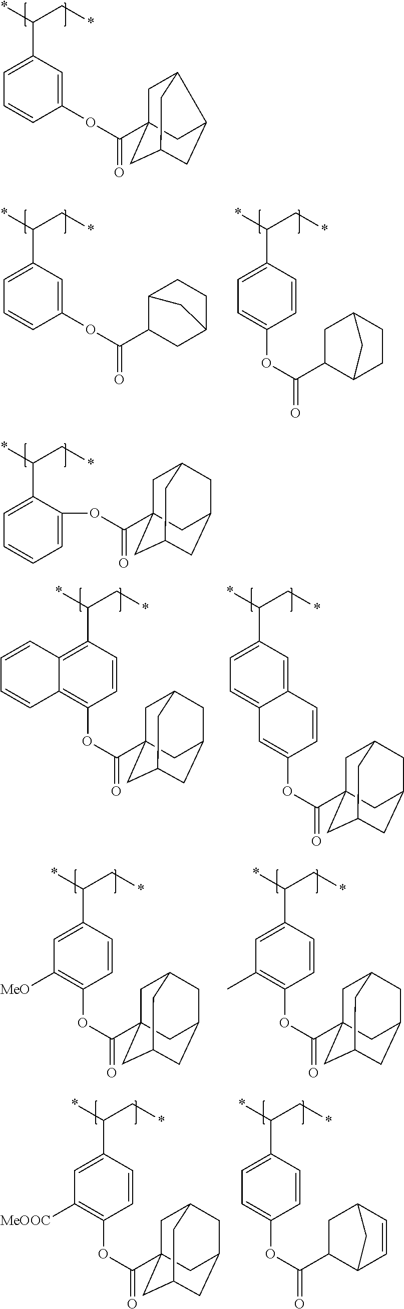

In a case where the resin (A2) contains a repeating unit having a structure in which a hydrogen atom of the phenolic hydroxyl group is substituted with a group having the aforementioned polycyclic alicyclic hydrocarbon structure having non-acid-decomposable properties, a content rate of the repeating unit is, with respect to all of the repeating units of the resin (A2) as a polymer compound, preferably 1 to 40 mol %, and more preferably 2 to 30 mol %.

It is also preferable that the resin (A2) used in the present invention further has the following repeating units (hereinafter, referred to as “other repeating units” as well) as repeating units other than the aforementioned repeating unit.

Examples of polymerizable monomers for forming the aforementioned other repeating units include styrene, alkyl-substituted styrene, alkoxy-substituted styrene, halogen-substituted styrene, O-alkylated styrene, O-acylated styrene, hydrogenated hydroxystyrene, maleic anhydride, an acrylic acid derivative (an acrylic acid, an acrylic acid ester, or the like), a methacrylic acid derivative (a methacrylic acid, a methacrylic acid ester, or the like), N-substituted maleimide, acrylonitrile, methacrylonitrile, vinyl naphthalene, vinyl anthracene, indene which may have a substituent, and the like.

The resin (A2) may or may not contain the aforementioned other repeating units. In a case where the resin (A2) contains other repeating units, a content of other repeating units in the resin (A2) is, with respect to all of the repeating units constituting the resin (A2), generally 1 to 30 mol %, preferably 1 to 20 mol %, and more preferably 2 to 10 mol %.

The resin (A2) can be synthesized by a known radical polymerization method, an anionic polymerization method, or a living radical polymerization method (iniferter method or the like). For example, in an anionic polymerization method, by dissolving a vinyl monomer in an appropriate organic solvent and causing a reaction by using a metal compound (butyllithium or the like) as an initiator generally under cooling conditions, a polymer can be obtained.

As the resin (A2), it is also possible to use an aromatic ketone or an aromatic aldehyde, a polyphenol compound manufactured by a condensation reaction of a compound containing 1 to 3 phenolic hydroxyl groups (for example, JP2008-145539A), a calixarene derivative (for example, JP2004-18421A), a Noria derivative (for example, JP2009-222920A), and a polyphenol derivative (for example, JP2008-94782A). The resin (A2) may be synthesized by modifying these through a polymer reaction.

It is preferable that the resin (A2) is synthesized by modifying a polymer synthesized by a radical polymerization method or an anionic polymerization method through a polymer reaction.

A weight-average molecular weight of the resin (A2) is preferably 1,000 to 200,000, more preferably 2,000 to 50,000, and even more preferably 2,000 to 15,000.

A dispersity (molecular weight distribution) (Mw/Mn) of the resin (A2) is preferably equal to or less than 2.0. From the viewpoint of improving sensitivity and resolution, the dispersity is 1.0 to 1.80, more preferably 1.0 to 1.60, and most preferably 1.0 to 1.20. It is preferable to use living polymerization such as living anionic polymerization, because then the dispersity (molecular weight distribution) of the obtained polymer compound becomes uniform. The weight-average molecular weight and the dispersity of the resin (A2) are measured by GPC and defined as a value expressed in terms of polystyrene.

An amount of the resin (A2) added to the composition of the present invention is, with respect to the total solid contents of the composition, preferably 30% to 99% by mass, more preferably 40% to 98% by mass, and particularly preferably 50% to 97% by mass.

Specific examples of the resin (A2) will be shown below, but the present invention is not limited thereto.

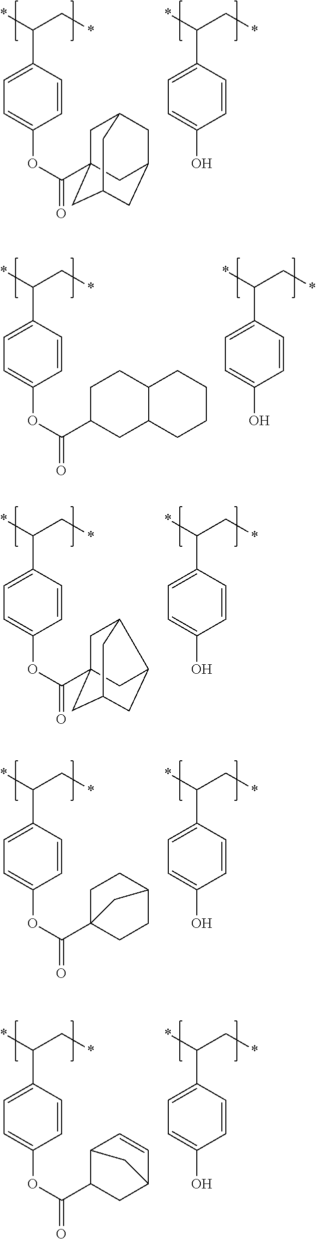

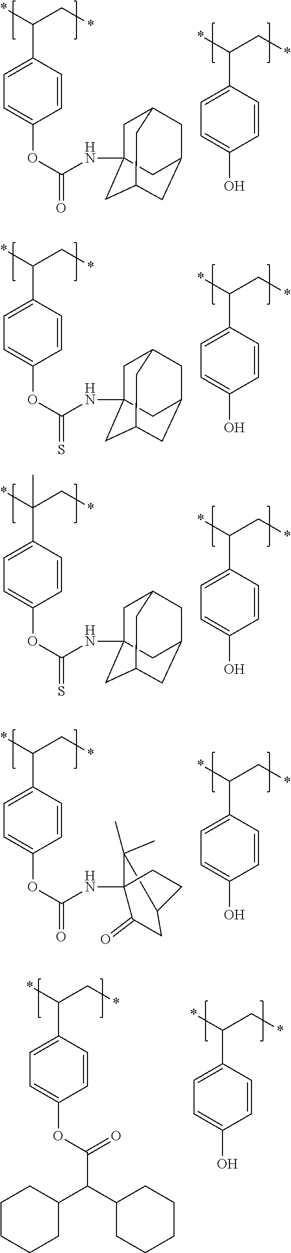

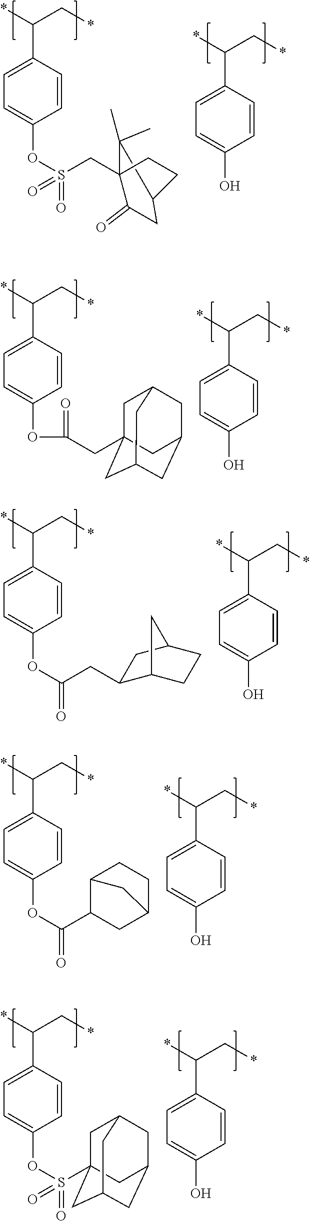

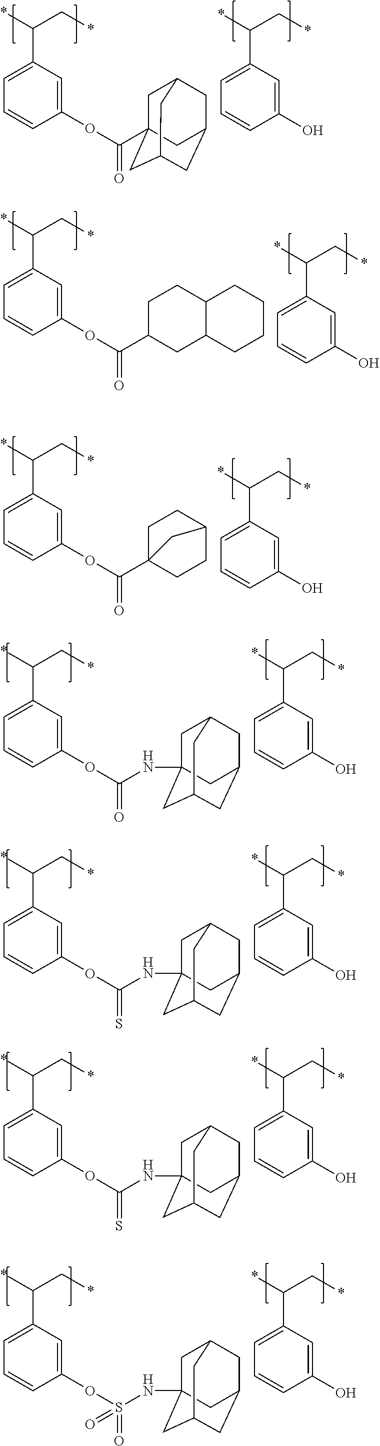

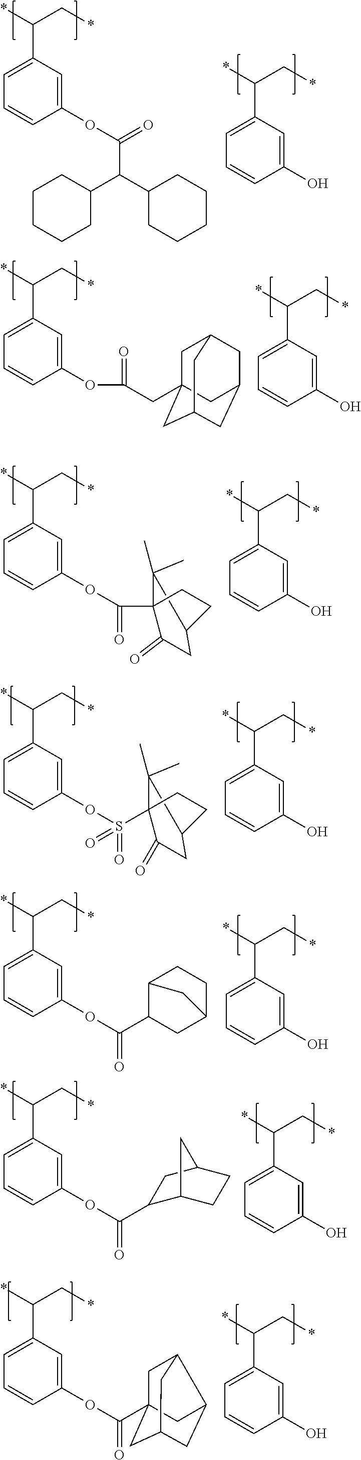

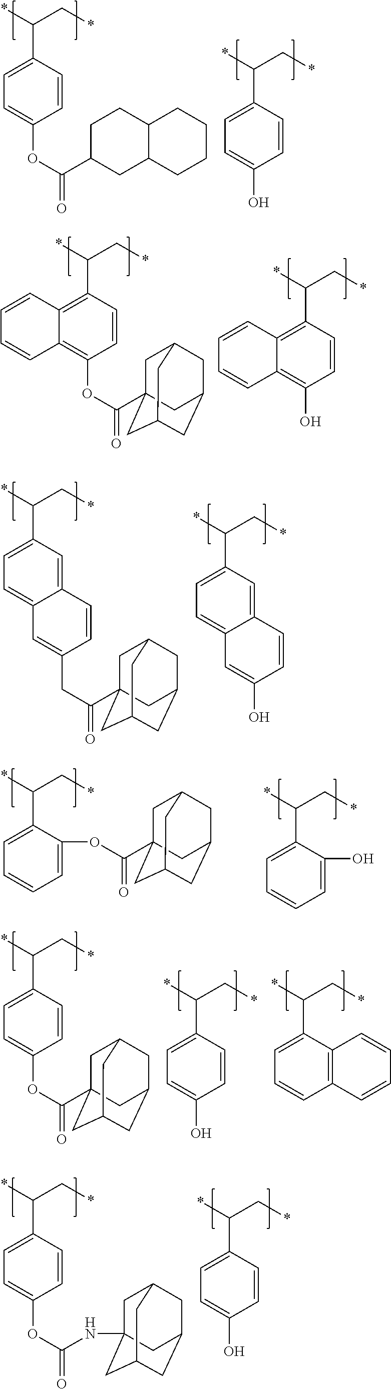

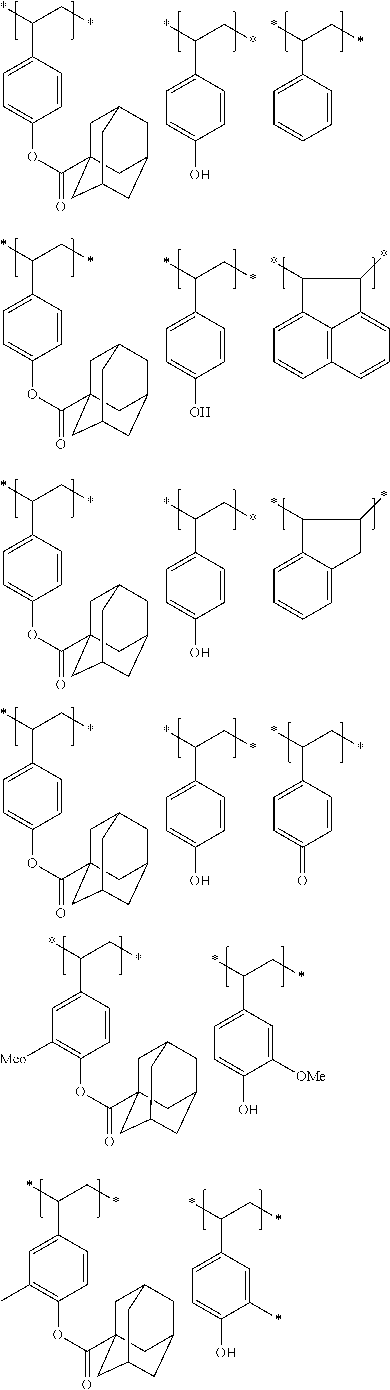

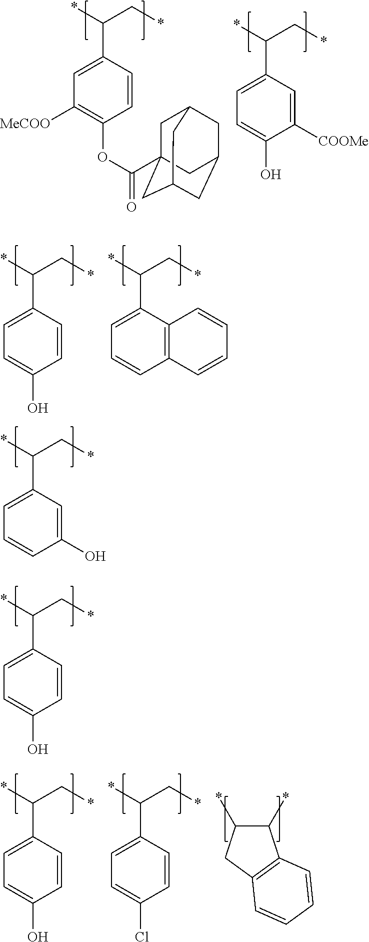

<Compound (B) Generating Acid by being Irradiated with Actinic Rays or Radiation>

it is preferable that the resist composition in the present invention contains a compound (B) (hereinafter, referred to as an “acid generator” or a “compound (B)” as well) generating an acid by being irradiated with actinic rays or radiation. The compound (B) generating an acid by being irradiated with actinic rays or radiation is preferably a compound generating an organic acid by being irradiated with actinic rays or radiation.

The compound (B) generating an acid by being irradiated with actinic rays or radiation may be in the form of a low-molecular weight compound or in the form of a compound incorporated into a portion of a polymer. Furthermore, a low-molecular weight compound and a compound incorporated into a portion of a polymer may be used in combination.

In a case where the compound (B) generating an acid by being irradiated with actinic rays or radiation is in the form of a low-molecular weight compound, a molecular weight thereof is preferable equal to or less than 3,000, more preferably equal to or less than 2,000, and even more preferably equal to or less than 1,000.

In a case where the compound (B) generating an acid by being irradiated with actinic rays or radiation is in the form of a compound incorporated into a portion of a polymer, the compound (B) may be incorporated into a portion of the aforementioned acid-decomposable resin or may be incorporated into a resin different from the acid-decomposable resin. As an aspect in which the compound (B) generating an acid by being irradiated with actinic rays or radiation is incorporated into a portion of a polymer, a resin having the repeating unit described in paragraphs “0311” to “0314” in JP2012-93737A is exemplified.

As the acid generator, it is possible to appropriately select and use known compounds, which generate an acid by being irradiated with actinic rays or radiation, or a mixture thereof used in a photoinitiator for photo-cationic polymerization, a photoinitiator for photo-radical polymerization, a colorant-type photodecolorizer, a photo-discoloring agent, a micro resist, and the like.

Examples of the acid generator include a diazonium salt, a phosphonium salt, a sulfonium salt, an iodonium salt, imide sulfonate, oxime sulfonate, diazo disulfone, disulfone, and o-nitrobenzyl sulfonate.

Examples of compounds preferable as the acid generator include compounds represented by the following Formulae (ZI), (ZII), and (ZIII).

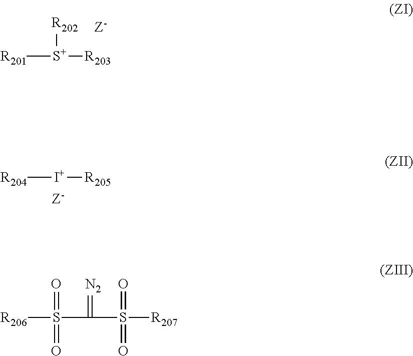

In Formula (ZI), R₂₀₁, R₂₀₂, and R₂₀₃ each independently represent an organic group.

The number of carbon atoms of the organic group as R₂₀₁, R₂₀₂, and R₂₀₃ is generally 1 to 30, and preferably 1 to 20.

Two out of R₂₀₁ to R₂₀₃ may form a ring structure by being bonded to each other, and the ring may contain an oxygen atom, a sulfur atom, an ester bond, an amide bond, or a carbonyl group in the ring. Examples of the group formed by the bonding between two out of R₂₀₁ to R₂₀₃ include an alkylene group (for example, a butylene group or a pentylene group).

Z⁻ represents a non-nucleophilic anion.

Examples of the non-nucleophilic anion as Z⁻ include a sulfonate anion, a carbonate anion, a sulfonylimide anion, a bis(alkyl sulfonyl)imide anion, a tri (alkylsulfonyl)methyl anion, and the like.

A non-nucleophilic anion is an anion which has a markedly poor ability to cause a nucleophilic reaction and can inhibit the decomposition that progresses with the passage of time due to an intermolecular nucleophilic reaction. Due to the non-nucleophilic anion, temporal stability of the resist composition is improved.

Examples of the sulfonate anion include an aliphatic sulfonate anion, an aromatic sulfonate anion, a camphorsulfonate anion, and the like.

Examples of the carbonate anion include an aliphatic carbonate anion, an aromatic carbonate anion, an aralkyl carbonate anion, and the like.

In the aliphatic sulfonate anion and the aliphatic carbonate anion, the aliphatic moiety may be an alkyl group or a cycloalkyl group, and preferably an alkyl group having 1 to 30 carbon atoms and a cycloalkyl group having 3 to 30 carbon atoms.

An aromatic group in the aromatic sulfonate anion and the aromatic carbonate anion is preferably an aryl group having 6 to 14 carbon atoms, and examples thereof include a phenyl group, a tolyl group, a naphthyl group, and the like.

The alkyl group, the cycloalkyl group, and the aryl group in the aliphatic sulfonate anion and the aromatic sulfonate anion may have a substituent.

Examples of other non-nucleophilic anions include fluorinated phosphorus (for example, PF₆⁻), fluorinated boron (for example, BF₄⁻), fluorinated antimony (for example, SbF₆⁻), and the like.

The non-nucleophilic anion as Z⁻ is preferably an aliphatic sulfonate anion in which at least the α position of a sulfonic acid is substituted with a fluorine atom, an aromatic sulfonate anion substituted with a fluorine atom or a group having a fluorine atom, a bis(alkylsulfonyl)imide anion in which an alkyl group is substituted with a fluorine atom, or a tris(alkylsulfonyl)methide anion in which an alkyl group is substituted with a fluorine atom. The non-nucleophilic anion is more preferably a perfluoro aliphatic sulfonate anion having 4 to 8 carbon atoms or a benzene sulfonate anion having a fluorine atom, and even more preferably a nonafluorobutane sulfonate anion, a perfluorooctane sulfonate anion, a pentafluorobenzene sulfonate anion, or a 3,5-bis(trifluoromethyl)benzene sulfonate anion.

The acid generator is preferably a compound generating an acid represented by the following Formula (IIIB) or (IVB) by being irradiated with actinic rays or radiation. If the acid generator is a compound generating an acid represented by the following Formula (MB) or (IVB), the acid generator has a cyclic organic group, and accordingly, resolution and roughness performance can be further improved.

As the non-nucleophilic anion, an anion generating an organic acid represented by the following Formula (IIIB) or (IVB) can be used.

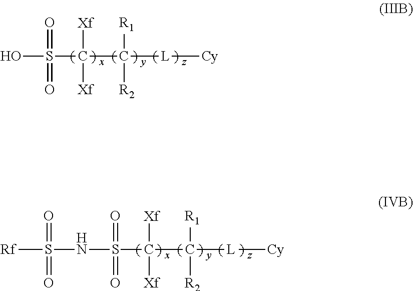

In the above formulae, Xf each independently represents a fluorine atom or an alkyl group substituted with at least one fluorine atom.

R₁ and R₂ each independently represent a hydrogen atom, a fluorine atom, or an alkyl group.

L each independently represents a divalent linking group.

Cy represents a cyclic organic group.

Rf represents a group containing a fluorine atom.

x represents an integer of 1 to 20.

y represents an integer of 0 to 10.

z represents an integer of 0 to 10.

Xf represents a fluorine atom or an alkyl group substituted with at least one fluorine atom. The number of carbon atoms of the alkyl group is preferably 1 to 10, and more preferably 1 to 4. The alkyl group substituted with at least one fluorine atom is preferably a perfluoroalkyl group.

Xf is preferably a fluorine atom or a perfluoroalkyl group having 1 to 4 carbon atoms. More specifically, Xf is preferably a fluorine atom or CF₃. It is particularly preferable that both of Xf's represent a fluorine atom.

R₁ and R₂ each independently represent a hydrogen atom, a fluorine atom, or an alkyl group.

The alkyl group as R₁ and R₂ may have a substituent and preferably has 1 to 4 carbon atoms. R₁ and R₂ preferably represent a hydrogen atom.

L represents a divalent linking group. Examples of the divalent linking group include —COO—, —OCO—, —CONH—, —NHCO—, —CO—, —O—, —S—, —SO—, —SO₂—, an alkylene group (preferably having 1 to 6 carbon atoms), cycloalkylene group (preferably having 3 to 10 carbon atoms), an alkenylene group (preferably having 2 to 6 carbon atoms), a divalent linking group obtained by combining a plurality of these groups, and the like. Among these, —COO—, —OCO—, —CONH—, —NHCO—, —CO—, —O—, —SO₂—, —COO-alkylene group-, —OCO-alkylene group-, —CONH-alkylene group-, or —NHCO-alkylene group- is preferable, and —COO—, —OCO—, —CONH—, —SO₂—, —COO-alkylene group-, or —OCO-alkylene group- is more preferable.

Cy represents a cyclic organic group. Examples of the cyclic organic group include an alicyclic group, an aryl group, and a heterocyclic group.

The alicyclic group may be monocyclic or polycyclic. Examples of the monocyclic alicyclic group include a monocyclic cycloalkyl group such as a cyclopentyl group, a cyclohexyl group, and a cyclooctyl group. Examples of the polycyclic alicyclic group include a polycyclic cycloalkyl group such as a norbornyl group, a tricyclodecanyl group, a tetracyclodecanyl group, a tetracyclododecanyl group, and an adamantyl group. Among these, from the viewpoint of inhibiting diffusivity in a film during the post exposure bake (PEB) step and improving a Mask Error Enhancement Factor (MEEF), alicyclic groups having a bulky structure having 7 or more carbon atoms, such as a norbornyl group, a tricyclodecanyl group, a tetracyclodecanyl group, a tetracyclododecanyl group, and an adamantyl group, are preferable.

The aryl group may be monocyclic or polycyclic. Examples of the aryl group include a phenyl group, a naphthyl group, a phenanthryl group, and an anthryl group. Among these, a naphthyl group having a relatively low absorbance at 193 nm is preferable.

Although the heterocyclic group may be monocyclic or polycyclic, the polycyclic heterocyclic group can more reliably inhibit the diffusion of an acid. The heterocyclic group may or may not have aromaticity. Examples of the heterocyclic ring having aromaticity include a furan ring, a thiophene ring, a benzofuran ring, a benzothiophene ring, a dibenzofuran ring, a dibenzothiophene ring, and a pyridine ring. Examples of the heterocyclic ring not having aromaticity include a tetrahydrofuran ring, a lactone or sultone ring, and a decahydroisoquinoline ring. As a heterocyclic ring in the heterocyclic group, a furan ring, a thiophene ring, a pyridine ring, or a decahydroisoquinoline ring is particularly preferable. Examples of the lactone ring and the sultone ring include the lactone structure and the sultone structure exemplified for the resin (A1) described above.

The aforementioned cyclic organic group may have a substituent. Examples of the substituent include an alkyl group (may be any of linear and branched alkyl groups, preferably having 1 to 12 carbon atoms), a cycloalkyl group (may be any of monocyclic, polycyclic, and spiro rings, preferably having 3 to 20 carbon atoms), an aryl group (preferably having 6 to 14 carbon atoms), a hydroxyl group, an alkoxy group, an ester group, an amide group, a urethane group, a ureide group, a thioether group, a sulfonamide group, and a sulfonic acid ester group. The carbon constituting the cyclic organic group (carbon that contributes to the formation of a ring) may be carbonyl carbon.

x is preferably 1 to 8, more preferably 1 to 4, and particularly preferably 1. y is preferably 0 to 4, and more preferably 0. z is preferably 0 to 8, more preferably 0 to 4, and even more preferably 1.

Examples of the group having a fluorine atom represented by Rf include an alkyl group having at least one fluorine atom, a cycloalkyl group having at least one fluorine atom, and an aryl group having at least one fluorine atom.

These alkyl group, cycloalkyl group, and aryl group may be substituted with either a fluorine atom or other fluorine atom-containing substituents. In a case where Rf is a cycloalkyl group having at least one fluorine atom or an aryl group having at least one fluorine atom, examples of other fluorine atom-containing substituents include an alkyl group substituted with at least one fluorine atom.

Furthermore, these alkyl group, cycloalkyl group, and aryl group may be further substituted with a substituent not containing a fluorine atom. Examples of the substituent include the substituents which were described above for Cy and do not contain a fluorine atom.

Examples of the alkyl group having at least one fluorine atom that is represented by Rf include the same alkyl group as the alkyl group described above that is represented by Xf and substituted with at least one fluorine atom. Examples of the cycloalkyl group having at least one fluorine atom that is represented by Rf include a perfluorocyclopentyl group and a perfluorocyclohexyl group. Examples of the aryl group having at least one fluorine atom that is represented by Rf include a perfluorophenyl group.

In the above formulae, a particularly preferred aspect is an aspect in which x represents 1, two Xf's represent a fluorine atom, y is 0 to 4, both of R₁ and R₂ represent a hydrogen atom, and z is 1. In this aspect, the number of fluorine atoms is small, and the fluorine atom is not easily localized within the surface at the time of forming the resist film and are easily uniformly distributed in the resist film.

Examples of the organic group represented by R₂₀₁, R₂₀₂, and R₂₀₃ include the corresponding groups in the compounds (ZI-1), (ZI-2), (ZI-3), and (ZI-4) which will be described later.

The acid generator may be a compound having a plurality of structures represented by Formula (ZI). For example, the acid generator may be a compound having a structure in which at least one of R₂₀₁ to R₂₀₃ of a compound represented by Formula (ZI) is bonded to at least one of R₂₀₁ to R₂₀₃ of the other compound represented by Formula (ZI) through a single bond or a linking group.

Examples of a more preferred (ZI) component include compounds (ZI-1), (ZI-2), (ZI-3), and (ZI-4) described below.

First, the compound (ZI-1) will be described.

The compound (ZI-1) is an aryl sulfonium compound in which at least one of R₂₀₁ to R₂₀₃ of Formula (ZI) is an aryl group, that is, a compound using aryl sulfonium as a cation.

In the aryl sulfonium compound, all of R₂₀₁ to R₂₀₃ may be an aryl group. Alternatively, some of R₂₀₁ to R₂₀₃ may be an aryl group, and the rest may be an alkyl group or a cycloalkyl group.

Examples of the aryl sulfonium compound include a triaryl sulfonium compound, a diaryl alkyl sulfonium compound, an aryl dialkyl sulfonium compound, a diaryl cycloalkyl sulfonium compound, and an aryl dicycloalkyl sulfonium compound.

The aryl group of the aryl sulfonium compound is preferably a phenyl group or a naphthyl group, and more preferably a phenyl group. The aryl group may be an aryl group having a heterocyclic structure having an oxygen atom, a nitrogen atom, a sulfur atom, and the like. Examples of the heterocyclic structure include a pyrrole residue, a furan residue, a thiophene residue, an indole residue, a benzofuran residue, a benzothiophene residue, and the like. In a case where the aryl sulfonium compound has two or more aryl groups, the two or more aryl groups may be the same as or different from each other.

As the alkyl group or the cycloalkyl group that the aryl sulfonium compound has if necessary, a linear or branched alkyl group having 1 to 15 carbon atoms and a cycloalkyl group having 3 to 15 carbon atoms are preferable. Examples thereof include a methyl group, an ethyl group, a propyl group, a n-butyl group, a sec-butyl group, a t-butyl group, a cyclopropyl group, a cyclobutyl group, a cyclohexyl group, and the like.

The aryl group, the alkyl group, and the cycloalkyl group as R₂₀₁ to R₂₀₃ may have, as a substituent, an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group, or a phenylthio group.

Next, the compound (ZI-2) will be described.

The compound (ZI-2) is a compound in which R₂₀₁ to R₂₀₃ in Formula (ZI) each independently represent an organic group not having an aromatic ring. The aromatic ring also includes a heteroatom-containing aromatic ring.

The organic group not containing an aromatic ring that is represented by R₂₀₁ to R₂₀₃ generally has 1 to 30 carbon atoms and preferably has 1 to 20 carbon atoms.

R₂₀₁ to R₂₀₃ each independently preferably represent an alkyl group, a cycloalkyl group, an allyl group, or a vinyl group, more preferably represent a linear or branched 2-oxoalkyl group, a 2-oxocycloalkyl group, or an alkoxycarbonyl methyl group, and particularly preferably represent a linear or branched 2-oxoalkyl group.

Preferred examples of the alkyl group and the cycloalkyl group represented by R₂₀₁ to R₂₀₃ include a linear or branched alkyl group having 1 to 10 carbon atoms (for example, a methyl group, an ethyl group, a propyl group, a butyl group, or a pentyl group) and a cycloalkyl group having 3 to 10 carbon atoms (a cyclopentyl group, a cyclohexyl group, or a norbornyl group).

R₂₀₁ to R₂₀₃ may be further substituted with a halogen atom, an alkoxy group (for example, having 1 to 5 carbon atoms), a hydroxyl group, a cyano group, or a nitro group.

Next, the compound (ZI-3) will be described.

The compound (ZI-3) is a compound which is represented by the following Formula (ZI-3) and has a phenacyl sulfonium salt structure.

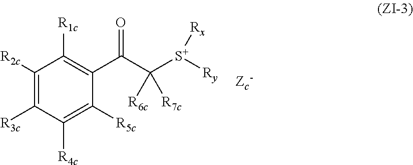

In Formula (ZI-3), R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} each independently represent a hydrogen atom, an alkyl group, a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonyl alkyl group, an allyl group, or a vinyl group.

Any two or more groups out of R_{1c} to R_{5c}, R_{5c} and R_{6c}, R_{6c} and R_{7c}, R_{5c} and Rₓ, and Rₓ and R_{y} may form a ring structure by being bonded to each other respectively, and the ring structure may contain an oxygen atom, a sulfur atom, a ketone group, an ester bond, or an amide bond.

Examples of the ring structure include an aromatic or non-aromatic hydrocarbon ring, an aromatic or non-aromatic heterocyclic ring, or a polycyclic condensed ring in which two or more of these rings are combined. Examples of the ring structure include a 3- to 10-membered ring. The ring structure is preferably a 4- to 8-membered ring, and more preferably a 5- or 6-membered ring.

Examples of the group formed by the bonding between any two or more groups out of R_{1c} to R_{5c}, the bonding between R_{6c} and R_{7c}, and the bonding between Rₓ and R_{y} include a butylene group, a pentylene group, and the like.

As the group formed by the bonding between R_{5c} and R_{6c} and the bonding between R_{5c} and Rₓ, a single bond or an alkylene group is preferable. Examples of the alkylene group include a methylene group and an ethylene group.

Zc⁻ represents a non-nucleophilic anion, and examples thereof include the same non-nucleophilic anion as Z⁻ in Formula (ZI).

Specific examples of the alkoxy group in the alkoxycarbonyl group as R₁c to R₅c are the same as the specific examples of the alkoxy group as R₁c to R₅c described above.

Specific examples of the alkyl group in the alkylcarbonyloxy group and the alkylthio group as R₁c to R₅c are the same as the specific examples of the alkyl group as R₁c to R₅c described above.

Specific examples of the cycloalkyl group in the cycloalkylcarbonyloxy group as R₁c to R₅c are the same as the specific examples of the cycloalkyl group as R₁c to R₅c described above.

Specific examples of the aryl group in the aryloxy group and the arylthio group as R₁c to R₅c are the same as the specific examples of the aryl group as R₁c to R₅c described above.

As the cation in the compound (ZI-2) or (ZI-3) in the present invention, the cations described from paragraph “0036” of US2012/0076996A can be exemplified.

Next, the compound (ZI-4) will be described.

The compound (ZI-4) is represented by the following Formula (ZI-4).

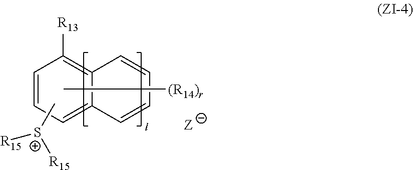

In Formula (ZI-4), R₁₃ represents a hydrogen atom, a fluorine atom, a hydroxyl group, an alkyl group, a cycloalkyl group, an alkoxy group, an alkoxycarbonyl group, or a group having a cycloalkyl group. These groups may have a substituent.

In a case where there is a plurality of R₁₄'s, R₁₄ each independently represents a hydrogen atom, an alkyl group, a cycloalkyl group, an alkoxy group, an alkoxycarbonyl group, an alkylcarbonyl group, an alkylsulfonyl group, a cycloalkyl sulfonyl group, or a group having a cycloalkyl group. These groups may have a substituent.

R₁₅ each independently represents an alkyl group, a cycloalkyl group, or a naphthyl group. Two R₁₅'s may form a ring by being bonded to each other. When two R₁₅'s form a ring by being bonded to each other, the ring may contain a heteroatom such as an oxygen atom or a nitrogen atom in the skeleton of the ring. In an aspect, it is preferable that two R₁₅'s represent an alkylene group and form a ring structure by being bonded to each other.

1 represents an integer of 0 to 2.

r represents an integer of 0 to 8.

Z⁻ represents a non-nucleophilic anion, and examples thereof include the same non-nucleophilic anion as Z⁻ in Formula (ZI).

In Formula (ZI-4), the alkyl group as R₁₃, R₁₄, and R₁₅ is preferably a linear or branched alkyl group having 1 to 10 carbon atoms. The alkyl group is preferably a methyl group, an ethyl group, a n-butyl group, a t-butyl group, or the like.

As the cation of the compound represented by Formula (ZI-4) in the present invention, the cations described in paragraphs “0121”, “0123”, and “0124” of JP2010-256842A and paragraphs “0127”, “0129”, and “0130” of JP2011-76056A can be exemplified.

Next, Formulae (ZII) and (ZIII) will be described.

In Formulae (ZII) and (ZIII), R₂₀₄ to R₂₀₇ each independently represent an aryl group, an alkyl group, or a cycloalkyl group.

The aryl group as R₂₀₄ to R₂₀₇ is preferably a phenyl group or a naphthyl group, and more preferably a phenyl group. The aryl group as R₂₀₄ to R₂₀₇ is preferably an aryl group having a heterocyclic structure having an oxygen atom, a nitrogen atom, a sulfur atom, or the like. Examples of the skeleton of the aryl group having the heterocyclic structure include pyrrole, furan, thiophene, indole, benzofuran, benzothiophene, and the like.

Preferred examples of the alkyl group and the cycloalkyl group as R₂₀₄ to R₂₀₇ include a linear or branched alkyl group having 1 to 10 carbon atoms (for example, a methyl group, an ethyl group, a propyl group, a butyl group, or a pentyl group) and a cycloalkyl group having 3 to 10 carbon atoms (a cyclopentyl group, a cyclohexyl group, or a norbornyl group).

The aryl group, the alkyl group, and the cycloalkyl group as R₂₀₄ to R₂₀₇ may have a substituent. Examples of the substituent that the aryl group, the alkyl group, and the cycloalkyl group as R₂₀₄ to R₂₀₇ may have include an alkyl group (for example, preferably having 1 to 15 carbon atoms), a cycloalkyl group (for example, preferably having 3 to 15 carbon atoms), an aryl group (for example, preferably having 6 to 15 carbon atoms), an alkoxy group (for example, preferably having 1 to 15 carbon atoms), a halogen atom, a hydroxyl group, a phenyl group, and the like.

Z⁻ represents a non-nucleophilic anion, and examples thereof include the same non-nucleophilic anion as Z⁻ in Formula (ZI).

Examples of the acid generator also include compounds represented by the following Formulae (ZIV), (ZV), and (ZVI).

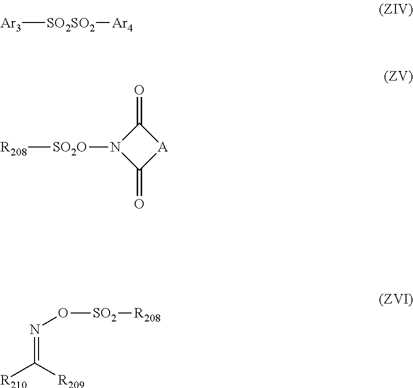

In Formulae (ZIV) to (ZVI), Ar₃ and Ar₄ each independently represent an aryl group.

R₂₀₈, R₂₀₉, and R₂₁₀ each independently represent an alkyl group, a cycloalkyl group, or an aryl group.

A represents an alkylene group, an alkenylene group, or an arylene group.

Specific examples of the aryl group as Ar₃, Ar₄, R₂₀₈, R₂₀₉, and R₂₁₀ include are the same as the specific examples of the aryl group as R₂₀₁, R₂₀₂, and R₂₀₃ in Formula (ZI-1) described above.

Specific examples of the alkyl group and the cycloalkyl group as R₂₀₈, R₂₀₉, and R₂₁₀ are the same as the specific examples of the alkyl group and the cycloalkyl group as R₂₀₁, R₂₀₂, and R₂₀₃ in Formula (ZI-2) described above.

Examples of the alkylene group as A include an alkylene group having 1 to 12 carbon atoms (for example, a methylene group, an ethylene group, a propylene group, an isopropylene group, a butylene group, or an isobutylene group). Examples of the alkenylene group as A include an alkenylene group having 2 to 12 carbon atoms (for example, an ethenylene group, a propenylene group, or a butenylene group). Examples of the arylene group as A include an arylene group having 6 to 10 carbon atoms (for example, a phenylene group, a tolylene group, or a naphthylene group).

Among the acid generators, the compounds described in paragraph “0143” of US2012/0207978A1 can be exemplified as particularly preferable acid generators.

The acid generator can be synthesized by a known method. For example, the acid generator can be synthesized based on the methods described in JP2007-161707A.

One kind of acid generator can be used singly, or two or more kinds thereof may be used in combination.

A content of the compound generating an acid by being irradiated with actinic rays or radiation in the composition (in a case where the composition contains plural kinds of the compound, a total content thereof) is, with respect to the total solid content of the first resist composition, preferably 0.1% to 30% by mass, more preferably 0.5% to 25% by mass, even more preferably 1% to 20% by mass, and particularly preferably 2% to 15% by mass.

In a case where the acid generator is represented by Formula (ZI-3) or (ZI-4), a content thereof (in a case where the composition contains plural kinds of the compound, a total content thereof) is, with respect to the total solid contents of the composition, preferably 5% to 35% by mass, more preferably 8% to 30% by mass, even more preferably 9% to 30% by mass, and particularly preferably 9% to 25% by mass.

Specific examples of the acid generator will be shown below, but the present invention is not limited thereto.

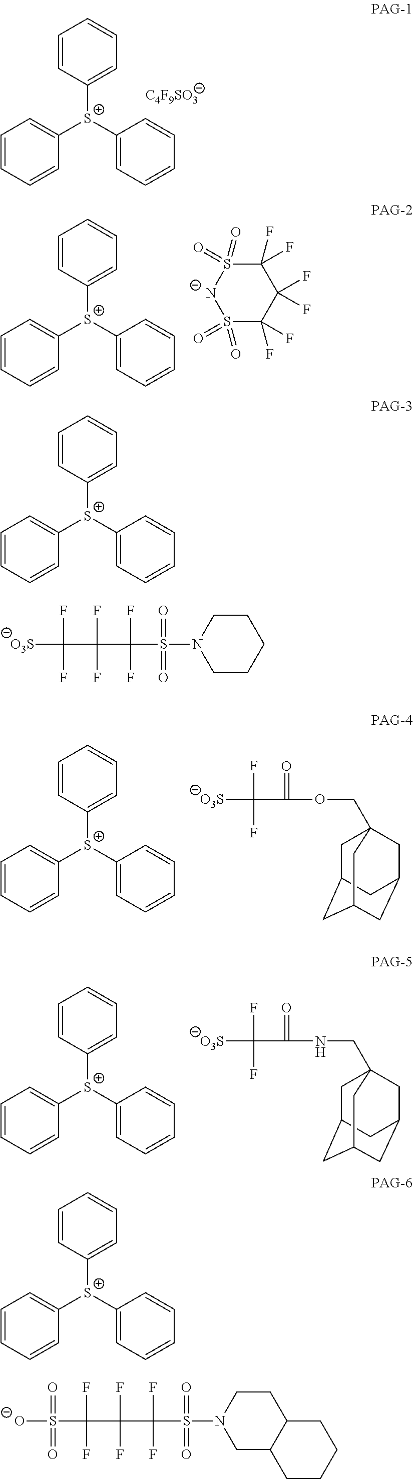

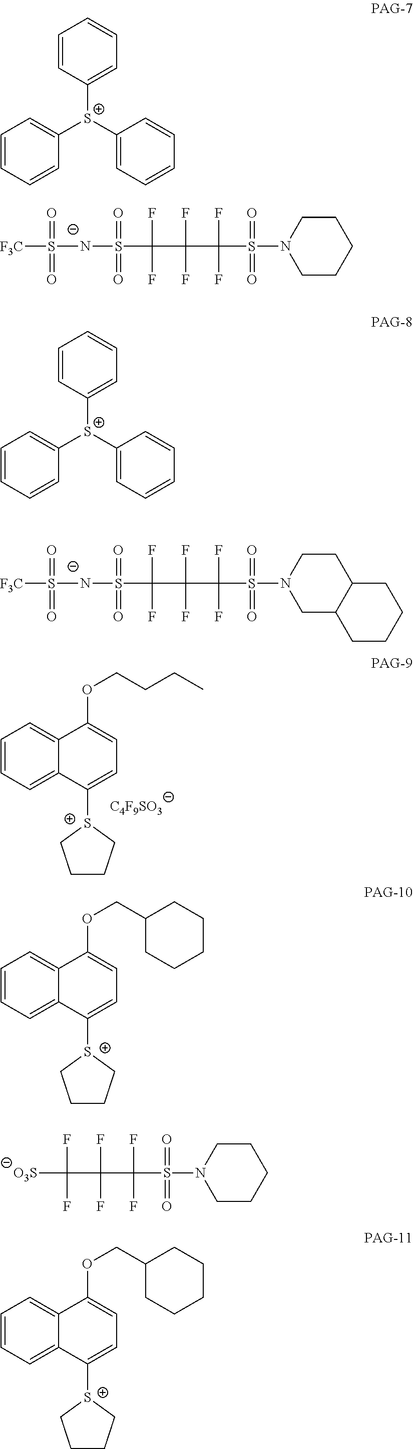

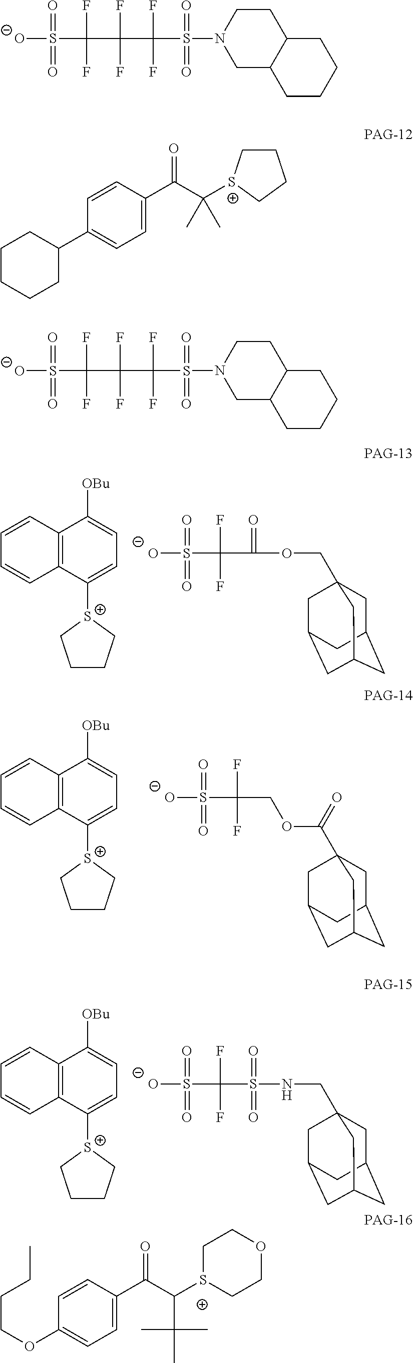

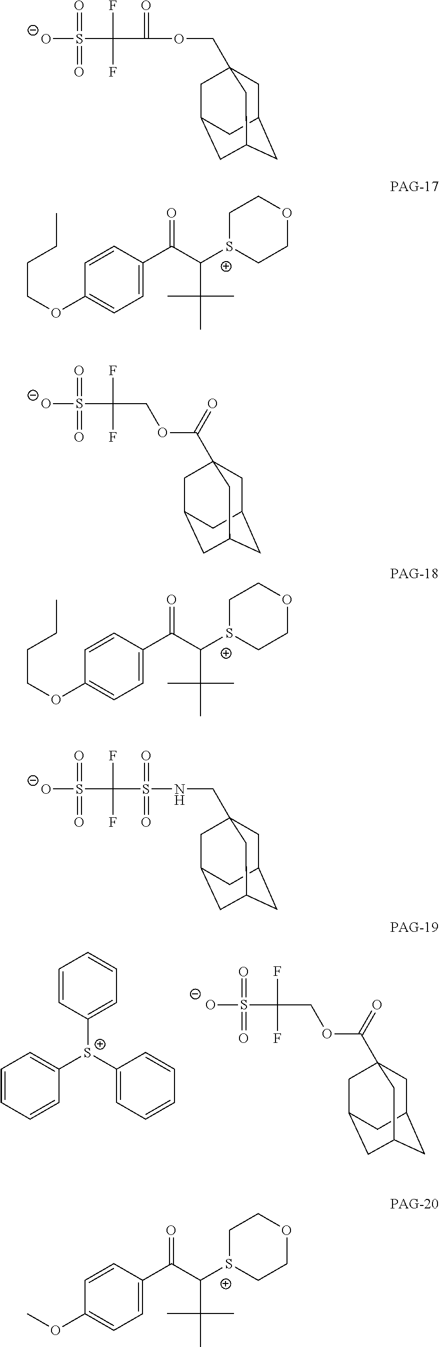

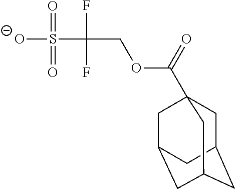 [SMILES: O=C(OCC(F)(F)S(=O)(=O)[O-])C12CC3CC(CC(C3)C1)C2]

(Cross-Linking Agent (C)>

In a case where the resin (A2) having a phenolic hydroxyl group is used as the resin (A), and the composition of the present invention is used for forming a negative pattern, it is preferable that the composition of the present invention contains, as a cross-linking agent, a compound having two or more methylol groups in a molecule (hereinafter, referred to as a “compound (C)”, a “cross-linking agent”, or the like). Herein, the methylol group is a group represented by Formula (M) described above.

Examples of preferred cross-linking agents include a hydroxymethylated or alkoxymethylated phenol compound, an alkoxymethylated melamine-based compound, an alkoxymethyl glycoluril-based compound, and an alkoxymethylated urea-based compound. These may have any substituent. Examples of the compound (C) particularly preferable as a cross-linking agent include a phenol derivative or an alkoxymethyl glycoluril derivative which contains 3 to 5 benzene rings in a molecule, has a total of two or more hydroxymethyl groups or alkoxymethyl groups, and has a molecular weight of equal to or less than 1,200.

As the alkoxymethyl group, a methoxymethyl group or an ethoxymethyl group is preferable.

Among the aforementioned cross-linking agents, the phenol derivative having a hydroxymethyl group can be obtained by reacting a phenol compound, which does not have the corresponding hydroxymethyl group, with formaldehyde in the presence of a basic catalyst. Furthermore, the phenol derivative having an alkoxymethyl group can be obtained by reacting a phenol derivative having the corresponding hydroxymethyl group with an alcohol in the presence of an acidic catalyst.

Examples of other preferred cross-linking agents include compounds having a N-hydroxymethyl group or a N-alkoxymethyl group such as an alkoxymethylated melamine-based compound, alkoxymethyl glycoluril-based compounds, and an alkoxymethylated urea-based compound.

Examples of these compounds are include hexamethoxymethyl melamine, hexaethoxymethyl melamine, tetramethoxymethyl glycoluril, 1,3-bismethoxymethyl-4,5-bismethoxyethylene urea, bismethoxymethyl urea, and the like. These compounds are disclosed in EP0133216A, West German Patent Nos. 3634671 and 3711264, and EP0212482A.

Examples of particularly preferred cross-linking agents among the above cross-linking agents will be shown below.

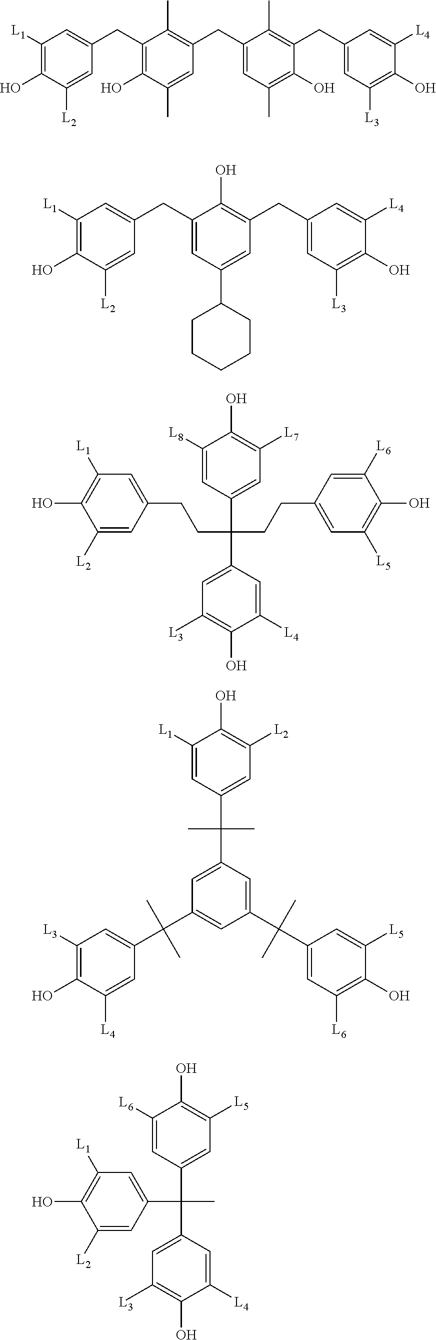

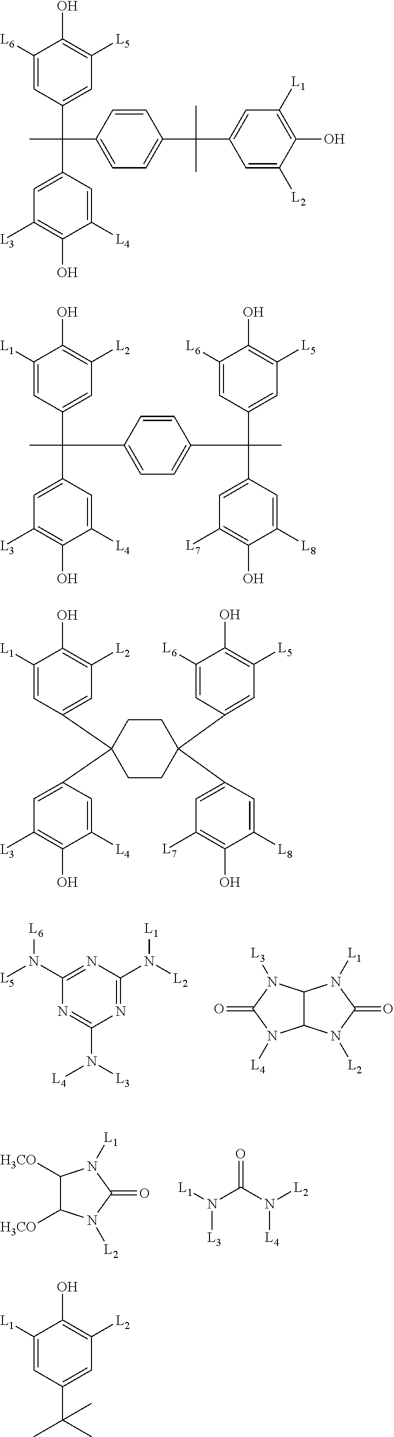

In the formulae, L₁ to L₈ each independently represent a hydrogen atom, a hydroxymethyl group, a methoxymethyl group, an ethoxymethyl group, or an alkyl group having 1 to 6 carbon atoms.

In the present invention, a content of the cross-linking agent in the composition of the present invention containing the resin (A2) having a phenolic hydroxyl group is, with respect to the total solid contents of the composition, preferably 3% to 65% by mass, and more preferably 5% to 50% by mass. If the content rate of the cross-linking agent is within a range of 3% to 65% by mass, it is possible to prevent a decrease of a film retention rate and a resolving power and to keep the stability of the composition of the present invention excellent at the time of storage.

In the present invention, one kind of cross-linking agent (C) may be used singly, or two or more kinds thereof may be used in combination. From the viewpoint of an excellent pattern shape, it is preferable to use two or more kinds thereof in combination.

For example, in a case where other cross-linking agents such as a compound having the aforementioned N-alkoxymethyl group are used in combination with the aforementioned phenol derivative, a ratio between the phenol derivative and other cross-linking agents is generally 90/10 to 20/80, preferably 85/15 to 40/60, and more preferably 80/20 to 50/50, in terms of molar ratio.

<Basic Compound>

In order to reduce a performance change that occurs as time passes from exposure to heating, the resist composition of the present invention preferably contains a basic compound.

Preferred examples of the basic compound include compounds having structures represented by the following Formulae (A) to (E).

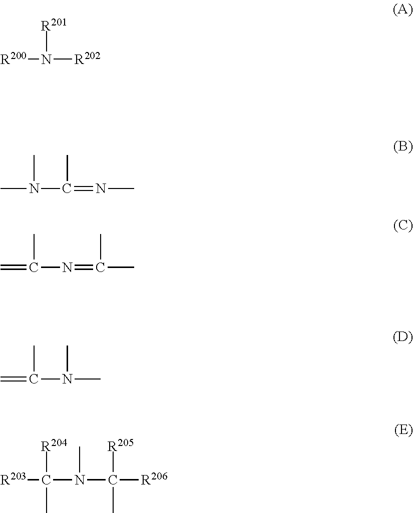

In Formulae (A) and (E), R²⁰⁰, R²⁰¹, and R²⁰² may be the same as or different from each other, and each represent a hydrogen atom, an alkyl group (preferably having 1 to 20 carbon atoms), a cycloalkyl group (preferably having 3 to 20 carbon atoms), or an aryl group (preferably having 6 to 20 carbon atoms). R²⁰¹ and R²⁰² may form a ring by being bonded to each other.

R²⁰³, R²⁰⁴, R²⁰⁵, and R²⁰⁶ may be the same as or different from each other, and each represent an alkyl group having 1 to 20 carbon atoms.

The alkyl group may have a substituent, and as the alkyl group having a substituent, an aminoalkyl group having 1 to 20 carbon atoms, a hydroxyalkyl group having 1 to 20 carbon atoms, or a cyanoalkyl group having 1 to 20 carbon atoms is preferable.

The alkyl group in Formulae (A) and (E) is more preferably unsubstituted.

Examples of the compound preferably include guanidine, aminopyridine, pyrazole, pyrazoline, piperazine, aminomorpholine, aminoalkyl morpholine, piperidine, and the like, and more preferably include a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, an aniline derivative having a hydroxyl group and/or an ether bond, and the like.

Examples of the compound having an imidazole structure include imidazole, 2,4,5-triphenylimidazole, benzimidazole, 2-phenylbenzimidazole, and the like. Examples of the compound having a diazabicyclo structure include 1,4-diazabicyclo[2,2,2]octane, 1,5-diazabicyclo[4,3,0]non-5-ene, 1,8-diazabicyclo[5,4,0]undec-7-ene, and the like. Examples of the compound having an onium hydroxide structure include tetrabutylammonium hydroxide, triaryl sulfonium hydroxide, phenacyl sulfonium hydroxide, and sulfonium hydroxide having a 2-oxoalkyl group, and specific examples thereof include triphenyl sulfonium hydroxide, tri s(t-butylphenyl)sulfonium hydroxide, bis(t-butylphenyl)iodonium hydroxide, phenacyl thiophenium hydroxide, 2-oxopropyl thiophenium hydroxide, and the like. Examples of the compound having an onium carboxylate structure include a compound in which an anion portion of a compound having an onium hydroxide structure becomes carboxylate, and examples thereof include acetate, adamantane-1-carboxylate, perfluoroalkyl carboxylate, and the like. Examples of the compound having a trialkylamine structure include tri(n-butyl)amine, tri(n-octyl)amine, and the like. Examples of the aniline compound include 2,6-diisopropylaniline, N,N-dimethylaniline, N,N-dibutylaniline, N,N-dihexylaniline, and the like. Examples of the alkylamine derivative having a hydroxyl group and/or an ether bond include ethanolamine, diethanolamine, triethanolamine, N-phenyldiethanolamine, tris(methoxyethoxyethyl)amine, and the like. Examples of the aniline derivative having a hydroxyl group and/or an ether bond include N,N-bis(hydroxyethyl)aniline and the like.

Examples of the preferred basic compound further include an amine compound having a phenoxy group, an ammonium salt compound having a phenoxy group, an amine compound having a sulfonic acid ester group, and an ammonium salt compound having a sulfonic acid ester group, and the like.

As the amine compound, it is possible to use a primary, secondary, or a tertiary amine compound. The amine compound is preferably an amine compound in which at least one alkyl group is bonded to a nitrogen atom, and more preferably a tertiary amine compound. As long as at least one alkyl group (preferably having 1 to 20 carbon atoms) is bonded to a nitrogen atom in the amine compound, a cycloalkyl group (preferably having 3 to 20 carbon atoms) or an aryl group (preferably having 6 to 12 carbon atoms) may be bonded to the nitrogen atom in addition to the alkyl group. It is preferable that the amine compound has an oxygen atom in an alkyl chain such that an oxyalkylene group is formed. The number of oxyalkylene groups in a molecule is 1 or greater, preferably 3 to 9, and more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

As the ammonium salt compound, it is possible to use a primary, secondary, tertiary, or quaternary ammonium salt compound. The ammonium salt compound is preferably an ammonium salt compound in which at least one alkyl group is bonded to a nitrogen atom. As long as at least one alkyl group (preferably having 1 to 20 carbon atoms) is bonded to a nitrogen atom in the ammonium salt compound, a cycloalkyl group (preferably having 3 to 20 carbon atoms) or an aryl group (preferably having 6 to 12 carbon atoms) may be bonded to the nitrogen atom in addition to the alkyl group. It is preferable that the ammonium salt compound has an oxygen atom in an alkyl chain such that an oxyalkylene group is formed. The number of oxyalkylene groups in a molecule is 1 or greater, preferably 3 to 9, and more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

Examples of an anion of the ammonium salt compound include a halogen atom, sulfonate, borate, phosphate, and the like. Among these, a halogen atom and sulfonate are preferable. As the halogen atom, chloride, bromide, and iodide are particularly preferable. As the sulfonate, organic sulfonate having 1 to 20 carbon atoms is particularly preferable. Examples of the organic sulfonate include alkyl sulfonate and aryl sulfonate having 1 to 20 carbon atoms. The alkyl group of the alkyl sulfonate may have a substituent, and examples of the substituent include fluorine, chlorine, bromine, an alkoxy group, an acyl group, an aryl group, and the like. Specific examples of the alkyl sulfonate include a methane sulfonate, ethane sulfonate, butane sulfonate, hexane sulfonate, octane sulfonate, benzyl sulfonate, trifluoromethane sulfonate, pentafluoroethane sulfonate, nonafluorobutane sulfonate, and the like. Examples of the aryl group of the aryl sulfonate include a benzene ring, a naphthalene ring, and an anthracene ring. The benzene ring, the naphthalene ring, and the anthracene ring may have a substituent, and as the substituent, a linear or branched alkyl group having 1 to 6 carbon atoms and a cycloalkyl group having 3 to 6 carbon atoms are preferable. Specific examples of the linear or branched alkyl group and the cycloalkyl group include methyl, ethyl, n-propyl, isopropyl, n-butyl, i-butyl, t-butyl, n-hexyl, cyclohexyl, and the like. Examples of other substituents include an alkoxy group having 1 to 6 carbon atoms, a halogen atom, cyano, nitro, an acyl group, an acyloxy group, and the like.

The amine compound having a phenoxy group or the ammonium salt compound having a phenoxy group is a compound having a phenoxy group on a terminal on the side opposite to the nitrogen atom of the alkyl group of the amine compound or the ammonium salt compound. The phenoxy group may have a substituent. Examples of the substituent of the phenoxy group include an alkyl group, an alkoxy group, a halogen atom, a cyano group, a nitro group, a carboxyl group, an carboxylic acid ester group, a sulfonic acid ester group, an aryl group, an aralkyl group, an acyloxy group, an aryloxy group, and the like. The substitution position of the substituent may be any of the 2- to 6-position, and the number of substituents may be within a range of 1 to 5.

It is preferable that at least one oxyalkylene group is present between a phenoxy group and a nitrogen atom. The number of oxyalkylene groups in a molecule is 1 or greater, preferably 3 to 9, and more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

The sulfonic acid ester group in the amine compound having a sulfonic acid ester group or in the ammonium salt compound having a sulfonic acid ester group may be any of an alkyl sulfonic acid ester, a sulfonic acid ester of a cycloalkyl group, and an aryl sulfonic acid ester. In a case of an alkyl sulfonic acid ester, the alkyl group preferably has 1 to 20 carbon atoms. In a case of a cycloalkyl sulfonic acid ester, the cycloalkyl group preferably has 3 to 20 carbon atoms. In a case of an aryl sulfonic acid ester, the aryl group preferably has 6 to 12 carbon atoms. The alkyl sulfonic acid ester, the cycloalkyl sulfonic acid ester, and the aryl sulfonic acid ester may have a substituent. As the substituent, a halogen atom, a cyano group, a nitro group, a carboxyl group, a carboxylic acid ester group, and a sulfonic acid ester group are preferable.

It is preferable that at least one oxyalkylene group is present between a sulfonic acid ester group and a nitrogen atom. The number of oxyalkylene groups in a molecule is equal to or greater than 1, preferably 3 to 9, and even more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

The following compounds are also preferable as the basic compound.

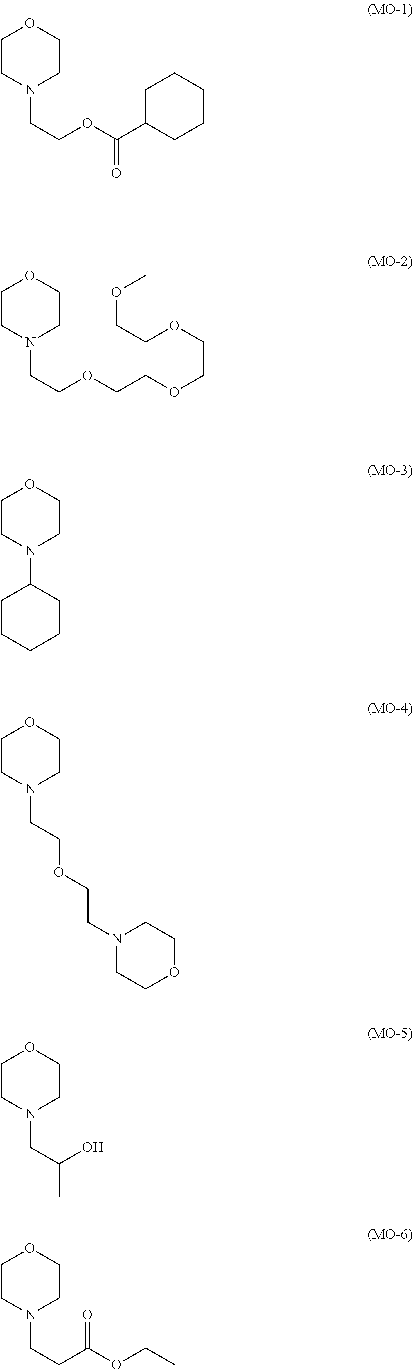

As the basic compound, in addition to the aforementioned compounds, it is possible to use the compounds described in paragraphs “0180” to “0225” in JP2011-22560A, paragraphs “0218” and “0219” of JP2012-137735A, and paragraphs “0416” to “0438” of WO2011/158687A1. The basic compound may be a basic compound or an ammonium salt compound that undergoes a decrease of basicity when being irradiated with actinic rays or radiation.

One kind of basic compound may be used singly, or two or more kinds thereof may be used in combination.

The composition of the present invention may or may not contain the basic compound. In a case where the composition contains the basic compound, a content rate of the basic compound is, with respect to the solid contents of the resist composition, generally 0.001% to 10% by mass, and preferably 0.01% to 5% by mass.

A ratio between the acid generator (including the acid generator (B′)) and the basic compound used in the composition is preferably acid generator/basic compound (molar ratio)=2.5 to 300. That is, in view of sensitivity and resolution, the molar ratio is preferably equal to or greater than 2.5. In view of suppressing a decrease of resolution resulting from the thickening of a resist pattern caused with the passage of time until the post exposure baking treatment, the molar ratio is equal to or less than 300. The acid generator/basic compound (molar ratio) is more preferably 5.0 to 200, and even more preferably 7.0 to 150.

The molar ratio of the used basic compound to the following low-molecular weight compound (D) is preferably low-molecular weight compound (D)/basic compound=100/0 to 10/90, more preferably 100/0 to 30/70, and particularly preferably 100/0 to 50/50.

The basic compound referred herein does not include (D) a low-molecular weight compound which has a nitrogen atom and a group eliminated by the action of an acid.

<Low-Molecular Weight Compound Having Nitrogen Atom an Group Eliminated by Action of Acid>

The composition of the present invention may contain a compound (hereinafter, referred to as a “compound (D)” as well) which has a nitrogen atom and a group eliminated by the action of an acid.

The group eliminated by the action of an acid is not particularly limited, but is preferably an acetal group, a carbonate group, a carbamate group, a tertiary ester group, a tertiary hydroxyl group, or a hemiaminal ether group, and particularly preferably a carbamate group or a hemiaminal ether group.

A molecular weight of the compound (D) having a group eliminated by the action of an acid is preferably 100 to 1,000, more preferably 100 to 700, and particularly preferably 100 to 500.

As the compound (D), an amine derivative having a group eliminated by the action of an acid on a nitrogen atom is preferable.

The compound (D) may have a carbamate group having a protective group on a nitrogen atom. The protective group constituting the carbamate group can be represented by the following Formula (d-1).

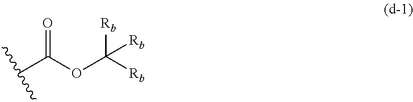

In Formula (d-1), Rb each independently represents a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). Rb's may form a ring by being bonded to each other.

The alkyl group, the cycloalkyl group, the aryl group, and the aralkyl group represented by Rb may be substituted with a functional group such as a hydroxyl group, a cyano group, an amino group, a pyrrolidino group, a piperidino group, a morpholino group, or an oxo group, an alkoxy group, or a halogen atom. The alkoxyalkyl group represented by Rb may be substituted with the same substituent as described above.

Examples of the alkyl group, the cycloalkyl group, the aryl group, or the aralkyl group (these alkyl group, cycloalkyl group, aryl group, and aralkyl group may be substituted with the aforementioned functional group, an alkoxy group, or a halogen atom) as Rb include groups obtained by substituting groups derived from linear or branched alkanes such as methane, ethane, propane, butane, pentane, hexane, heptane, octane, nonane, decane, undeane, and dodecane and groups derived from these alkanes with one or more kinds of cycloalkyl group such as a cyclobutyl group, a cyclopentyl group, or a cyclohexyl group or with one or more cycloalkyl groups; groups obtained by substituting groups derived from cycloalkanes such as cyclobutane, cyclopentane, cyclohexane, cycloheptane, cyclooctane, norbornane, adamantane, and noradamantane or groups derived from these cycloalkanes with one or more kinds of linear or branched alkyl group such as a methyl group, an ethyl group, a n-propyl group, an i-propyl group, a n-butyl group, a 2-methylpropyl group, a 1-methylpropyl group, or a t-butyl group or with one or more linear or branched alkyl groups; groups obtained by substituting groups derived from aromatic compounds such as benzene, naphthalene, and anthracene or groups derived from these aromatic compounds with one or more kinds of linear or branched alkyl group such as a methyl group, an ethyl group, a n-propyl group, an i-propyl group, a n-butyl group, a 2-methylpropyl group, a 1-methylpropyl group, or a t-butyl group or with one or more linear or branched alkyl groups; groups obtained by substituting groups derived from heterocyclic compounds such as pyrrolidine, piperidine, morpholine, tetrahydrofuran, tetrahydropyran, indole, indoline, quinoline, perhydroquinoline, indazole, and benzimidazole or groups derived from these heterocyclic compounds with one or more kinds of linear or branched alkyl group or with one or more kinds of group derived from an aromatic compound; groups obtained by substituting a group derived from linear or branched alkane or a group derived from cycloalkane with one or more kinds of group derived from an aromatic compound such as a phenyl group, a naphthayl group, or an anthracenyl group or with one or more aromatic compounds; groups obtained by substituting the above substituents with a functional group such as a hydroxyl group, a cyano group, an amino group, a pyrrolidino group, a piperidino group, a morpholino group, or an oxo group; and the like.

Rb is preferably a linear or branched alkyl group, a cycloalkyl group, or an aryl group, and more preferably a linear or branched alkyl group or a cycloalkyl group.

Examples of the ring formed by two Rb's linked to each other include an alicyclic hydrocarbon group, an aromatic hydrocarbon group, a heterocyclic hydrocarbon group, a derivative thereof, and the like.

Specific structures of the group represented by Formula (d-1) will be shown below.

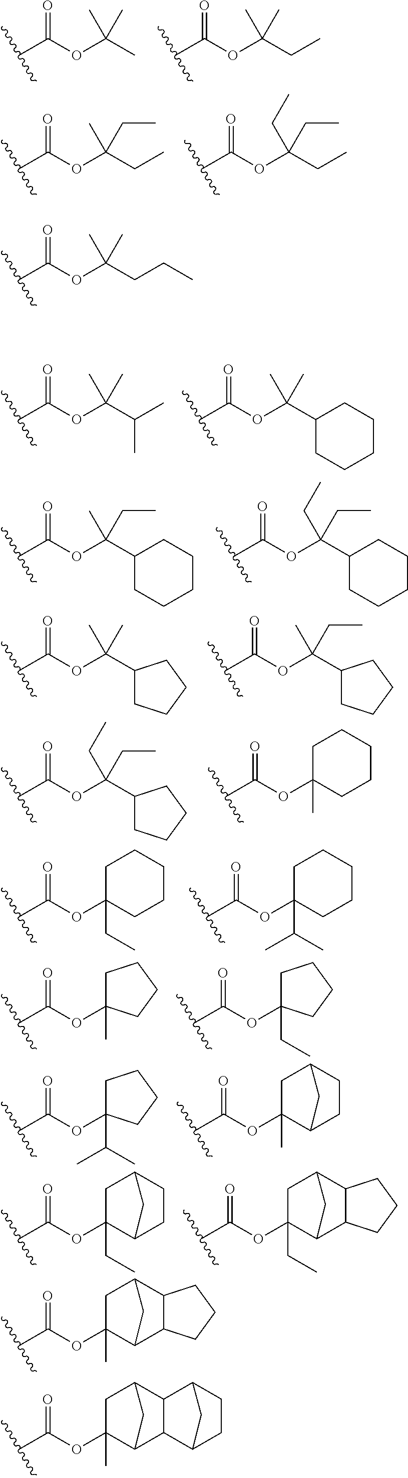

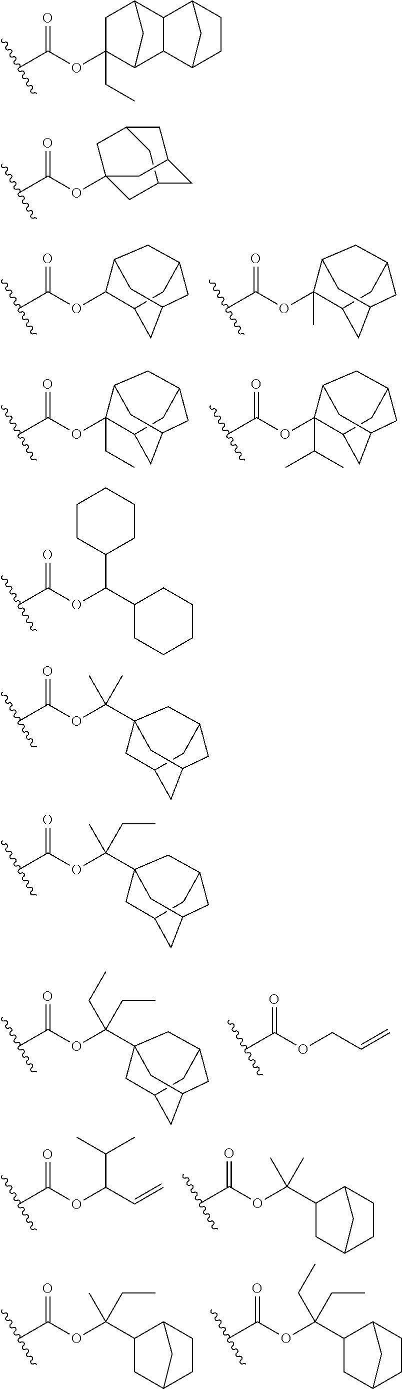

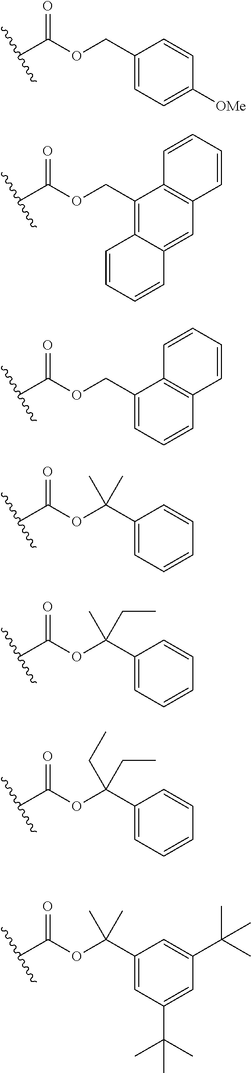

The compound (D) particularly preferably has a structure represented by the following Formula (6).

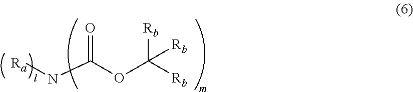

In Formula (6), Ra represents a hydrogen atom, an alkyl group, a cycloalkyl group, an aryl group, or an aralkyl group. When 1 is 2, two Ra's may be the same as or different from each other, and two Ra's may for a heterocyclic ring together with the nitrogen atom in the formula by being bonded to each other. The heterocyclic ring may contain a heteroatom other than the nitrogen atom in the formula.

Rb has the same definition as Rb in Formula (d-1), and preferred examples are also the same.

l represents an integer of 0 to 2, m represents an integer of 1 to 3, and l+m equals 3.

In Formula (6), the alkyl group, the cycloalkyl group, the aryl group, and the aralkyl group as Ra may be substituted with the same group as the group described above as a group with which the alkyl group, the cycloalkyl group, the aryl group, and the aralkyl group as Rb may be substituted.

Specific examples of the alkyl group, the cycloalkyl group, the aryl group, and the aralkyl group as Ra (these alkyl group, cycloalkyl group, aryl group, and aralkyl group may be substituted with the aforementioned group) include the same groups as the specific examples described above for Rb.

The heterocyclic ring formed by Ra's linked to each other is preferably a group having 20 or less carbon atoms, and examples thereof include those obtained by substituting groups derived from heterocyclic compounds such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1, 5,7-triazabicyclo[4.4.0]dec-5-ene, indole, indoline, 1,2,3,4-tetrahydroquinoxaline, perhydroquinoline, and 1,5,9-triazacyclododecane or groups derived from these heterocyclic compounds with a group derived from linear or branched alkane, a group derived from cycloalkane, a group derived from an aromatic compound, a group derived from a heterocyclic compound, one or more kinds of functional group such as a hydroxyl group, a cyano group, an amino group, a pyrrolidino group, a piperidino group, a morpholino group, or an oxo group, or one or more functional groups, and the like.

Specific examples of the particularly preferred compound (D) in the present invention will be shown below, but the present invention is not limited thereto.

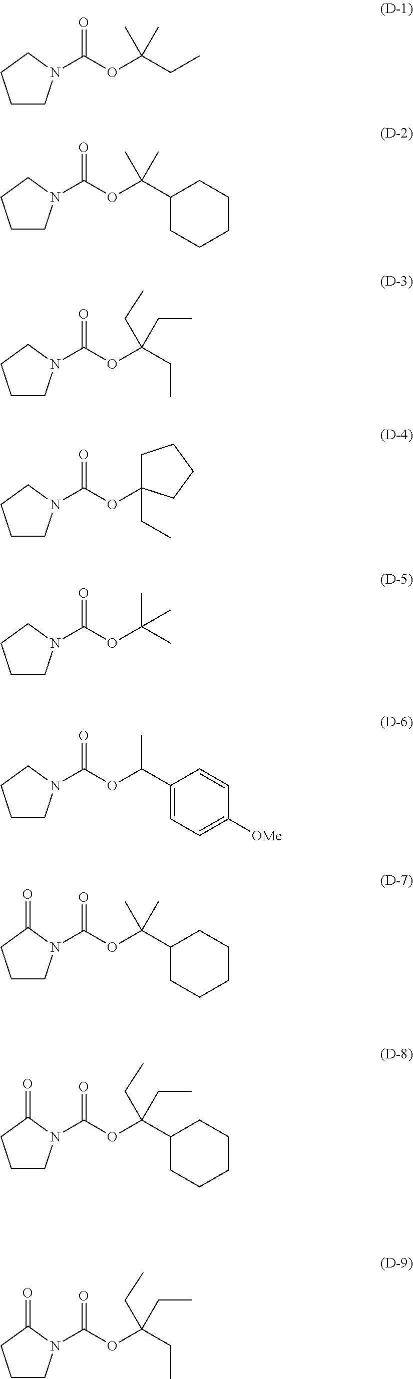

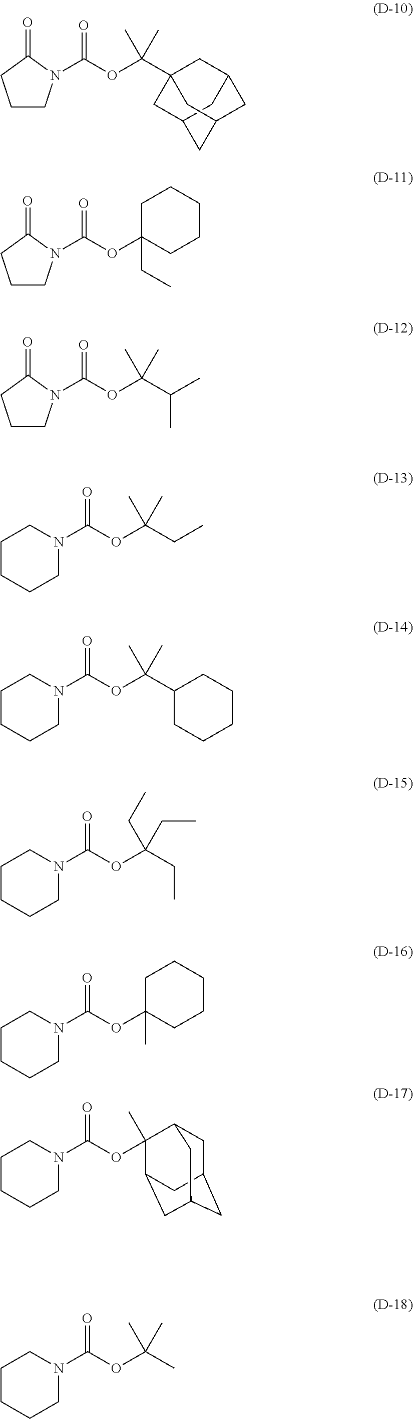

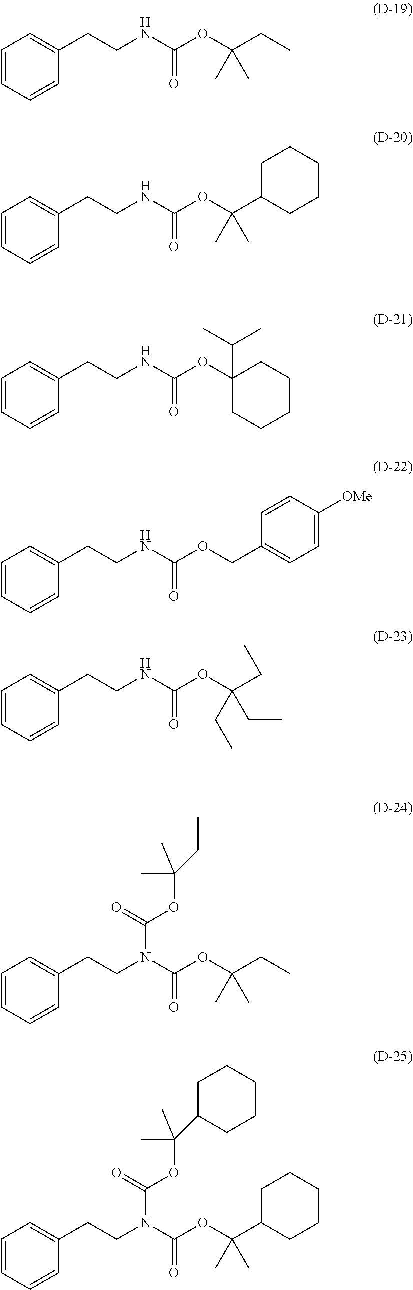

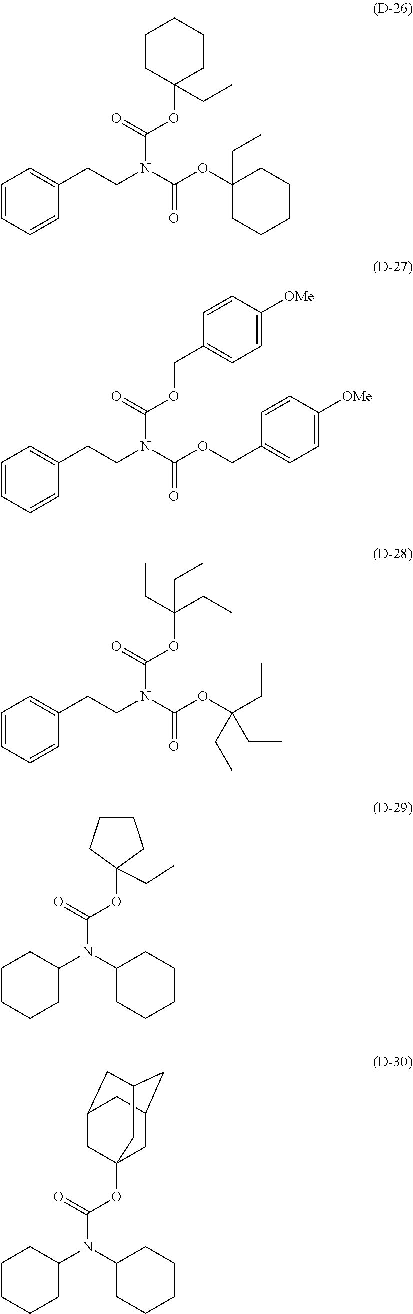 [SMILES: CCC1(OC(=O)N(CCc2ccccc2)C(=O)OC2(CC)CCCCC2)CCCCC1 ; COc1ccc(COC(=O)N(CCc2ccccc2)C(=O)OCc2ccc(OC)cc2)cc1 ; CCC(CC)(CC)OC(=O)N(CCc1ccccc1)C(=O)OC(CC)(CC)CC ; CCC1(OC(=O)N(C2CCCCC2)C2CCCCC2)CCCC1 ; O=C(OC12CC3CC(CC(C3)C1)C2)N(C1CCCCC1)C1CCCCC1]

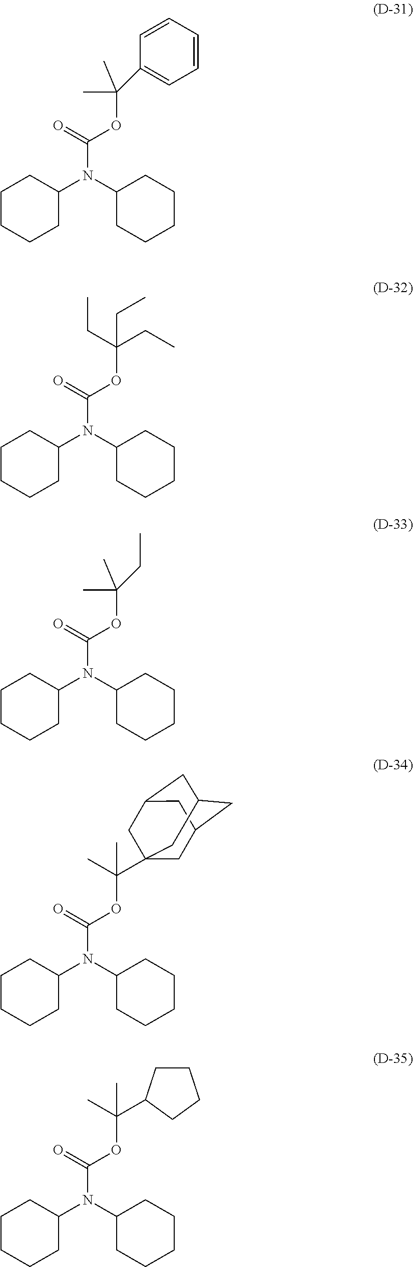

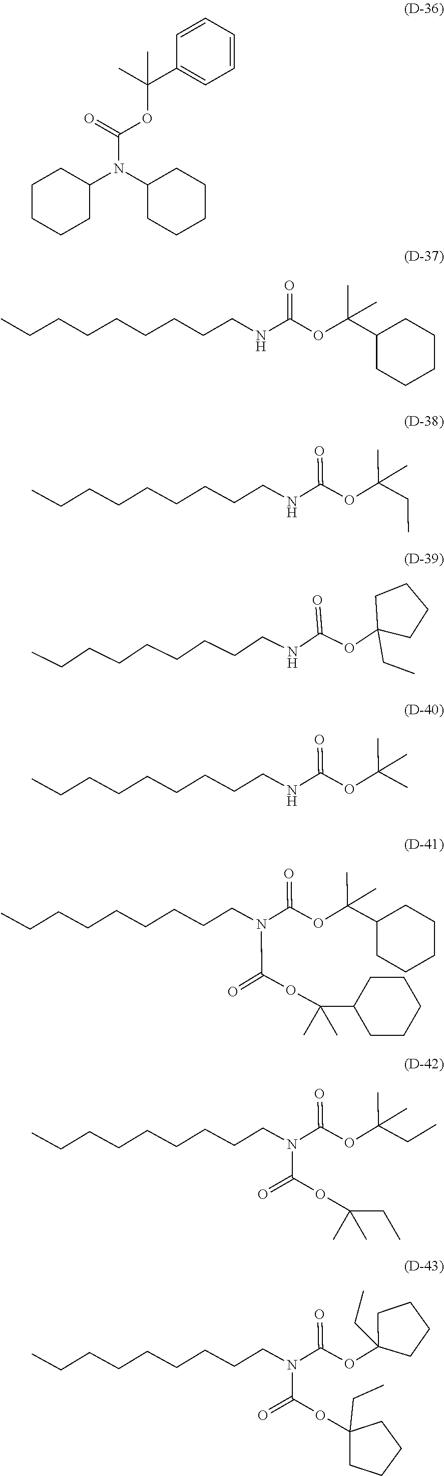

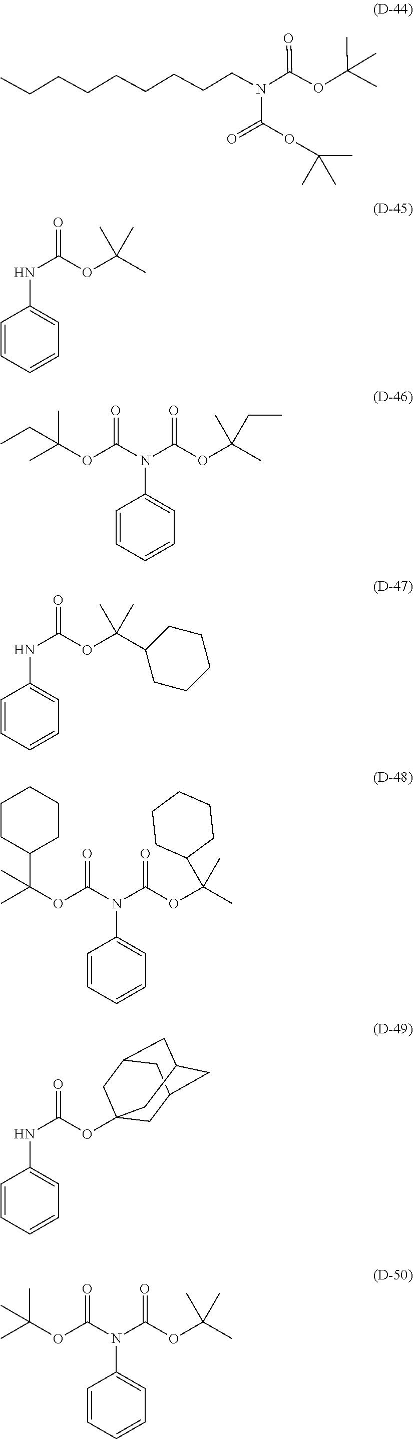

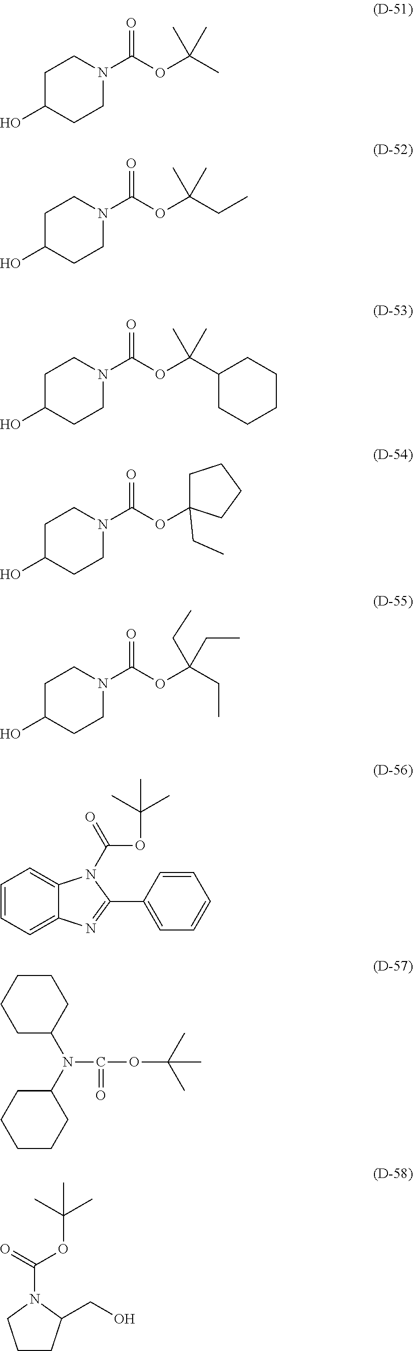

The compound represented by Formula (6) can be synthesized based on JP2007-298569A, JP2009-199021A, and the like.

In the present invention, one kind of low-molecular weight compound (D) having a group eliminated by the action of an acid on a nitrogen atom can be used singly, or two or more kinds thereof can be used by being mixed together.

A content of the compound (D) in the resist composition of the present invention is, with respect to the total solid contents of the composition, preferably 0.001% to 20% by mass, more preferably 0.001% to 10% by mass, and even more preferably 0.01% to 5% by mass.

<Basic Compound (E) of which Basicity is Reduced or Lost by Irradiation of Actinic Rays or Radiation>

The composition of the present invention may contain a basic compound (E) of which the basicity is reduced or lost by the irradiation of actinic rays or radiation. Examples of the basic compound of which the basicity is reduced or lost by the irradiation of actinic rays or radiation include the compounds described in pp. 171˜188 of WO2011/083872A1. Examples of the basic compound of which the basicity is reduced or lost by the irradiation of actinic rays or radiation also include a sulfonium salt compound represented by the following Formula (a1) and an iodonium salt compound represented by the following Formula (a2).

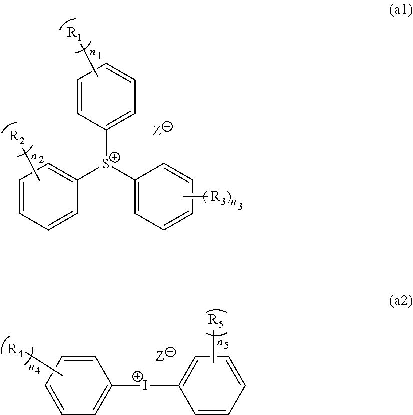

In Formulae (a1) and (a2), R₁ to R₅ each independently represent an alkyl group, a cycloalkyl group, an alkoxy group, a hydroxyl group, or a halogen atom. Z⁻ represents a counter anion which is, for example, OH⁻, R—COO⁻, R—SO3⁻, or an anion represented by the following Formula (a3). R is a monovalent organic group. n1 to n5 each independently represent an integer of 0 to 5.

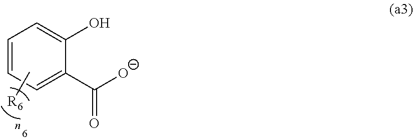

In Formula (a3), R₆ represents a substituent, and n6 represents an integer of 0 to 4.

Examples of the compound (E) represented by Formulae (a1) and (a2) include compounds represented by the following structural formulae.

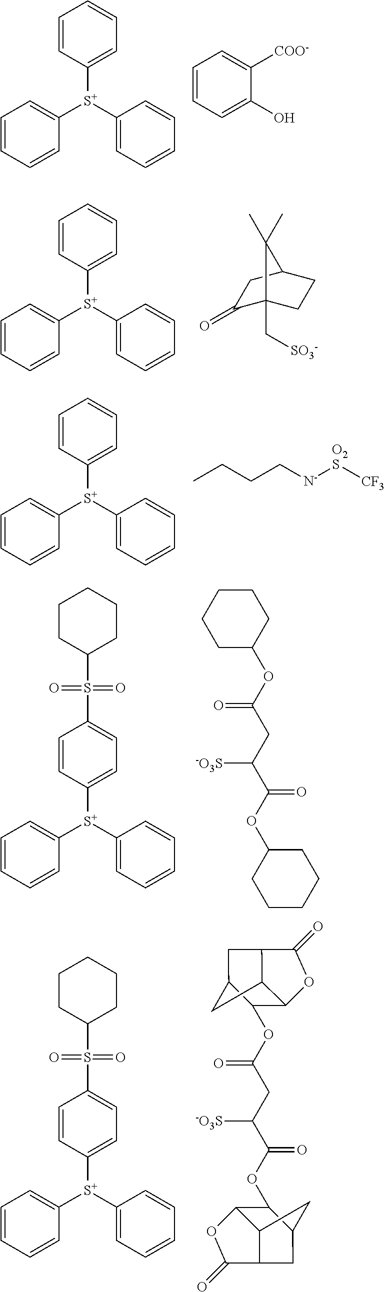

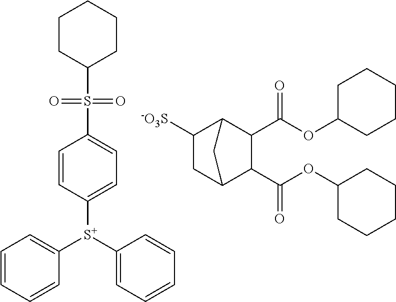

<Hydrophobic Surface Modification Resin (HR)>

The resist composition according to the present invention may contain a hydrophobic surface modification resin (hereinafter, referred to as a “hydrophobic surface modification resin (HR)” or simply as a “resin (HR)” as well) particularly when the composition is used for liquid immersion exposure. It is preferable that the hydrophobic surface modification resin (HR) is different from the resin (A) described above.

If the above aspect is adopted, the hydrophobic surface modification resin (HR) is localized within the surface of the film, and in a case where the liquid immersion medium is water, a static/dynamic contact angle of the resist film surface with respect to water can be improved, and conformity to the immersion liquid can be improved.

It is preferable that the hydrophobic surface modification resin (HR) is designed such that the resin is localized in an interface as described above. However, unlike a surfactant, the hydrophobic surface modification resin (HR) does not need to have a hydrophobic group in a molecule, and may not contribute to the uniform mixing of a polar substance with a non-polar substance.

From the viewpoint of localization in a surface layer of the film, the hydrophobic surface modification resin (HR) is preferably a resin having any one or more kinds among a “fluorine atom”, a “silicon atom”, and “a CH₃ partial structure contained in a side chain portion of a resin”, and more preferably a resin having two or more kinds among the above.

In a case where the hydrophobic surface modification resin (HR) contains a fluorine atom and/or a silicon atom, the fluorine atom and/or the silicon atom in the hydrophobic surface modification resin (HR) may be contained in a main chain or a side chain of the resin.

In a case where the hydrophobic surface modification resin (HR) contains a fluorine atom, as the partial structure having the fluorine atom, a resin having a fluorine atom-containing alkyl group, a fluorine atom-containing cycloalkyl group, or a fluorine atom-containing aryl group.

The fluorine atom-containing alkyl group (preferably having 1 to 10 carbon atoms and more preferably having 1 to 4 carbon atoms) is a linear or branched alkyl group in which at least one hydrogen atom is substituted with a fluorine atom and which may further have a substituent other than a fluorine atom.

The fluorine atom-containing cycloalkyl group is a monocyclic or polycyclic cycloalkyl group in which at least one hydrogen atom is substituted with a fluorine atom and which may further have a substituent other than a fluorine atom.

Examples of the fluorine atom-containing aryl group include an aryl group in which at least one hydrogen atom is substituted with a fluorine atom, such as a phenyl group or a naphthyl group. The fluorine atom-containing aryl group may further have a substituent other than a fluorine atom.

Preferred examples of the fluorine atom-containing alkyl group, the fluorine atom-containing cycloalkyl group, and the fluorine atom-containing aryl group include groups represented by the following Formulae (F2) to (F4), but the present invention is not limited thereto.

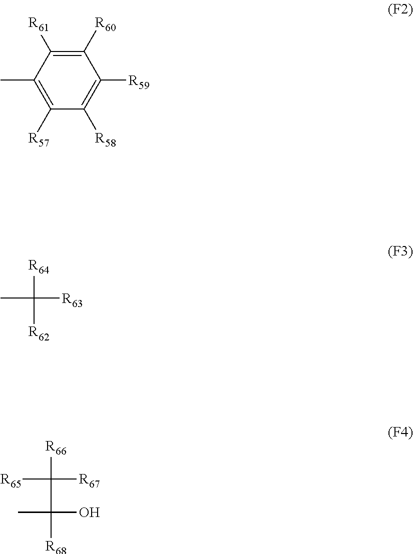

In Formulae (F2) to (F4), R₅₇ to R₆₈ each independently represent a hydrogen atom, a fluorine atom, or an alkyl group (linear or branched). Here, at least one of R₅₇, R₅₈, R₅₉, R₆₀, or R₆₁, at least one of R₆₂, R₆₃, or R₆₄, and at least one of R₆₅, R₆₆, R₆₇, or R₆₈ each independently represent a fluorine atom or an alkyl group (preferably having 1 to 4 carbon atoms) in which at least 1 hydrogen atom is substituted with a fluorine atom.

It is preferable that all of R₅₇ to R₆₁ and R₆₅ to R₆₇ represent a fluorine atom. R₆₂, R₆₃, and R₆₈ preferably represent an alkyl group (preferably having 1 to 4 carbon atoms) in which at least one hydrogen atom is substituted with a fluorine atom, and more preferably represent a perfluoroalkyl group having 1 to 4 carbon atoms. R₆₂ and R₆₃ may form a ring by being bonded to each other.

Specific examples of the group represented by Formula (F2) include a p-fluorophenyl group, a pentafluorophenyl group, a 3,5-di(trifluoromethyl)phenyl group, and the like.

Specific examples of the group represented by Formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group, and the like. Among these, a hexafluoroisopropyl group, a heptafluoroisopropyl group, a hexafluoro(2-methyl)isopropyl group, an octafluoroisobutyl group, a nonafluoro-t-butyl group, and a perfluoroisopentyl group are preferable, and a hexafluoroisopropyl group and a heptafluoroisopropyl group are more preferable.

Specific examples of the group represented by Formula (F4) include —C(CF₃)₂OH, —C(C₂F₅)₂OH, —C(CF₃)(CH₃)OH, —CH(CF₃)OH, and the like. Among these, —C(CF₃)₂OH is preferable.

The fluorine atom-containing partial structure may be directly bonded to a main chain or may be bonded to a main chain through a group selected from the group consisting of an alkylene group, a phenylene group, an ether bond, a thioether bond, a carbonyl group, an ester bond, an amide bond, a urethane bond, and a ureilene bond or through a group obtained by combining two or more of the above groups.

Specific examples of the fluorine atom-containing repeating unit will be shown below, but the present invention is not limited thereto.

In the specific examples, X₁ represents a hydrogen atom, —CH₃, —F, or —CF₃. X₂ represents —F or —CF₃.

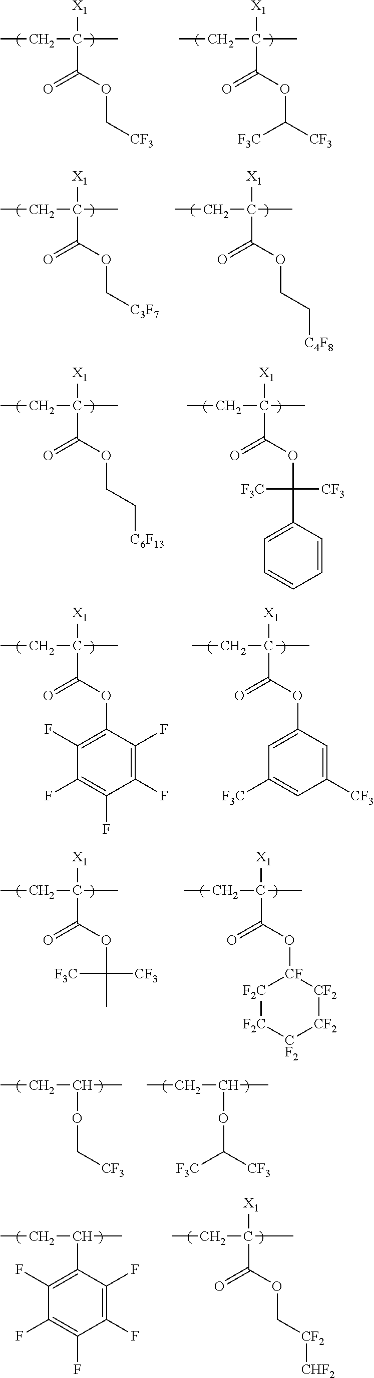

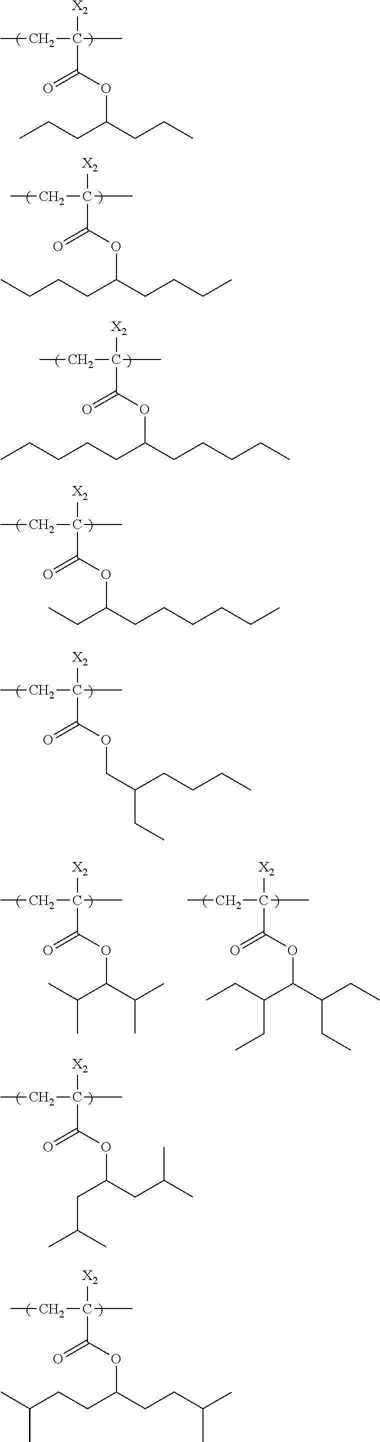

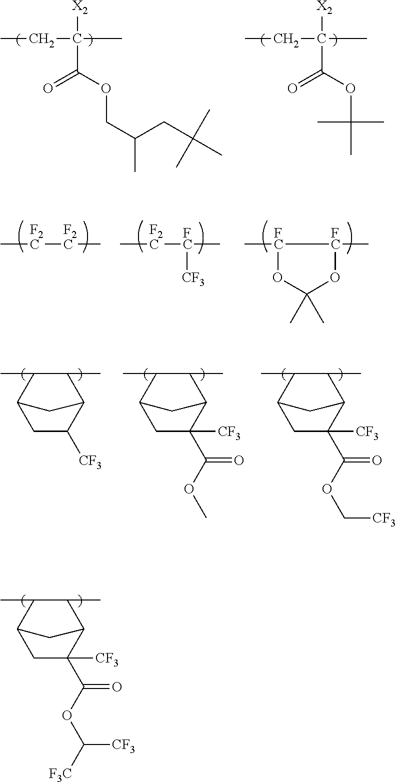

The hydrophobic surface modification resin (HR) may contain a silicon atom. The hydrophobic surface modification resin (HR) is preferably a resin which has, as a silicon atom-containing partial structure, an alkylsilyl structure (preferably a trialkylsilyl group) or a cyclic siloxane structure.

As described above, it is also preferable that the hydrophobic surface modification resin (HR) contains a CH₃ partial structure on a side chain portion.

Herein, the CH₃ partial structure that the resin (HR) has in a side chain portion (hereinafter, simply referred to as a “side chain CH₃ partial structure” as well) includes a CH₃ partial structure that an ethyl group, a propyl group, or the like has.

A methyl group directly bonded to a main chain of the resin (HR) (for example, an α-methyl group of a repeating unit having a methacrylic acid structure) makes a small contribution to the surface localization of the resin (HR) due to the influence of the main chain. Therefore, the methyl group is not included in the CH₃ partial structure in the present invention.

More specifically, in a case where the resin (HR) contains a repeating unit, which is derived from a monomer having a polymerizable moiety having a carbon-carbon double bond, such as a repeating unit represented by the following Formula (M), and R₁₁ to R₁₄ represent CH₃, the CH₃ is not included in the CH₃ partial structure that the side chain portion in the present invention has.

In contrast, a CH₃ partial structure linked to a C—C main chain through some atoms is regarded as corresponding to the CH₃ partial structure in the present invention. For example, in a case where R₁₁ represents an ethyl group (CH₂CH₃), the ethyl group is regarded as having “one” CH₃ partial structure in the present invention.

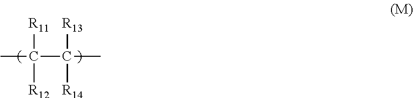

In Formula (M), R₁₁ to R₁₄ each independently represent a side chain portion.

Examples of R₁₁ to R₁₄ as a side chain portion include a hydrogen atom, a monovalent organic group, and the like.

Examples of the monovalent organic group as R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, an arylaminocarbonyl group, and the like. These groups may further have a substituent.

The hydrophobic surface modification resin (HR) is preferably a resin having a repeating unit having a CH₃ partial structure on a side chain portion, and more preferably a resin having, as the aforementioned repeating unit, at least one kind of repeating unit (x) between a repeating unit represented by the following Formula (II) and a repeating unit represented by the following Formula (III).

Hereinafter, the repeating unit represented by Formula (II) will be specifically described.

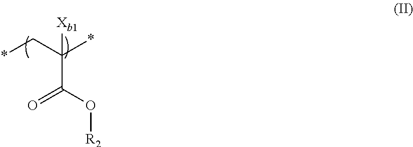

In Formula (II), X_{b1} represents a hydrogen atom, an alkyl group, a cyano group, or a halogen atom, and R₂ represents an organic group which has one or more CH₃ partial structures and is stable against an acid. More specifically, the organic group stable against an acid is preferably an organic group not having the “group generating a polar group by being decomposed by the action of an acid” described above for the resin (A).

The alkyl group as X_{b1} preferably has 1 to 4 carbon atoms, and examples thereof include a methyl group, an ethyl group, a propyl group, a hydroxymethyl group, a trifluoromethyl group, and the like. The alkyl group is preferably a methyl group.

X_{b1} is preferably a hydrogen atom or a methyl group.

Examples of R₂ include an alkyl group, a cycloalkyl group, an alkenyl group, a cycloalkenyl group, an aryl group, and an aralkyl group which have one or more CH₃ partial structures. The above cycloalkyl group, alkenyl group, cycloalkenyl group, aryl group, and aralkyl group may further have an alkyl group has a substituent.

R₂ is preferably an alkyl group or an alkyl-substituted cycloalkyl group having one or more CH₃ partial structures.

The organic group as R₂ that has one or more CH₃ partial structures and is stable against an acid preferably has 2 to 10 CH₃ partial structures and more preferably has 2 to 8 CH₃ partial structures.

The alkyl group as R₂ that has one or more CH₃ partial structures is preferably a branched alkyl group having 3 to 20 carbon atoms. Specific examples of the preferred alkyl group include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, and the like. Among these, an isobutyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, and a 2,3,5,7-tetramethyl-4-heptyl group are more preferable.

The cycloalkyl group as R₂ that has one or more CH₃ partial structures may be monocyclic or polycyclic. Specific examples thereof include a group having a monocyclo, bicyclo, tricyclo, or tetracyclo structure having 5 or more carbon atoms. The number of carbon atoms of the cycloalkyl group is preferably 6 to 30, and particularly preferably 7 to 25. Examples of the preferred cycloalkyl group include an adamantyl group, a noradamantyl group, a decalin residue, a tricyclodecanyl group, a tetracyclododecanyl group, a norbornyl group, a cedrol group, a cyclopentyl group, a cyclohexyl group, a cycloheptyl group, a cyclooctyl group, a cyclodecanyl group, and a cyclododecanyl group. Among these, an adamantyl group, a norbornyl group, a cyclohexyl group, a cyclopentyl group, a tetracyclododecanyl group, and a tricyclodecanyl group are more preferable, and a norbornyl group, a cyclopentyl group, and a cyclohexyl group are even more preferable.

The alkenyl group as R₂ having one or more CH₃ partial structures is preferably a linear or branched alkenyl group having 1 to 20 carbon atoms, and more preferably a branched alkenyl group.

The aryl group as R₂ that has one or more CH₃ partial structures is preferably an aryl group having 6 to 20 carbon atoms. Examples thereof include a phenyl group and a naphthyl group, and between these, a phenyl group is preferable.

The aralkyl group as R₂ that has one or more CH₃ partial structures is preferably an aralkyl group having 7 to 12 carbon atoms. Examples thereof include a benzyl group, a phenethyl group, a naphthyl methyl group, and the like.

Specific examples of the alkyl group as R₂ that has two or more CH₃ partial structures include an isopropyl group, an isobutyl group, a t-butyl group, a 3-pentyl group, a 2-methyl-3-butyl group, a 3-hexyl group, a 2,3-dimethyl-2-butyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 4-isopropylcyclohexyl group, a 4-t butylcyclohexyl group, an isobornyl group, and the like. The hydrocarbon group is more preferably an isobutyl group, a t-butyl group, a 2-methyl-3-butyl group, a 2,3-dimethyl-2-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 3,5-di tert-butylcyclohexyl group, a 4-isopropylcyclohexyl group, a 4-t butylcyclohexyl group, or an isobornyl group.

Specific examples preferred as the repeating unit represented by Formula (II) will be shown below, but the present invention is not limited thereto.

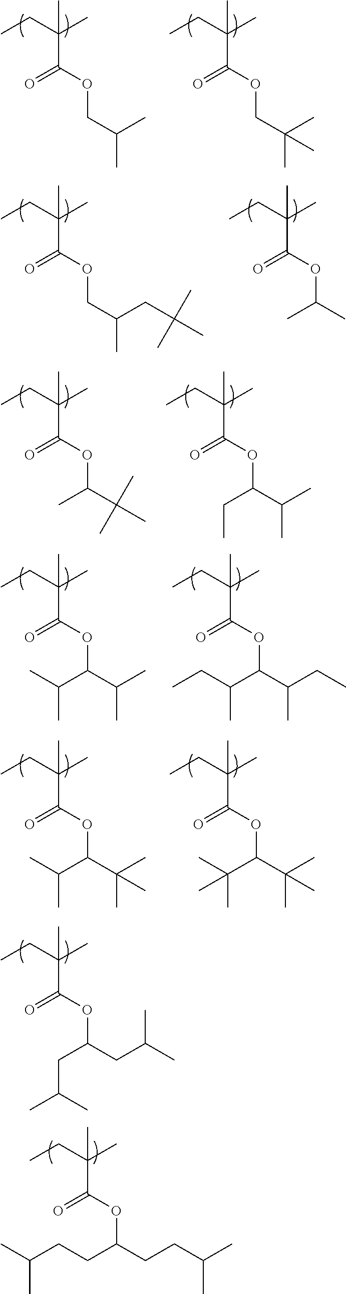

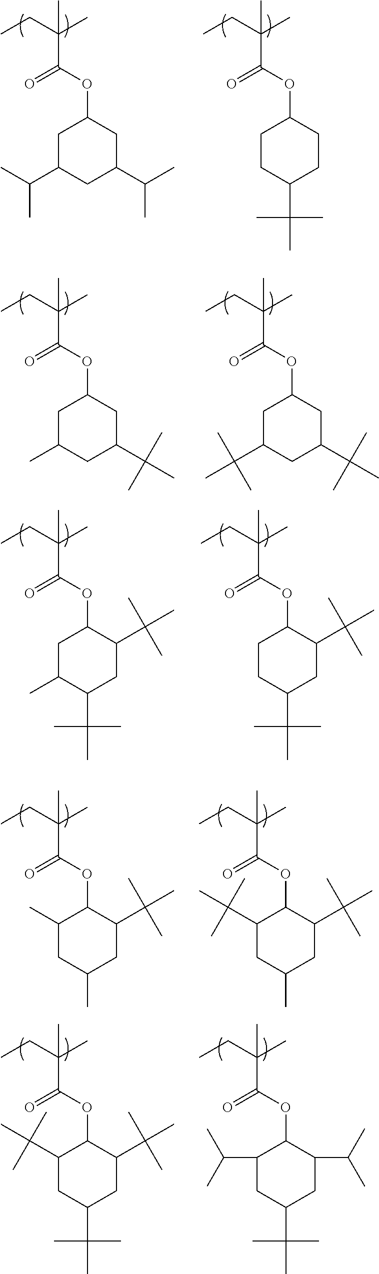

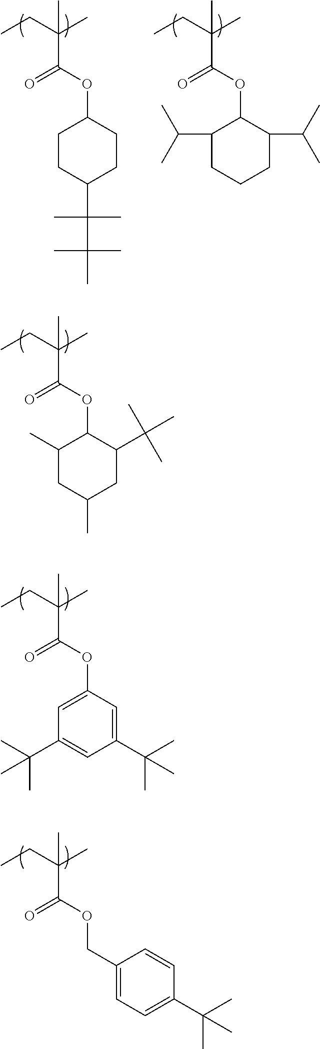

The repeating unit represented by Formula (II) is preferably a (non-acid-decomposable) repeating unit stable against an acid. Specifically, the repeating unit is preferably a repeating unit which does not have a group generating a polar group by being decomposed by the action of an acid.

Hereinafter, the repeating unit represented by Formula (III) will be specifically described.

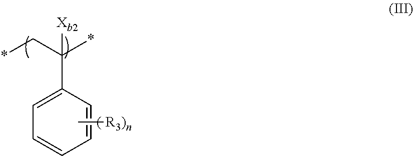

In Formula (III), X_{b2} represents a hydrogen atom, an alkyl group, a cyano group, or a halogen atom, R₃ represents an organic group which has one or more CH₃ partial structures and is stable against an acid, and n represents an integer of 1 to 5.

The alkyl group as X_{b2} is preferably an alkyl group having 1 to 4 carbon atoms, and examples thereof include a methyl group, an ethyl group, a propyl group, a hydroxymethyl group, a trifluoromethyl group, and the like. X_{b2} is preferably a hydrogen atom.

R₃ is an organic group stable against an acid. Therefore, more specifically, R₃ is preferably an organic group which does not have the “group generating a polar group by being decomposed by the action of an acid” described above for the resin (A).

Examples of R₃ include an alkyl group having one or more CH₃ partial structures.

The organic group as R₃ that has one or more CH₃ partial structures and is stable against an acid preferably has 1 to 10 CH₃ partial structures, more preferably has 1 to 8 CH₃ partial structures, and even more preferably has 1 to 4 CH₃ partial structures.

The alkyl group as R₃ that has one or more CH₃ partial structures is preferably a branched alkyl group having 3 to 20 carbon atoms. Specific examples of the preferred alkyl group include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, and the like. The alkyl group is more preferably an isobutyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, or a 2,3,5,7-tetramethyl-4-heptyl group.

Specific examples of the alkyl group as R₃ that has two or more CH₃ partial structures include an isopropyl group, an isobutyl group, a t-butyl group, a 3-pentyl group, a 2,3-dimethylbutyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, and the like. The alkyl group is more preferably an alkyl group having 5 to 20 carbon atoms, such as an isopropyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, or a 2,6-dimethylheptyl group.

n represents an integer of 1 to 5. n preferably represents an integer of 1 to 3, and more preferably represents 1 or 2.

Specific preferred examples of the repeating unit represented by Formula (III) will be shown below, but the present invention is not limited thereto.

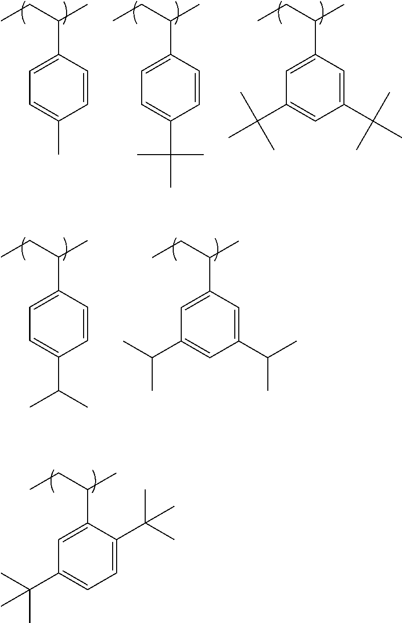

The repeating unit represented by Formula (III) is preferably a (non-acid-decomposable) repeating unit stable against an acid. Specifically, the repeating unit is preferably a repeating unit which does not have a group generating a polar group by being decomposed by the action of an acid.

In a case where the resin (HR) contains a CH₃ partial structure on a side chain portion and particularly does not have a fluorine atom and a silicon atom, a content of at least one kind of repeating unit (x) between the repeating unit represented by Formula (II) and the repeating unit represented by Formula (III) is, with respect to all of the repeating units of the resin (C), preferably equal to or greater than 90 mol %, and more preferably equal to or greater than 95 mol %. The content is generally equal to or less than 100 mol % with respect to all of the repeating units of the resin (HR).

If the content of at least one kind of repeating unit (x) between the repeating unit represented by Formula (II) and the repeating unit represented by Formula (III) in the resin (HR) is equal to or greater than 90 mol % with respect to all of the repeating units of the resin (HR), a surface free energy of the resin (HR) is increased. As a result, the resin (HR) is not easily localized within the surface of the resist film, a static/dynamic contact angle of the resist film with respect to water is reliably improved, and conformity to the immersion liquid can be improved.

In both of (i) a case where the hydrophobic surface modification resin (HR) contains a fluorine atom and/or a silicon atom and (ii) a case where the hydrophobic surface modification resin (HR) contains a CH₃ partial structure in a side chain portion, the resin (HR) may have at least one group selected from the group consisting of the following (x) to (z).

(x) an acid group

(y) a group having a lactone structure, an acid anhydride group, or an acid imide group

(z) a group decomposed by the action of an acid

Examples of the acid group (x) include a phenolic hydroxyl group, a carboxylic acid group, a fluorinated alcohol group, a sulfonic acid group, a sulfonamide group, a sulfonylimide group, an (alkyl sulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group, and the like.

Examples of the preferred acid group include a fluorinated alcohol group (preferably hexafluoroisopropanol), a sulfonimide group, and a bis(alkylcarbonyl)methylene group.

Examples of the repeating unit having the acid group (x) include a repeating unit in which an acid group is directly bonded to a main chain of a resin, such as a repeating unit composed of an acrylic acid or a methacrylic acid, a repeating unit in which an acid group is bonded to a main chain of a resin through a linking group, and the like. Furthermore, by using a polymerization initiator or a chain transfer agent having an acid group, the repeating unit can be introduced into a terminal of a polymer chain. All of the aforementioned repeating units are preferable. The repeating unit having the acid group (x) may have at least either a fluorine atom or a silicon atom.

A content of the repeating unit having the acid group (x) is, with respect to all of the repeating units in the hydrophobic surface modification resion (HR), preferably 1 to 50 mol %, more preferably 3 to 35 mol %, and even more preferably 5 to 20 mol %.

Specific examples of the repeating unit having the acid group (x) will be shown below, but the present invention is not limited thereto. In the formulae, Rx represents a hydrogen atom, CH₃, CF₃, or CH₂OH.

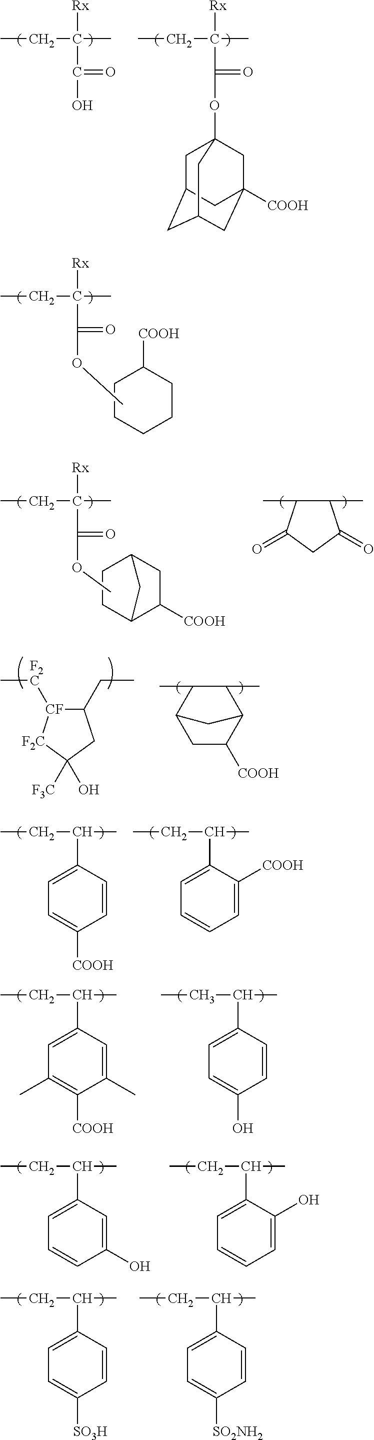

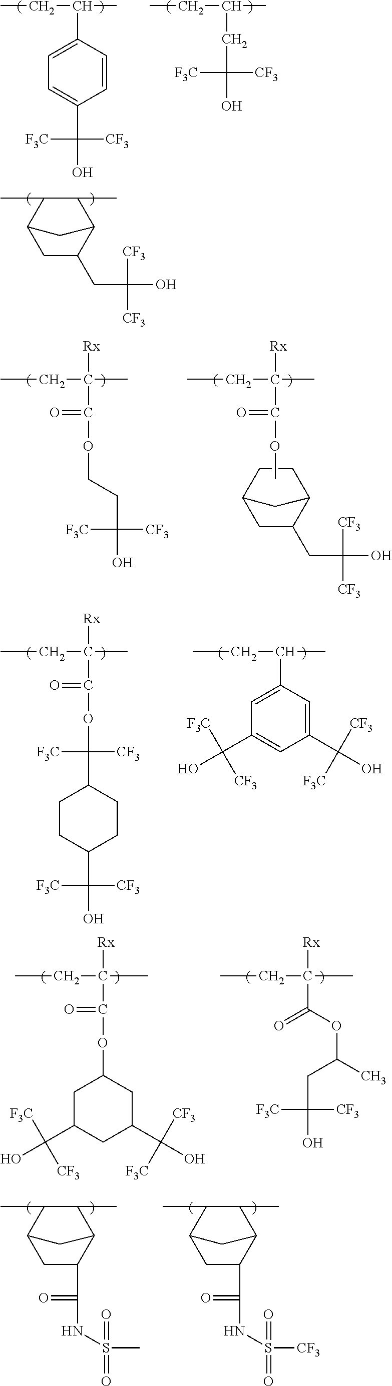

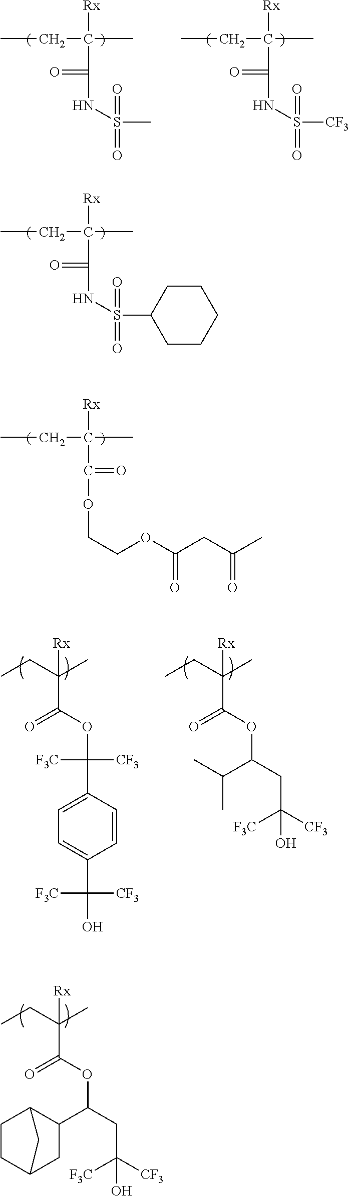

As the group having a lactone structure, the acid anhydride group, or the imide group (y), a group having a lactone structure is particularly preferable.

The repeating unit having these groups is, for example, a repeating unit in which these groups are directly bonded to a main chain of a resin, such as a repeating unit composed of an acrylic acid ester or a methacrylic acid ester. Alternatively, the repeating unit may be a repeating unit in which these groups are bonded to a main chain of a resin through a linking group. Otherwise, the repeating unit may be introduced into a terminal of a resin at the time of polymerization by using a polymerization initiator or a chain transfer agent having these groups.

Examples of the repeating unit having the group having a lactone structure are the same as the examples of the repeating unit having a lactone structure described above for the resin (A1).

A content of the repeating unit having the group having a lactone structure, the acid anhydride group, and the imide group is, based on all of the repeating units in the hydrophobic surface modification resion (HR), preferably 1 to 100 mol %, more preferably 3 to 98 mol %, and even more preferably 5 to 95 mol %.

Examples of the repeating unit, which has the group (z) decomposed by the action of an acid, in the hydrophobic surface modification resin (HR) are the same as the examples of the repeating unit having an acid-decomposable group exemplified above for the resin (A1). The repeating unit which has the group (z) decomposed by the action of an acid may have at least either a fluorine atom or a silicon atom. A content of the repeating unit, which has the group (z) decomposed by the action of an acid, in the hydrophobic surface modification resin (HR) is, with respect to all of the repeating units in the resin (HR), is preferably 1 to 80 mol %, more preferably 10 to 80 mol %, and even more preferably 20 to 60 mol %.

The hydrophobic surface modification resin (HR) may further have a repeating unit represented by the following Formula (III).

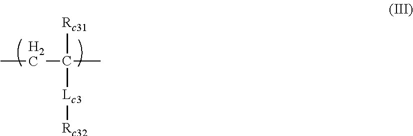

In Formula (III), R_{c31} represents a hydrogen atom, an alkyl group (may be substituted with a fluorine atom or the like), a cyano group, or a —CH₂—O—Rac₂ group. In the formula, Rac₂ represents a hydrogen atom, an alkyl group, or an acyl group. R_{c31} is preferably a hydrogen atom, a methyl group, a hydroxymethyl group, or a trifluoromethyl group, and particularly preferably a hydrogen atom or a methyl group.

R_{c32} represents an alkyl group, a cycloalkyl group, an alkenyl group, a cycloalkenyl group, or an aryl group. These groups may be substituted with a group containing a fluorine atom or a silicon atom.

L_{c3} represents a single bond or a divalent linking group.

The alkyl group as R_{c32} in Formula (III) is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms, and more preferably a phenyl group or a naphthyl group. These may have a substituent.

R_{c32} is preferably an unsubstituted alkyl group or an alkyl group substituted with a fluorine atom.

The divalent linking group as L_{c3} is preferably an alkylene group (preferably having 1 to 5 carbon atoms), an ether bond, a phenylene group, or an ester bond (group represented by —COO—).

A content of the repeating unit represented by Formula (III) is, based on all of the repeating units in the hydrophobic resin, preferably 1 to 100 mol %, more preferably 10 to 90 mol %, and even more preferably 30 to 70 mol %.

It is also preferable that the hydrophobic surface modification resin (HR) has a repeating unit represented by the following Formula (CII-AB).

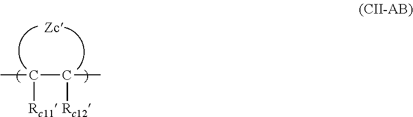

In Formula (CII-AB), R_{c11}′ and R_{c12}′ each independently represent a hydrogen atom, a cyano group, a halogen atom, or an alkyl group.

Zc′ represents an atomic group which contains two carbon atoms (C—C) bonded and is for forming an alicyclic structure.

A content of the repeating unit represented by Formula (CII-AB) is, based on all of the repeating units in the hydrophobic surface modification resin, preferably 1 to 100 mol %, more preferably 10 to 90 mol %, and even more preferably 30 to 70 mol %.

Specific examples of the repeating units represented by Formulae (III) and (CII-AB) will be shown below, but the present invention is not limited thereto. In the formulae, Ra represents H, CH₃, CH₂OH, CF₃, or CN.

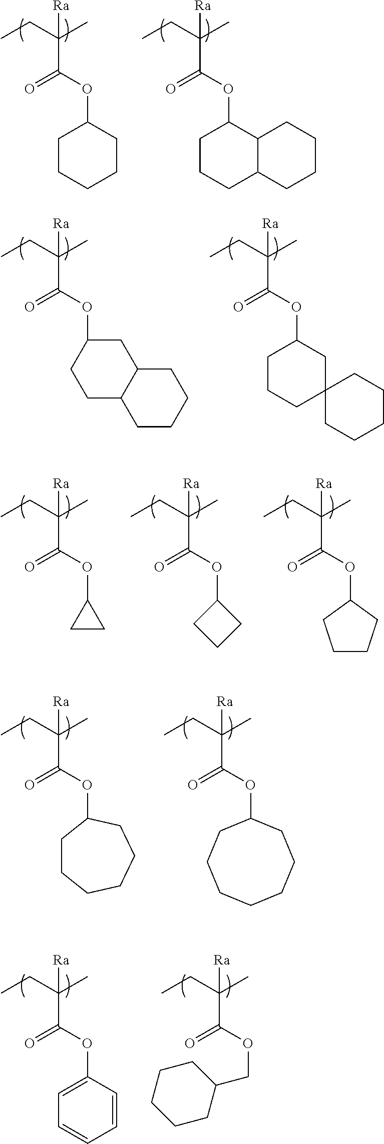

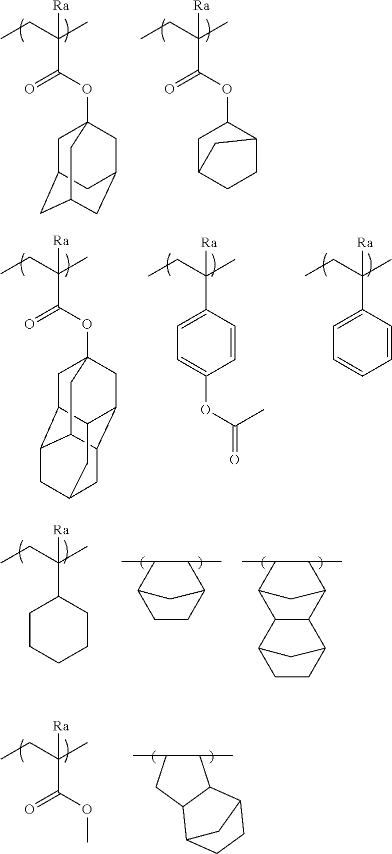

In a case where the hydrophobic surface modification resin (HR) has a fluorine atom, a content of the fluorine atom is, with respect to a weight-average molecular weight of the hydrophobic surface modification resion (HR), preferably 5% to 80% by mass, and more preferably 10% to 80% by mass. A content of the repeating unit containing a fluorine atom is preferably 10 to 100 mol %, and more preferably 30 to 100 mol % with respect to all of the repeating units contained in the hydrophobic surface modification resion (HR).

In a case where the hydrophobic surface modification resin (HR) has a silicon atom, a content of the silicon atom is, with respect to a weight-average molecular weight of the hydrophobic surface modification resion (HR), preferably 2% to 50% by mass, and more preferably 2% to 30% by mass. A content of the repeating unit containing a silicon atom is preferably 10 to 100 mol %, and more preferably 20 to 100 mol % with respect to all of the repeating units contained in the hydrophobic surface modification resion (HR).

Particularly, in a case where the resin (HR) contains a CH₃ partial structure on a side chain portion, it is preferable that the resin (HR) substantially does not contain a fluorine atom and a silicon atom. In this case, specifically, a content of the repeating unit having a fluorine atom or a silicon atom is, with respect to all of the repeating units in the resin (HR), preferably equal to or less than 5 mol %, more preferably equal to or less than 3 mol %, and even more preferably equal to or less than 1 mol %. Ideally, the content of the aforementioned repeating unit is 0 mol %, that is, the resin (HR) does not contain a fluorine atom and a silicon atom. Furthermore, it is preferable that the resin (HR) is substantially constituted only with a repeating unit which is constituted only with an atom selected from a carbon atom, an oxygen atom, a hydrogen atom, a nitrogen atom, and a sulfur atom. More specifically, a content of the repeating unit which is constituted only with an atom selected from a carbon atom, an oxygen atom, a hydrogen atom, a nitrogen atom, and a sulfur atom is preferably, with respect to all of the repeating units of the resin (HR), preferably equal to or greater than 95 mol %, more preferably equal to or greater than 97 mol %, even more preferably equal to or greater than 99 mol %, and ideally 100 mol %.

A weight-average molecular weight of the hydrophobic surface modification resin (HR) expressed in terms of standard polystyrene is preferably 1,000 to 100,000, more preferably 1,000 to 50,000, and even more preferably 2,000 to 15,000.

One kind of hydrophobic surface modification resin (HR) may be used singly, or plural kinds thereof may be used in combination.

A content of the hydrophobic surface modification resin (HR) in the composition is, with respect to the total solid contents in the composition of the present invention, preferably 0.01% to 10% by mass, more preferably 0.05% to 8% by mass, and even more preferably 0.1% to 7% by mass.

Although it goes without saying that the hydrophobic surface modification resin (HR) hardly contains impurities such as a metal just like the resin (A), a content of a residual monomer or an oligomer component in the resin (HR) is preferably 0.01% to 5% by mass, more preferably 0.01% to 3% by mass, and even more preferably 0.05% to 1% by mass. If the content of the residual monomer or the oligomer component is within the above range, a resist composition is obtained in which impurities, sensitivity, and the like do not change over time. In view of the resolution, resist shape, side wall of the resist pattern, roughness, and the like, a molecular weight distribution (Mw/Mn, referred to as a dispersity as well) of the resin (HR) is preferably within a range of 1 to 5, more preferably 1 to 3, and even more preferably within a range of 1 to 2.

Various commercially available products can be used as the hydrophobic surface modification resion (HR). Furthermore, the hydrophobic surface modification resin (HR) can be synthesized according to a common method (for example, radical polymerization). Examples of the general synthesis method include a batch polymerization method in which polymerization is performed by dissolving a monomer species and an initiator in a solvent and heating the solution, a dropping polymerization method in which a solution containing a monomer species and an initiator is added dropwise to a heated solvent for 1 to 10 hours, and the like. Among these, a dropping polymerization method is preferable.

The reaction solvent, the polymerization initiator, the reaction conditions (temperature, concentration, and the like), and the purification method used after the reaction are the same as those described above for the resin (A). In synthesizing the hydrophobic surface modification resion (HR), the concentration or reaction is preferably 30% to 50% by mass.

Specific examples of the hydrophobic surface modification resin (HR) will be shown below. In addition, a molar ratio (corresponding to each repeating unit in order form the left) of a repeating unit in each resin, a weight-average molecular weight, and a dispersity will be shown in the following table.

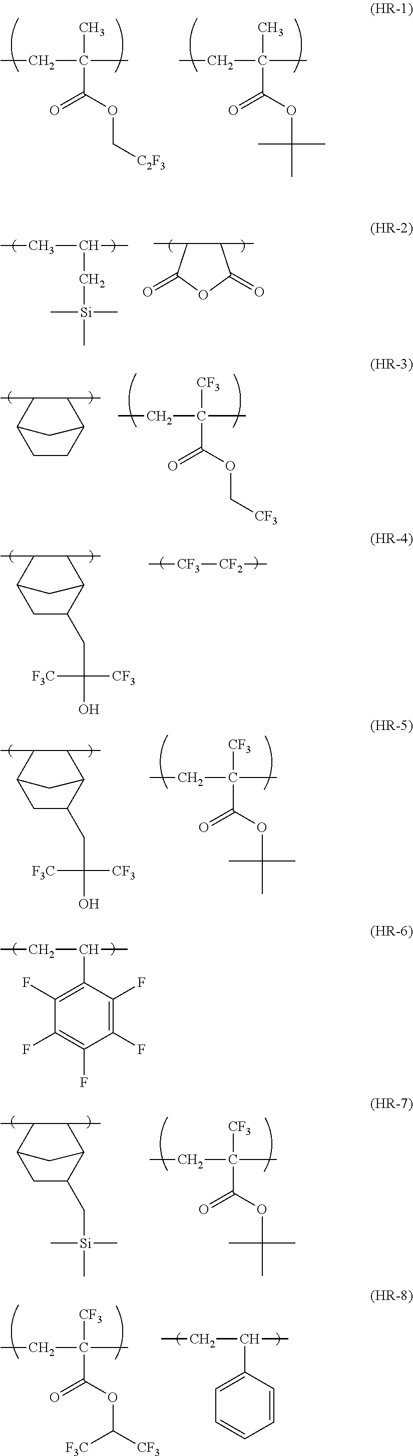

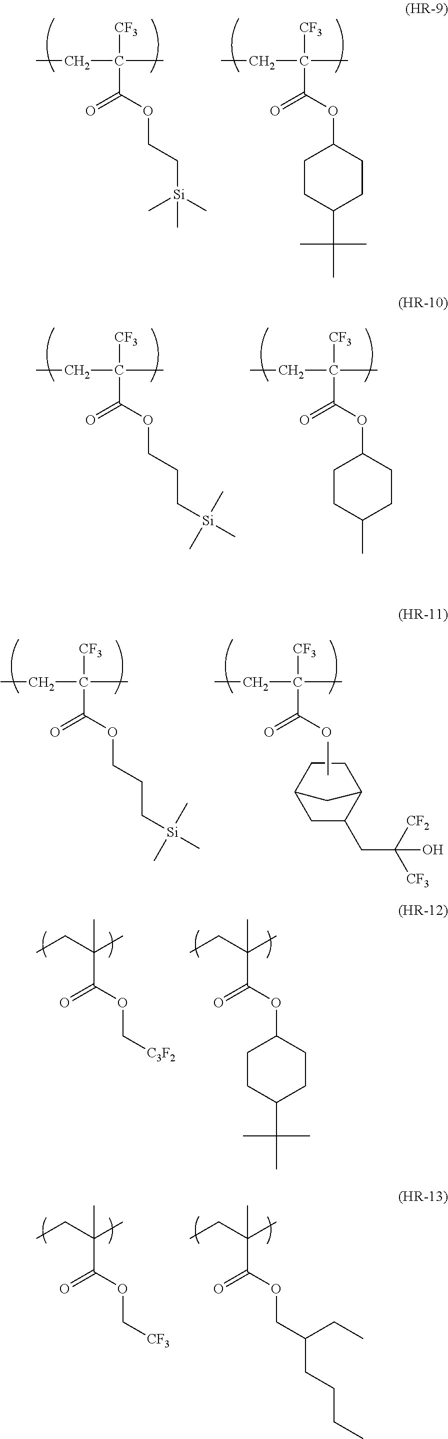

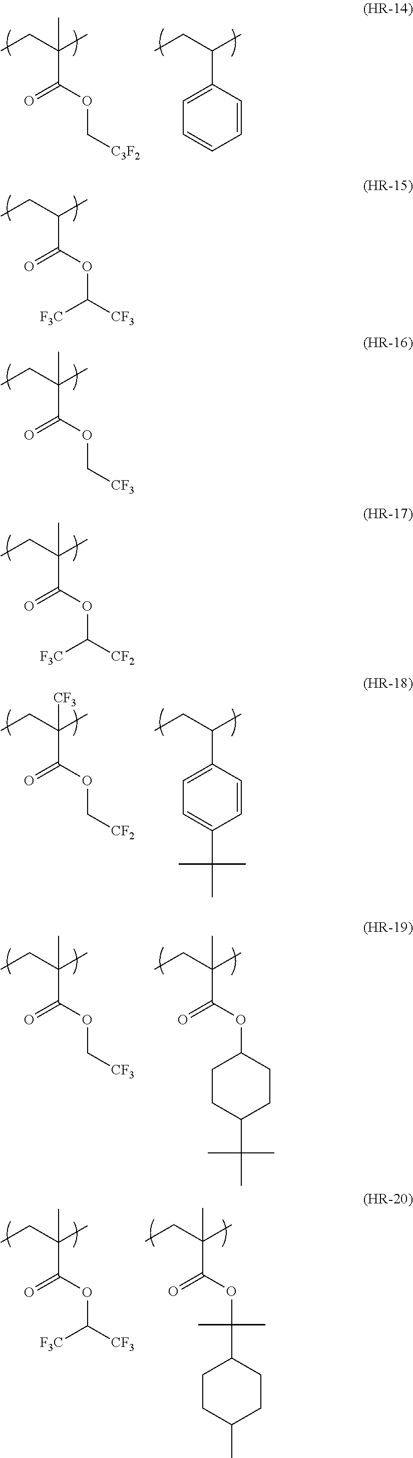

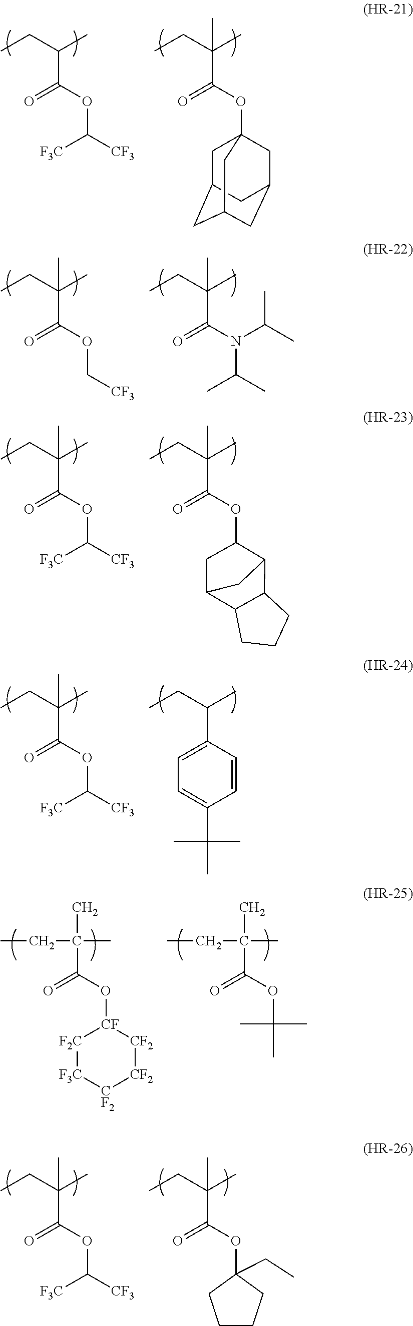

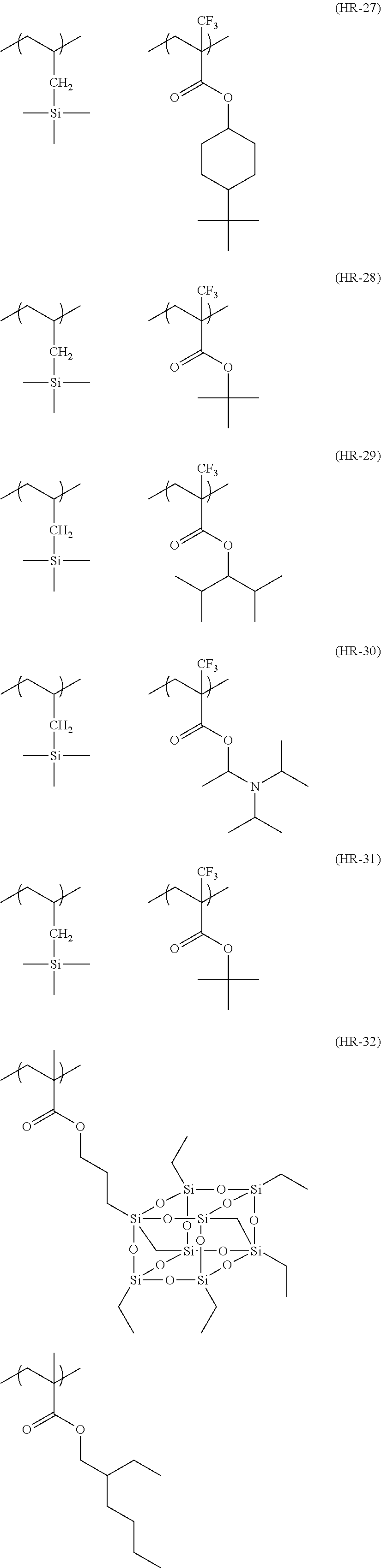

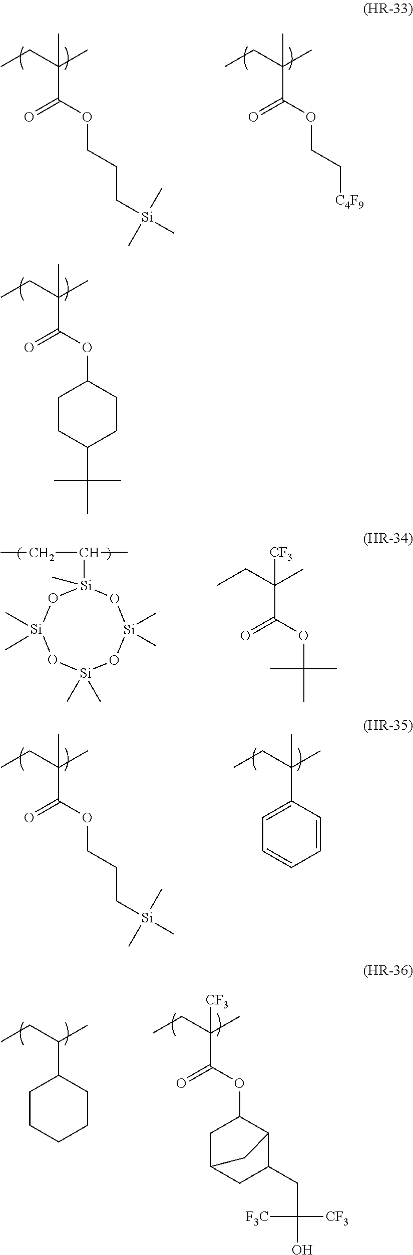

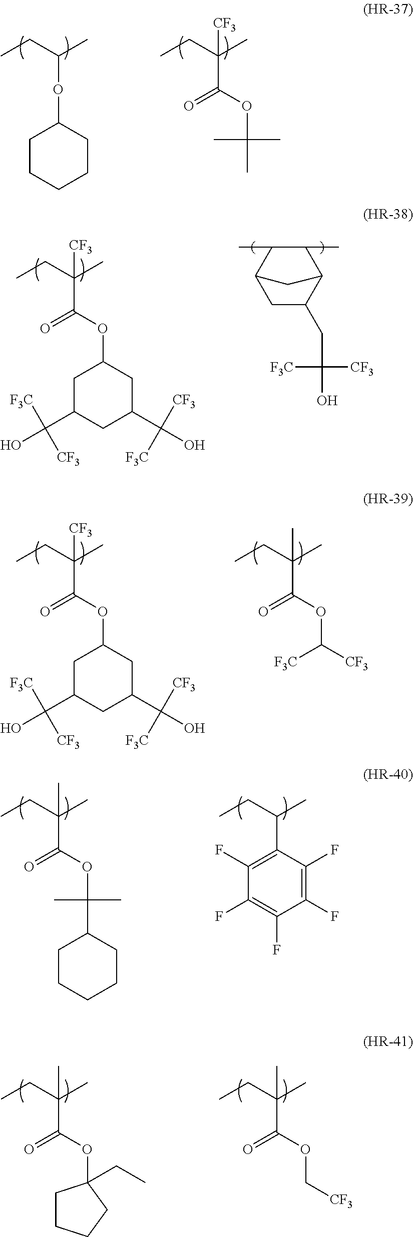

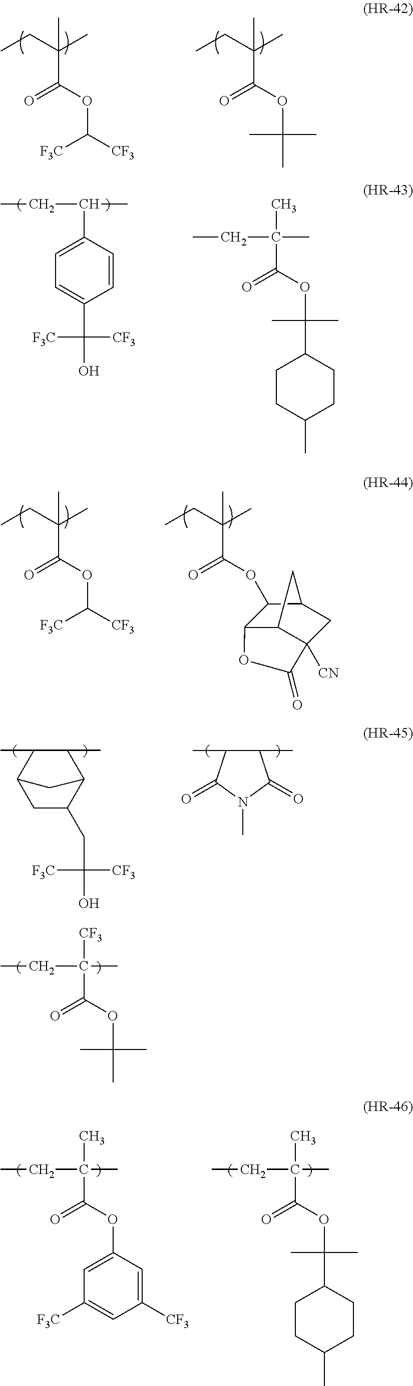

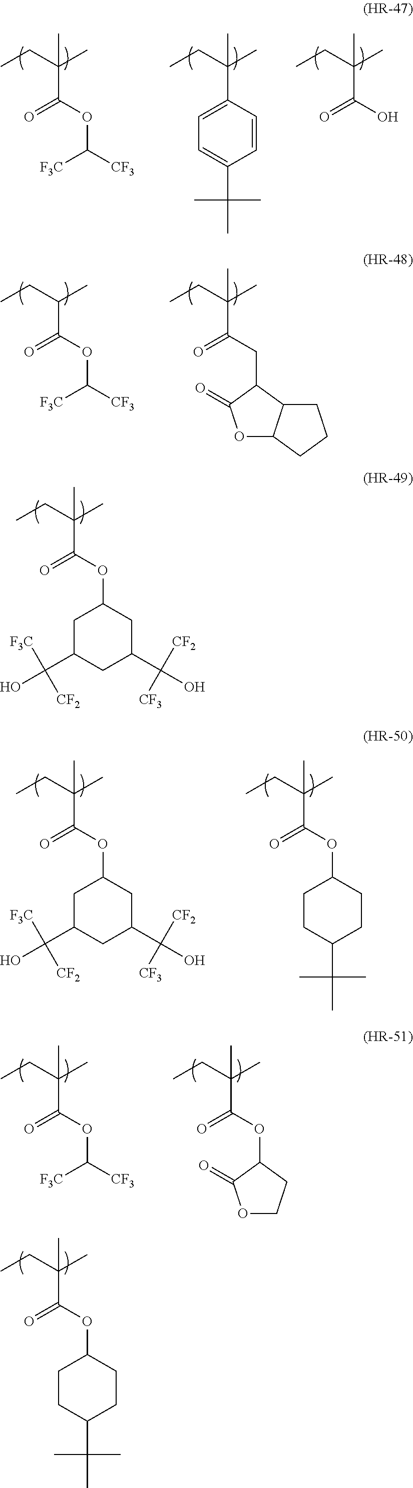

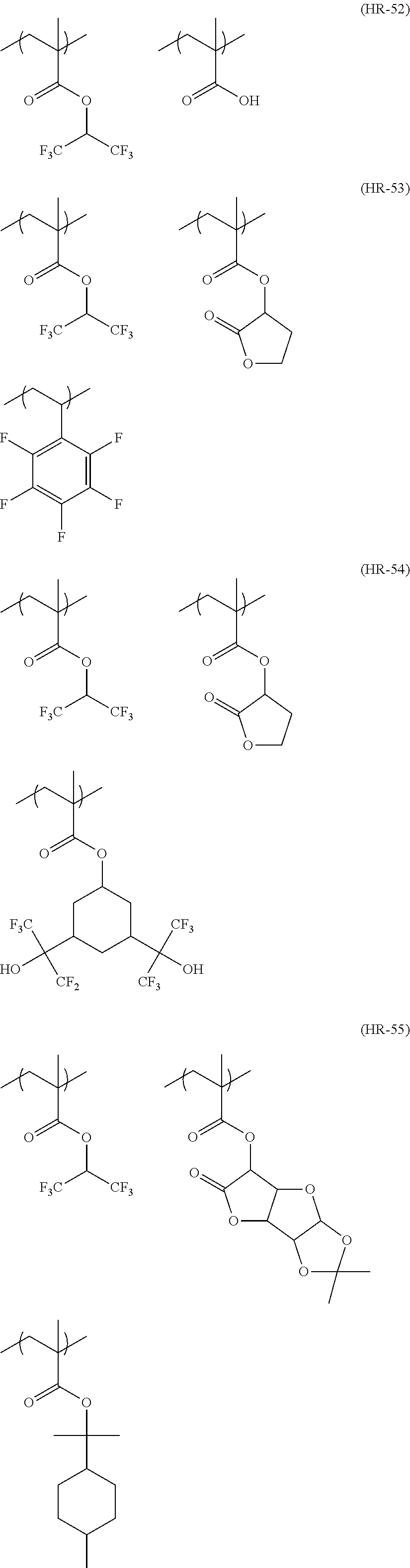

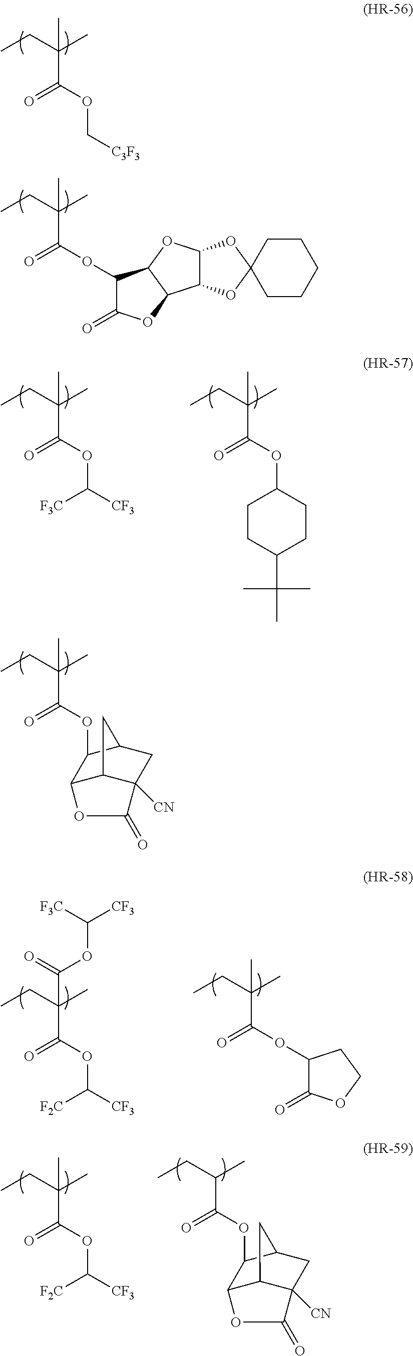

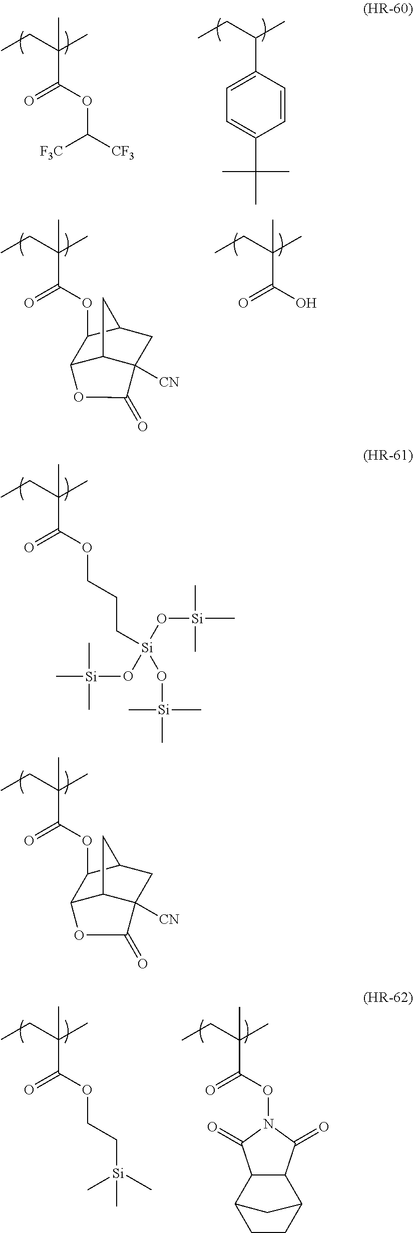

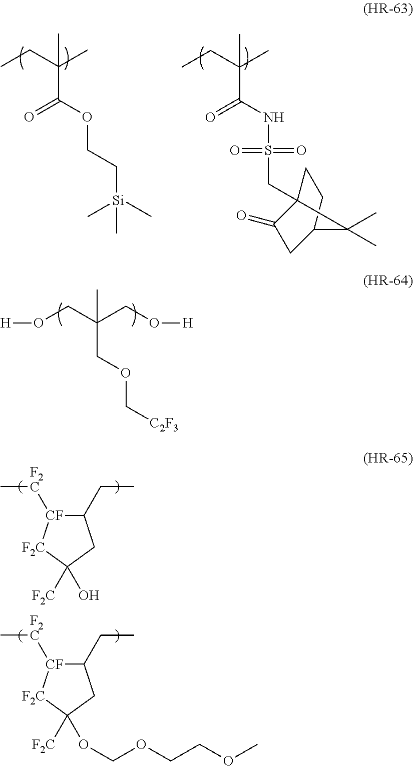

TABLE 1

| Resin | Composition | Mw | Mw/Mn |
|---|---|---|---|
| HR-1 | 50/50 | 4,900 | 1.4 |
| HR-2 | 50/50 | 5,100 | 1.6 |
| HR-3 | 50/50 | 4,800 | 1.5 |
| HR-4 | 50/50 | 5,300 | 1.6 |
| HR-5 | 50/50 | 4,500 | 1.4 |
| HR-6 | 100 | 5,500 | 1.6 |
| HR-7 | 50/50 | 5,800 | 1.9 |
| HR-8 | 50/50 | 4,200 | 1.3 |
| HR-9 | 50/50 | 5,500 | 1.8 |
| HR-10 | 40/60 | 7,500 | 1.6 |
| HR-11 | 70/30 | 6,600 | 1.8 |
| HR-12 | 40/60 | 3,900 | 1.3 |
| HR-13 | 50/50 | 9,500 | 1.8 |
| HR-14 | 50/50 | 5,300 | 1.6 |
| HR-15 | 100 | 6,200 | 1.2 |
| HR-16 | 100 | 5,600 | 1.6 |
| HR-17 | 100 | 4,400 | 1.3 |
| HR-18 | 50/50 | 4,300 | 1.3 |
| HR-19 | 50/50 | 6,500 | 1.6 |
| HR-20 | 30/70 | 6,500 | 1.5 |
| HR-21 | 50/50 | 6,000 | 1.6 |
| HR-22 | 50/50 | 3,000 | 1.2 |
| HR-23 | 50/50 | 5,000 | 1.5 |
| HR-24 | 50/50 | 4,500 | 1.4 |
| HR-25 | 30/70 | 5,000 | 1.4 |
| HR-26 | 50/50 | 5,500 | 1.6 |
| HR-27 | 50/50 | 3,500 | 1.3 |
| HR-28 | 50/50 | 6,200 | 1.4 |
| HR-29 | 50/50 | 6,500 | 1.6 |
| HR-30 | 50/50 | 6,500 | 1.6 |
| HR-31 | 50/50 | 4,500 | 1.4 |
| HR-32 | 30/70 | 5,000 | 1.6 |
| HR-33 | 30/30/40 | 6,500 | 1.8 |
| HR-34 | 50/50 | 4,000 | 1.3 |
| HR-35 | 50/50 | 6,500 | 1.7 |
| HR-36 | 50/50 | 6,000 | 1.5 |
| HR-37 | 50/50 | 5,000 | 1.6 |
| HR-38 | 50/50 | 4,000 | 1.4 |
| HR-39 | 20/80 | 6,000 | 1.4 |
| HR-40 | 50/50 | 7,000 | 1.4 |
| HR-41 | 50/50 | 6,500 | 1.6 |
| HR-42 | 50/50 | 5,200 | 1.6 |
| HR-43 | 50/50 | 6,000 | 1.4 |
| HR-44 | 70/30 | 5,500 | 1.6 |
| HR-45 | 50/20/30 | 4,200 | 1.4 |
| HR-46 | 30/70 | 7,500 | 1.6 |
| HR-47 | 40/58/2 | 4,300 | 1.4 |
| HR-48 | 50/50 | 6,800 | 1.6 |
| HR-49 | 100 | 6,500 | 1.5 |
| HR-50 | 50/50 | 6,600 | 1.6 |
| HR-51 | 30/20/50 | 6,800 | 1.7 |
| HR-52 | 95/5 | 5,900 | 1.6 |
| HR-53 | 40/30/30 | 4,500 | 1.3 |
| HR-54 | 50/30/20 | 6,500 | 1.8 |
| HR-55 | 30/40/30 | 7,000 | 1.5 |
| HR-56 | 60/40 | 5,500 | 1.7 |
| HR-57 | 40/40/20 | 4,000 | 1.3 |
| HR-58 | 60/40 | 3,800 | 1.4 |
| HR-59 | 80/20 | 7,400 | 1.6 |
| HR-60 | 40/40/15/5 | 4,800 | 1.5 |
| HR-61 | 60/40 | 5,600 | 1.5 |
| HR-62 | 50/50 | 5,900 | 2.1 |
| HR-63 | 80/20 | 7,000 | 1.7 |
| HR-64 | 100 | 5,500 | 1.8 |
| HR-65 | 50/50 | 9,500 | 1.9 |

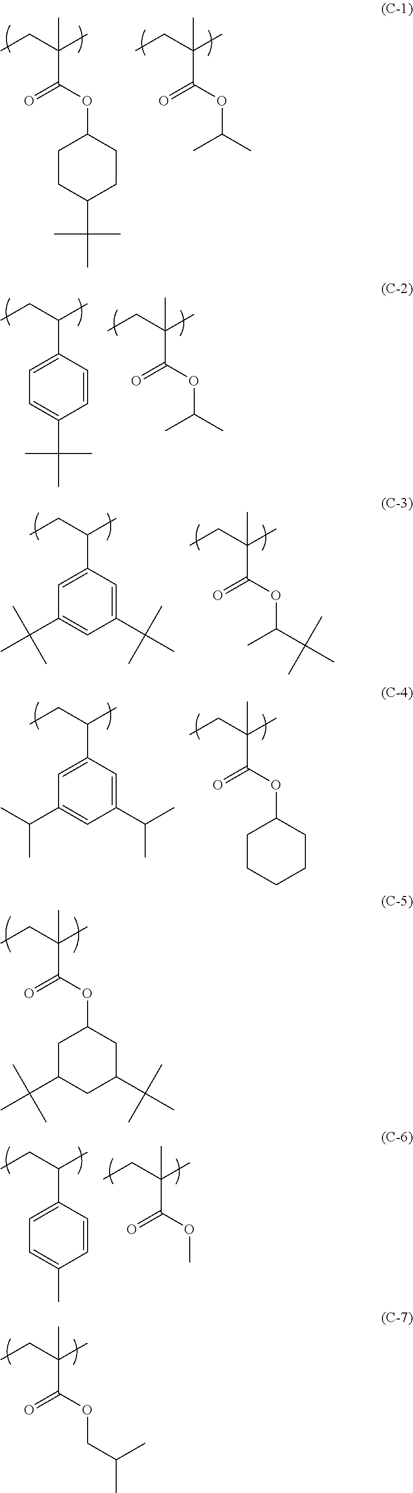

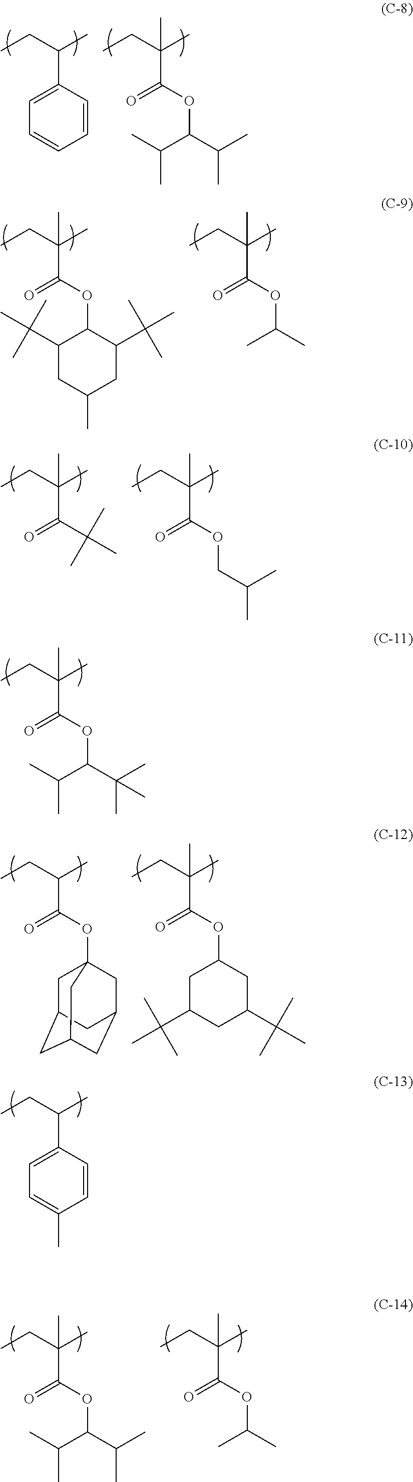

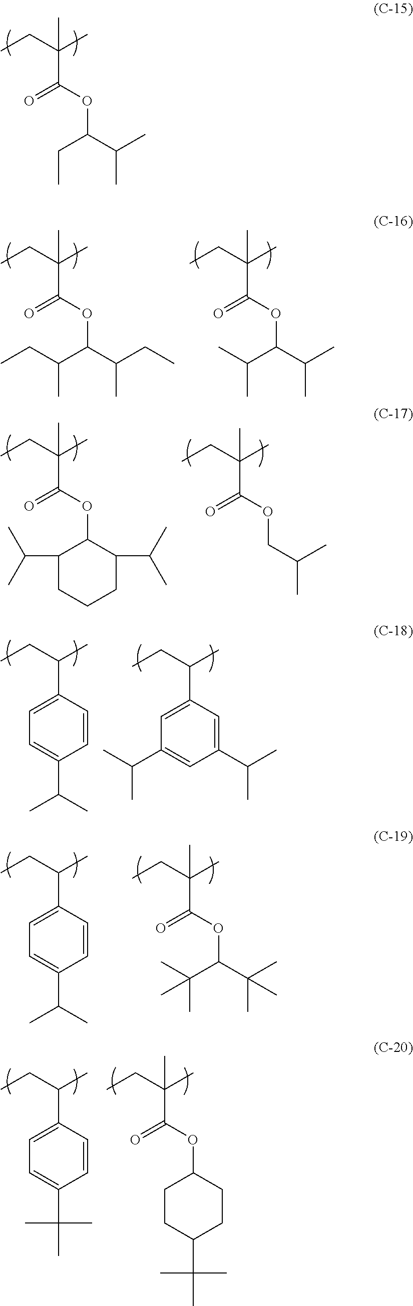

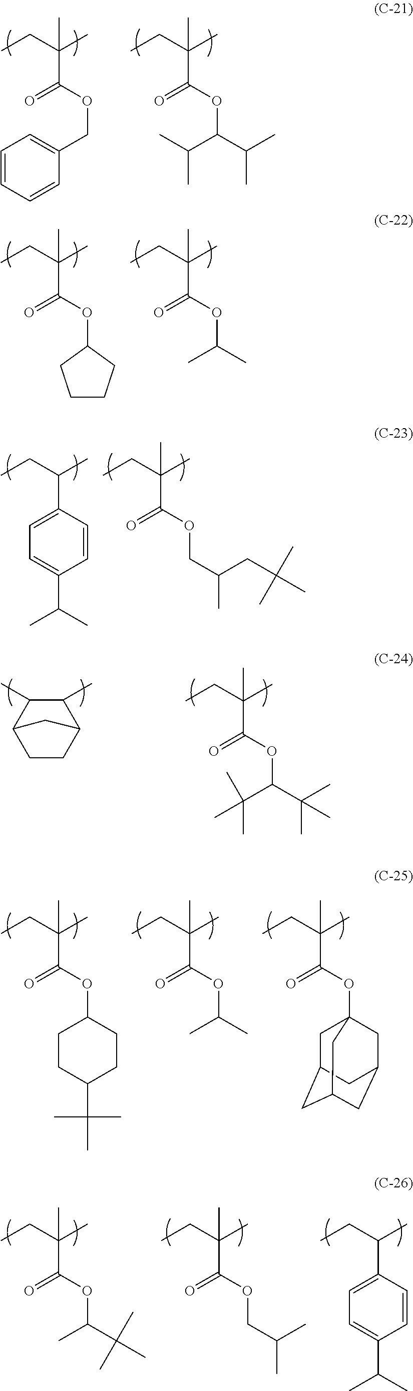

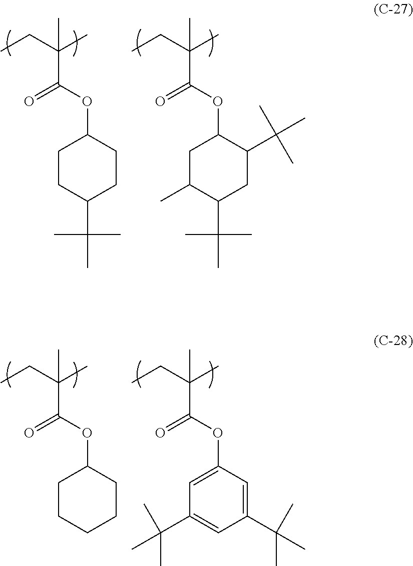

TABLE 2

| Resin | Composition | Mw | Mw/Mn |
|---|---|---|---|
| C-1 | 50/50 | 9,600 | 1.74 |
| C-2 | 60/40 | 34,500 | 1.43 |
| C-3 | 30/70 | 19,300 | 1.69 |
| C-4 | 90/10 | 26,400 | 1.41 |
| C-5 | 100 | 27,600 | 1.87 |
| C-6 | 80/20 | 4,400 | 1.96 |
| C-7 | 100 | 16,300 | 1.83 |
| C-8 | 5/95 | 24,500 | 1.79 |
| C-9 | 20/80 | 15,400 | 1.68 |
| C-10 | 50/50 | 23,800 | 1.46 |
| C-11 | 100 | 22,400 | 1.57 |
| C-12 | 10/90 | 21,600 | 1.52 |
| C-13 | 100 | 28,400 | 1.58 |
| C-14 | 50/50 | 16,700 | 1.82 |
| C-15 | 100 | 23,400 | 1.73 |
| C-16 | 60/40 | 18,600 | 1.44 |
| C-17 | 80/20 | 12,300 | 1.78 |
| C-18 | 40/60 | 18,400 | 1.58 |
| C-19 | 70/30 | 12,400 | 1.49 |
| C-20 | 50/50 | 23,500 | 1.94 |
| C-21 | 10/90 | 7,600 | 1.75 |
| C-22 | 5/95 | 14,100 | 1.39 |
| C-23 | 50/50 | 17,900 | 1.61 |
| C-24 | 10/90 | 24,600 | 1.72 |
| C-25 | 50/40/10 | 23,500 | 1.65 |
| C-26 | 60/30/10 | 13,100 | 1.51 |
| C-27 | 50/50 | 21,200 | 1.84 |
| C-28 | 10/90 | 19,500 | 1.66 |

<Surfactant>

The composition of the present invention may or may not further contain a surfactant. As the surfactant, a surfactant based on fluorine and/or silicon is preferable.

Examples of the surfactants include MEGAFACE F176 and MEGAFACE R08 manufactured by DIC Corporation, PF656 and PF6320 manufactured by OMNOVA Solutions Inc., TROYZOL S-366 manufactured by Troy Chemical Industries, FLUORAD FC430 manufactured by Sumitomo 3M Limited, a polysiloxane polymer KP-341 manufactured by Shin-Etsu Chemical Co., Ltd, and the like.

Furthermore, it is possible to use surfactants other than the surfactant based on fluorine and/or silicon. More specifically, examples of the surfactants include polyoxyethylene alkyl ethers, polyoxyethylene alkyl aryl ethers, and the like.

In addition, other known surfactants can be appropriately used. Examples of the surfactants that can be used include the surfactants described from paragraph “0273” of US2008/0248425A1. Furthermore, in view of uniformity of the thickness of the resist film, the surfactants described in JP2013-6928A can be preferably used.

One kind of surfactant may be used singly, or two or more kinds thereof may be used in combination.

The resist composition of the present invention may or may not contain a surfactant. In a case where the composition contains a surfactant, an amount of the surfactant used is, with respect to the total solid contents of the composition, preferably 0.0001% to 2% by mass, more preferably 0.0001% to 1% by mass, and particularly preferably 0.0005% to 1% by mass.

An amount of the surfactant added is preferably equal to or less than 10 ppm, or alternatively, the resist composition preferably does not contain a surfactant. If the amount of the surfactant added is as described above, due to the surface localization properties of the hydrophobic surface modification resion, it is possible to make the surface of the resist film more hydrophobic and to improve conformity to water at the time of liquid immersion exposure.

<Solvent>

The resist composition according to the present invention generally further contains a solvent.

Examples of the solvent include organic solvents such as alkylene glycol monoalkyl ether carboxylate, alkylene glycol monoalkyl ether, lactic acid alkyl ester, alkyl alkoxypropionate, cyclic lactone (preferably having 4 to 10 carbon atoms), a monoketone compound (preferably having 4 to 10 carbon atoms) which may contain a ring, alkylene carbonate, alkyl alkoxyacetate, and alkyl piruvate.

Examples of the alkylene glycol monoalkyl ether carboxylate preferably include propylene glycol monomethyl ether acetate (PGMEA, in another name, 1-methoxy-2-acetoxypropane), propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate.

Examples of the alkylene glycol monoalkyl ether preferably include propylene glycol monomethyl ether (PGME, in another name, 1-methoxy-2-propanol), propylene glycol monoethyl ether, propylene glycol monopropyl ether, propylene glycol monobutyl ether, ethylene glycol monomethyl ether, and ethylene glycol monoethyl ether.

Examples of the lactic acid alkyl ester preferably include methyl lactate, ethyl lactate, propyl lactate, and butyl lactate.

Examples of the alkyl alkoxypropionate preferably include ethyl 3-ethoxypropionate, methyl 3-methoxypropionate, methyl 3-ethoxypropionate, and ethyl 3-methoxypropionate.

Examples of the cyclic lactone preferably include β-propiolactone, β-butyrolactone, γ-butyrolactone, α-methyl-γ-butyrolactone, β-methyl-γ-butyrolactone, γ-valerolactone, γ-caprolactone, γ-octanoic lactone, and α-hydroxy-γ-butyrolactone.

Examples of the ketone compound which may contain a ring preferably include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethyl cycl ohexanone, cycloheptanone, 2-methylcycloheptanone, and 3-methylcycloheptanone.

Examples of the alkylene carbonate preferably include propylene carbonate, vinylene carbonate, ethylene carbonate, and butylene carbonate.

Examples of the alkylalkoxy acetate include 2-methoxyethyl acetate, 2-ethoxyethyl acetate, 2-(2-ethoxyethoxy)ethyl acetate, 3-methoxy-3-methyl butyl acetate, and 1-methoxy-2-propyl acetate.

Examples of the alkyl piruvate preferably include methyl piruvate, ethyl piruvate, and propyl piruvate.

Examples of solvents that can be preferably used include solvents having a boiling point of equal to or higher than 130° C. at a normal temperature under normal pressure. Specific examples thereof include cyclopentanone, γ-butyrolactone, cyclohexanone, ethyl lactate, ethylene glycol monoethyl ether acetate, propylene glycol monomethyl ether acetate, ethyl 3-ethoxypropionate, ethyl piruvate, 2-ethoxyethyl acetate, 2-(2-ethoxyethoxy)ethyl acetate, and propylene carbonate.

In the present invention, one kind of solvent described above may be used singly, or two or more kinds thereof may be used in combination.

In the present invention, as an organic solvent, a mixed solvent obtained by mixing a solvent containing a hydroxyl group in the structure with a solvent not containing a hydroxyl group may be used.

As the solvent containing a hydroxyl group and the solvent not containing a hydroxyl group can be appropriately selected from the compounds exemplified above. As the solvent containing a hydroxyl group, alkylene glycol monoalkyl ether, alkyl lactate, and the like are preferable, and propylene glycol monomethyl ether and ethyl lactate are more preferable. As the solvent not containing a hydroxyl group, alkylene glycol monoalkyl ether acetate, alkylalkoxy propionate, a monoketone compound which may contain a ring, cyclic lactone, alkyl acetate, and the like are preferable. Among these, propylene glycol monomethyl ether acetate, ethyl ethoxypropionate, 2-heptanone, γ-butyrolactone, cyclohexanone, and butyl acetate are particularly preferable, and propylene glycol monomethyl ether acetate, ethyl ethoxypropionate, and 2-heptanone are most preferable. As the solvent containing a hydroxyl group, methyl 2-hydroxyisobutyrate is also preferable.

A mixing ratio (mass) between the solvent containing a hydroxyl group and the solvent not containing a hydroxyl group is 1/99 to 99/1, preferably 10/90 to 90/10, and even more preferably 20/80 to 60/40. In view of coating uniformity, a mixed solvent containing the solvent not containing a hydroxyl group in an amount of equal to or greater than 50% by mass is particularly preferable.

It is preferable that the solvent is a mixed solvent composed of two or more kinds of solvent containing propylene glycol monomethyl ether acetate.

<Dissolution Inhibiting Compound of which Solubility in Alkaline Developer Increases by being Decomposed by the Action of Acid and which has a Molecular Weight of Equal to or Less than 3,000>

As a dissolution inhibiting compound of which the solubility in an alkaline developer increases by being decomposed by the action of an acid and which has a molecular weight of equal to or less than 3,000 (hereinafter, referred to as a “dissolution inhibiting compound” as well), an alicyclic or aliphatic compound containing an acid-decomposable group, such as a cholic acid derivative containing an acid-decomposable group described in Proceeding of SPIE, 2724, 355 (1996), is preferable, because such a compound does not deteriorate transparency at a wavelength of equal to or less than 220 nm. Examples of the acid-decomposable group and the alicyclic structure include the same acid decomposable group and the alicyclic structure as described above for the resin (A1).

In a case where the resist composition of the present invention is exposed to a KrF excimer laser or irradiated with electron beams, as the dissolution inhibiting compound, a compound is preferable which contains a structure in which a phenolic hydroxyl group of a phenol compound is substituted with an acid-decomposable group. The phenol compound preferably has 1 to 9 phenol skeletons, and more preferably has 2 to 6 phenol skeletons.

An amount of the dissolution inhibiting compound added is, with respect to solid contents of the resist composition, preferably 0.5% to 50% by mass, and more preferably 0.5% to 40% by mass.

Specific examples of the dissolution inhibiting compound will be shown below, but the present invention is not limited thereto.

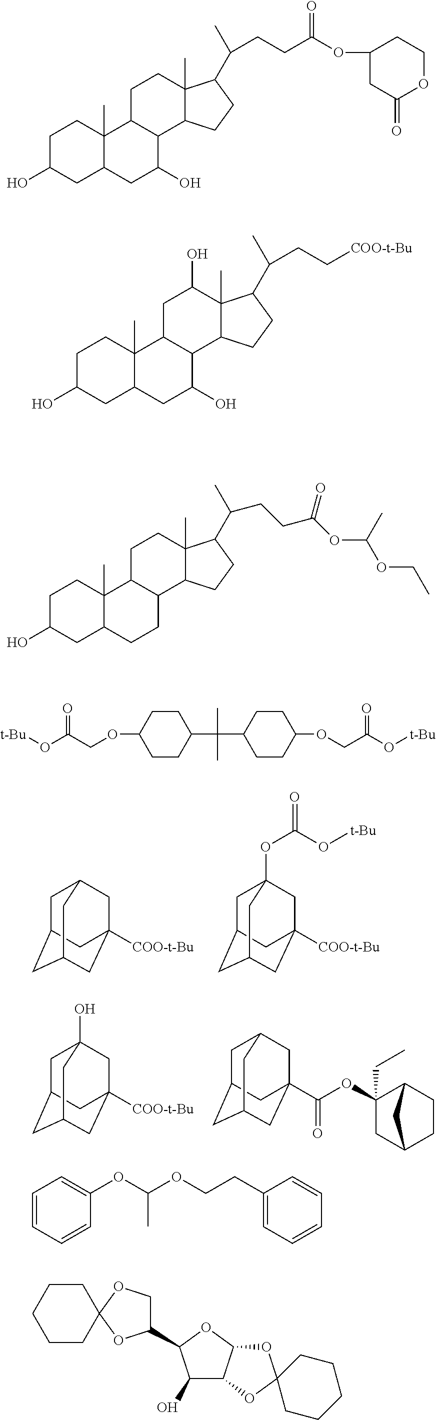

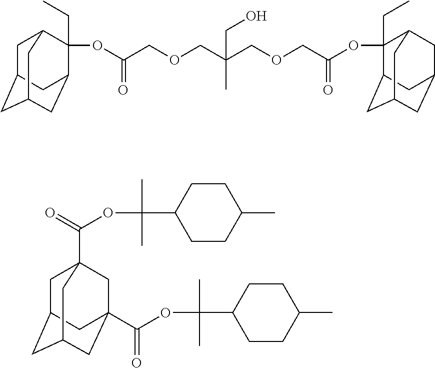 [SMILES: CCC1(OC(=O)COCC(C)(CO)COCC(=O)OC2(CC)C3CC4CC(C3)CC2C4)C2CC3CC(C2)CC1C3 ; CC1CCC(C(C)(C)OC(=O)C23CC4CC(C2)CC(C(=O)OC(C)(C)C2CCC(C)CC2)(C4)C3)CC1]

<Other Components>

If necessary, the composition of the present invention may further contain a carboxylic acid onium salt, a photosensitizer, a light absorber, a dye, a plasticizer, an acid amplifier (described in WO95/29968A, WO98/24000A, JP1996-305262A (JP-H08-305262A), JP1997-34106A (JP-H09-34106A), JP1996-248561A (JP-08-248561A), JP1996-503082A (JP-H08-503082A), U.S. Pat. No. 5,445,917A, JP1996-503081A (JP-H08-503081A), U.S. Pat. No. 5,534,393A, U.S. Pat. No. 5,395,736A, U.S. Pat. No. 5,741,630A, U.S. Pat. No. 5,334,489A, U.S. Pat. No. 5,582,956A, U.S. Pat. No. 5,578,424A, U.S. Pat. No. 5,453,345A, U.S. Pat. No. 5,445,917A, EP665960B, EP757628B, EP665961B, U.S. Pat. No. 5,667,943A, JP1998-1508A (JP-H10-1508A), JP1998-282642A (JP-H10-282642A), JP1997-512498A (JP-H09-512498A), JP2000-62337A, JP2005-17730A, JP2008-209889A, and the like), and the like. Examples of these compounds include each of the compounds described in JP2008-268935A.

The concentration of solid contents of the resist composition of the present invention is generally 4.0% to 20% by mass, preferably 5.0% to 15% by mass, and even more preferably 6.0% to 12% by mass. If the concentration of solid contents is within the above range, a substrate can be uniformly coated with a resist solution, and a resist pattern excellent in line edge roughness can be formed. The reason is unclear but is assumed to be as below. If the concentration of the solid contents is set to be equal to or less than 20% by mass and preferably set to be equal to or less than 15% by mass, a material in the resist solution, particularly, a photoacid generator is inhibited from being aggregated, and as a result, a uniform resist film can be formed.

The concentration of the solid contents is a weight percentage of a weight of resist components excluding a solvent in a total weight of the resist composition.

The composition of the present invention is used in a manner in which the aforementioned components are dissolve in a solvent, subjected to filtration using a filter, and then used for coating a support. The filter is preferably made of polytetrafluoroethylene, polyethylene, or nylon having a pore size of equal to or less than 0.1 μm, more preferably equal to or less than 0.05 μm, and even more preferably equal to or less than 0.03 μm. At the time of performing filtration using a filter, for example, as described in JP2002-62667A, circulative filtration may be performed, or different filters may be connected to each other in series for performing filtration. Furthermore, in addition to the filtration using a filter, a deaeration treatment or the like may be performed.

<Composition for Forming a Planarization Layer (a)>

Next, the composition for forming a planarization layer (a) used in the pattern forming method of the present invention will be described.

The composition for forming a planarization layer (a) is typically a composition containing a solvent, and is preferably a resin composition containing a resin and a solvent. By coating a stepped substrate with the resin composition, step portions (for example, depressions) of on the stepped substrate are filled with the resin composition, and hence a planarization layer is suitably formed.

The resin composition may contain an optional component such as a surfactant that is generally used in a resist composition or an underlayer film of a resist film, in addition to the resin and the solvent. Here, as described above, it is preferable that the resin composition does not contain one or more kinds of component selected from a resin having a thermally cross-linkable group, a photo-cross-linkable group, an acid-cross-linkable group, or a radically cross-linkable group, an acid, an acid generator, and a radical generator.

The resin contained in the resin composition is preferably a resin having an Onishi parameter of equal to or greater than 3.0, more preferably a resin having an Onishi parameter of equal to or greater than 5.0, and even more preferably a resin having an Onishi parameter of equal to or greater than 5.5.

The planarization layer preferably contains a resin having an Onishi parameter of equal to or greater than 3.0, more preferably contains a resin having an Onishi parameter of equal to or greater than 5.0, and even more preferably contains a resin having an Onishi parameter of equal to or greater than 5.5.

The aforementioned resin is generally a resin having an Onishi parameter of equal to or less than 15.

Herein, an Onishi parameter of a resin is defined as below by an Onishi parameter of a monomer corresponding to a repeating unit constituting the resin.

(Onishi parameter of monomer)=(total number of atoms)/{(number of carbon atoms) (number of oxygen atoms)}

(Onishi parameter of resin)=Σ{(ratio of monomer introduced (weight ratio))×(Onishi parameter of monomer)}

As the composition for forming a planarization layer (a), it is possible to use known composition for forming a planarization layer, composition for forming an underlayer film, and composition for forming an antireflection film.

The composition for forming a planarization layer (a) may be any of a composition mainly composed of a resin, a composition mainly composed of a low-molecular weight compound, and a mixture of a resin and a low-molecular weight compound.

Examples of the resin contained in the composition for forming a planarization layer (a) include a resin containing a (meth)acryl-based repeating unit, a resin containing a styrene-based repeating unit, a polyester-based resin, a polycarbonate-based resin, a polyvinyl alcohol-based resin, a polyether ketone-based resin, a polysiloxane-based resin, and the like.

The resin contained in the composition for forming a planarization layer (a) may be constituted by appropriately selecting each of the aforementioned repeating units exemplified above as repeating units that the resin (A) in the resist composition may have.

A content of the resin is, with respect to the total solid contents of the composition for forming a planarization layer (a), preferably 85% to 100% by mass, more preferably 90% to 100% by mass, and even more preferably 95% to 100% by mass.

Examples of the solvent that the composition for forming a planarization layer (a) contains include the aforementioned solvents for the resist composition. The solvent contained in the composition for forming a planarization layer (a) is not particularly limited, and may be an organic solvent (for example, a hydrocarbon, an alcohol, or an ether), an inorganic solvent (for example, water, a basic aqueous solution, or an acidic aqueous solution), or a mixed solvent of an organic solvent and an inorganic solvent.

The present invention also relates to a method for manufacturing an electronic device including the aforementioned pattern forming method of the present invention and an electronic device manufactured by the manufacturing method.

The electronic device of the present invention is suitably mounted on electric and electronic instruments (home appliances, OA•media-related instruments, optical instruments, communication instruments, and the like).

### EXAMPLES

Hereinafter, the present invention will be more specifically described based on examples, but the present invention is not limited to the following examples.

### Synthesis Example Synthesis of Resin (Pol-1)

Under a nitrogen stream, 61.2 parts by mass of cyclohexanone is put into a three-neck flask and heated to 80° C. Then, a mixed solution of a monomer (15.0 parts by mass) corresponding to the following unit-1, a monomer (3.54 parts by mass) corresponding to the following unit-2, a monomer (12.3 parts by mass) corresponding to the following unit-3, dimethyl 2,2′-azobisisobutyrate [V-601, manufactured by Wako Pure Chemical Industries, Ltd.] (1.38 parts by mass), and cyclohexanone (113.6 parts by mass) was added dropwise to the flask for 4 hours. After the dropwise addition ended, the reaction solution was further reacted for 2 hours at 80° C. The reaction solution was left to cool, reprecipitation was then performed using a large amount of heptane/ethyl acetate (mass ratio: 8/2), followed by filtration, and the obtained solid was dried in a vacuum, thereby obtaining 27.0 parts by mass of a resin (pol-1). The obtained resin (pol-1) had a weight-average molecular weight of 12,000 and a dispersity (Mw/Mn) of 1.7, and a compositional ratio in the resin measured by ¹³C-NMR was 40/10/50.

Resins (pol-2) to (pol-11) were synthesized by performing the same operation as in the synthesis example described above.

The following Tables 3 and 4 show the repeating units (units), compositional ratio (molar ratio), weight-average molecular weight (Mw), and dispersity of the resins (pol-1) to (pol-11). The compositional ratio correspond to each repeating unit from the left.

TABLE 3

| | | | | | Com | | |
|---|---|---|---|---|---|---|---|
| | | | | | posi- | | |
| | | | | | tional | | |
| | | | | | ratio | | Dis- |
| | | | | | (molar | | per- |
| | Unit 1 | Unit 2 | Unit 3 | Unit 4 | ratio) | Mw | sity |
| pol- 1 | 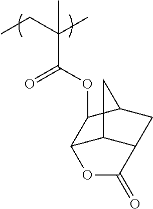 | 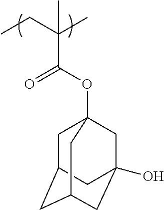 | 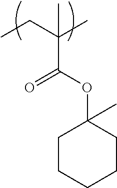 unit-3 | — | 40/10/ 50 | 12.000 | 1.7 |
| | unit-1 | unit-2 | | | | | |
| pol- 2 | 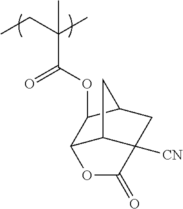 | 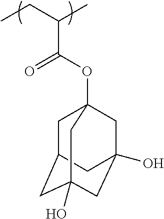 | 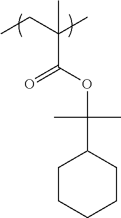 | 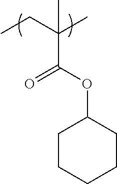 unit-7 | 30/10/ 50/10 | 8.000 | 1.6 |
| | unit-4 | unit-5 | unit-6 | | | | |
| pol- 3 | 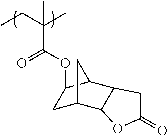 | 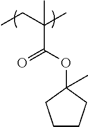 | — | — | 55/45 | 10.000 | 1.6 |
| | unit-8 | unit-9 | | | | | |
| pol- 4 | 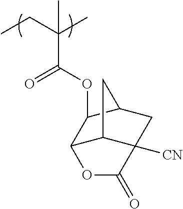 | 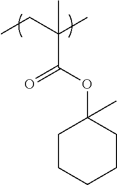 unit-3 | 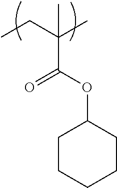 unit-7 | unit-21 (described later) | 40/30/ 10/20 | 8.000 | 1.6 |
| | unit-4 | | | | | | |
| pol- 5 | 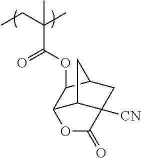 | 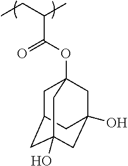 | 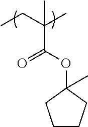 unit-9 | 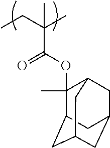 unit-10 | 40/20/ 20/20 | 16.000 | 1.8 |
| | unit-1 | unit-5 | | | | | |
| pol- 6 | 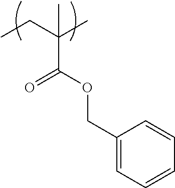 | 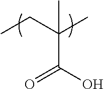 unit-12 | 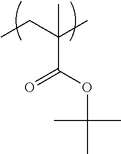 unit-13 | — | 30/10/ 60 | 20.000 | 1.9 |
| | unit-11 | | | | | | |
| pol- 7 | 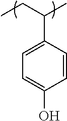 unit-14 | 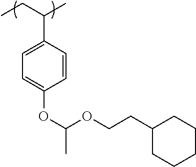 | | | 60/40 | 14.000 | 1.6 |
| | | unit-15 | | | | | |
| pol- 8 | 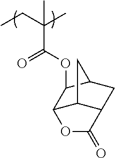 | 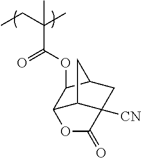 | 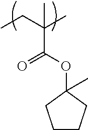 unit-9 | | 30/30/ 40 | 10.000 | 1.6 |
| | unit-1 | unit-4 | | | | | |

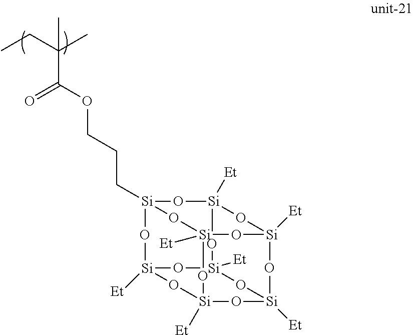

TABLE 4

| | | | | | Compositional | | |
|---|---|---|---|---|---|---|---|
| | | | | | ratio (molar | | |
| | Unit 1 | Unit 2 | Unit 3 | Unit 4 | ratio) | Mw | Dispersity |
| pol-9 | 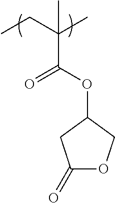 | 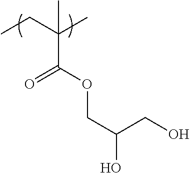 unit-17 | 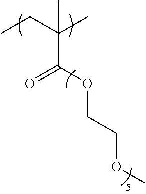 | — | 25/40/35 | 6.000 | 1.6 |
| | unit-16 | | unit-18 | | | | |
| pol-10 | 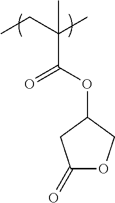 | 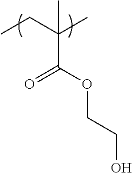 unit-19 | — | — | 30/70 | 7.000 | 1.6 |
| | unit-16 | | | | | | |
| pol-11 | 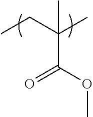 unit-20 | 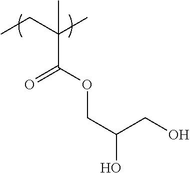 unit-17 | 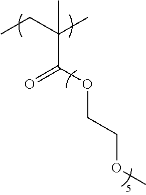 | — | 10/70/20 | 7.000 | 1.6 |
| | | | unit-18 | | | | |

The resins (pol-9) to (pol-11) contained in the resin composition forming an underlayer of Examples 1 to 10 which will be described later has an Onishi parameter of 6.5, 6.0, and 7.1 respectively.

[Preparation of Resin Composition]

The components shown in the following Table 5 were dissolved in a solvent, thereby preparing each resin solution. The resin solution was filtered through a polyethylene filter having a pore size of 0.03 μm, thereby preparing a resin composition. The concentration of solid contents of each resin composition was appropriately adjusted within a range of 2.0% to 7.0% by mass such that coating can be performed to yield a film thickness shown in the following Tables 6 and 7.

TABLE 5

| | | Acid | Basic | | Cross- | |
|---|---|---|---|---|---|---|
| Resin | Resin | generator | compound | Additive | linking agent | Solvent |
| composition | (% by mass) | (% by mass) | (% by mass) | (% by mass) | (% by mass) | (mass ratio) |
| R-1 | pol-1(96.1) | PAG-1(3.0) | N-1(0.50) | W-1(0.40) | — | SL-1/SL-2(70/30) |
| R-2 | pol-2(95.3) | PAG-1(4.0) | N-2(0.40) | W-1(0.30) | — | SL-1(100) |
| R-3 | pol-3(94.3) | PAG-2(5.0) | N-3(0.40) | W-1(0.30) | — | SL-1/SL-3(90/10) |
| R-4 | pol-4(97.3) | PAG-2(2.0) | N-4(0.30) | W-1(0.40) | — | SL-1/SL-4(95/5) |
| R-5 | pol-5(95.8) | PAG-1(3.0) | N-4(0.90) | W-2(0.30) | — | SL-1/SL-2(20/80) |
| R-6 | pol-6(96.2) | PAG-1(3.0) | N-2(0.80) | — | — | SL-1/SL-2(50/50) |
| R-7 | pol-7(95.7) | PAG-1(3.0) | N-3(1.0) | W-3(0.30) | — | SL-1/SL-2(20/80) |
| R-8 | pol-8(95.0) | PAG-3(4.0) | N-1(0.70) | W-1(0.30) | — | SL-1/SL-2(50/50) |
| R-9 | pol-9(99.7) | — | — | W-1(0.30) | — | SL-3(100) |
| R-10 | pol-10(99.2) | — | N-1(0.5) | W-1(0.30) | — | SL-3/SL-4(90/10) |
| R-11 | pol-11(97.7) | PAG-1(2.0) | — | W-1(0.30) | — | SL-5(100) |
| R-12 | pol-10(80.0) | TAG-1(1.0) | — | W-1(0.30) | CR-1(18.7) | SL-1(100) |

* In the table, (% by mass) is a value with respect to the total solid contents of the composition.

The component and abbreviation in Table 5 are as below.

### [Acid Generator]

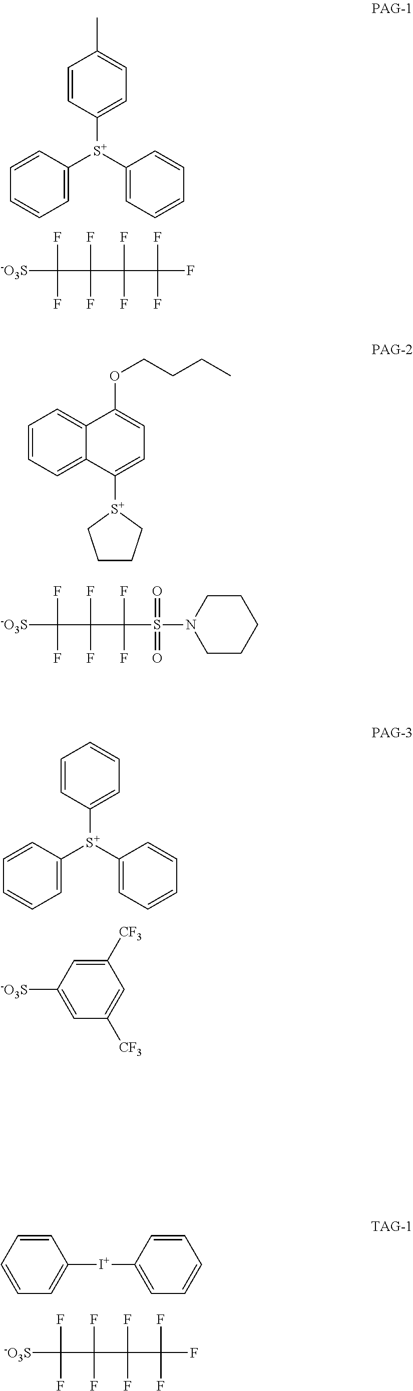

[Basic Compound]

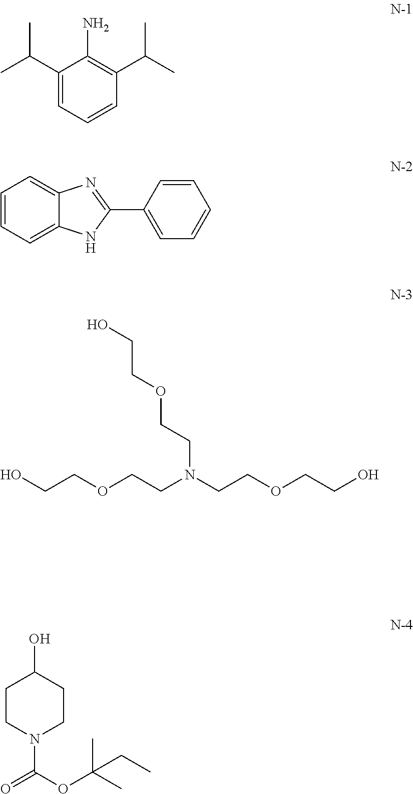 [SMILES: CC(C)c1cccc(C(C)C)c1N ; c1ccc(-c2nc3ccccc3[nH]2)cc1 ; OCCOCCN(CCOCCO)CCOCCO ; CCC(C)(C)OC(=O)N1CCC(O)CC1]

[Additive (Surfactant)]

W-1: MEGAFACE F176 (manufactured by DIC CORPORATION; based on fluorine)

W-2: MEGAFACE R08 (manufactured by DIC CORPORATION; based on fluorine and silicon)

W-3: polysiloxane polymer KP-341 (manufactured by Shin-Etsu Chemical Co., Ltd.; based on silicon)

[Solvent]
SL-1: propylene glycol monomethyl ether acetate (PGMEA)
SL-2: propylene glycol monomethyl ether (PGME)
SL-3: cyclohexanone
SL-4: γ-butyrolactone
SL-5: pure water

[Cross-Linking Agent]

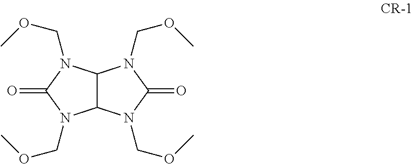

The prepared resin composition was evaluated by the following methods.

### [ArF Exposure Example] (Examples 1 to 7 and Comparative Examples 1 to 3)

A stepped substrate having a shape in which cubical structures each having a side of 80 nm were disposed at an equal interval at a pitch of 100 nm (that is, a shape in which groove portions having a groove width of 20 nm are provided to become orthogonal to each other) was coated with a first resin composition shown in the following Table 6, followed by baking (Pre Bake; PB1) under the conditions shown in the following Table 6, thereby forming an underlayer film having a film thickness shown in the following Table 6. The film thickness of the formed film is a height from the bottom of the step (that is, the bottom surface of the stepped substrate) to the surface of the underlayer film. Then, the obtained underlayer film was coated with a second resin composition, followed by pre-heating (Pre Bake; PB2) under the conditions shown in the following Table 6, thereby forming a resist film as a second layer (upper layer) having a film thickness shown in the following Table 6. In this way, a wafer in which films composed of two kinds of resin composition were layered was obtained. In Table 6, in a case where the second resin composition was not used, the process moved on to the next step in a state where the underlayer film was formed.

The obtained wafer was pattern-wise exposed by using an ArF excimer laser scanner (manufactured by ASML, PAS 5500/1100) (NA: 0.75) through a half tone mask having a line-and-space pattern having a width of light blocking portion of 110 nm and a width of an opening portion of 110 nm. Then, the wafer was baked (Post Exposure Bake; PEB) under the conditions shown in the following Table 6, then developed in a puddle for 30 seconds by using a developer shown in the following Table 6, and rinsed in a puddle by using a rinsing liquid shown in the following Table 6 (here, in a case where a rinsing liquid is not described in the following table, it means that the sample was not rinsed). Thereafter, the wafer was spun for 30 seconds at a rotation speed of 4,000 rpm, thereby obtaining a line-and-space (1:1) pattern having a pitch of 220 nm and a line width of 110 nm.

### [KrF Exposure Example] (Examples 8 to 10 and Comparative Examples 4 and 5)

A stepped substrate having a shape in which cubical structures each having a side of 80 nm were disposed at an equal interval at a pitch of 100 nm (that is, a shape in which groove portions having a groove width of 20 nm are provided to become orthogonal to each other) was coated with a first resin composition shown in the following Table 7, followed by baking (Pre Bake; PB1) under the conditions shown in the following Table 7, thereby forming an underlayer film having a film thickness shown in the following Table 7. The film thickness of the formed film is a height from the bottom of the step (that is, the bottom surface of the stepped substrate) to the surface of the underlayer film. Then, the obtained underlayer film was coated with a second resin composition, followed by pre-heating (Pre Bake; PB2) under the conditions shown in the following Table 7, thereby forming a resist film as a second layer (upper layer) having a film thickness shown in the following Table 7. In this way, a wafer in which films composed of two kinds of resin composition were layered was obtained. In Table 7, in a case where the second resin composition was not used, the process moved on to the next step in a state where the underlayer film was formed.

The obtained wafer was pattern-wise exposed by using a KrF excimer laser scanner (manufactured by ASML, PAS 5500/850) (NA: 0.80) through a half tone mask having a line-and-space pattern having a width of light blocking portion of 150 nm and a width of an opening portion of 150 nm. Then, the wafer was baked (Post Exposure Bake; PEB) under the conditions shown in the following Table 7, then developed in a puddle for 30 seconds by using a developer shown in the following Table 7, and rinsed in a puddle by using a rinsing liquid shown in the following Table 7 (here, in a case where a rinsing liquid is not described in the following table, it means that the sample was not rinsed). Thereafter, the wafer was spun for 30 seconds at a rotation frequency of 4,000 rpm, thereby obtaining a line-and-space (1:1) pattern having a pitch of 300 nm and a line width of 150 nm.

[Method for Evaluating Resolution]

By using a scanning electron microscope (SEM manufactured by Hitachi, Ltd., S-9380II), the obtained line-and-space pattern was observed. In a case where pattern collapse did not occur, and no residue was observed in the resist space portion, the resolution was evaluated to be “excellent”, and in a case where pattern collapse occurred, or a residue was clearly observed in the resist space portion, the resolution was evaluated to be “poor”.

[Method for Evaluating Peeling Properties of Underlayer Film]

Each of the obtained line-and-space patterns was subjected to puddling for 30 seconds by using the same solvent as in the first resist composition used for forming an underlayer film in the formation of a pattern, thereby performing a treatment for peeling the underlayer film. By using a scanning electron microscope (SEM manufactured by Hitachi, Ltd., S-9380II), the pattern having undergone the treatment was observed. In a case where a no residue was observed in a void portion of the stepped substrate, the peeling properties were evaluated to be “excellent”, and in a case where a residue is clearly observed, the peeling properties were evaluated to be “poor”.

The following Tables 6 and 7 show the result of the ArF exposure example and the KrF exposure example. In the following tables, a description of “100° C./60 sec” means that the wafer was heated to 100° C. for 60 seconds. The abbreviations of the developer and the rinsing liquid in the following tables are as below.

[Developer•Rinsing Liquid]
D-1: butyl acetate
D-2: 2-pentanone
D-3: 2.38% by mass aqueous tetramethylammonium hydroxide solution
D-4: 4-methyl-2-pentanol
D-5: pure water

TABLE 6

| | Conditions for forming | | | Conditions for forming | | | | | | | Result of performance | |
|---|---|---|---|---|---|---|---|---|---|---|---|---|
| | underlayer | | | upper layer | | | | Development | | | evaluation | |
| | Resin | | Film | Resin | | Film | | Develop- | | | | Peeling |
| | compo- | | thick- | compo- | | thick- | | ment | Devel- | Rinsing | Resolu- | proper- |
| | sition | PB1 | ness/nm | sition | PB2 | ness/nm | PEB | type | oper | liquid | tion | ties |
| Example 1 | R-9 | 100° C./ | 100 | R-1 | 130° C./ | 180 | 110° C./ | Negative | D-1 | — | Excellent | Excellent |
| | | 60 sec | | | 60 sec | | 60 sec | | | | | |
| Example 2 | R-9 | 90° C./ | 120 | R-2 | 110° C./ | 200 | 100° C./ | Negative | D-1 | D-4 | Excellent | Excellent |
| | | 60 sec | | | 60 sec | | 60 sec | | | | | |
| Example 3 | R-9 | 100° C./ | 90 | R-3 | 100° C./ | 130 | 110° C./ | Negative | D-2 | D-4 | Excellent | Excellent |
| | | 90 sec | | | 60 sec | | 60 sec | | | | | |
| Example 4 | R-10 | 100° C./ | 80 | R-4 | 90° C./ | 150 | 130° C./ | Negative | D-1 | D-4 | Excellent | Excellent |
| | | 60 sec | | | 60 sec | | 60 sec | | | | | |
| Example 5 | R-11 | 80° C./ | 100 | R-5 | 100° C./ | 100 | 100° C./ | Negative | D-1 | — | Excellent | Excellent |
| | | 60 sec | | | 90 sec | | 90 sec | | | | | |
| Example 6 | R-9 | 130° C./ | 150 | R-1 | 100° C./ | 200 | 80° C./ | Positive | D-3 | D-5 | Excellent | Excellent |
| | | 60 sec | | | 60 sec | | 60 sec | | | | | |
| Example 7 | R-10 | 110° C./ | 100 | R-3 | 80° C./ | 80 | 130° C./ | Positive | D-3 | D-5 | Excellent | Excellent |
| | | 60 sec | | | 60 sec | | 60 sec | | | | | |
| Comparative | R-1 | 100° C./ | 150 | — | — | — | 110° C./ | Negative | D-1 | — | Poor | Excellent |
| Example 1 | | 60 sec | | | | | 60 sec | | | | (collapse) | |
| Comparative | R-3 | 120° C./ | 180 | — | — | — | 110° C./ | Positive | D-3 | D-5 | Poor | Excellent |
| Example 2 | | 60 sec | | | | | 60 sec | | | | (residue) | |
| Comparative | R-12 | 180° C./ | 100 | R-1 | 110° C./ | 120 | 110° C./ | Negative | D-2 | D-4 | Excellent | Poor |
| Example 3 | | 60 sec | | | 60 sec | | 60 sec | | | | | |

As is evident from Table 6 showing the results regarding the ArF exposure example, in Comparative Examples 1 and 2 in which the pattern was formed using a single-layered resist film, pattern collapse or a residue was observed. Therefore, it is understood that Comparative Examples 1 and 2 are poor in terms of the resolution on the stepped substrate. Furthermore, it is understood that Comparative Example 3 in which the underlayer was formed using a cross-linkable film is poor in terms of the peeling properties of the underlayer.

In contrast, it is understood that, in Examples 1 to 7 in which the underlayer was formed using a non-cross-linkable film and the resist film was formed thereon, both of the resolution on the stepped substrate and the peeling properties of the underlayer are excellent. Therefore, by performing, for example, an etching treatment on the underlayer by using the resist pattern formed from the upper layer as a mask, a high-resolution resist pattern can be formed on the stepped substrate. Furthermore, in the step of peeling the resist pattern, the peeling properties can become excellent.

When the underlayer in Examples 1 to 7 was dipped into the developer (temperature measured using a QCM sensor: 25° C.) used in each example for 1,000 seconds in the “ArF exposure example” described above, the average dissolution rate (planarization layer reduction rate) was less than 0.01 nm/sec in all of the examples.

In addition, when the underlayer in Examples 1 to 7 was dipped into the same solvent (temperature measured using a QCM sensor: 25° C.) as the solvent of the first resin composition for 1,000 seconds in the “Method for evaluating peeling properties of underlayer film” described above, the average dissolution rate (planarization layer reduction rate) was equal to or greater than 10 nm/sec in all of the examples, but the dissolution rate of the underlayer in Comparative Example 3 was less than 0.1 nm/sec.

TABLE 7

| | Conditions for forming | | | Conditions for forming | | | | | | | Results of performance | |
|---|---|---|---|---|---|---|---|---|---|---|---|---|
| | underlayer | | | upper layer | | | | Development | | | evaluation | |
| | Resin | | Film | Resin | | Film | | Develop- | | | | Peeling |
| | compo- | | thick- | compo- | | thick- | | ment | Devel- | Rinsing | Resolu- | proper- |
| | sition | PB1 | ness/nm | sition | PB2 | ness/nm | PEB | type | oper | liquid | tion | ties |
| Example 8 | R-9 | 100° C./ | 100 | R-6 | 110° C./ | 200 | 100° C./ | Negative | D-1 | D-4 | Excellent | Excellent |
| | | 60 sec | | | 60 sec | | 60 sec | | | | | |
| Example 9 | R-10 | 90° C./ | 120 | R-7 | 100° C./ | 150 | 130° C./ | Positive | D-3 | D-5 | Excellent | Excellent |
| | | 60 sec | | | 60 sec | | 60 sec | | | | | |
| Example 10 | R-11 | 110° C./ | 100 | R-8 | 100° C./ | 100 | 100° C./ | Negative | D-1 | — | Excellent | Excellent |
| | | 60 sec | | | 90 sec | | 90 sec | | | | | |
| Comparative | R-9 | 120° C./ | 200 | — | — | — | 120° C./ | Negative | D-1 | D-4 | Poor | Excellent |
| Example 4 | | 60 sec | | | | | 60 sec | | | | (collapse) | |
| Comparative | R-12 | 180° C./ | 150 | R-6 | 110° C./ | 120 | 110° C./ | Negative | D-2 | D-4 | Excellent | Poor |
| Example 5 | | 60 sec | | | 60 sec | | 60 sec | | | | | |

As is evident from Table 7 showing the results regarding the KrF exposure example, in Comparative Example 4 in which the pattern was formed using a single-layered resist film, pattern collapse was observed. Therefore, it is understood that Comparative Example 4 is poor in terms of the resolution on the stepped substrate. Furthermore, it is understood that Comparative Example 5 in which the underlayer was formed using a cross-linkable film is poor in terms of the peeling properties of the underlayer. In contrast, it is understood that, in Examples 8 to 10 in which the underlayer was formed using a non-cross-linkable film and the resist film was formed thereon, both of the resolution on the stepped substrate and the peeling properties of the underlayer are excellent. Therefore, by performing, for example, an etching treatment on the underlayer by using the resist pattern formed from the upper layer as a mask, a high-resolution resist pattern can be formed on the stepped substrate. Furthermore, in the step of peeling the resist pattern, the peeling properties can become excellent.

When the underlayer in Examples 8 to 10 was dipped into the developer (temperature measured using a QCM sensor: 25° C.) used in each example for 1,000 seconds in the “KrF exposure example” described above, the average dissolution rate (planarization layer reduction rate) was less than 0.01 nm/sec in all of the examples.

In addition, when the underlayer in Examples 8 to 10 was dipped into the same solvent (temperature measured using a QCM sensor: 25° C.) as the solvent of the first resin composition for 1,000 seconds in the “Method for evaluating peeling properties of underlayer film” described above, the average dissolution rate (planarization layer reduction rate) was equal to or greater than 10 nm/sec in all of the examples, but the dissolution rate of the underlayer in Comparative Example 5 was less than 0.1 nm/sec.

According to the present invention, it is possible to provide a pattern forming method, which makes it possible to form a high-resolution resist pattern on a ultrafine stepped substrate (for example, a stepped substrate having groove portions having a groove width of equal to or less than 40 nm and cylindrical depressions having a diameter of equal to or less than 40 nm) and to make the resist pattern exhibit excellent peeling properties in a resist pattern peeling step, a method for manufacturing an electronic device using the pattern forming method, and an electronic device.

Although the present invention has been described in detail with reference to specific embodiments, those in the related art clearly know that the present invention can be changed or modified in various ways without departing from the gist and scope of the present invention.

The present application claims priority based on JP2014-169674 field on Aug. 22, 2014, the content of which is incorporated herein by reference.

### EXPLANATION OF REFERENCES

51: stepped substrate
52: resist film
53: resist film having undergone exposure
54: first pattern
61: mask
71: actinic rays or radiation
75: etching gas
81: planarization layer
82: second pattern

What is claimed is:

1. A pattern forming method comprising:
(A) a step of forming a planarization layer on a stepped substrate by using a composition (a) for forming the planarization layer, the composition (a) containing a solvent;
(B) a step of forming a resist film on the planarization layer by using a resist composition;
(C) a step of subjecting the resist film to exposure; and
(D) a step of forming a first pattern by developing the resist film having undergone exposure,
wherein the planarization layer having undergone the step (D) is dissolved in the solvent.

2. The pattern forming method according to claim 1,
wherein the composition (a) does not contain a compound that causes a reaction triggered by at least either heat or light.

3. The pattern forming method according to claim 1,
wherein the planarization layer is substantially not developed by the step (D).

4. The pattern forming method according to claim 1,
wherein the step (D) is a step of forming a positive pattern as the first pattern by using an alkaline developer.

5. The pattern forming method according to claim 1,
wherein the step (D) is a step of forming a negative pattern as the first pattern by using a developer containing an organic solvent.

6. The pattern forming method according to claim 1,
wherein the planarization layer is a layer containing a resin having an Onishi parameter of equal to or greater than 3.0.

7. The pattern forming method according to claim 1,
wherein the first pattern contains a silicon atom.

8. The pattern forming method according to claim 1,
wherein the exposure in the step (C) is exposure performed using a KrF excimer laser.

9. The pattern forming method according to claim 1,
wherein the exposure in the step (C) is exposure performed using an ArF excimer laser.

10. The pattern forming method according to claim 1, further comprising:
(E) a step of forming a second pattern by performing an etching treatment on the planarization layer by using the first pattern as a mask, after the step (D).

11. A method for manufacturing an electronic device, comprising:
the pattern forming method according to claim 1.
